(19) United States
(12) Patent Application Publication
(10) Pub. No.: US 2026/0123169 A1
(43) Pub. Date: Apr. 30, 2026

(54) COMPOSITION FOR ORGANIC LIGHT EMITTING DEVICE AND ORGANIC LIGHT EMITTING DEVICE COMPRISING THE SAME

(71) Applicant: LG CHEM, LTD., Seoul (KR)

(72) Inventors: Young Seok KIM, Daejeon (KR); Miyeon HAN, Daejeon (KR); Min Woo JUNG, Daejeon (KR); Jun Hyoung PARK, Daejeon (KR); Joongsuk OH, Daejeon (KR); Hoon Jun KIM, Daejeon (KR); Hye Min CHO, Daejeon (KR); Hojung LEE, Daejeon (KR); Soyeon KIM, Daejeon (KR); Hyungjin PARK, Daejeon (KR); Jeonghoe HEO, Daejeon (KR)

(21) Appl. No.: 19/339,076

(22) Filed: Sep. 24, 2025

(30) Foreign Application Priority Data
Oct. 29, 2024 (KR) 10-2024-0149673

(51) Int. Cl. H10K 50/11; H10K 50/15; H10K 50/16; H10K 50/17; H10K 50/18; H10K 85/30; H10K 85/60

(52) U.S. Cl. CPC H10K 50/11; H10K 85/342; H10K 85/615; H10K 85/654; H10K 85/6572; H10K 85/6574; H10K 85/6576; H10K 50/15; H10K 50/16; H10K 50/171; H10K 50/181

(57) ABSTRACT

A composition for an organic light emitting device and an organic light emitting device including the same. The composition includes a first compound represented by the following Chemical Formula 1 and a second compound represented by the following Chemical Formula 2:

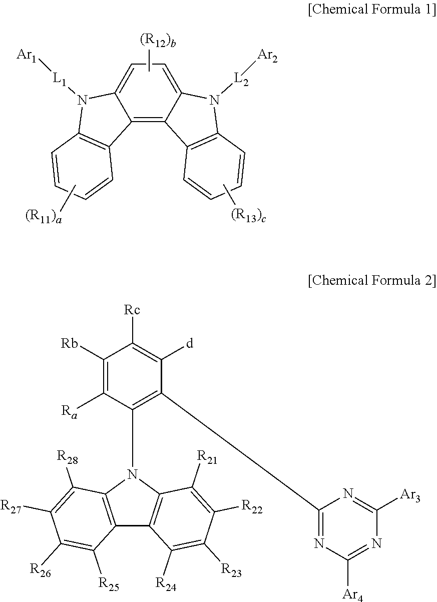

where the substituents are as defined in the specification. Organic light emitting devices including the composition exhibited excellent efficiency, driving voltage, and lifetime characteristics.

### CROSS-REFERENCE TO RELATED APPLICATION

This application claims priority to and the benefit of Korean Patent Application No. 10-2024-0149673 filed with the Korean Intellectual Property Office on Oct. 29, 2024, the entire contents of which are incorporated herein by reference.

### TECHNICAL FIELD

The present disclosure relates to a composition for an organic light-emitting device and an organic light-emitting device comprising the same.

### BACKGROUND ART

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer can be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

There is a continuous need to develop a new material for the organic material used in the organic light emitting device as described above.

### PRIOR ART LITERATURE

### Patent Literature

(Patent Literature 0001) Korean Unexamined Patent Publication No. 10-2000-0051826

### DETAILED DESCRIPTION OF THE INVENTION

### Technical Problem

It is an object of the present disclosure to provide a composition for an organic light emitting device including two types of compounds, which are included in an organic material layer of an organic light-emitting device and can improve the efficiency and lifetime characteristics of the organic light-emitting device.

In addition, it is an object of the present disclosure to provide an organic light emitting device including the composition for the organic light emitting device.

Furthermore, it is an object of the present disclosure to provide an organic light-emitting device including the above two types of compounds.

### Technical Solution

According to the present disclosure, there is provided a composition for an organic light emitting device comprising a first compound represented by the following Chemical Formula 1 and a second compound represented by the following Chemical Formula 2:

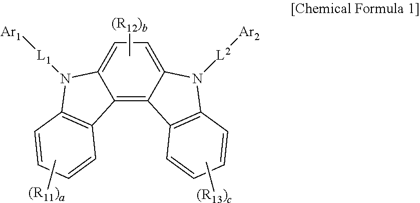

wherein in the Chemical Formula 1,
Ar₁ and Ar₂ are each independently a substituted or unsubstituted C₆₋₆₀ aryl; or a substituted or unsubstituted C₂₋₆₀ heteroaryl containing any one or more selected from the group consisting of N, O and S,
L₁ and L₂ are each independently a single bond; or a substituted or unsubstituted C₆₋₆₀ arylene,
R₁₁, R₁₂ and R₁₃ are each independently deuterium,
a and c are each independently an integer of 0 to 4,
b is an integer of 0 to 2, and

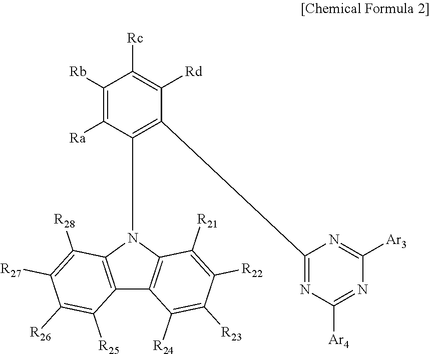

wherein in Chemical Formula 2,
Ar₃ and Ar₄ are each independently a substituted or unsubstituted C₆₋₁₅ aryl,

Rₐ and R_{d} are each independently hydrogen; deuterium; or a substituted or unsubstituted C₆₋₆₀ aryl,
R_{b} is hydrogen or deuterium,
R_{c} is hydrogen; deuterium; or a C₆₋₆₀ aryl unsubstituted or substituted with deuterium,
R₂₁ to R₂₈ are each independently hydrogen; deuterium; or a substituted or unsubstituted C₆₋₆₀ aryl, provided that at least one of R₂₁ to R₂₈ is deuterium or a C₆₋₆₀ aryl substituted with deuterium, and
the second compound is substituted with six or more deuteriums.

According to another aspect of the present disclosure, there is provided an organic light emitting device comprising: an anode, a cathode, and one or more organic material layers provided between the anode and the cathode, wherein one or more layers of the organic material layers comprise the composition for the organic light emitting device.

According to another aspect of the present disclosure, there is provided an organic light emitting device comprising: an anode, a cathode, and a light emitting layer interposed between the anode and the cathode, wherein the light emitting layer comprises a first compound represented by the following Chemical Formula 1 and a second compound represented by the following Chemical Formula 2:

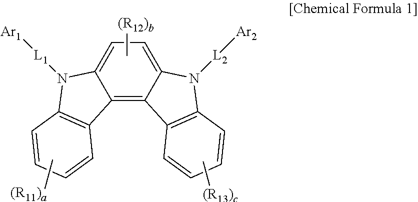

wherein in the Chemical Formula 1,
An and Ar₂ are each independently a substituted or unsubstituted C₆₋₆₀ aryl; or a substituted or unsubstituted C₂₋₆₀ heteroaryl containing any one or more selected from the group consisting of N, O and S,
L₁ and L₂ are each independently a single bond; or a substituted or unsubstituted C₆₋₆₀ arylene,
R₁₁, R₁₂ and R₁₃ are each independently deuterium,
a and c are each independently an integer of 0 to 4,
b is an integer of 0 to 2, and

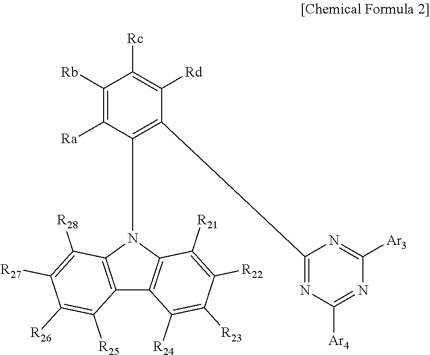

wherein in Chemical Formula 2,
Ar₃ and Ar₄ are each independently a substituted or unsubstituted C₆₋₁₅ aryl,
Rₐ and R_{d} are each independently hydrogen; deuterium; or a substituted or unsubstituted C₆₋₆₀ aryl,
R_{b} is hydrogen or deuterium,
R_{c} is hydrogen; deuterium; or a C₆₋₆₀ aryl unsubstituted or substituted with deuterium,
R₂₁ to R₂₈ are each independently hydrogen; deuterium; or a substituted or unsubstituted C₆₋₆₀ aryl, provided that at least one of R₂₁ to R₂₈ is deuterium or a C₆₋₆₀ aryl substituted with deuterium, and
the second compound is substituted with six or more deuteriums.

### Advantageous Effects

The above-mentioned composition for an organic light emitting device can improve efficiency, driving voltage, and/or lifetime characteristics of the organic light emitting device by comprising two kind of host compounds having specific structures.

### BRIEF DESCRIPTION OF THE DRAWINGS

FIG. 1 shows an example of an organic light emitting device comprising a substrate 1, an anode 2, a light emitting layer 3, and a cathode 4.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron injection and transport layer 9, and a cathode 4.

### DETAILED DESCRIPTION OF THE EMBODIMENTS

Hereinafter, embodiments of the present disclosure will be described in more detail to facilitate understanding of the invention.

### DEFINITION OF TERMS

As used herein, the notation

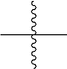

or [symbol] means a bond linked to another substituent group.

In the present disclosure, the term “substituted or unsubstituted” means being unsubstituted or substituted with one or more substituents selected from the group consisting of deuterium; a halogen group; a cyano group; a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and a heterocyclic group containing at least one of N, O and S atoms, or being unsubstituted or substituted with a substituent group to which two or more substituent groups of the above-exemplified substituent groups are linked. For example, “a substituent in which two or more substituents are linked” can be a biphenylyl group. Namely, a biphenylyl group can be an aryl group, or it can be interpreted as a substituent formed by linking two phenyl groups. In one example, the term “substituted or unsubstituted” can be understood as meaning “being unsubstituted or substituted with one or more substituents selected from the group consisting of deuterium, halogen, cyano, a silyl group, a C₁₋₁₀ alkyl, a C₁₋₁₀ alkoxy and a C₆₋₂₀ aryl”, or “being unsubstituted or substituted with one or more substituents selected from the group consisting of deuterium, halogen, cyano, methyl, ethyl, phenyl, biphenylyl and naphthyl”. Further, the term “substituted with one or more substituents” as used herein can be understood as meaning “being substituted with mono to the maximum number of substitutable hydrogens”. Alternatively, the term “substituted with one or more substituents” as used herein can be understood as meaning “being substituted with 1 to 5 substituents”, or “being substituted with one or two substituents”.

In the present disclosure, the carbon number of a carbonyl group is not particularly limited, but is preferably 1 to 40. Specifically, the carbonyl group can be a substituent having the following structural formulas, but is not limited thereto.

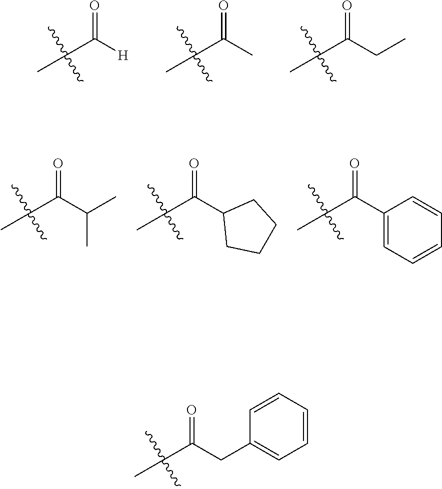

In the present disclosure, an ester group can have a structure in which oxygen of the ester group can be substituted by a straight-chain, branched-chain, or cyclic alkyl group having 1 to 25 carbon atoms, or an aryl group having 6 to 25 carbon atoms. Specifically, the ester group can be a substituent having the following structural formulas, but is not limited thereto.

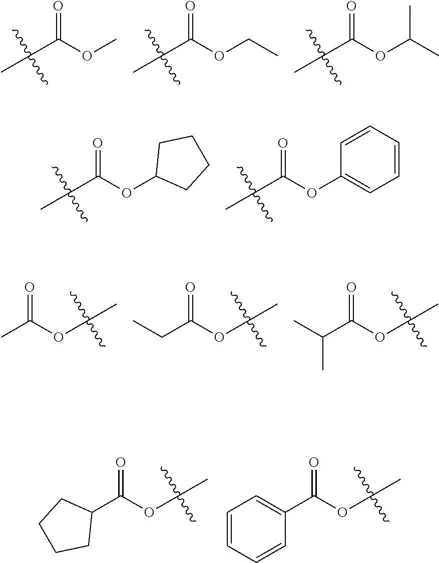

In the present disclosure, the carbon number of an imide group is not particularly limited, but is preferably 1 to 25. Specifically, the imide group can be a substituent group having the following structural formulas, but is not limited thereto.

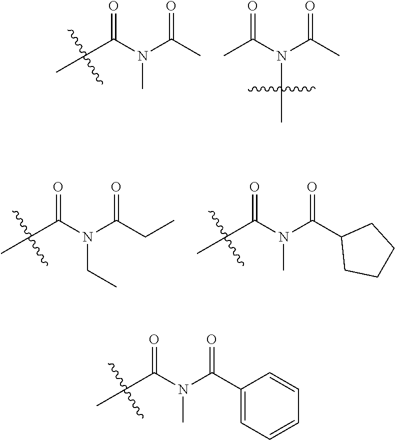

In the present disclosure, a silyl group means —Si(Z₁)(Z₂)(Z₃), wherein Z₁, Z₂ and Z₃ are each independently hydrogen, deuterium, a substituted or unsubstituted C₁₋₆₀ alkyl, a substituted or unsubstituted C₁₋₆₀ haloalkyl, a substituted or unsubstituted C₂₋₆₀ alkenyl, a substituted or unsubstituted C₂₋₆₀ haloalkenyl, or a substituted or unsubstituted C₆₋₆₀ aryl. According to one embodiment, Z₁, Z₂ and Z₃ can be each independently hydrogen, deuterium, a substituted or unsubstituted C₁₋₁₀ alkyl, a substituted or unsubstituted C₁₋₁₀ haloalkyl, or a substituted or unsubstituted C₆₋₂₀ aryl. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but are not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluoro, chloro, bromo, or iodo.

In the present disclosure, the alkyl group can be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. According to another embodiment, the carbon number of the alkyl group is 1 to 5. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, 1-ethyl-propyl, 1,1-dimethylpropyl, hexyl, n-hexyl, 1-methylpentyl, 2-methylpentyl, 4-methyl-2-pentyl, 3,3-dimethylbutyl, 2-ethylbutyl, heptyl, n-heptyl, isohexyl, 1-methylhexyl, 2-methylhexyl, 3-methylhexyl, 4-methylhexyl, 5-methylhexyl, cyclopentylmethyl, cyclohexylmethyl, octyl, n-octyl, tert-octyl, 1-methylheptyl, 2-ethylhexyl, 2,4,4-trimethyl-1-pentyl, 2,4,4-trimethyl-2-pentyl, 2-propylpentyl, n-nonyl, 2,2-dimethylheptyl, and the like, but are not limited thereto.

In the present disclosure, the alkenyl group can be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, the alicyclic group means a monovalent substituent derived from a saturated or unsaturated hydrocarbon ring compound that contains only carbon as a ring-forming atom, but does not have aromaticity, which is understood to encompass both monocyclic and fused polycyclic compounds. According to one embodiment, the carbon number of the alicyclic group is 3 to 60. According to another embodiment, the carbon number of the alicyclic group is 3 to 30. According to another embodiment, the carbon number of the alicyclic group is 3 to 20. According to another embodiment, the carbon number of the alicyclic group is 5 to 10. Examples of the alicyclic group include a monocyclic group such as a cycloalkyl group, a bridged hydrocarbon group, a spiro hydrocarbon group, a substituent derived from hydrogenated derivatives of aromatic hydrocarbon compound, and the like.

Specifically, examples of the cycloalkyl group include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

Further, examples of the bridged hydrocarbon group include bicyclo[1.1.0]butyl, bicyclo[2.2.1]heptyl, bicyclo[4.2.0]octa-1,3,5-trienyl, adamantyl, decalinyl, and the like, but are not limited thereto.

Further, examples of the spiro hydrocarbon group include spiro[3.4]octyl, spiro[5.5]undecanyl, and the like, but are not limited thereto.

Further, a substituent derived from a hydrogenated derivative of the aromatic hydrocarbon compound means a substituent derived from a monocyclic or polycyclic aromatic hydrocarbon compound in which a part of the compound is hydrogenated. Examples of such a substituent include 1H-indenyl, 2H-indenyl, 4H-indenyl, 2,3-dihydro-1H-indenyl, 1,4-dihydronaphthalenyl, 1,2,3,4-tetrahydronaphthalenyl, 6,7,8,9-tetrahydro-5H-benzo[7]annulenyl, 6,7-dihydro-5H-benzocycloheptenyl, and the like, but are not limited thereto.

In the present disclosure, an aryl group is understood to mean a substituent derived from a monocyclic or fused polycyclic compound containing only carbon as a ring-forming atom and also having aromaticity, and the carbon number thereof is not particularly limited, but is preferably 6 to 60. According to one embodiment, the carbon number of the aryl group is 6 to 30. According to one embodiment, the carbon number of the aryl group is 6 to 20. According to one embodiment, the carbon number of the aryl group is 6 to 12. According to one embodiment, the carbon number of the aryl group is 10 to 20. The aryl group can be a phenyl group, a biphenylyl group, a terphenylyl group or the like as the monocyclic aryl group, but is not limited thereto. The polycyclic aryl group includes a naphthyl group, an anthracenyl group, a phenanthryl group, a pyrenyl group, a perylenyl group, a chrysenyl group, a fluorenyl group, or the like, but is not limited thereto.

In the present disclosure, the fluorenyl group can be substituted, and two substituent groups can be linked with each other to form a spiro structure. In the case where the fluorenyl group is substituted,

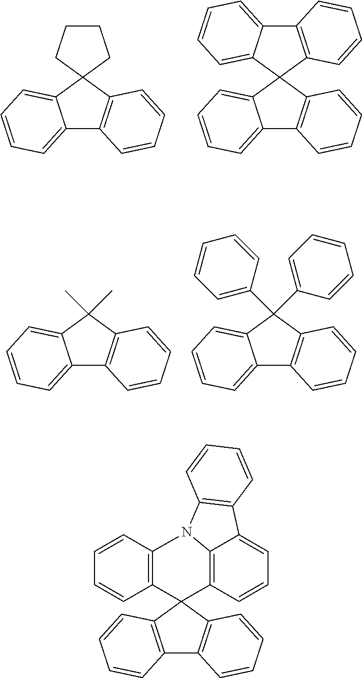

and the like can be formed. However, the structure is not limited thereto.

In the present disclosure, a heterocyclic group means a monovalent substituent derived from a monocyclic or fused polycyclic compound that further contains at least one heteroatom selected among O, N, Si, and S in addition to carbon as a ring-forming atom, and is understood to encompass both substituents with aromaticity and substituents without aromaticity. According to one embodiment, the carbon number of the heterocyclic group is 2 to 60 carbon atoms. According to another embodiment, the carbon number of the heterocyclic group is 2 to 30. According to another embodiment, the carbon number of the heterocyclic group is 2 to 20. Examples of such a heterocyclic group include a heteroaryl group, a substituent derived from a hydrogenated derivative of the heteroaromatic compound, and the like.

Specifically, the heteroaryl group means a substituent derived from a monocyclic or fused polycyclic compound which further contains at least one heteroatom selected among N, O and S in addition to carbon as a ring forming atom, and refers to a substituent having aromaticity. According to one embodiment, the carbon number of the heteroaryl group is 2 to 60. According to another embodiment, the carbon number of the heteroaryl group is 2 to 30. According to another embodiment, the carbon number of the heteroaryl group is 2 to 20. According to another embodiment, the carbon number of the heteroaryl group is 2 to 12. According to another embodiment, the carbon number of the heteroaryl group is 2 to 10. According to another embodiment, the carbon number of the heteroaryl group is 2 to 8. According to another embodiment, the carbon number of the heteroaryl group is 10 to 20. Examples of the heteroaryl group include a thiophenyl group, a furanyl group, a pyrrole group, an imidazolyl group, a thiazolyl group, an oxazolyl group, an oxadiazolyl group, a triazolyl group, a pyridinyl group, a bipyridinyl group, a pyrimidinyl group, a triazinyl group, an acridinyl group, a pyridazinyl group, a pyrazinyl group, a quinolinyl group, a quinazolinyl group, a quinoxalinyl group, a phthalazinyl group, a pyridopyrimidinyl group, a pyridopyrazinyl group, an isoquinolinyl group, an indolyl group, a carbazolyl group, a benzoxazolyl group, a benzoimidazolyl group, a benzothiazolyl group, a benzocarbazolyl group, a benzothiophenyl group, a dibenzothiophenyl group, a benzofuranyl group, a dibenzofuranyl group, a phenanthrolinyl group, an isoxazolyl group, a thiadiazolyl group, a phenothiazinyl group, and the like, but are not limited thereto.

Further, a substituent derived from a hydrogenated derivative of a heteroaromatic compound means a substituent derived from a monocyclic or polycyclic heteroaromatic compound in which a part of the unsaturated bond of the compound is hydrogenated. Examples of such substituents include 1,3-dihydroisobenzofuranyl, 2,3-dihydrobenzofuranyl, 1,3-dihydrobenzo[c]thiophenyl, 2,3-dihydro[b]thiophenyl, and the like, but are not limited thereto.

In the present disclosure, the aryl group in the aralkyl group, the aralkenyl group, the alkylaryl group, the arylamine group and the arylsilyl group is the same as the examples of the aryl group as defined above. In the present disclosure, the alkyl group in the aralkyl group, the alkylaryl group and the alkylamine group is the same as the examples of the alkyl group as defined above. In the present disclosure, the heteroaryl in the heteroarylamine can be applied to the description of the heteroaryl as defined above. In the present disclosure, the alkenyl group in the aralkenyl group is the same as the examples of the alkenyl group as defined above. In the present disclosure, the description of the aryl group as defined above can be applied except that the arylene is a divalent group. In the present disclosure, the description of the heteroaryl as defined above can be applied except that the heteroarylene is a divalent group. In the present disclosure, the description of the aryl group or cycloalkyl group as defined above can be applied except that the hydrocarbon ring is not a monovalent group but formed by combining two substituent groups. In the present disclosure, the description of the heteroaryl as defined above can be applied, except that the heterocycle is not a monovalent group but formed by combining two substituent groups.

In the present disclosure, the term “deuterated or substituted with deuterium” means that at least one of the substitutable hydrogens in a compound, a divalent linking group, or a monovalent substituent has been substituted with deuterium.

Further, the term “unsubstituted or substituted with deuterium” or “substituted with deuterium or unsubstituted” means that “mono to the maximum number of unsubstituted or substitutable hydrogens have been substituted with deuterium.” In one example, the term “phenanthryl unsubstituted or substituted with deuterium” can be understood as meaning “phenanthryl unsubstituted or substituted with 1 to 9 deuterium atoms”, considering that the maximum number of hydrogen that can be substituted with deuterium in the phenanthryl structure is 9.

Further, “deuterated structure” means to include compounds, divalent linking groups, or monovalent substituents of all structures in which at least one hydrogen is substituted with deuterium. As an example, the deuterated structure of phenyl can be understood to refer to monovalent substituents of all structures in which at least one substitutable hydrogen in the phenyl group is substituted with deuterium, as follows.

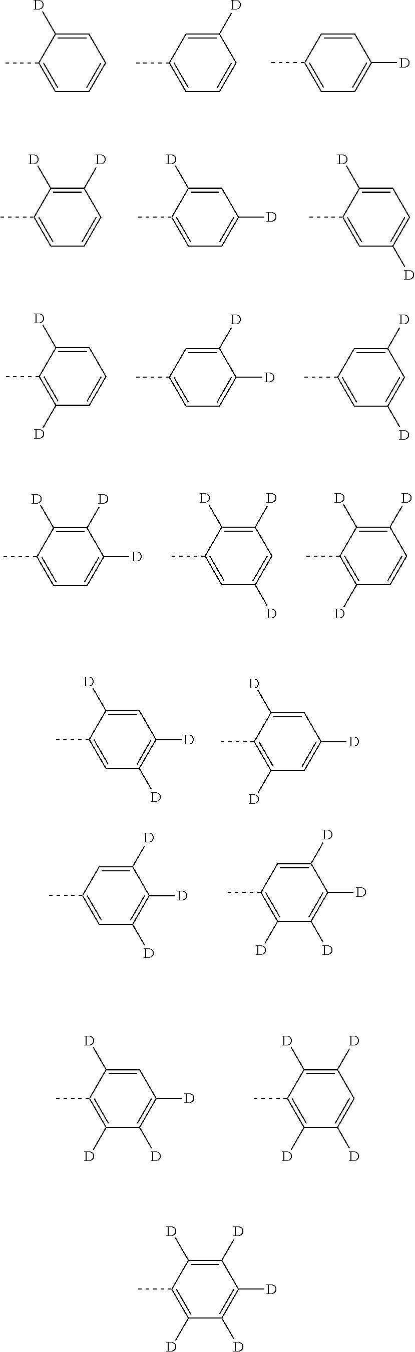

In addition, the “deuterium substitution rate” or “degree of deuteration” of a compound means that the ratio of the number of substituted deuterium atoms to the total number of hydrogen atoms (the sum of the number of hydrogen atoms substitutable with deuterium and the number of substituted deuterium atoms in a compound) that can exist in the compound is calculated as a percentage. Therefore, when the “deuterium substitution rate” or “degree of deuteration” of a compound is “K %”, it means that K % of the hydrogen atoms substitutable with deuterium in the compound are substituted with deuterium.

At this time, the “deuterium substitution rate” or “degree of deuteration” can be determined according to a commonly known method using MALDI-TOF MS (Matrix-Assisted Laser Desorption/Ionization Time-of-Flight Mass Spectrometer), a nuclear magnetic resonance spectroscopy (¹H NMR), TLC/MS (Thin-Layer Chromatography/Mass Spectrometry), GC/MS (Gas Chromatography/Mass Spectrometry), or the like. More specifically, when using MALDI-TOF MS, the “deuterium substitution rate” or “degree of deuteration” can be obtained by determining the number of substituted deuterium in the compound through MALDI-TOF MS analysis, and then calculating the ratio of the number of substituted deuterium to the total number of hydrogen atoms that can exist in the compound as a percentage.

In addition, for “tritiated structure,” “tritium substitution rate,” or “degree of tritiation,” the description related to deuterium described above can be applied, except that tritium is substituted instead of deuterium.

Hereinafter, the present disclosure will be described in detail.

### Composition for Organic Light Emitting Device

One embodiment of the present disclosure provides a composition for an organic light emitting device comprising the first compound represented by the Chemical Formula 1 and the second compound represented by the Chemical Formula 2. The first compound and the second compound can act as a host in the light emitting layer of an organic light emitting device. Specifically, the first compound functions as a p-type host material in which hole transport ability is superior to electron transport ability, and the second compound functions as an n-type host material in which electron transport ability is superior to hole transport ability, thereby forming an exciplex. Accordingly, excitons can be uniformly emitted throughout the light emitting layer, so that the luminous efficiency and lifetime characteristics of the organic light emitting device can be simultaneously improved.

Specifically, the first compound, which is a p-type host material, has an indolo[2,3-c]carbazole structure among indolocarbazoles, thereby exhibiting more excellent hole characteristics, and as a result, can improve the lifetime characteristics of the organic light emitting device. However, to maximize the excellent hole characteristics of indolocarbazole, the use of an n-type host material showing fast electron transport characteristics is essential, but if electron injection is too fast, the electron/hole balance can be broken, so assistance with hole injection characteristics is needed. In this regard, in the present disclosure, a second compound having a structure in which a carbazole and a triazine are bonded at the ortho position with respect to a benzene ring, and the carbazole and the triazine are twisted through steric hindrance, and further, which is deuterium-substituted to a certain level or more, is used as an n-type host material. As the carbazole and triazine in the second compound are bonded at the ortho position with respect to the benzene ring, it assists hole injection characteristics, and as a result, can greatly improve luminous efficiency. In addition, the twisted structure of the carbazole and triazine allows the electron characteristics of the triazine and the hole characteristics of the carbazole to operate separately without canceling each other out, and furthermore, deuterium substitution of a certain level or more can further improve the lifetime characteristics.

### First Compound

The first compound is represented by the Chemical Formula 1. Specifically, the first compound has a structure in which an aryl, dibenzofuranyl, or dibenzothiophenyl is substituted on an indolo[2,3-c]carbazole core structure, so that it can efficiently transfer holes to a dopant material. In particular, among various structures of indolocarbazoles, it has an indolo[2,3-c]carbazole structure, thereby exhibiting more excellent hole characteristics, and as a result, it can increase the recombination probability of holes and electrons in the light emitting layer together with the second compound having excellent electron transport ability.

In addition, in one embodiment, Ar₁ and Ar₂ can each independently be a substituted or unsubstituted C₆₋₂₀ aryl; or a substituted or unsubstituted C₂₋₂₀ heteroaryl comprising at least one selected from the group consisting of N, O, and S.

In another embodiment, Ar₁ and Ar₂ can each independently be C₆₋₂₀ aryl, dibenzofuranyl, dibenzothiophenyl, carbazolyl, or 9-phenyl carbazole,
wherein, Ar₁ and Ar₂ can each independently be unsubstituted, or substituted with one or more deuterium atoms.

In another embodiment, Ar₁ and Ar₂ can each independently be phenyl, biphenyl, terphenyl, triphenylenyl, dibenzofuranyl, dibenzothiophenyl, carbazolyl, or 9-phenyl carbazole,
wherein, Ar₁ and Ar₂ can each independently be unsubstituted, or substituted with one or more deuterium atoms.

For example, Ar₁ and Ar₂ can each independently be any one selected from the group consisting of the following and their deuterated structures:

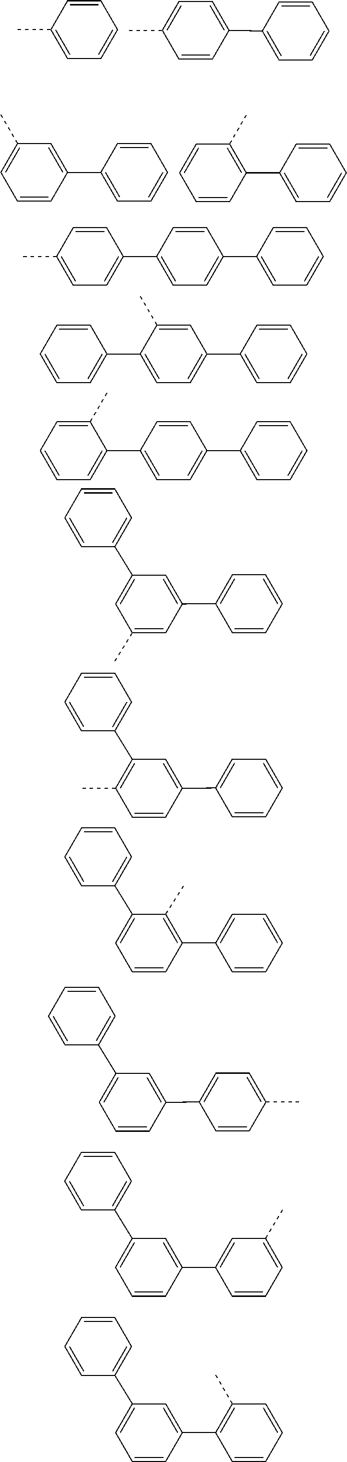

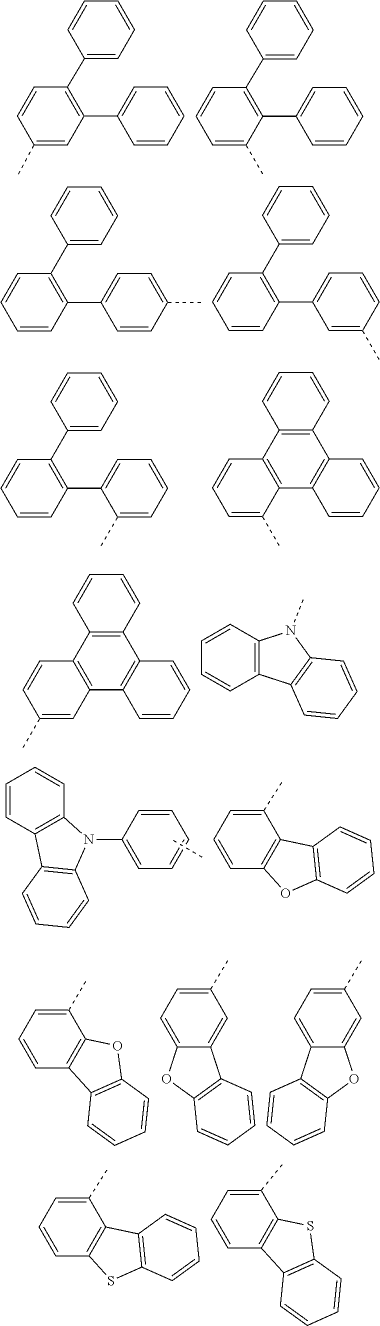

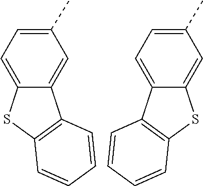

In another embodiment, one of Ar₁ and Ar₂ can be a C₆₋₂₀ monocyclic aryl which is unsubstituted or substituted with one or more deuterium atoms.

In another embodiment, one of Ar₁ and Ar₂ can be phenyl, biphenyl, or terphenyl, and the remainder is phenyl, biphenyl, terphenyl, triphenylenyl, dibenzofuranyl, dibenzothiophenyl, carbazolyl, or 9-phenyl carbazole,

wherein Ar₁ and Ar₂ can each independently be unsubstituted, or substituted with one or more deuterium atoms.

In another embodiment, Ar₁ and Ar₂ can each independently be unsubstituted, or substituted with 5 or more deuterium atoms.

In another embodiment, one or both of Ar₁ and Ar₂ can be fully substituted with deuterium.

In another embodiment, Ar₁ and Ar₂ can be the same as or different from each other.

In another embodiment, L₁—Ar₁ and L₂-Ar₂ cay be the same as or different from each other.

In one embodiment, L₁ and L₂ can each independently be a single bond, or a substituted or unsubstituted C₆₋₂₀ arylene.

In another embodiment, L₁ and L₂ can each independently be a single bond, a substituted or unsubstituted C₆₋₁₈ monocyclic arylene, or a substituted or unsubstituted C₁₀₋₂₀ polycyclic arylene.

In another embodiment, L₁ and L₂ can each independently be a single bond, phenylene, biphenyldiyl, terphenyldiyl, or naphthylene,

wherein, L₁ and L₂, which are not single bonds, can be unsubstituted or substituted with one or more deuterium atoms.

In another embodiment, L₁ and L₂ can each independently be a single bond or phenylene,
wherein, the phenylene can be unsubstituted or substituted with one or more deuterium atoms.

For example, L₁ and L₂ can each independently be a single bond, 1,2-phenylene substituted or unsubstituted with one or more deuterium atoms, 1,3-phenylene substituted or unsubstituted with one or more deuterium atoms, or 1,4-phenylene substituted or unsubstituted with one or more deuterium atoms.

In addition, when the phenylene can be substituted with deuterium, it can be substituted with one or more deuterium atoms, or with 4 deuterium atoms.

In one embodiment, R₁₁, R₁₂ and R₁₃ can each be deuterium.

In addition, a means the number of Ri, and can be an integer of 0, 1, 2, 3, or 4.

When a is 0, it means that it does not include the substituent R₁₁, that is, it is unsubstituted.

In addition, b means the number of R₁₂, and can be an integer of 0, 1, or 2.

When b is 0, it means that it does not include the substituent R₁₂, that is, it is unsubstituted.

In addition, c means the number of R₁₃, and can be an integer of 0, 1, 2, 3, or 4.

When c is 0, it means that it does not include the substituent R₁₃, that is, it is unsubstituted.

In one embodiment, a, b, and c can all be 0.

In another embodiment, a and c can each be 4, and b can be 2.

In one embodiment, the first compound can not include deuterium, or can include one or more deuterium atoms.

When the first compound includes deuterium, the deuterium substitution rate of the first compound can be 1% to 100%. Specifically, the deuterium substitution rate of the first compound can be 5% or more, 10% or more, 20% or more, 30% or more, 40% or more, 50% or more, 60% or more, 70% or more, 75% or more, 80% or more, or 90% or more, and 100% or less.

As an example, the first compound can not include deuterium, or can include 1 to 50 deuterium atoms. More specifically, the first compound can not include deuterium, or can include 1 or more, 2 or more, 3 or more, 4 or more, 5 or more, 6 or more, 7 or more, 8 or more, or 9 or more, and 50 or less, 40 or less, 30 or less, 28 or less, 26 or less, 24 or less, 22 or less, 20 or less, 18 or less, 16 or less, 14 or less, 13 or less, 12 or less, 11 or less, or 10 or less deuterium atoms.

Meanwhile, deuterium has a higher mass value than hydrogen, resulting in a lower potential energy level and a lower zero point energy, and as the atom is heavier, the vibration mode becomes smaller, resulting in a lower vibrational energy level than hydrogen. Therefore, when a hydrogen atom present in a compound is substituted with deuterium, the intermolecular van der Waals force is reduced, and a decrease in quantum efficiency due to collision by intermolecular vibration can be prevented.

In addition, since deuterium lowers the zero point energy with carbon, the bond energy of a C-D bond becomes higher than the bond energy of a C—H bond. Therefore, when the compound includes deuterium, it has a stronger bond energy within the molecule, and thus the material stability can be increased.

Representative examples of the compound represented by the Chemical Formula 1 are as follows:

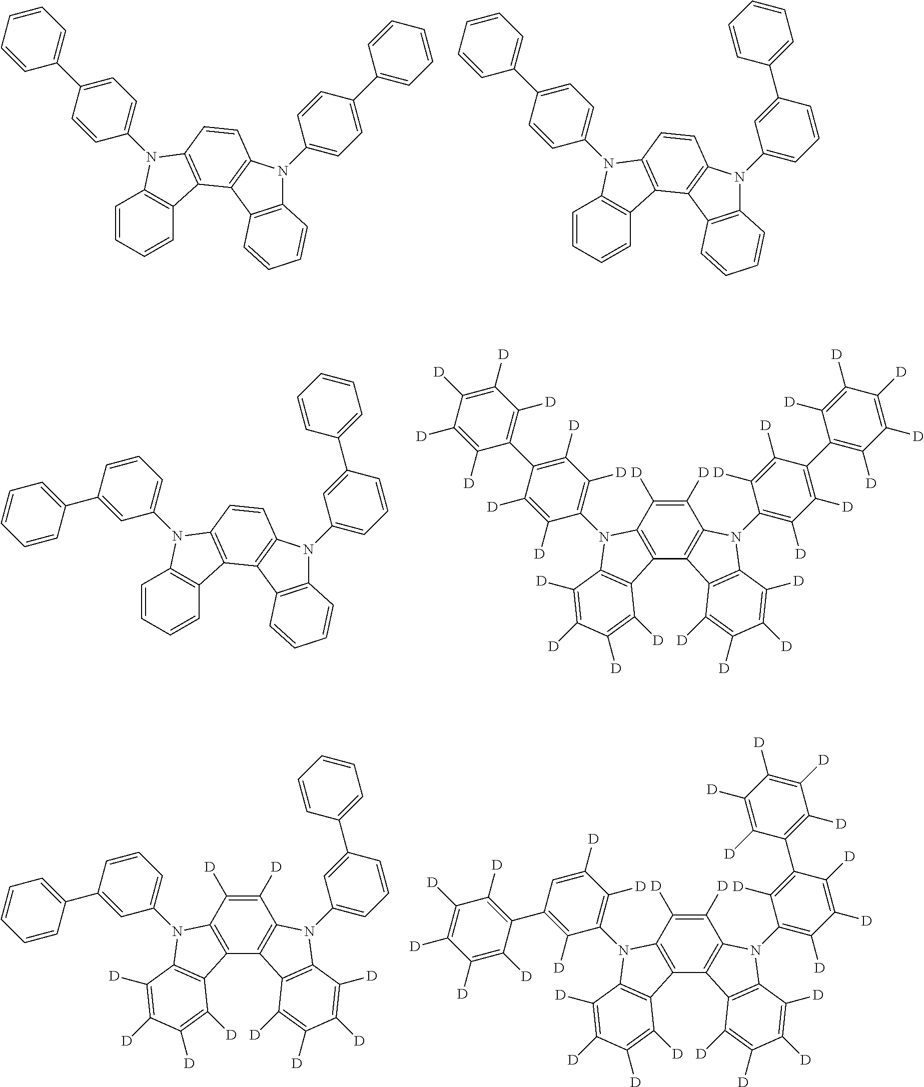

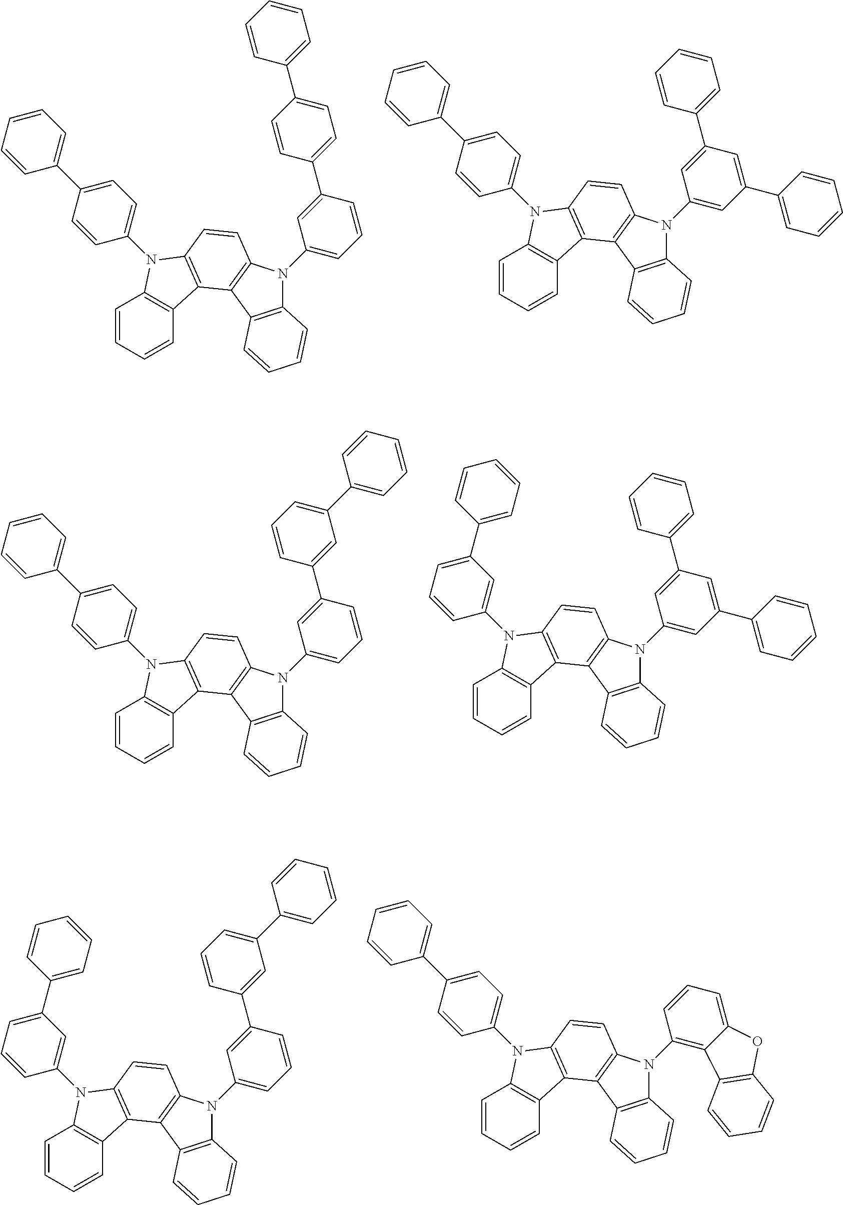

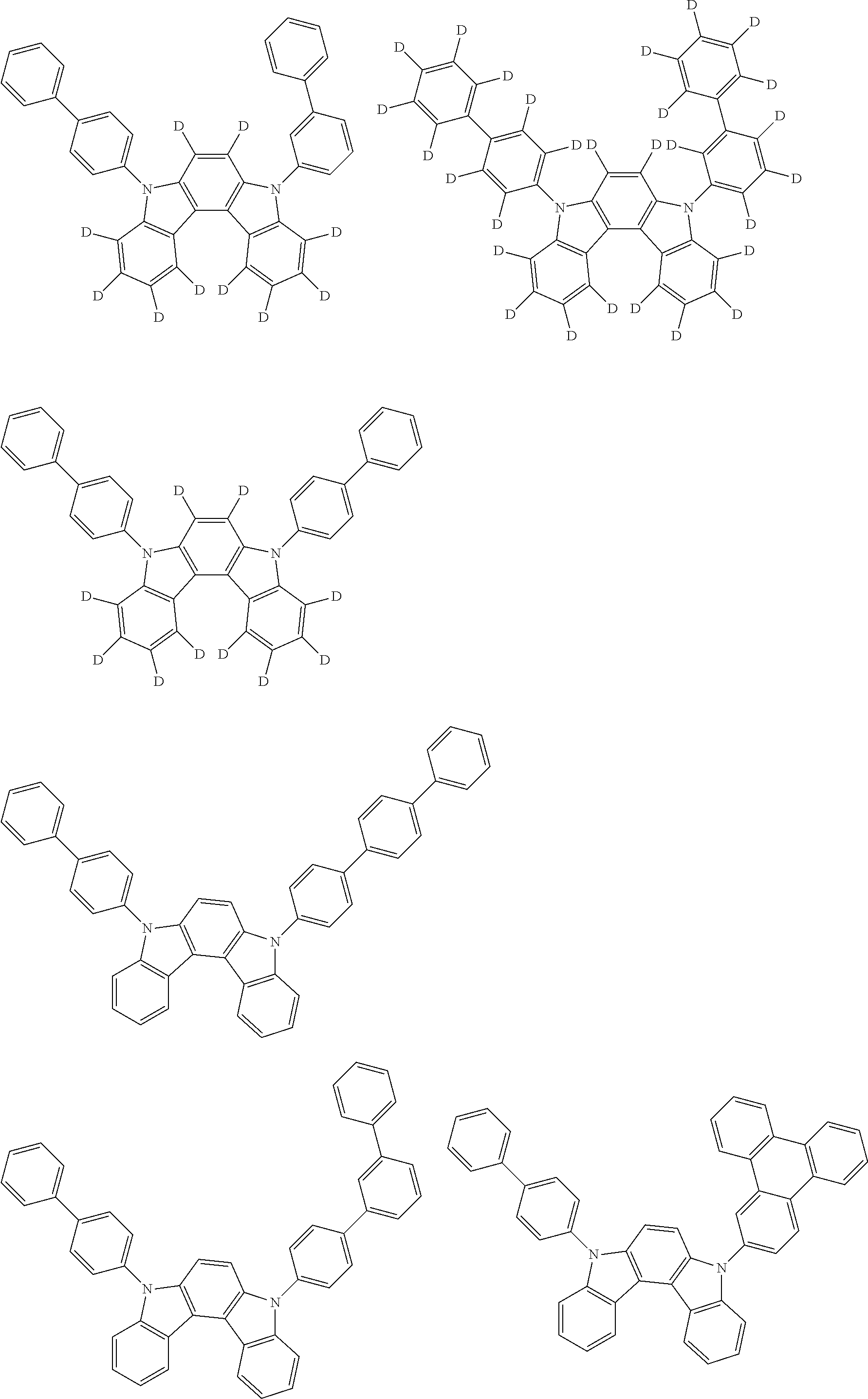

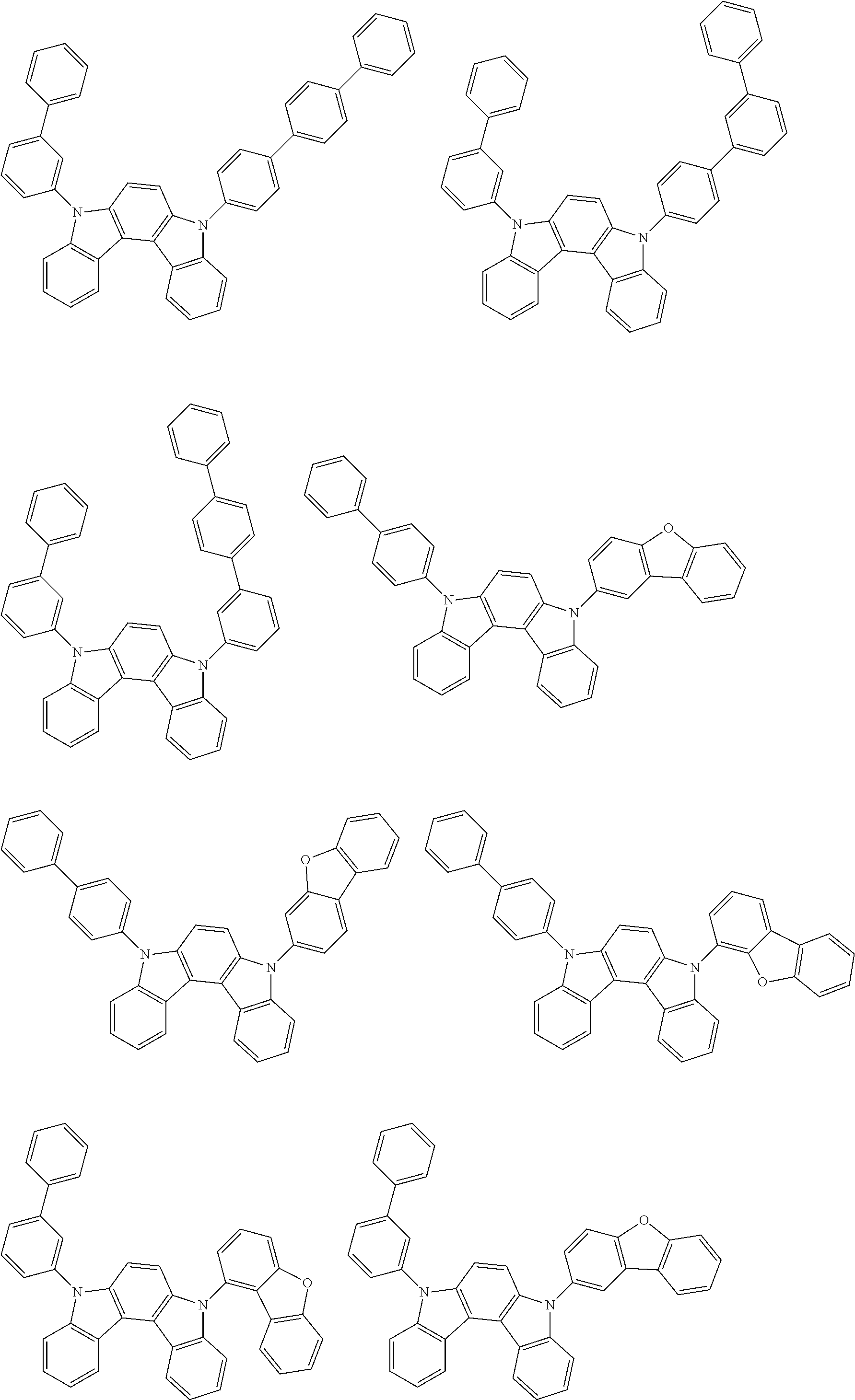

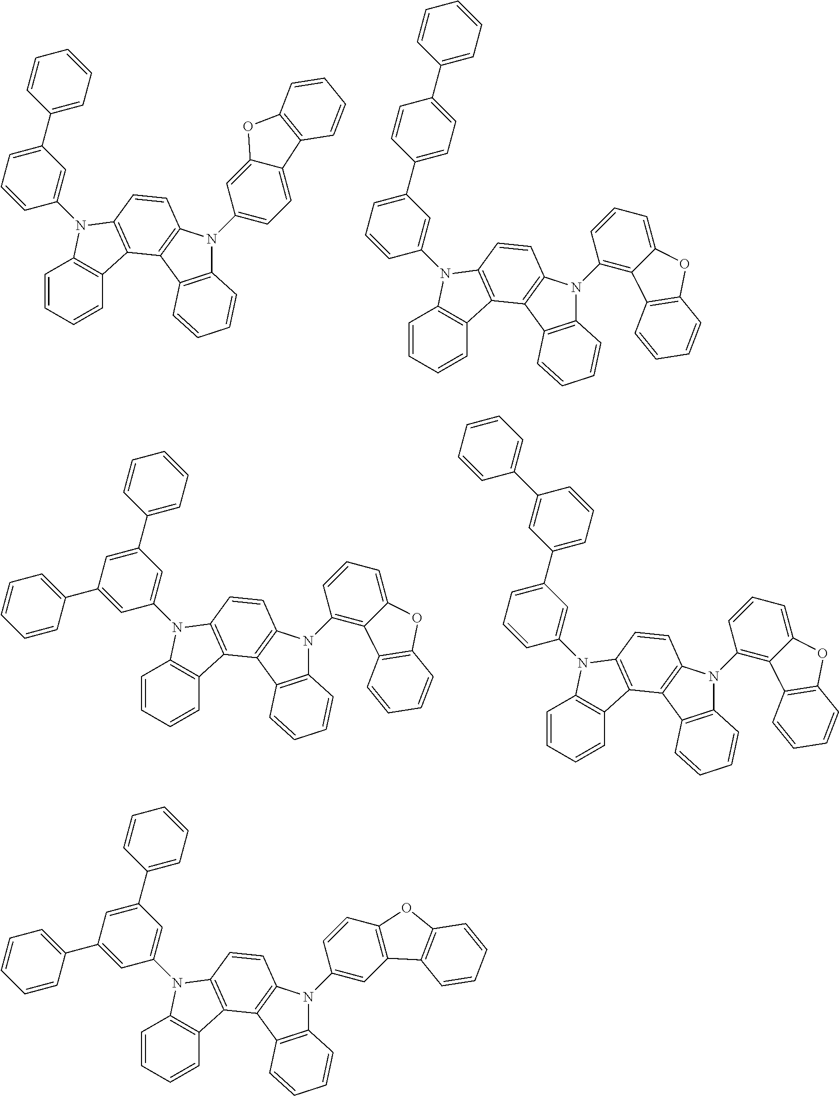 [SMILES: c1ccc(-c2cccc(-n3c4ccccc4c4c5c6ccccc6n(-c6ccc7c(c6)oc6ccccc67)c5ccc43)c2)cc1 ; c1ccc(-c2ccc(-c3cccc(-n4c5ccccc5c5c6c7ccccc7n(-c7cccc8oc9ccccc9c78)c6ccc54)c3)cc2)cc1 ; c1ccc(-c2cc(-c3ccccc3)cc(-n3c4ccccc4c4c5c6ccccc6n(-c6cccc7oc8ccccc8c67)c5ccc43)c2)cc1 ; c1ccc(-c2cccc(-c3cccc(-n4c5ccccc5c5c6c7ccccc7n(-c7cccc8oc9ccccc9c78)c6ccc54)c3)c2)cc1 ; c1ccc(-c2cc(-c3ccccc3)cc(-n3c4ccccc4c4c5c6ccccc6n(-c6ccc7oc8ccccc8c7c6)c5ccc43)c2)cc1]

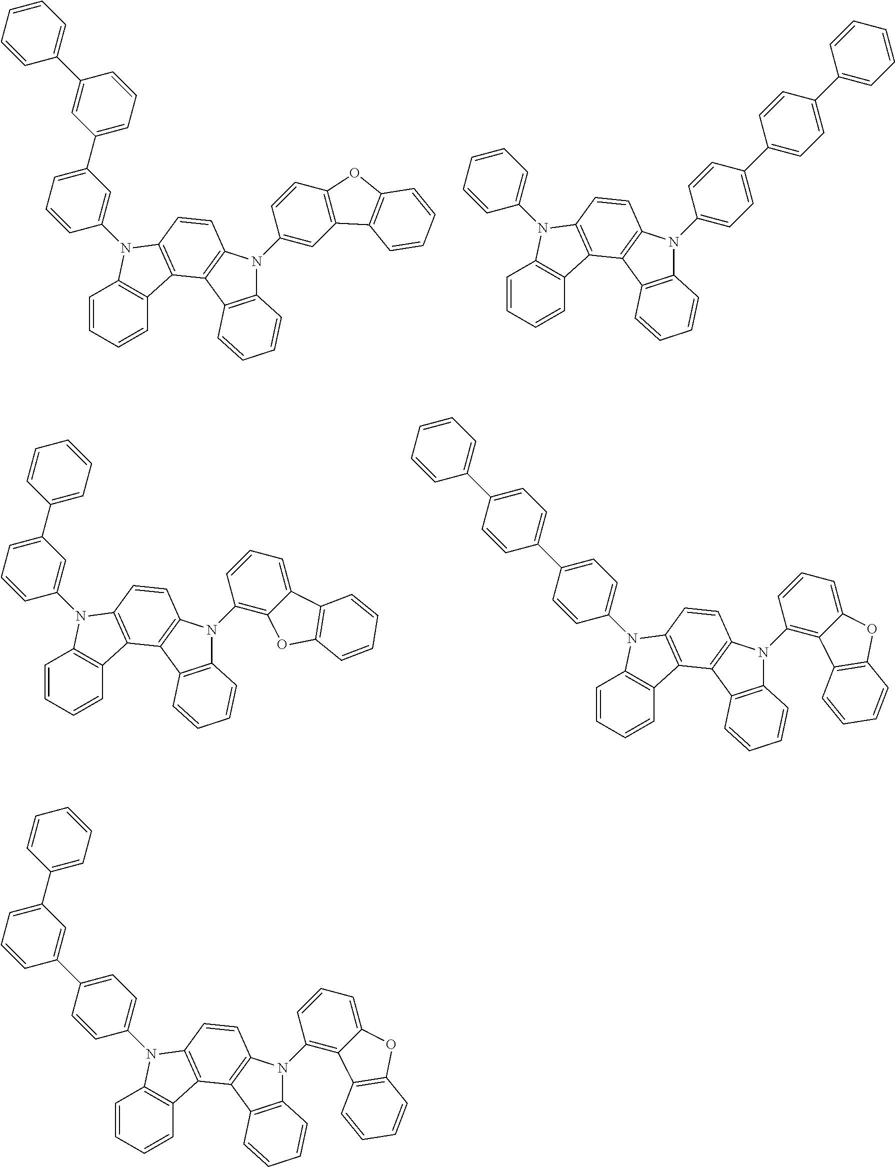

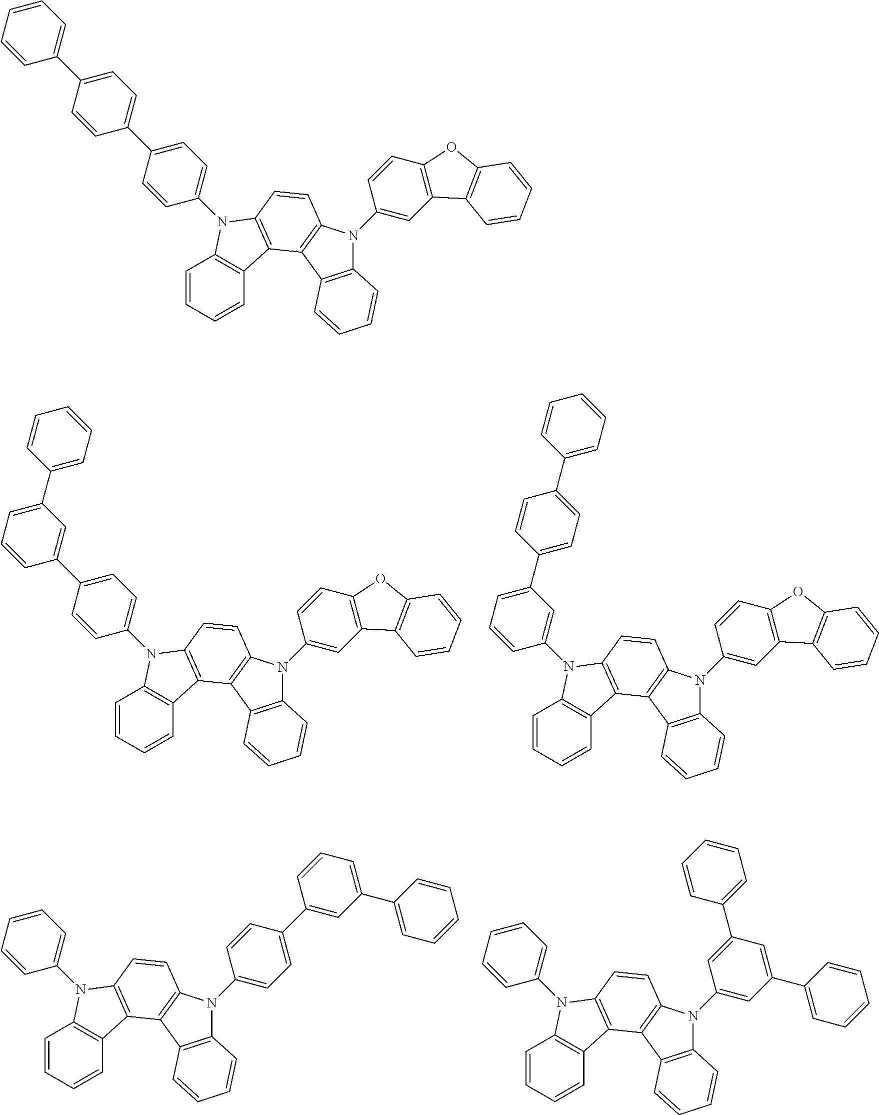

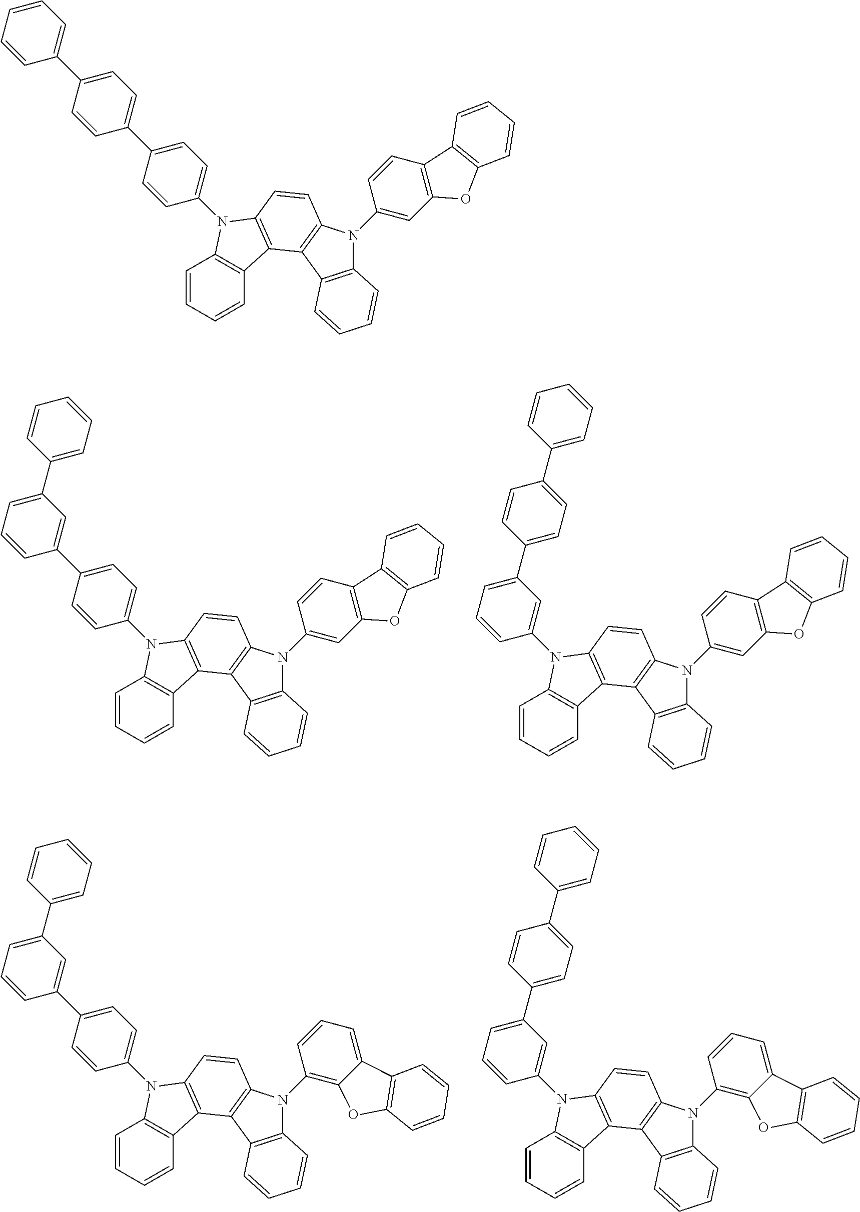

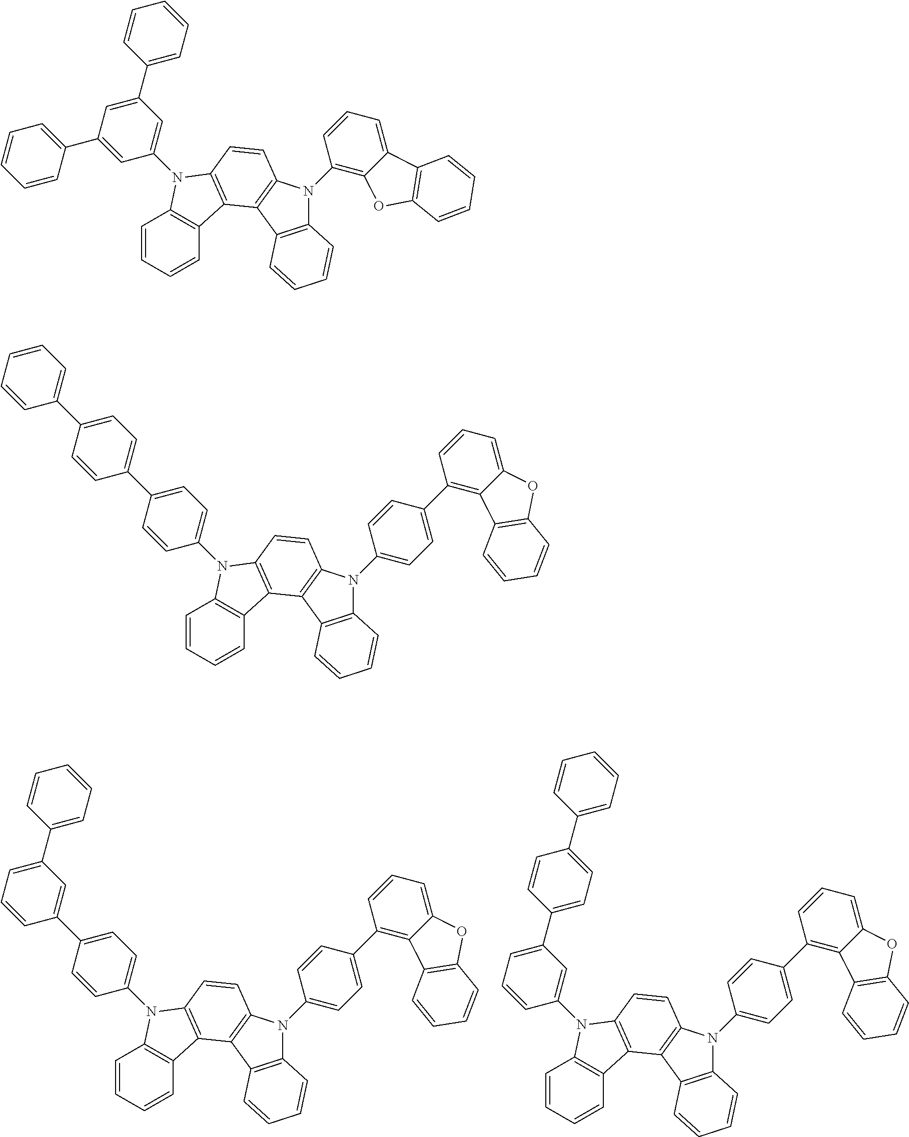

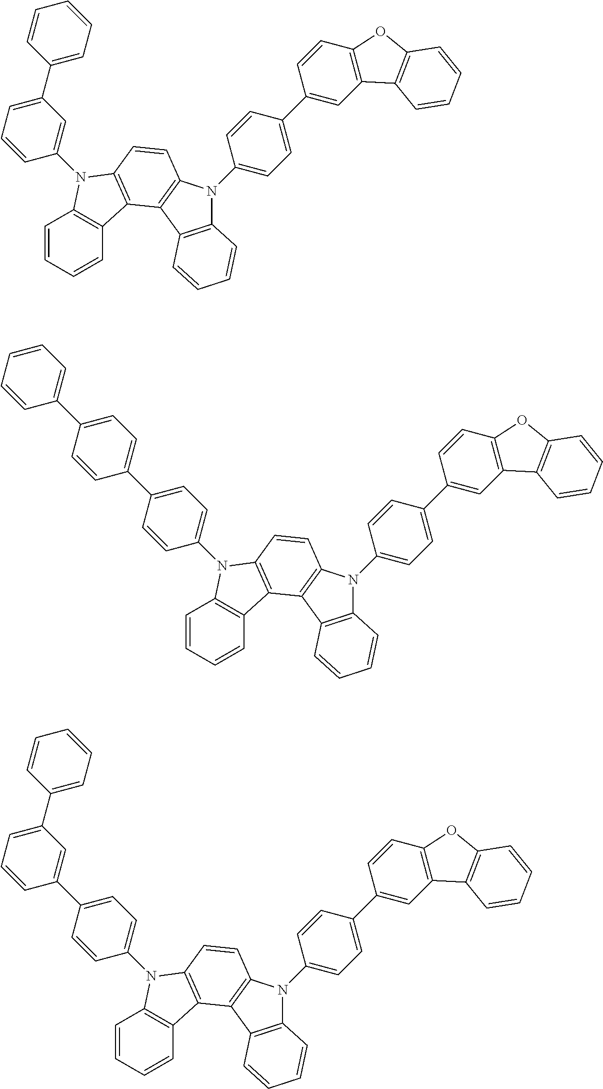 [SMILES: c1ccc(-c2cccc(-n3c4ccccc4c4c5c6ccccc6n(-c6ccc(-c7ccc8oc9ccccc9c8c7)cc6)c5ccc43)c2)cc1 ; c1ccc(-c2ccc(-c3ccc(-n4c5ccccc5c5c6c7ccccc7n(-c7ccc(-c8ccc9oc%10ccccc%10c9c8)cc7)c6ccc54)cc3)cc2)cc1 ; c1ccc(-c2cccc(-c3ccc(-n4c5ccccc5c5c6c7ccccc7n(-c7ccc(-c8ccc9oc%10ccccc%10c9c8)cc7)c6ccc54)cc3)c2)cc1]

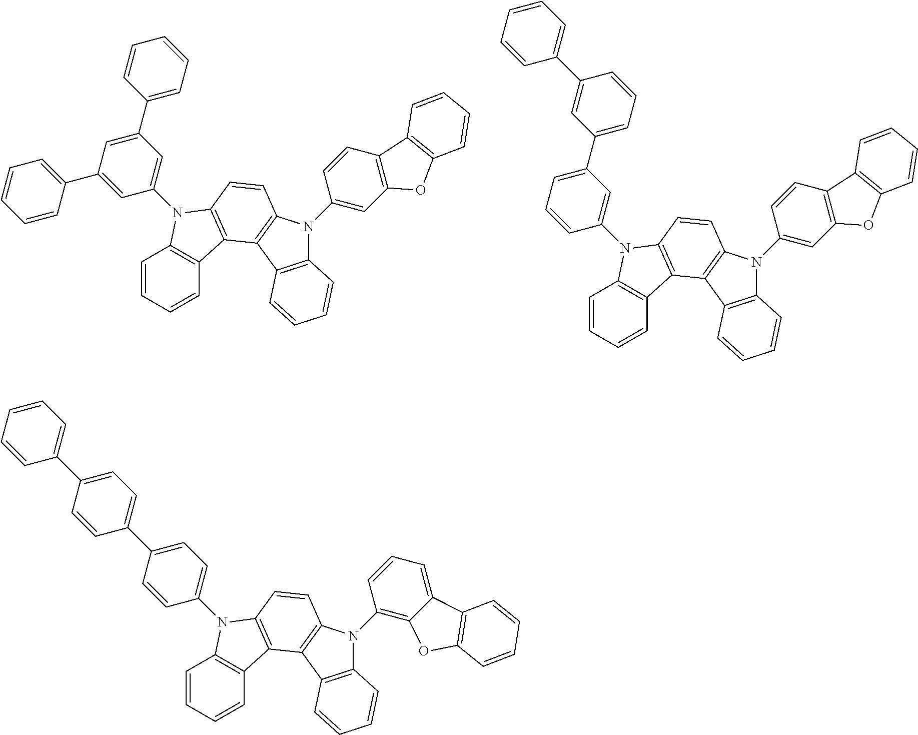 [SMILES: c1ccc(-c2cc(-c3ccccc3)cc(-n3c4ccccc4c4c5c6ccccc6n(-c6ccc7c(c6)oc6ccccc67)c5ccc43)c2)cc1 ; c1ccc(-c2cccc(-c3cccc(-n4c5ccccc5c5c6c7ccccc7n(-c7ccc8c(c7)oc7ccccc78)c6ccc54)c3)c2)cc1 ; c1ccc(-c2ccc(-c3ccc(-n4c5ccccc5c5c6c7ccccc7n(-c7cccc8c7oc7ccccc78)c6ccc54)cc3)cc2)cc1]

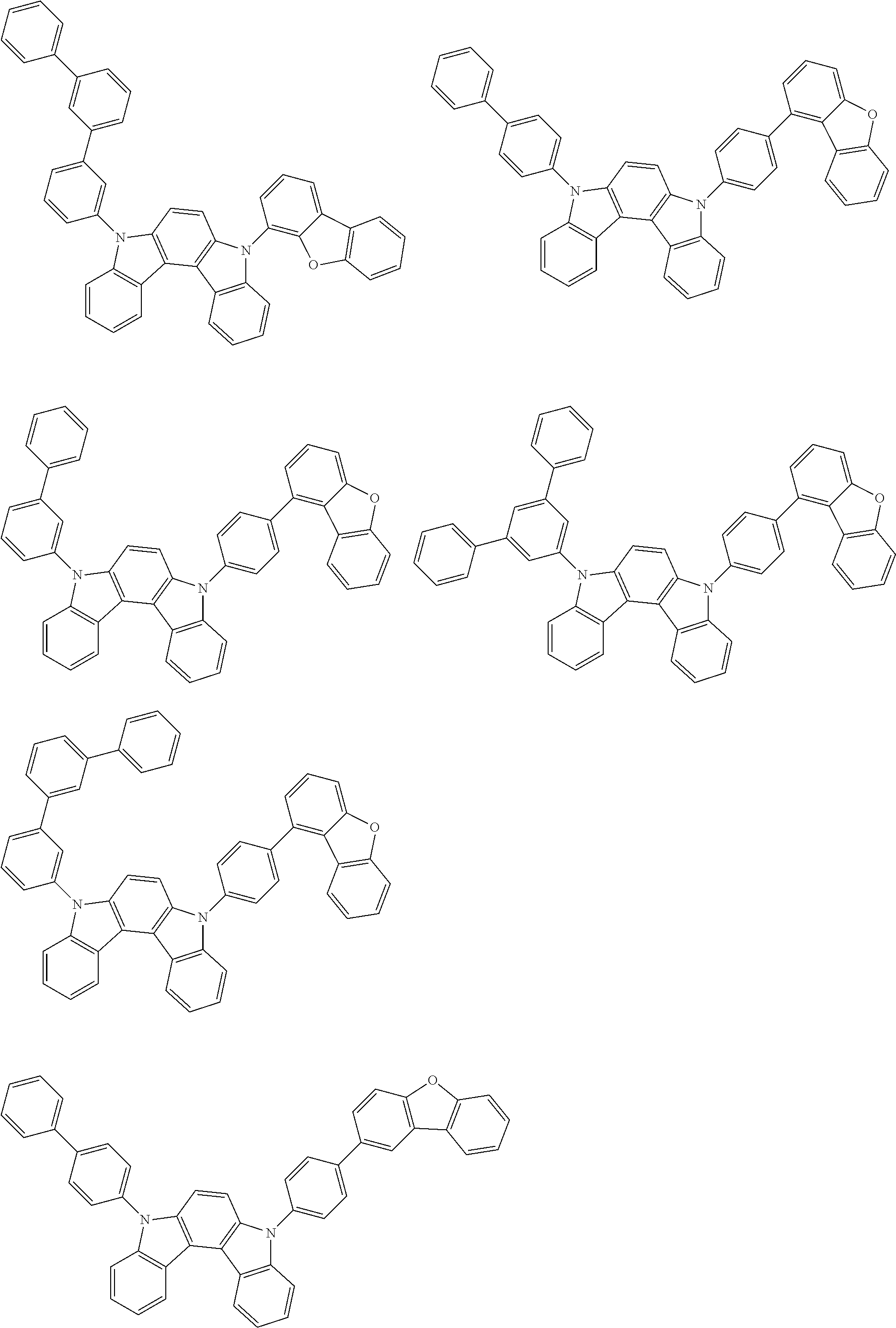

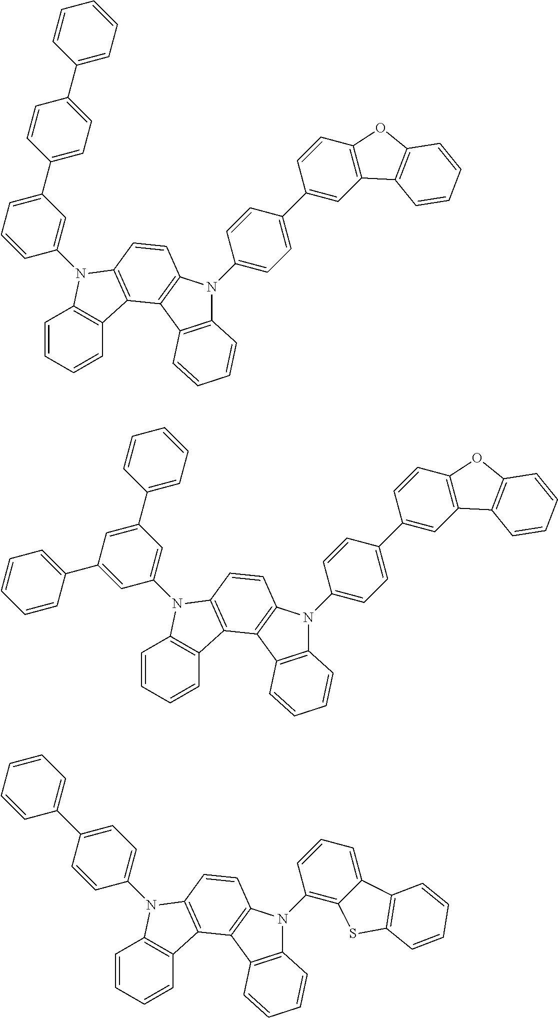 [SMILES: c1ccc(-c2ccc(-c3cccc(-n4c5ccccc5c5c6c7ccccc7n(-c7ccc(-c8ccc9oc%10ccccc%10c9c8)cc7)c6ccc54)c3)cc2)cc1 ; c1ccc(-c2cc(-c3ccccc3)cc(-n3c4ccccc4c4c5c6ccccc6n(-c6ccc(-c7ccc8oc9ccccc9c8c7)cc6)c5ccc43)c2)cc1 ; c1ccc(-c2ccc(-n3c4ccccc4c4c5c6ccccc6n(-c6cccc7c6sc6ccccc67)c5ccc43)cc2)cc1]

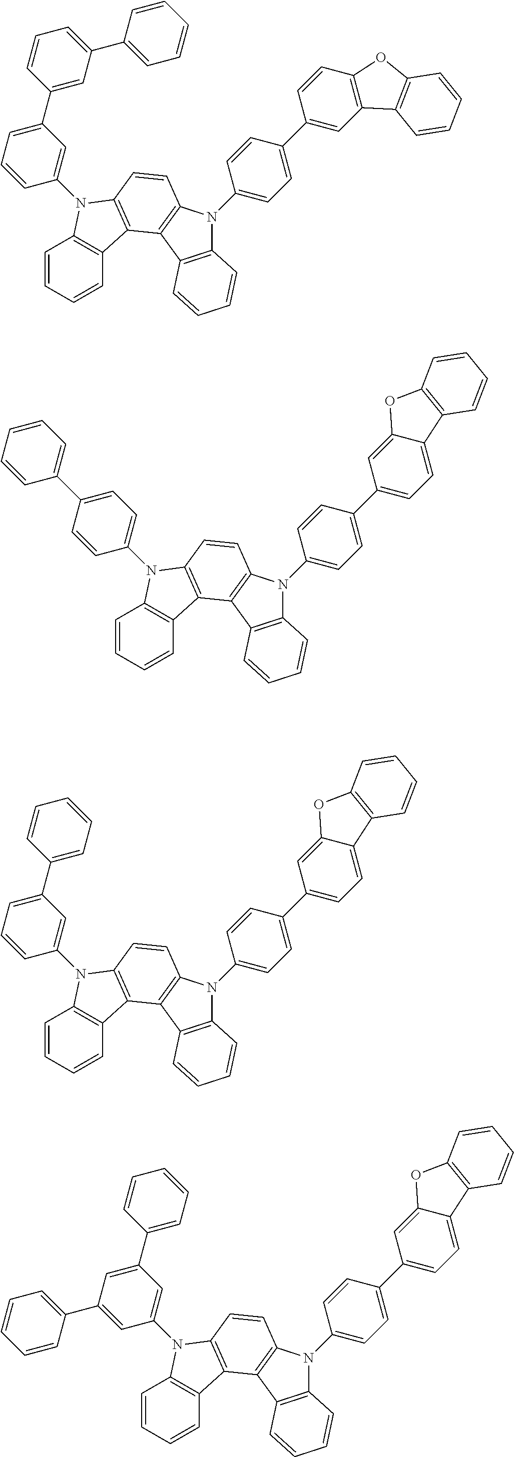 [SMILES: c1ccc(-c2cccc(-c3cccc(-n4c5ccccc5c5c6c7ccccc7n(-c7ccc(-c8ccc9oc%10ccccc%10c9c8)cc7)c6ccc54)c3)c2)cc1 ; c1ccc(-c2ccc(-n3c4ccccc4c4c5c6ccccc6n(-c6ccc(-c7ccc8c(c7)oc7ccccc78)cc6)c5ccc43)cc2)cc1 ; c1ccc(-c2cccc(-n3c4ccccc4c4c5c6ccccc6n(-c6ccc(-c7ccc8c(c7)oc7ccccc78)cc6)c5ccc43)c2)cc1 ; c1ccc(-c2cc(-c3ccccc3)cc(-n3c4ccccc4c4c5c6ccccc6n(-c6ccc(-c7ccc8c(c7)oc7ccccc78)cc6)c5ccc43)c2)cc1]

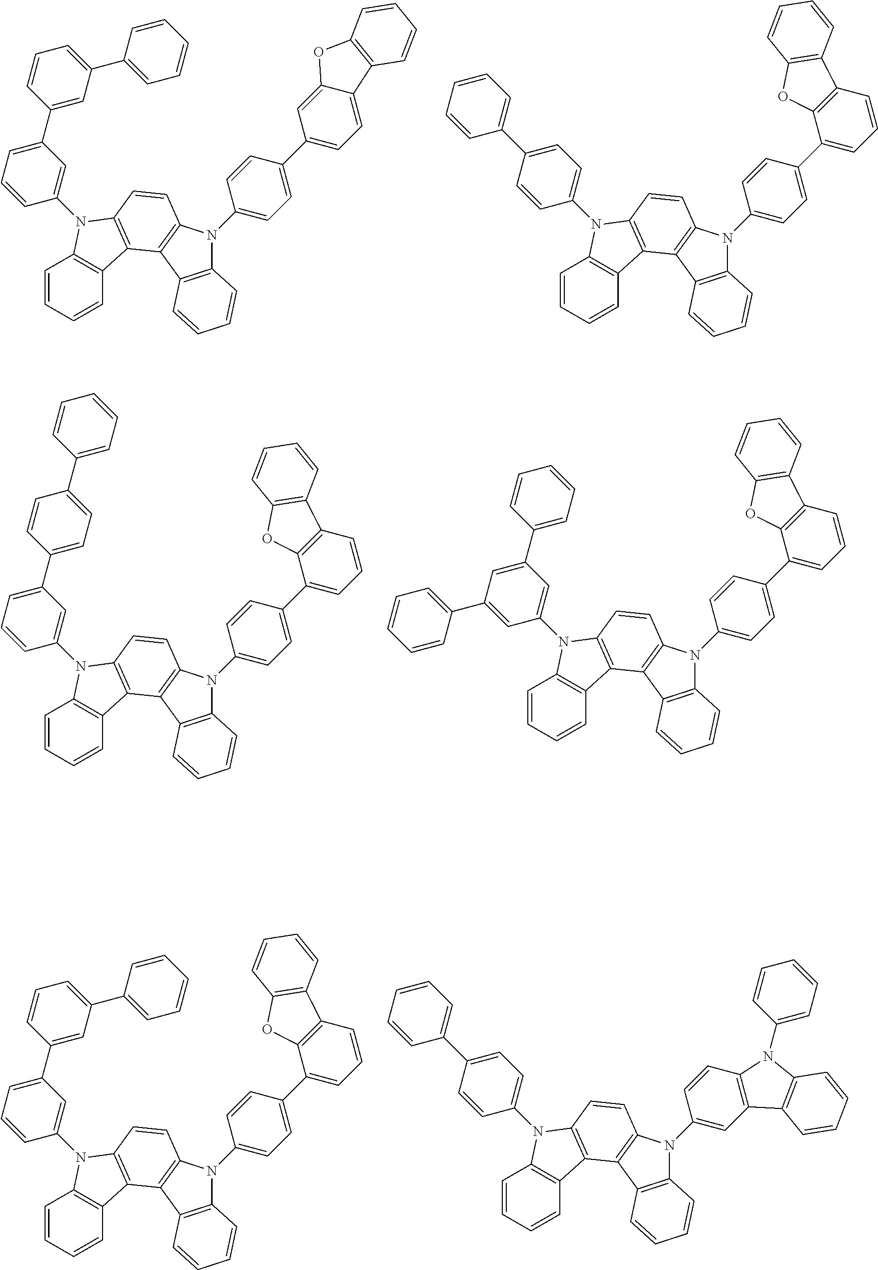

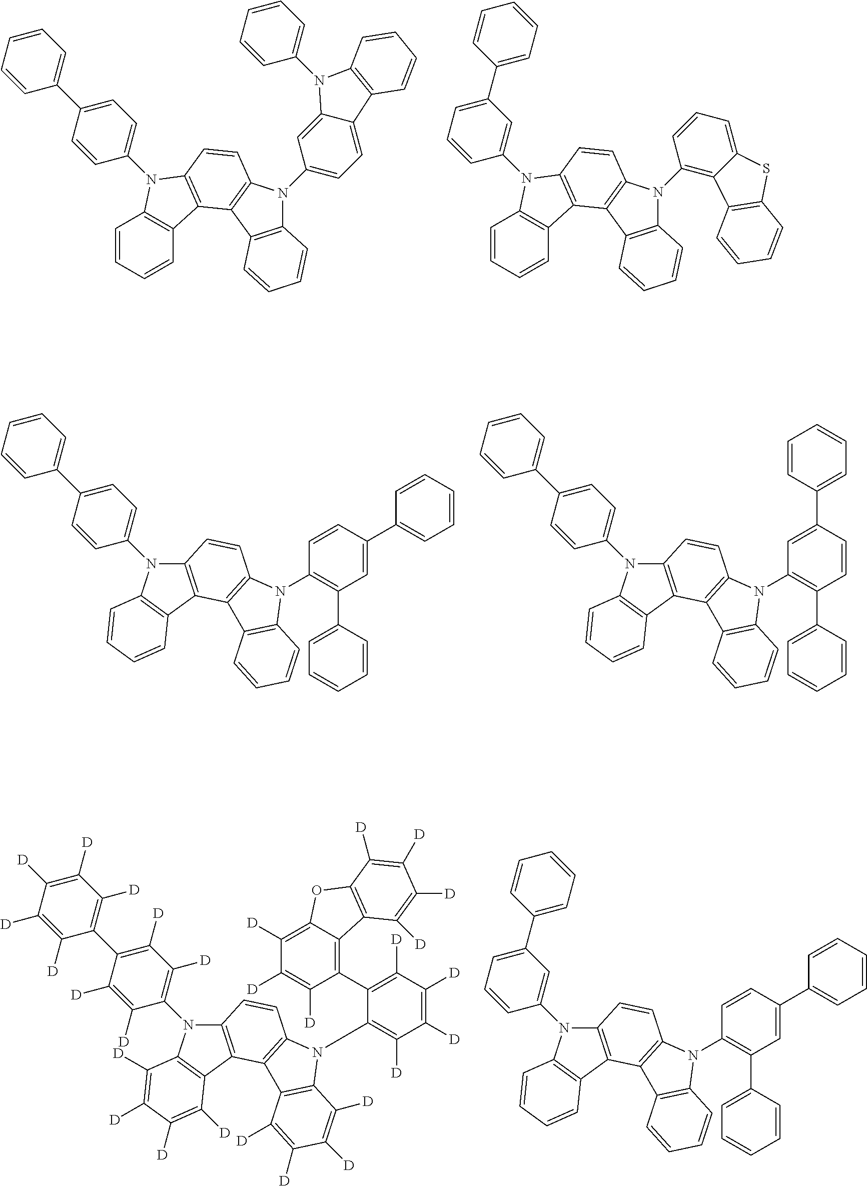

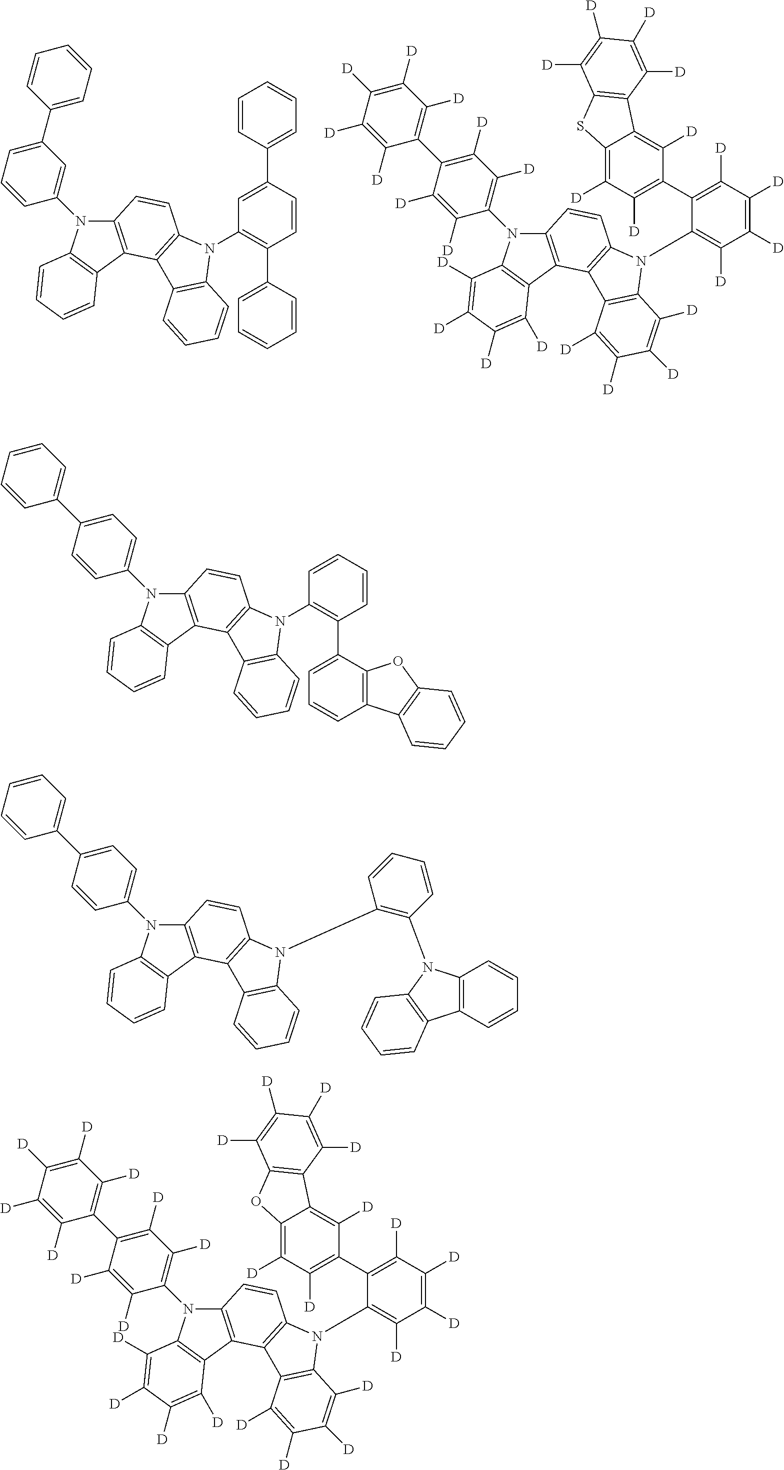

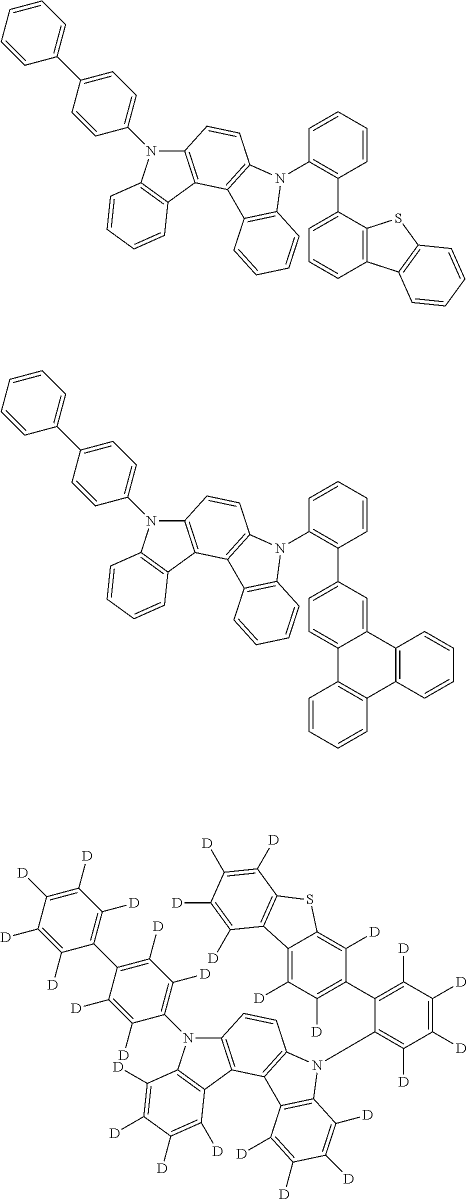 [SMILES: c1ccc(-c2ccc(-n3c4ccccc4c4c5c6ccccc6n(-c6ccccc6-c6cccc7c6sc6ccccc67)c5ccc43)cc2)cc1 ; c1ccc(-c2ccc(-n3c4ccccc4c4c5c6ccccc6n(-c6ccccc6-c6ccc7c8ccccc8c8ccccc8c7c6)c5ccc43)cc2)cc1 ; [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c6c(sc7c([2H])c([2H])c([2H])c([2H])c76)c5[2H])c4c4c([2H])c([2H])c([2H])c([2H])c43)c([2H])c2[2H])c([2H])c1[2H]]

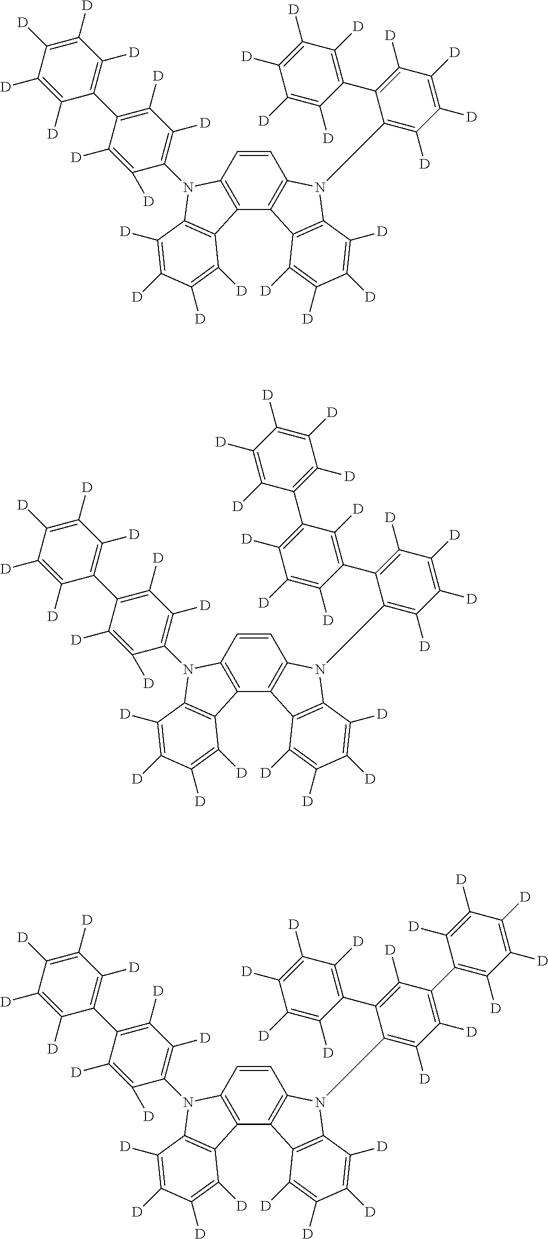

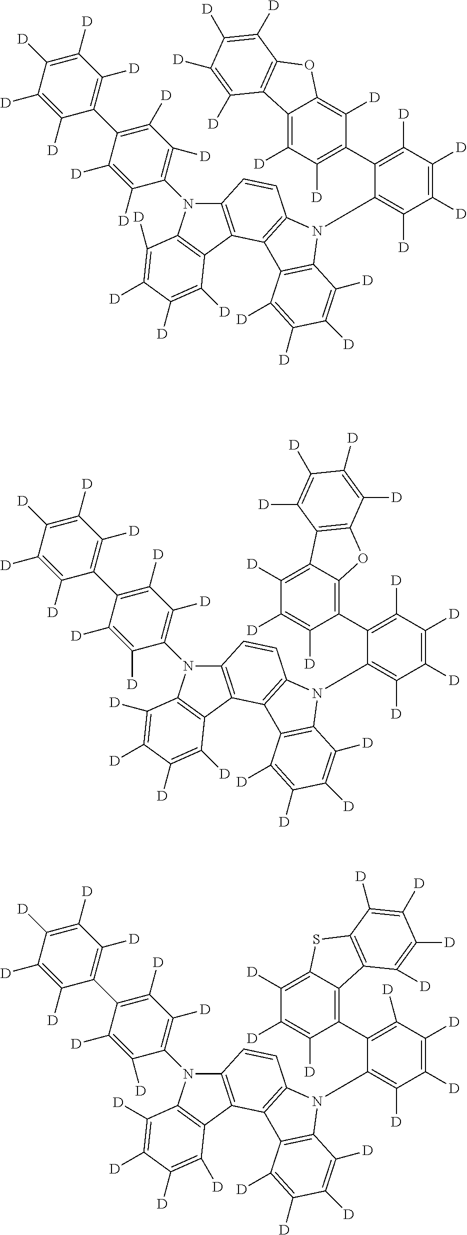

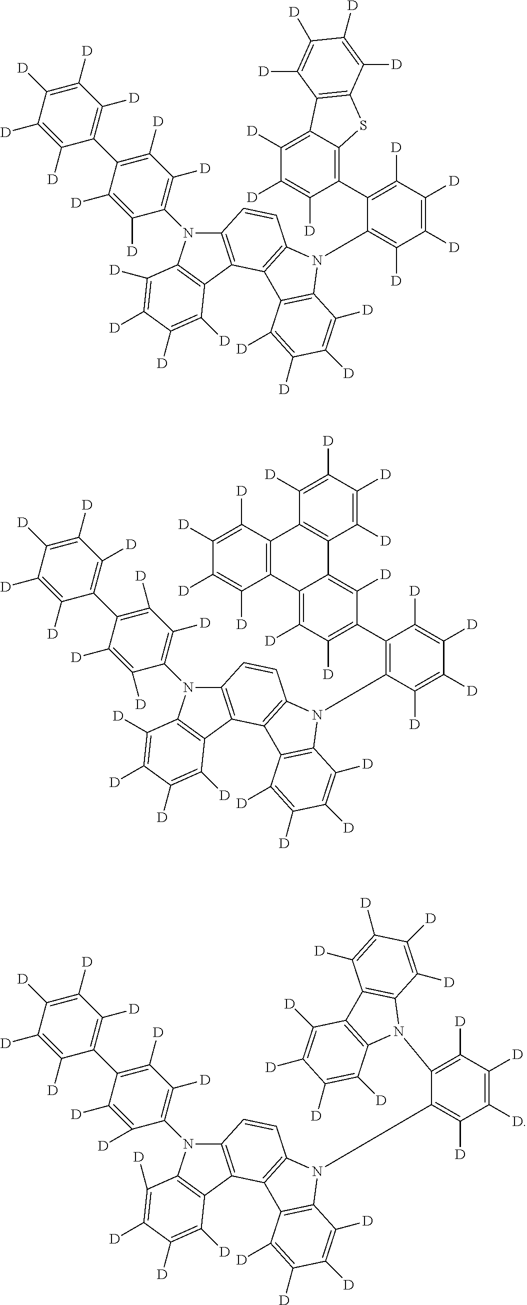

Meanwhile, the first compound represented by the Chemical Formula 1 can be prepared by a preparation method such as Reaction Scheme 1 below, for example.

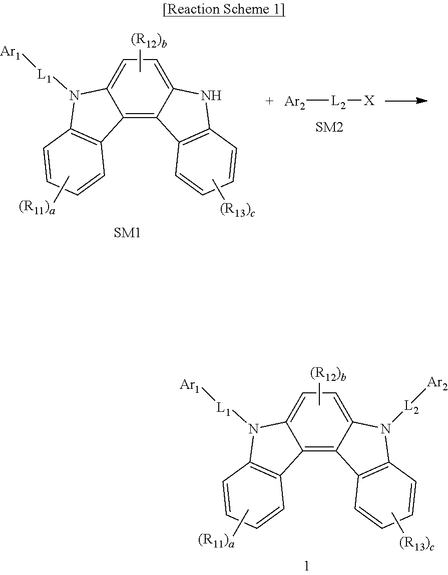

In the Reaction Scheme 1, Ar₁, Ar₂, L₁, L₂, R₁₁, R₁₂, R₁₃, a, b, and c are as defined in the Chemical Formula 1, and X is a halogen, and preferably X is fluoro, chloro, or bromo.

As another example, the first compound represented by the Chemical Formula 1 can be prepared by a preparation method such as Reaction Scheme 2 below.

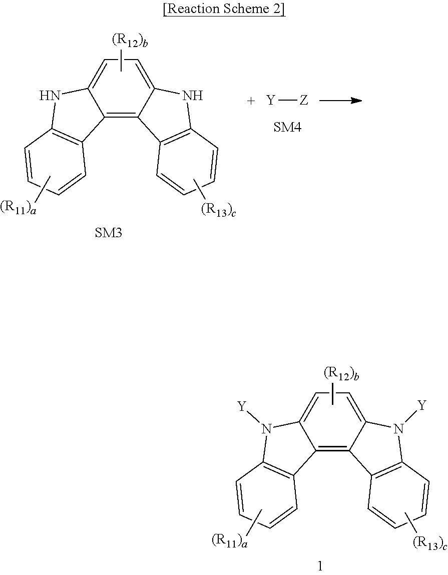

In the Reaction Scheme 2, R₁, R₁₂, R₁₃, a, b, and c are as defined in the Chemical Formula 1.

In addition, Y is

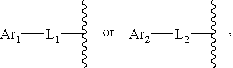

and Ar₁, Ar₂, L₁, and L₂ are as defined in the Chemical Formula 1. In addition, Z is a halogen, and preferably Z is fluoro, chloro, or bromo.

The Reaction Schemes 1 and 2 are both amine substitution reactions, and it is preferable to perform them in the presence of a palladium catalyst and a base, and the reactor for the amine substitution reaction can be changed as known in the art.

As another example, the first compound having at least one deuterium can be prepared by a preparation method such as Reaction Scheme 3 below.

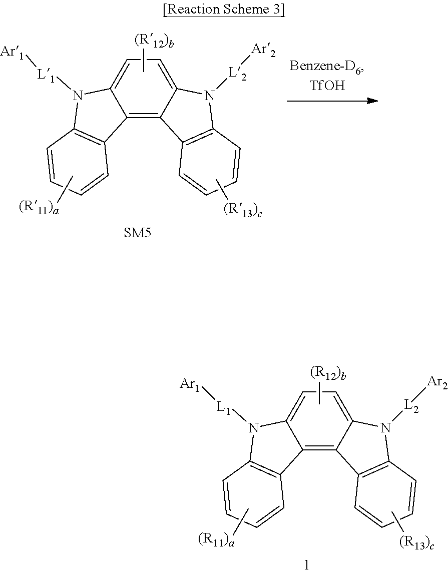

In the Reaction Scheme 3, L′₁, L′₂, Ar′₁, Ar′₂WR′₁₁ to R′₁₃ each mean an L₁, L₂, Ar₁, Ar₂, and R₁ to R₃ substituent not substituted with deuterium, and the definitions of the remaining substituents are as described above.

Specifically, the first compound having at least one deuterium can be prepared by deuterating the first compound not substituted with deuterium. At this time, the deuterium substitution reaction can be performed by adding the first compound not substituted with deuterium to a deuterated solvent such as a benzene-D₆ (C₆D₆) solution and then reacting it with TfOH (trifluoromethanesulfonic acid).

The remaining compounds can be similarly prepared.

The method for preparing the first compound represented by the Chemical Formula 1 can be more specified in the preparation examples described below.

### Second Compound

The second compound is represented by the Chemical Formula 2. Specifically, the second compound can exhibit excellent electron transport ability because a carbazole and a triazine are bonded at the ortho position with respect to a benzene ring, and the carbazole and the triazine are twisted through steric hindrance. As a result, it can efficiently transfer electrons to a dopant material, thereby increasing the recombination probability of electrons and holes in the light emitting layer. In addition, since it has a structure in which the substituent Rc is bonded at the para position with respect to the carbazole, it exhibits fast electron transport characteristics, and also assists hole injection characteristics to further maximize the hole transport characteristics of the first compound. Furthermore, since 6 or more hydrogen atoms in the second compound are substituted with deuterium, the vibrational energy in the radical anion state is lowered, so that it can have stable energy, and accordingly, the formed exciplex can also be in a more stable state. As a result, the lifetime characteristics of the organic light emitting device can be further improved.

In one embodiment, Ar₃ and Ar₄ can each independently be a substituted or unsubstituted C₆₋₁₄ aryl.

In another embodiment, Ar₃ and Ar₄ can each independently be phenyl or biphenyl,
wherein, Ar₃ and Ar₄ can each independently be unsubstituted, or substituted with one or more or 5 or more deuterium atoms.

In another embodiment, one of Ar₃ and Ar₄ can be phenyl, and the reminder can be phenyl or biphenyl,
wherein, Ar₃ and Ar₄ can each independently be unsubstituted, or substituted with one or more or 5 or more deuterium atoms.

In another embodiment, Ar₃ and Ar₄ can be the same as or different from each other.

In one embodiment, Rₐ and R_{d} can each independently be hydrogen, deuterium, or C₆₋₂₀ aryl,
wherein, the C₆₋₂₀ aryl can be unsubstituted, or substituted with one or more deuterium atoms.

In another embodiment, Rₐ and R_{d} can each independently be hydrogen, deuterium, phenyl, biphenyl, terphenyl, naphthyl, anthracenyl, phenanthrenyl, or triphenylenyl, and
the phenyl, biphenyl, terphenyl, naphthyl, anthracenyl, phenanthrenyl, and triphenylenyl can each independently be unsubstituted, or substituted with one or more, or 5 or more deuterium atoms.

For example, Rₐ and R_{d} can each independently be any one selected from the group consisting of hydrogen, deuterium, the following, and their deuterated structures:

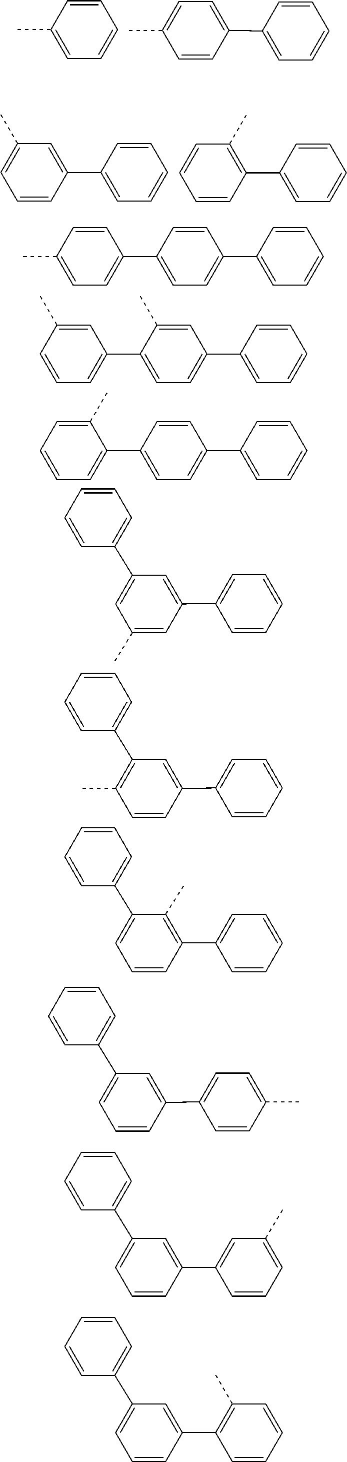

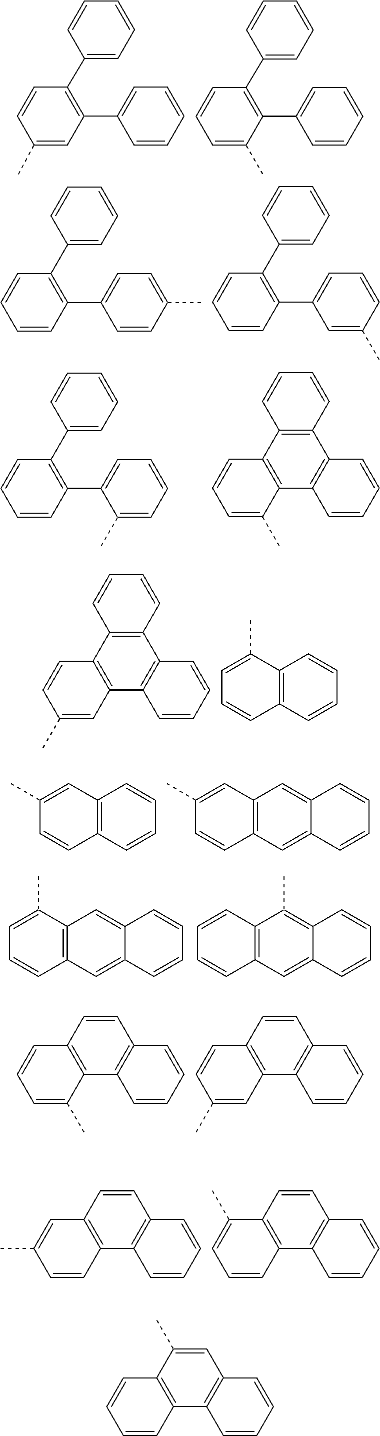

In another embodiment, Rₐ and R_{d} can be the same as or different from each other.

In one embodiment, R_{C} can be hydrogen; deuterium; or a C₆₋₂₀ aryl unsubstituted or substituted with deuterium.

In another embodiment, R_{C} can be hydrogen, deuterium, phenyl, biphenyl, terphenyl, naphthyl, anthracenyl, phenanthrenyl, or triphenylenyl,

wherein, the phenyl, biphenyl, terphenyl, naphthyl, anthracenyl, phenanthrenyl, and triphenylenyl can each independently be unsubstituted, or substituted with one or more, or 5 or more deuterium atoms.

In another embodiment, R_{C} can be unsubstituted phenyl, unsubstituted biphenyl, unsubstituted terphenyl, unsubstituted naphthyl, unsubstituted anthracenyl, unsubstituted phenanthrenyl, or unsubstituted triphenylenyl.

In one embodiment, R₂₁ to R₂₈ can each independently be hydrogen; deuterium; or a substituted or unsubstituted C₆₋₂₀ aryl, provided that at least one of R₂₁ to R₂₈ can be deuterium, or a C₆₋₂₀ aryl substituted with deuterium.

In another embodiment, R₂₁ to R₂₈ can each independently be hydrogen, deuterium, unsubstituted phenyl, or phenyl substituted with 1 to 5 deuterium atoms, provided that at least one of R₂₁ to R₂₈ can be deuterium or phenyl substituted with 1 to 5 deuterium atoms.

In another embodiment, 4 or more of R₂₁ to R₂₈ can be deuterium, and the remainder can be hydrogen, unsubstituted phenyl, or phenyl substituted with 1 to 5 deuterium atoms.

In another embodiment, 4 to 6 of R₂₁ to R₂₈ can be deuterium, and the remainder can be hydrogen.

In another embodiment, R₂₁ to R₂₈ can each be deuterium.

In another embodiment, one of R₂₁ to R₂₈ can be phenyl substituted with 1 to 5 deuterium atoms, and the remainder can be hydrogen or deuterium.

In another embodiment, R₂₁ to R₂₈ can each independently be hydrogen, deuterium, unsubstituted phenyl, or phenyl substituted with 1 to 5 deuterium atoms, provided that any one of R₂₅ and R₂₆ can be phenyl substituted with 1 to 5 deuterium atoms.

In another embodiment, R₂₁ to R₂₈ can each independently be hydrogen, deuterium, or phenyl substituted with 3 to 5 deuterium atoms, provided that any one of R₂₅ and R₂₆ can be phenyl substituted with 3 to 5 deuterium atoms.

In another embodiment, R₂₁ to R₂₈ can each independently be hydrogen, deuterium, or phenyl substituted with 1 to 5 deuterium atoms, provided that 4 to 6 of R₂₁ to R₂₈ can be deuterium, and any one of R₂₅ and R₂₆ can be phenyl substituted with 3 to 5 deuterium atoms.

In one embodiment, the second compound can include 6 or more deuterium atoms.

More specifically, the second compound can include 6 or more, 7 or more, 8 or more, or 9 or more, and 50 or less, 40 or less, 30 or less, 28 or less, 26 or less, 24 or less, 22 or less, 20 or less, 18 or less, 16 or less, 14 or less, 13 or less, 12 or less, 11 or less, or 10 or less deuterium atoms.

Representative examples of the second compound are as follows:

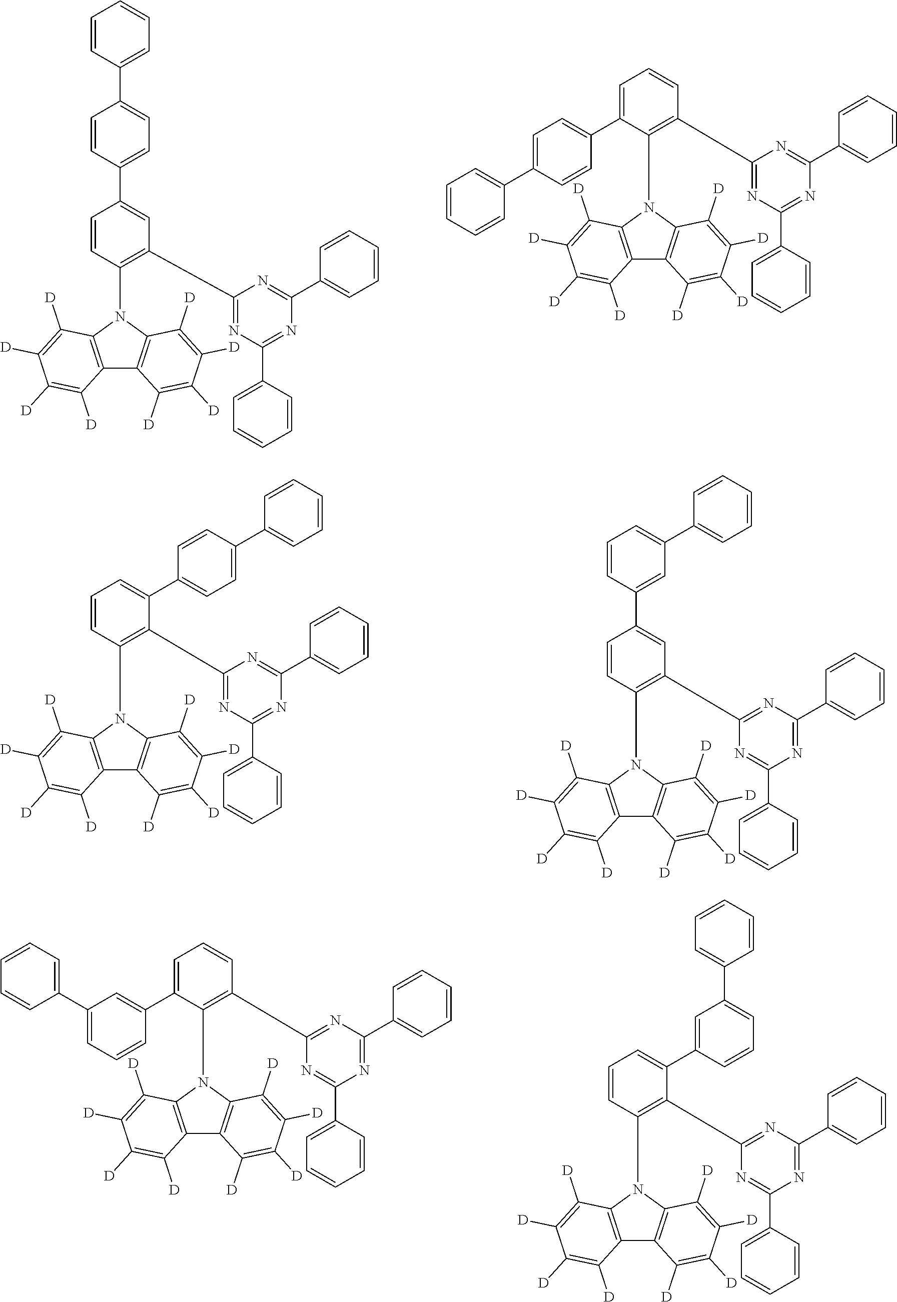

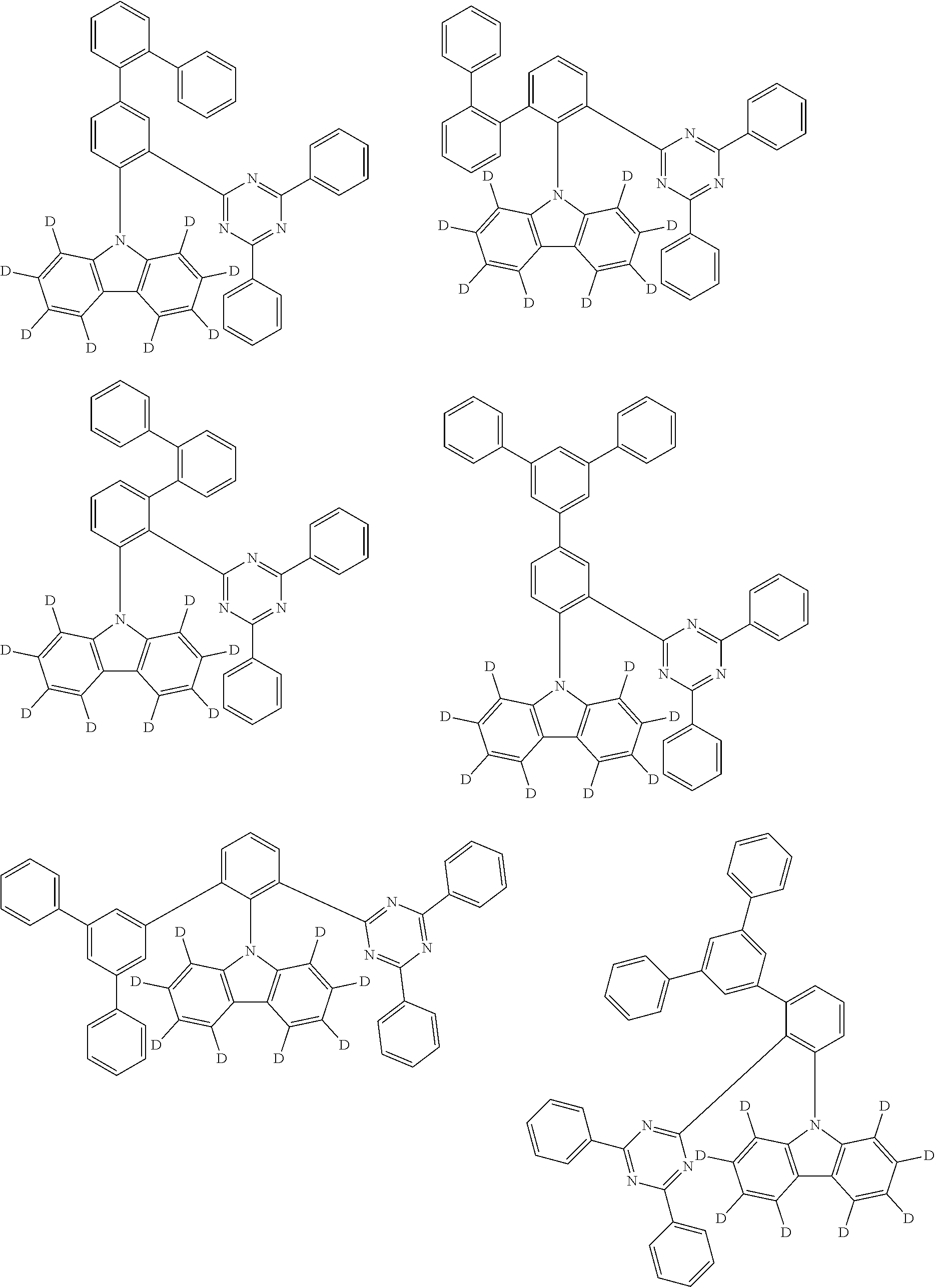

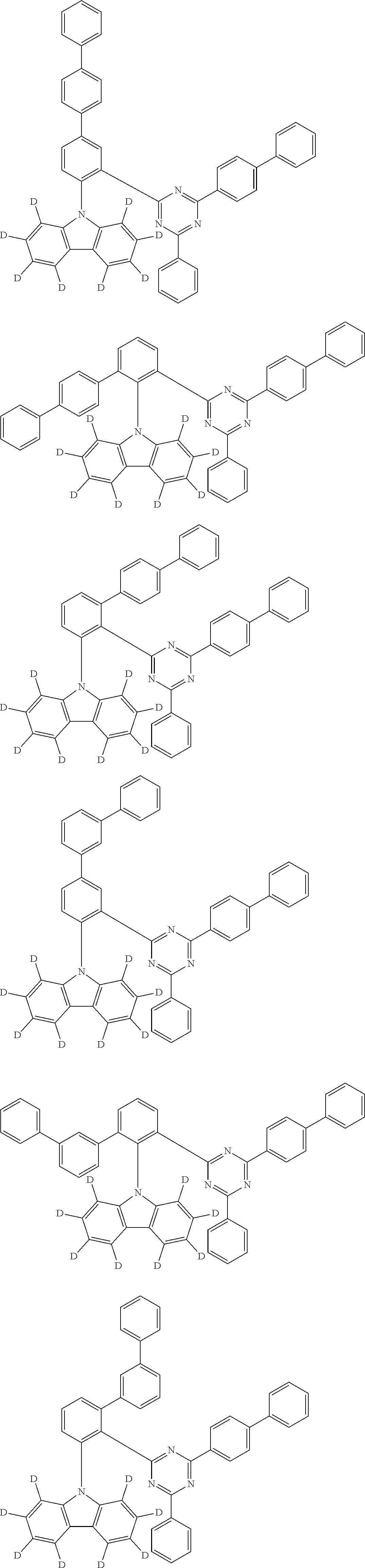

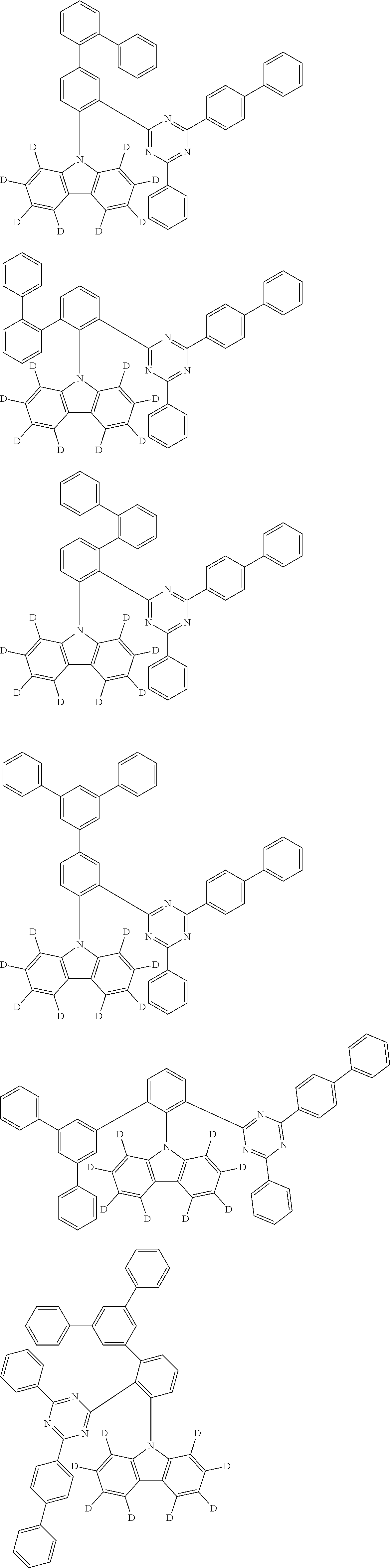

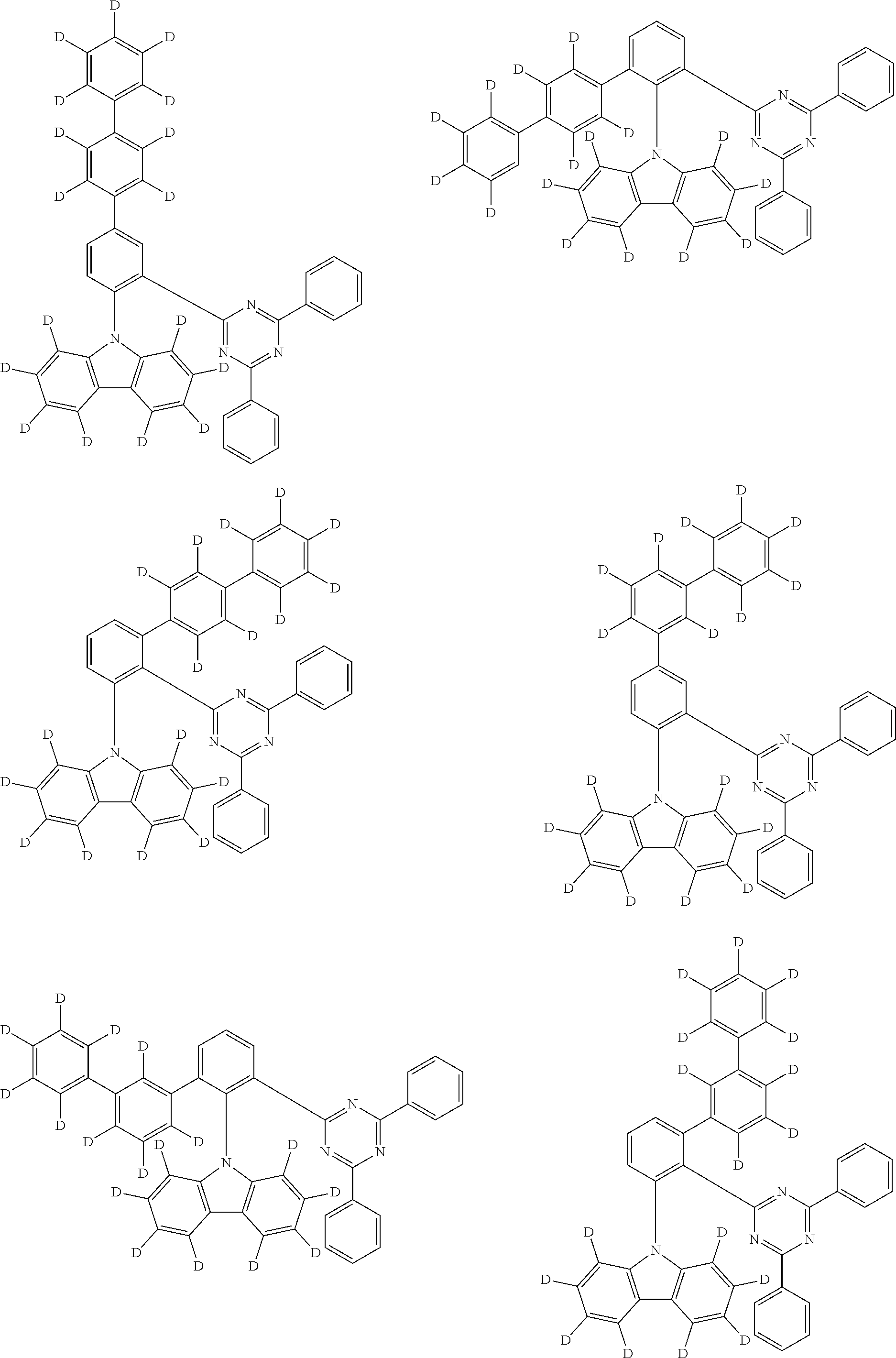

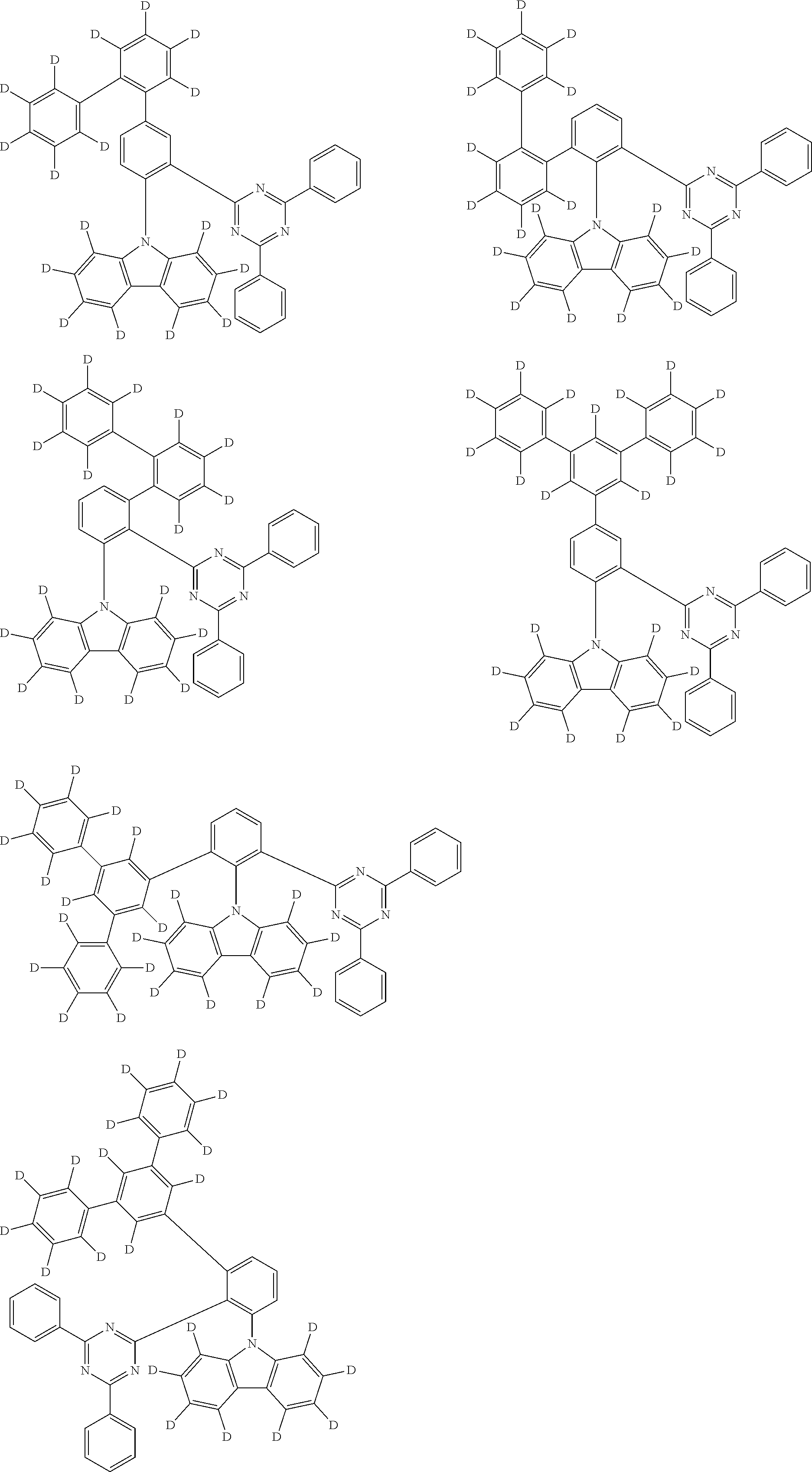

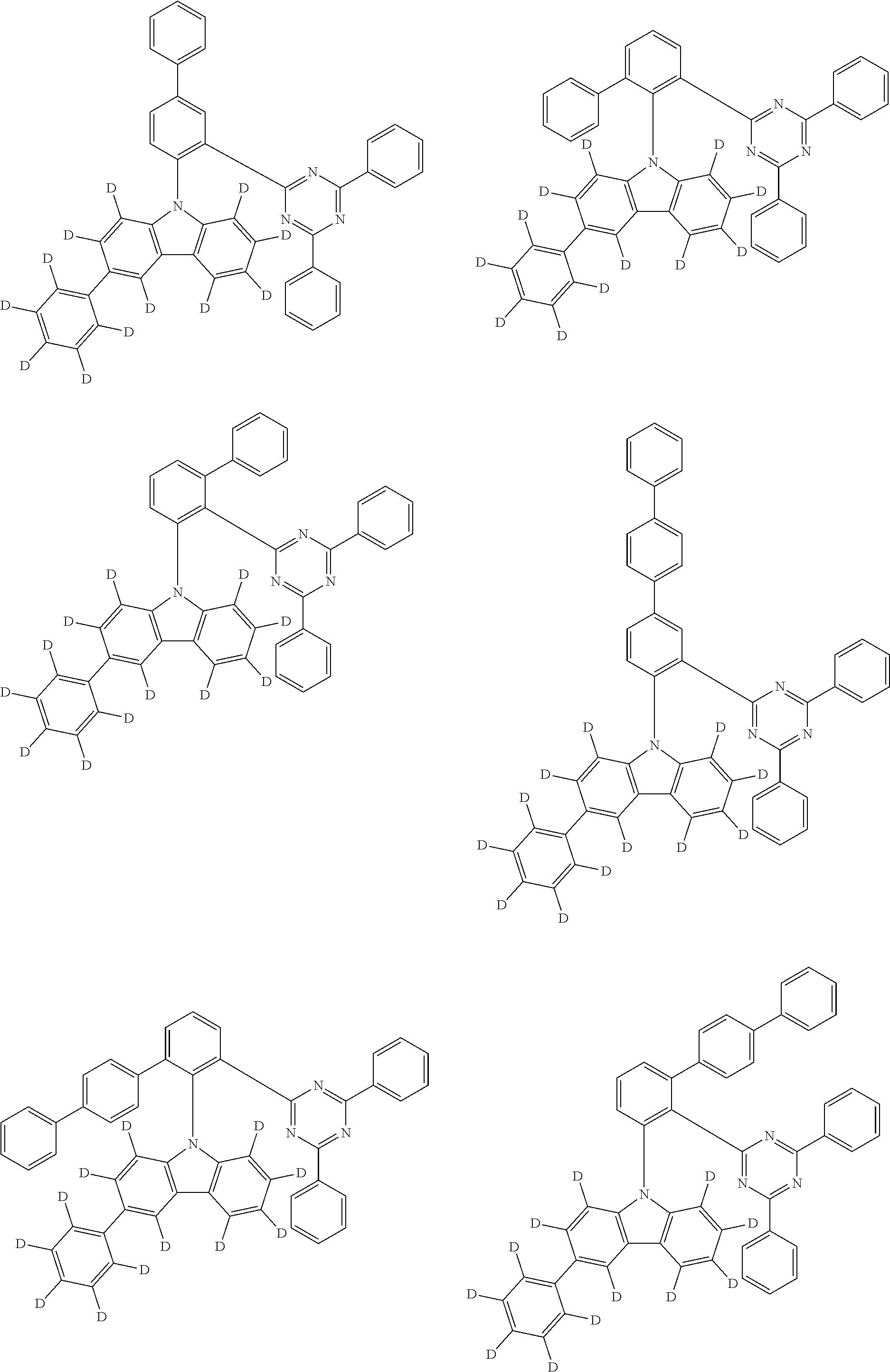

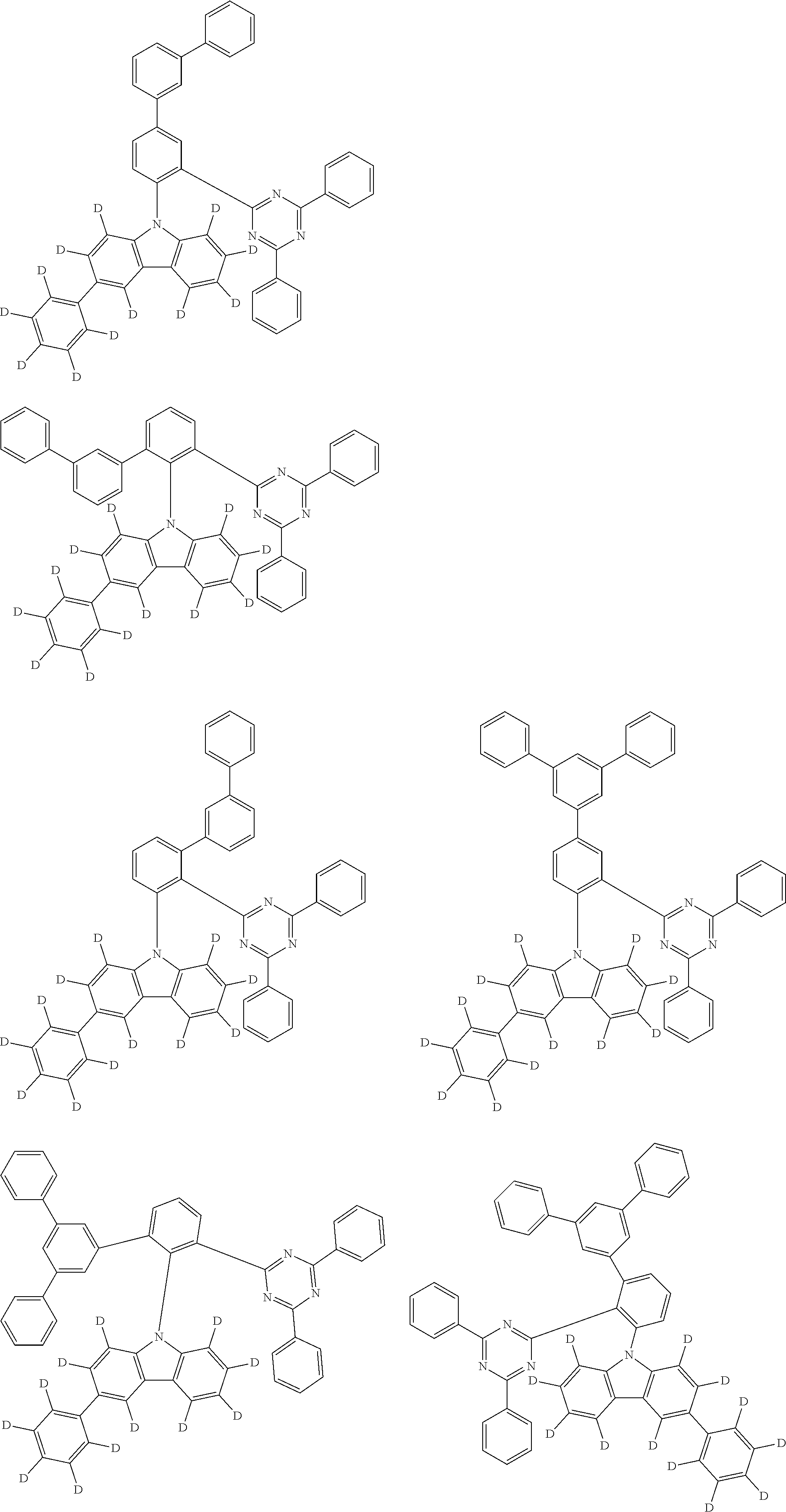

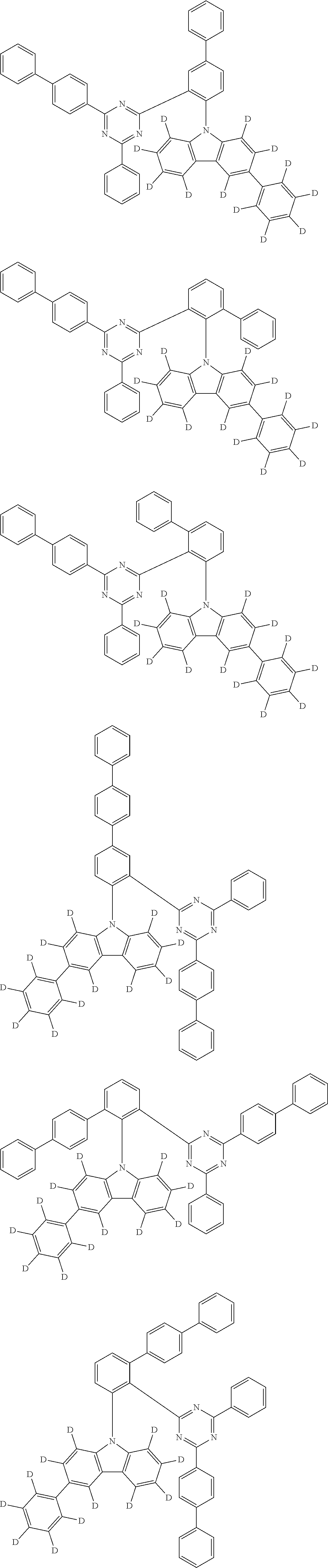

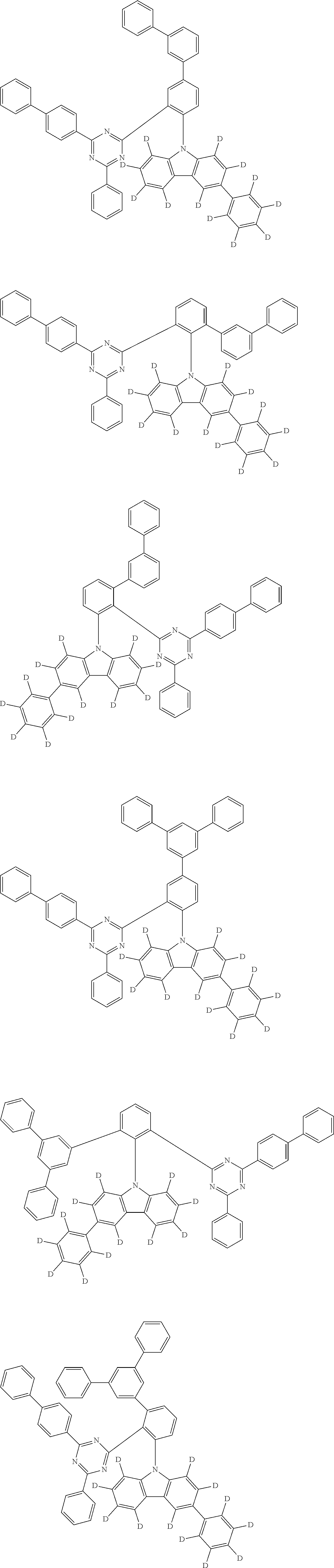

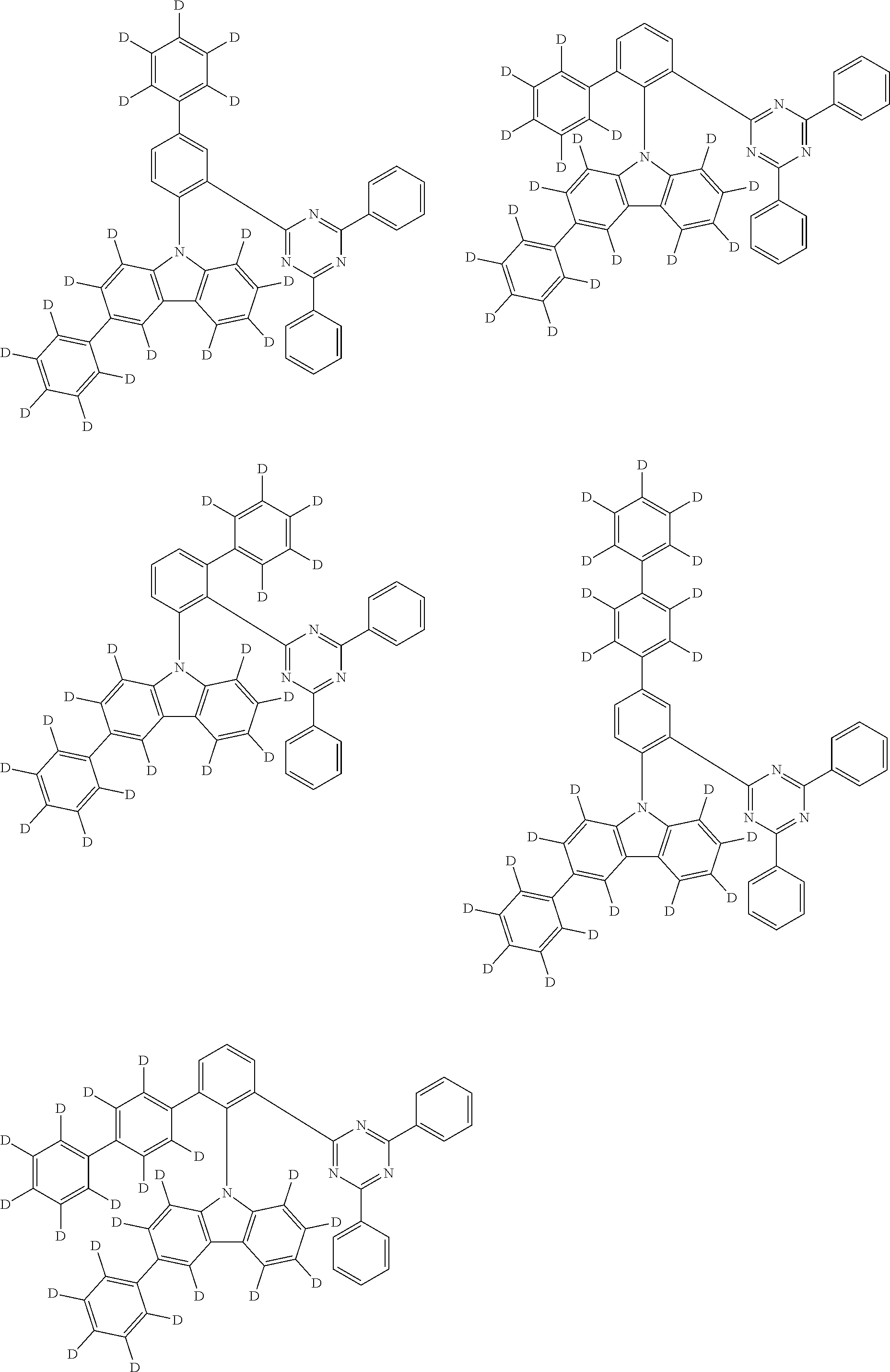

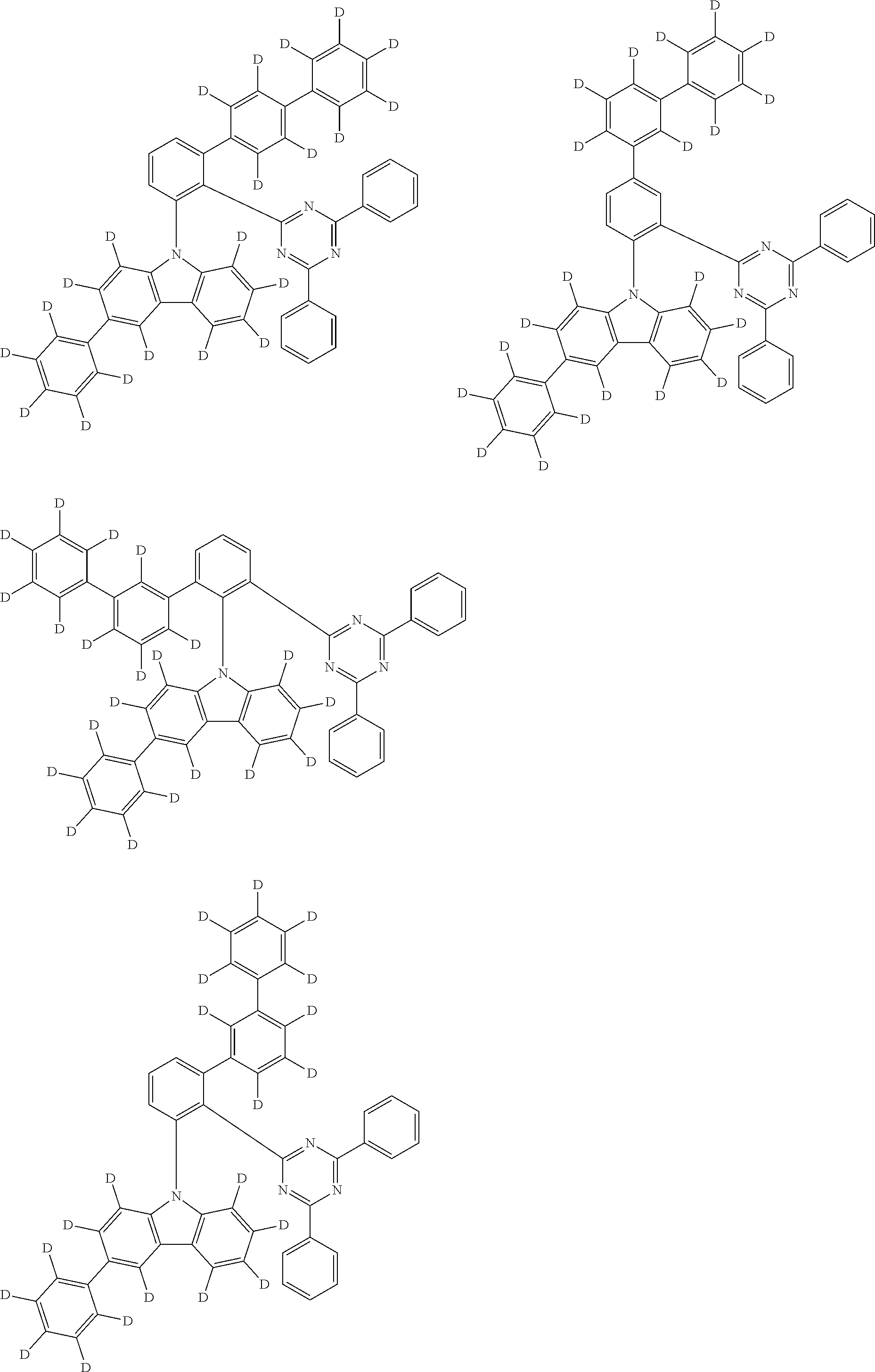

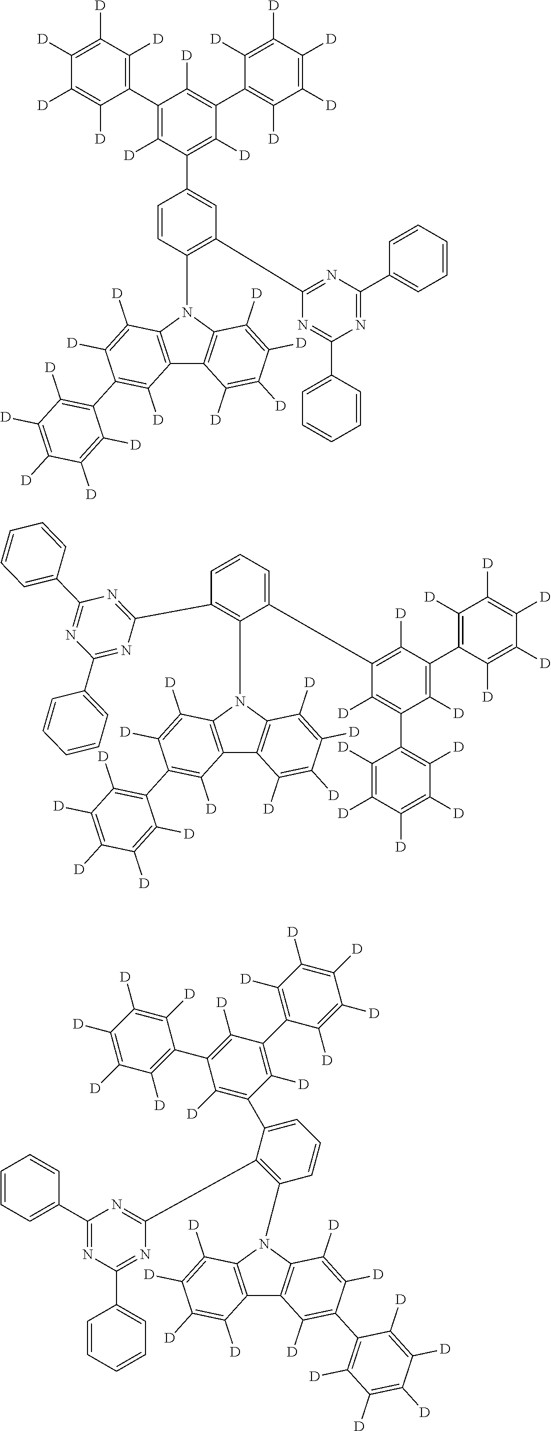

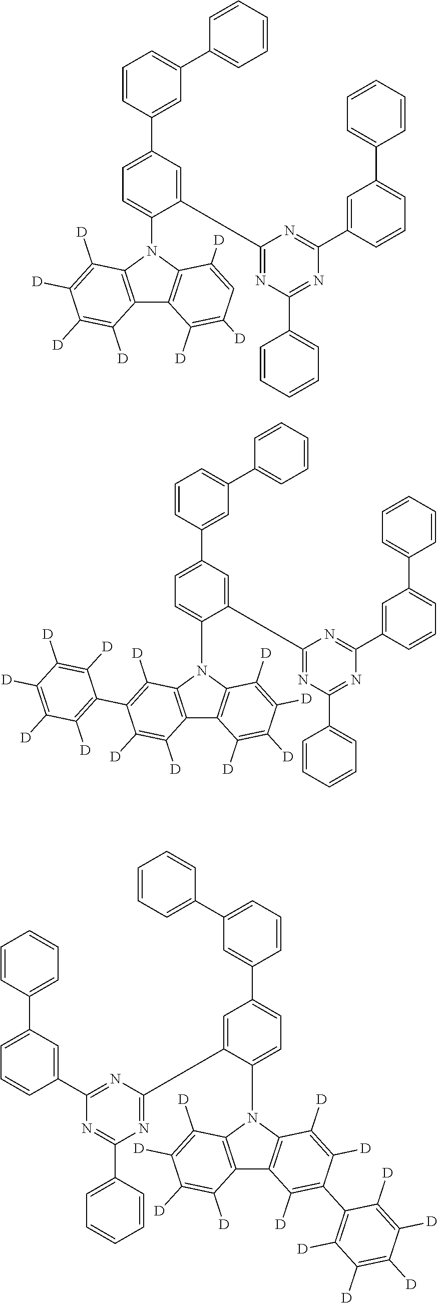

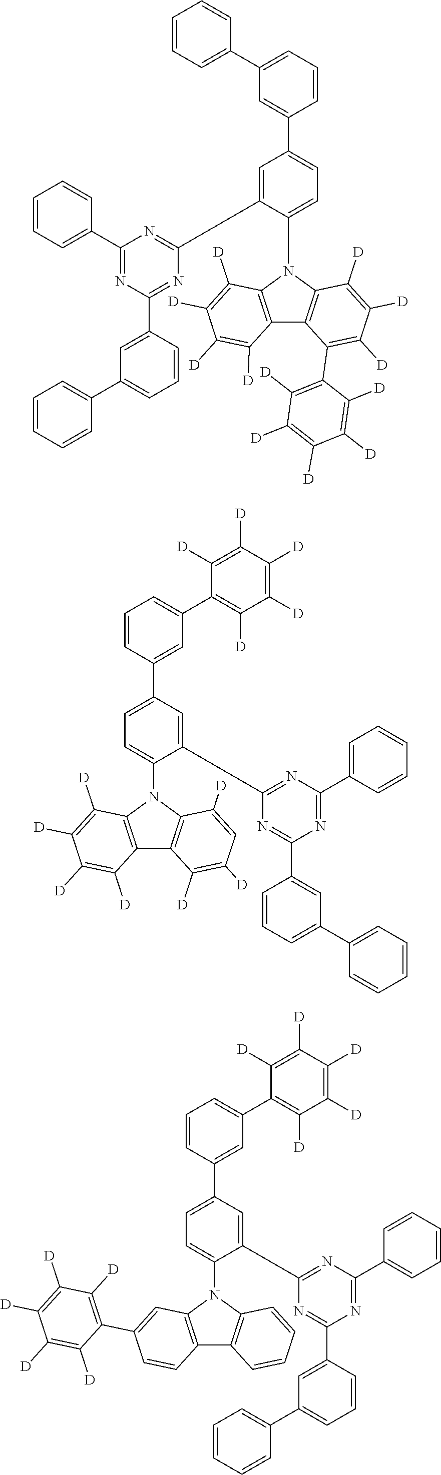 [SMILES: [2H]c1c([2H])c([2H])c(-c2c([2H])c([2H])c([2H])c3c2c2c([2H])c([2H])c([2H])c([2H])c2n3-c2ccc(-c3cccc(-c4ccccc4)c3)cc2-c2nc(-c3ccccc3)nc(-c3cccc(-c4ccccc4)c3)n2)c([2H])c1[2H] ; [2H]c1cc([2H])c2c(c1[2H])c1c([2H])c([2H])c([2H])c([2H])c1n2-c1ccc(-c2cccc(-c3c([2H])c([2H])c([2H])c([2H])c3[2H])c2)cc1-c1nc(-c2ccccc2)nc(-c2cccc(-c3ccccc3)c2)n1 ; [2H]c1c([2H])c([2H])c(-c2cccc(-c3ccc(-n4c5ccccc5c5ccc(-c6c([2H])c([2H])c([2H])c([2H])c6[2H])cc54)c(-c4nc(-c5ccccc5)nc(-c5cccc(-c6ccccc6)c5)n4)c3)c2)c([2H])c1[2H]]

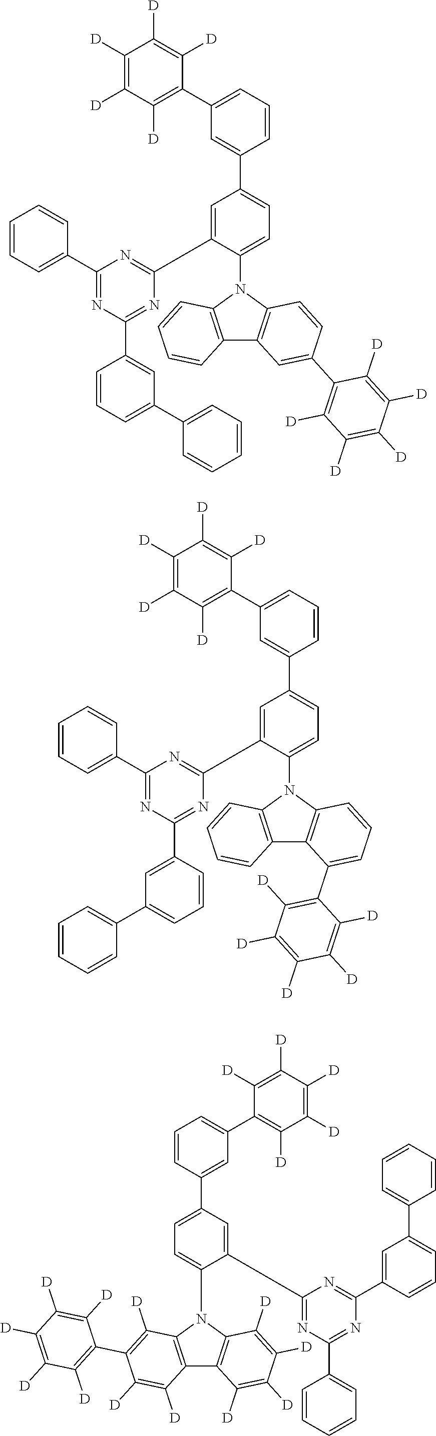

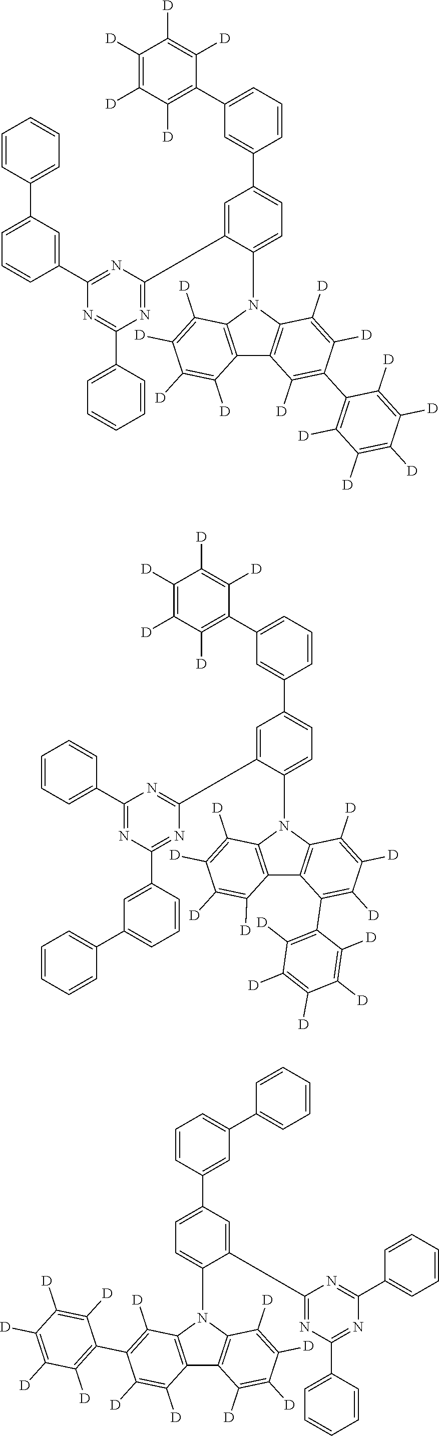

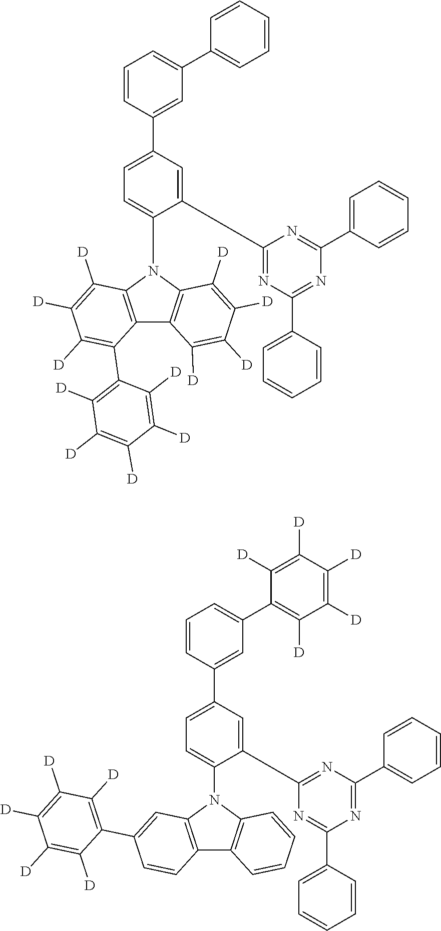 [SMILES: [2H]c1c([2H])c([2H])c(-c2c([2H])c([2H])c([2H])c3c2c2c([2H])c([2H])c([2H])c([2H])c2n3-c2ccc(-c3cccc(-c4ccccc4)c3)cc2-c2nc(-c3ccccc3)nc(-c3ccccc3)n2)c([2H])c1[2H] ; [2H]c1c([2H])c([2H])c(-c2cccc(-c3ccc(-n4c5ccccc5c5ccc(-c6c([2H])c([2H])c([2H])c([2H])c6[2H])cc54)c(-c4nc(-c5ccccc5)nc(-c5ccccc5)n4)c3)c2)c([2H])c1[2H]]

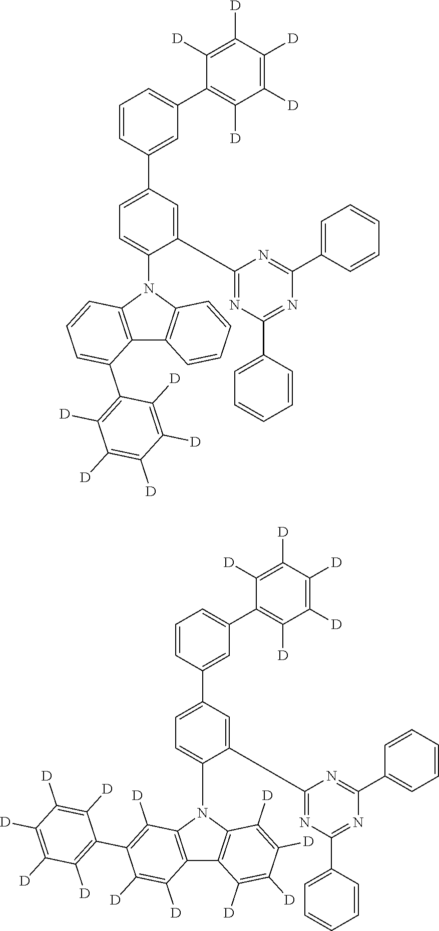 [SMILES: [2H]c1c([2H])c([2H])c(-c2cccc(-c3ccc(-n4c5ccccc5c5c(-c6c([2H])c([2H])c([2H])c([2H])c6[2H])cccc54)c(-c4nc(-c5ccccc5)nc(-c5ccccc5)n4)c3)c2)c([2H])c1[2H] ; [2H]c1c([2H])c([2H])c(-c2cccc(-c3ccc(-n4c5c([2H])c([2H])c([2H])c([2H])c5c5c([2H])c([2H])c(-c6c([2H])c([2H])c([2H])c([2H])c6[2H])c([2H])c54)c(-c4nc(-c5ccccc5)nc(-c5ccccc5)n4)c3)c2)c([2H])c1[2H]]

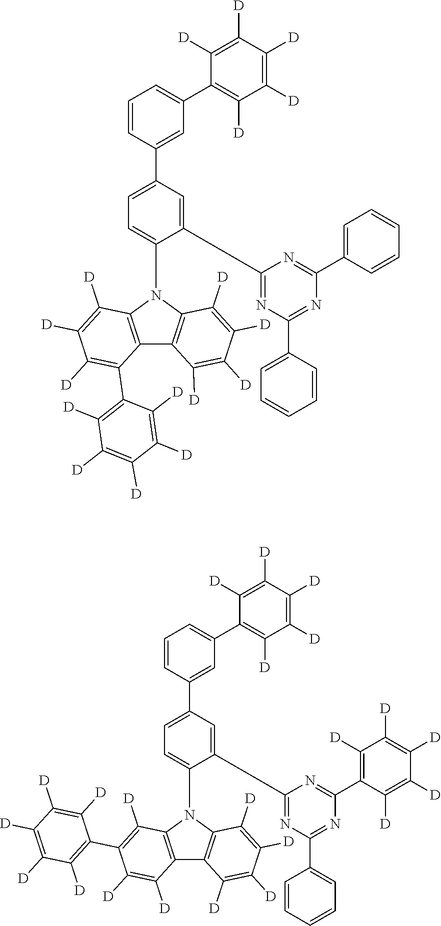 [SMILES: [2H]c1c([2H])c([2H])c(-c2cccc(-c3ccc(-n4c5c([2H])c([2H])c([2H])c([2H])c5c5c(-c6c([2H])c([2H])c([2H])c([2H])c6[2H])c([2H])c([2H])c([2H])c54)c(-c4nc(-c5ccccc5)nc(-c5ccccc5)n4)c3)c2)c([2H])c1[2H] ; [2H]c1c([2H])c([2H])c(-c2cccc(-c3ccc(-n4c5c([2H])c([2H])c([2H])c([2H])c5c5c([2H])c([2H])c(-c6c([2H])c([2H])c([2H])c([2H])c6[2H])c([2H])c54)c(-c4nc(-c5ccccc5)nc(-c5c([2H])c([2H])c([2H])c([2H])c5[2H])n4)c3)c2)c([2H])c1[2H]]

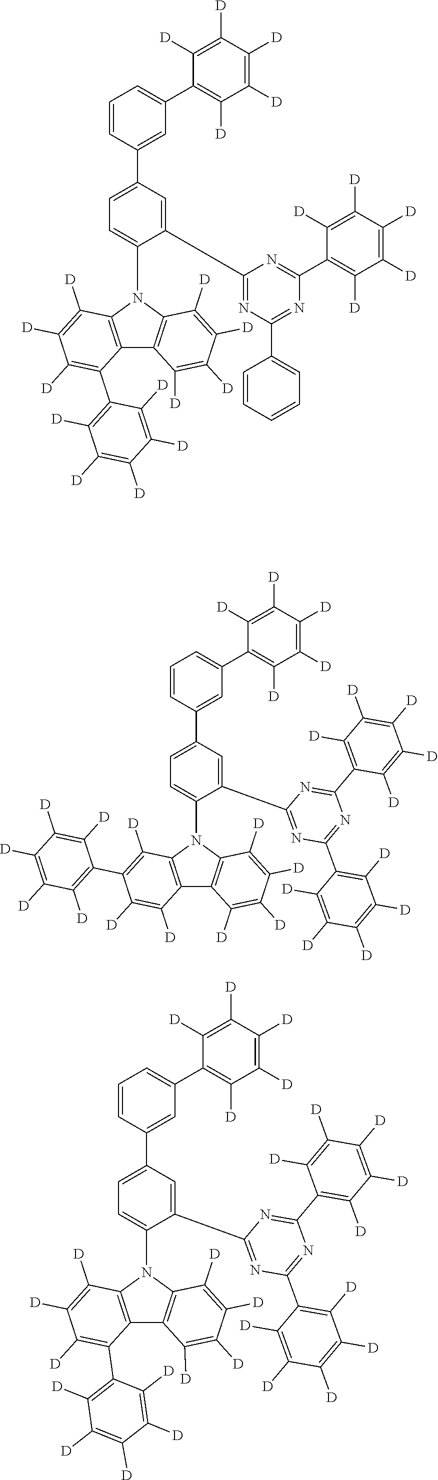

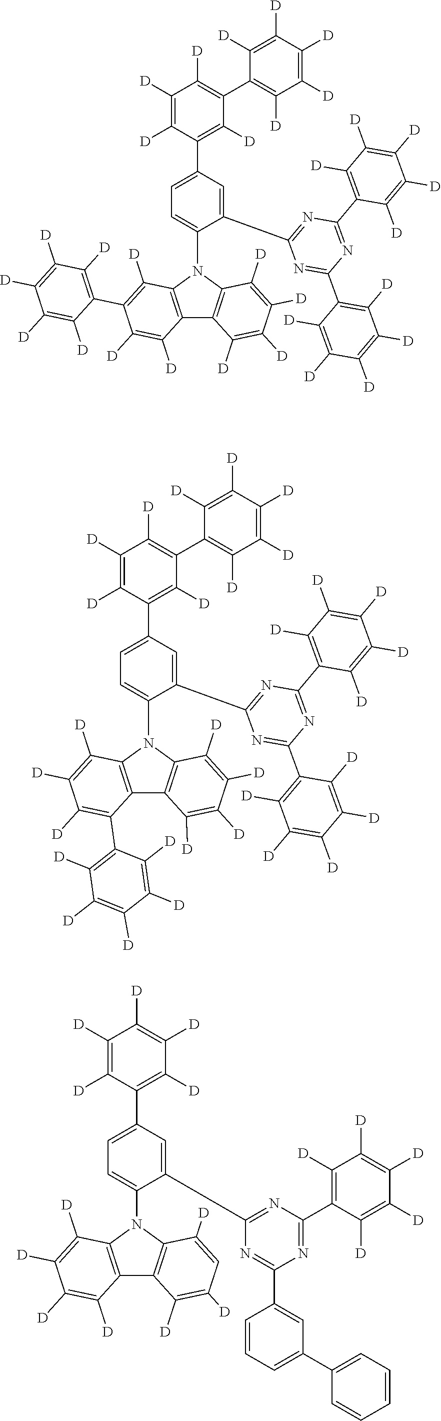

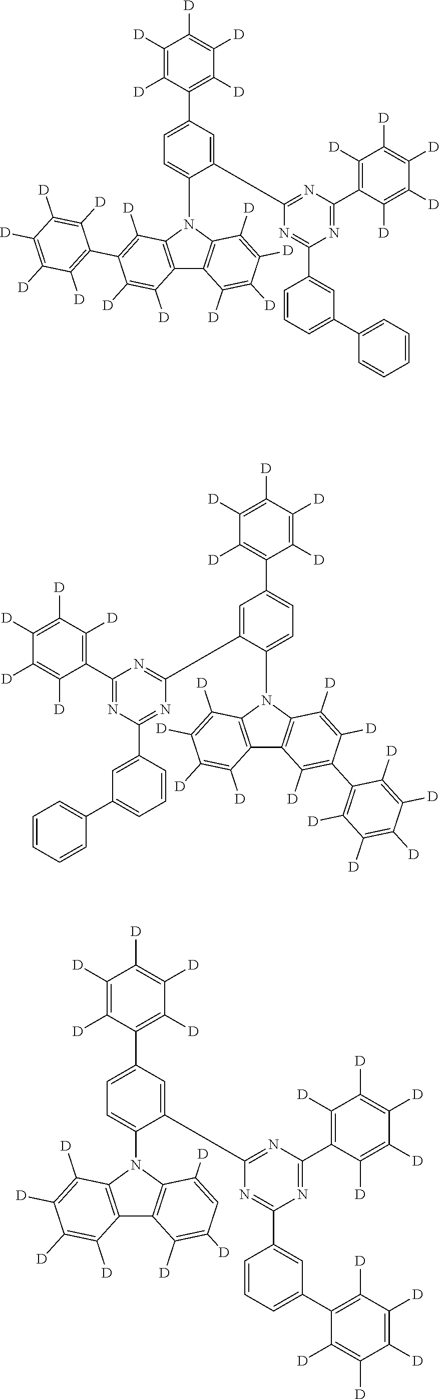

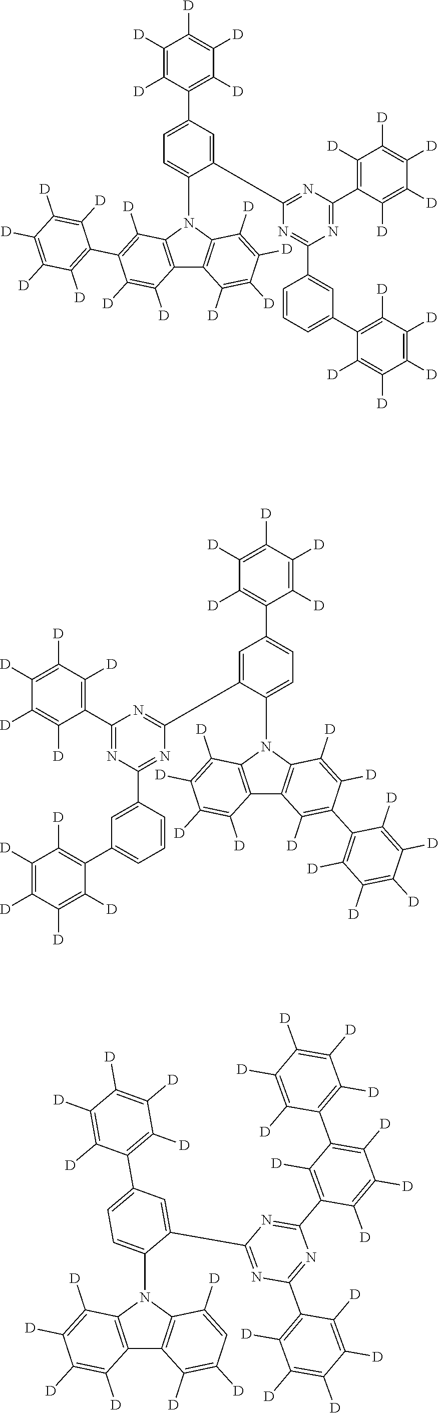

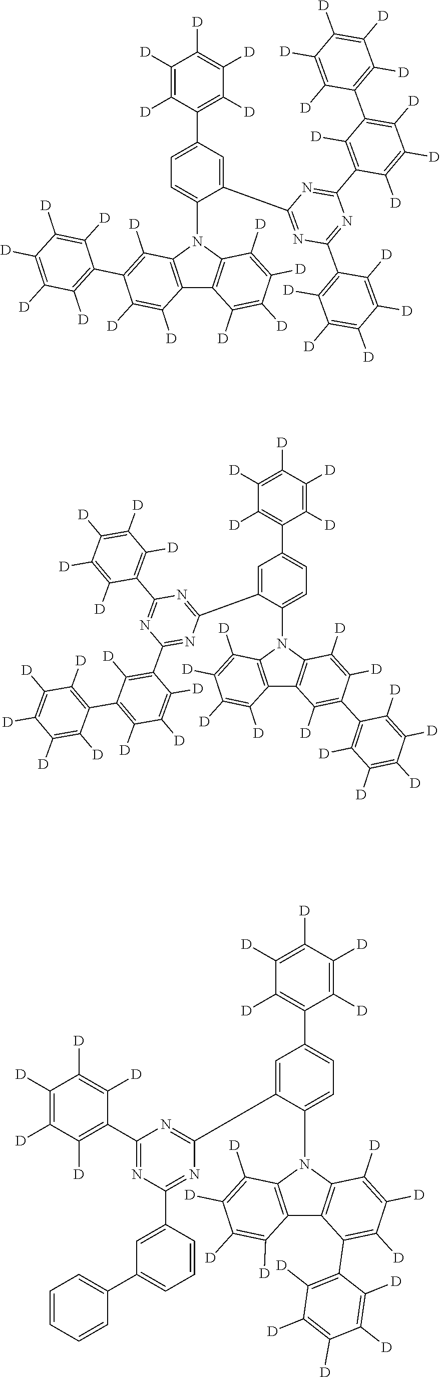

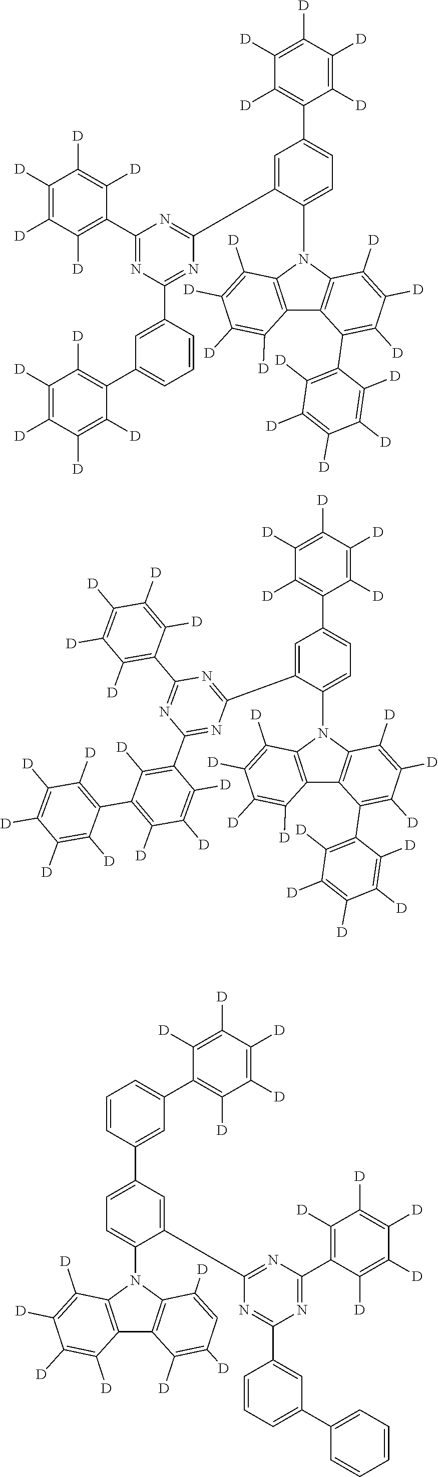

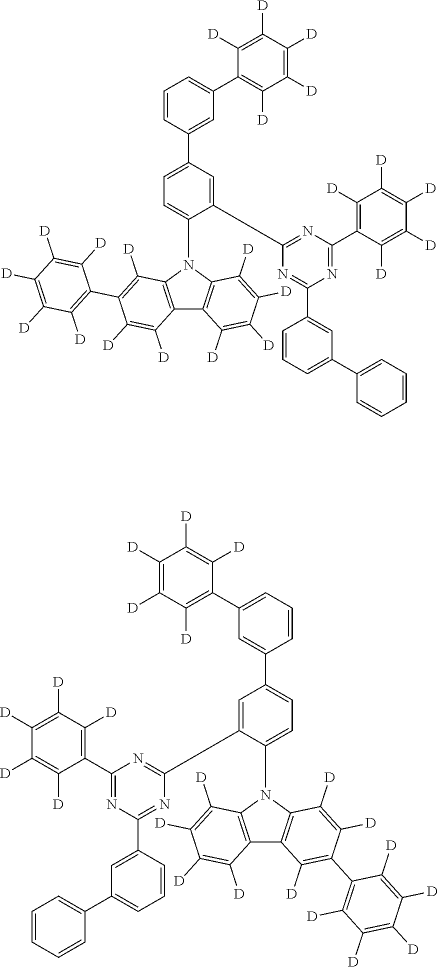 [SMILES: [2H]c1c([2H])c([2H])c(-c2cccc(-c3ccc(-n4c5c([2H])c([2H])c([2H])c([2H])c5c5c([2H])c([2H])c(-c6c([2H])c([2H])c([2H])c([2H])c6[2H])c([2H])c54)c(-c4nc(-c5cccc(-c6ccccc6)c5)nc(-c5c([2H])c([2H])c([2H])c([2H])c5[2H])n4)c3)c2)c([2H])c1[2H] ; [2H]c1c([2H])c([2H])c(-c2cccc(-c3ccc(-n4c5c([2H])c([2H])c([2H])c([2H])c5c5c([2H])c(-c6c([2H])c([2H])c([2H])c([2H])c6[2H])c([2H])c([2H])c54)c(-c4nc(-c5cccc(-c6ccccc6)c5)nc(-c5c([2H])c([2H])c([2H])c([2H])c5[2H])n4)c3)c2)c([2H])c1[2H]]

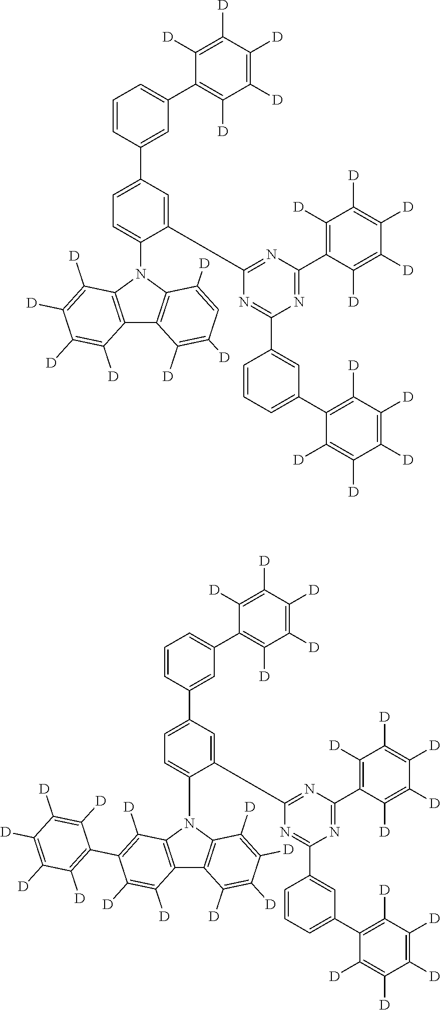 [SMILES: [2H]c1cc([2H])c2c(c1[2H])c1c([2H])c([2H])c([2H])c([2H])c1n2-c1ccc(-c2cccc(-c3c([2H])c([2H])c([2H])c([2H])c3[2H])c2)cc1-c1nc(-c2cccc(-c3c([2H])c([2H])c([2H])c([2H])c3[2H])c2)nc(-c2c([2H])c([2H])c([2H])c([2H])c2[2H])n1 ; [2H]c1c([2H])c([2H])c(-c2cccc(-c3ccc(-n4c5c([2H])c([2H])c([2H])c([2H])c5c5c([2H])c([2H])c(-c6c([2H])c([2H])c([2H])c([2H])c6[2H])c([2H])c54)c(-c4nc(-c5cccc(-c6c([2H])c([2H])c([2H])c([2H])c6[2H])c5)nc(-c5c([2H])c([2H])c([2H])c([2H])c5[2H])n4)c3)c2)c([2H])c1[2H]]

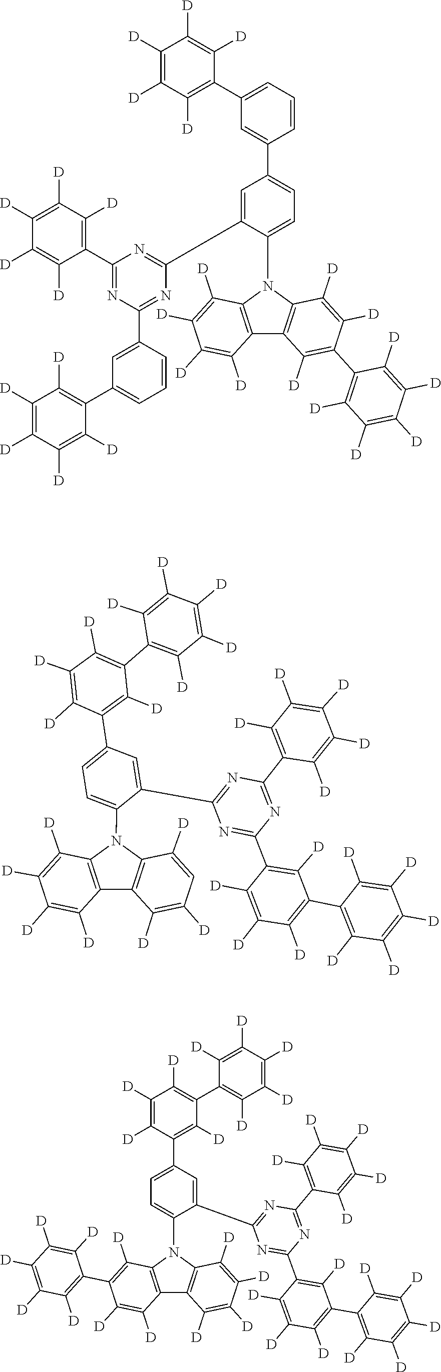

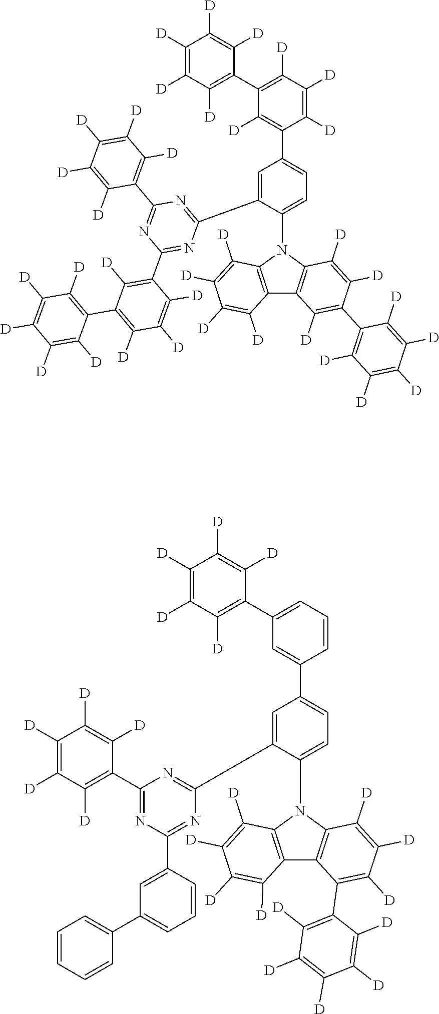

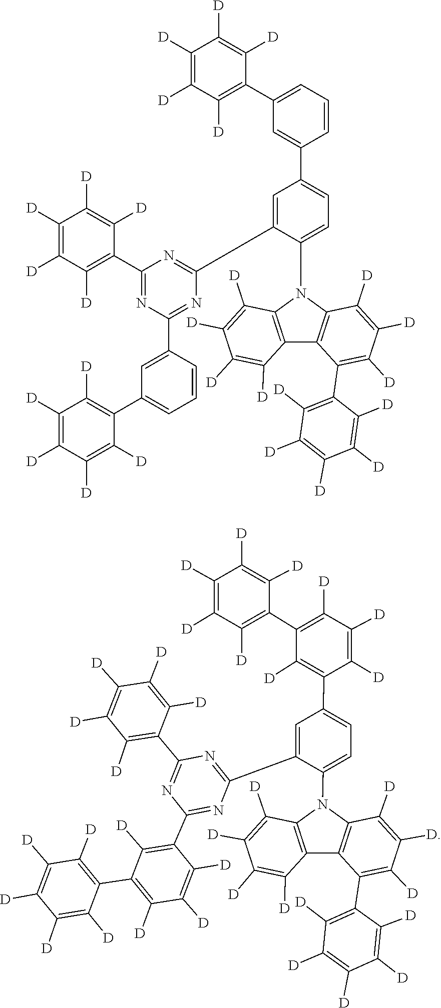

Meanwhile, the second compound can be prepared by a preparation method such as Reaction Scheme 4 below, for example, and the remaining compounds can be similarly prepared:

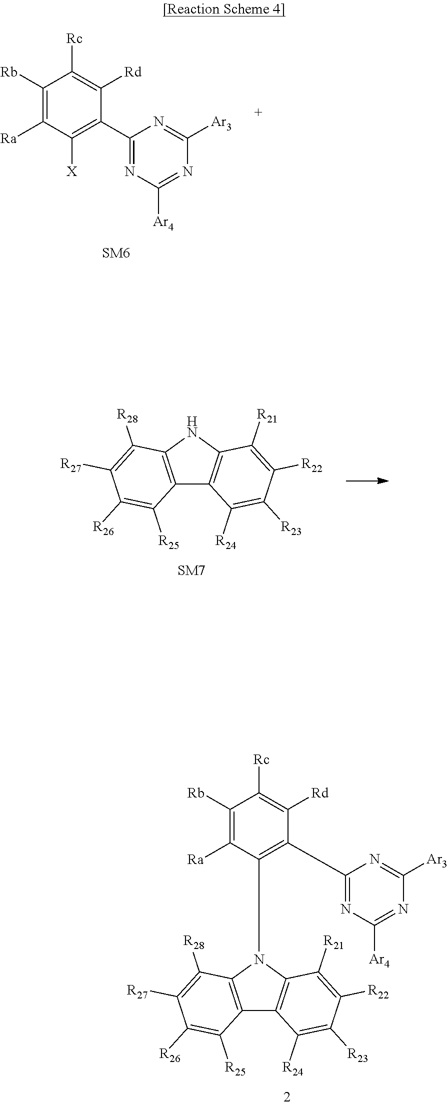

In the Reaction Scheme 4, Ar₃, Ar₄, Rₐ to R_{d}, and R₂₁ to R₂₈ are as defined in the Chemical Formula 2, and X is a halogen, and preferably X is fluoro or chloro.

Specifically, the Reaction Scheme 4 is an amine substitution reaction, and it is preferable to perform it in the presence of a palladium catalyst and a base, and the reactor for the amine substitution reaction can be changed as known in the art. The preparation method can be more specified in the preparation examples described below.

Meanwhile, the first compound and the second compound can be included in the composition in a weight ratio of 1:99 to 99:1. In addition, from the aspect of further improving the voltage, efficiency, and lifetime of the device by balancing holes and electrons, the first compound and the second compound can be included in a weight ratio of 10:90 to 90:10, or 20:80 to 50:50. More specifically, the first compound and the second compound can be included in the composition in a weight ratio of 40:60 to 50:50.

In addition, the composition can be a mixture or an organic alloy.

In one embodiment, the composition can be a mixture in which the first compound and the second compound are simply mixed. Such a mixture is one in which each compound is physically and homogeneously mixed without a separate pre-treatment, and can be prepared using a mixer commonly known in the technical field.

As such, when the first compound and the second compound are applied to an organic light emitting device in the form of a mixture composition, since each compound is supplied from a single source rather than separate sources during the formation of an organic material layer, the process can be simplified because a process control step for multiple sources is not required.

In another embodiment, the composition can be an organic alloy in which the first compound and the second compound have a chemical interaction by a pre-treatment. The pre-treatment can be, for example, cooling after a heat treatment process such as heating and/or sublimating a mixture of each compound, but is not limited thereto.

In addition, when the first compound and the second compound are applied to an organic light emitting device in the form of an organic alloy composition,
all compounds are supplied from a single source during the formation of an organic material layer, which not only simplifies the process but also ensures the uniformity and consistency of the deposited material. Therefore, when forming a plurality of organic material layers in a continuous process, organic material layers having substantially the same ratio of components can be continuously produced, and accordingly, the reproducibility and reliability of the organic material layers can be improved.

### Organic Light Emitting Device

Meanwhile, another embodiment of the present disclosure provides a light emitting device comprising an anode; a cathode provided opposite the anode; and one or more organic material layers provided between the anode and the cathode, wherein one or more of the organic material layers comprise the composition for an organic light emitting device. In such an organic light emitting device, the composition can be supplied through a single source during the formation of an organic material layer.

Herein, the organic material layer comprising the composition can be a light emitting layer.

In addition, another embodiment of the present disclosure provides an organic light emitting device, comprising an anode; a cathode provided opposite the anode; and one or more organic material layers provided between the anode and the cathode, wherein one or more of the organic material layers comprise the compound represented by the Chemical Formula 1 and the compound represented by the Chemical Formula 2. In such an organic light emitting device, the first compound and the second compound can be supplied through separate sources during the formation of an organic material layer. For example, in the organic light emitting device, the organic material layer comprising the first compound and the second compound can be formed through co-deposition of the first compound and the second compound.

Herein, the organic material layer comprising the first compound and the second compound can be a light emitting layer.

In addition, another embodiment of the present disclosure provides an organic light emitting device, comprising an anode; a cathode provided opposite the anode; and a light emitting layer provided between the anode and the cathode, wherein the light emitting layer comprises the first compound represented by the Chemical Formula 1 and the second compound represented by the Chemical Formula 2.

In this case, the descriptions of the first compound, the second compound, and the composition refer to the aforementioned descriptions.

In addition, the organic material layer of the organic light emitting device can have a single layer structure, but can have a multilayer structure in which two or more organic material layers are stacked. For example, the organic light emitting device of the present disclosure can have a structure comprising a hole injection layer, a hole transport layer, a light emitting layer, an electron transport layer, an electron injection layer, etc. as an organic material layer. However, the structure of the organic light emitting device is not limited thereto and can include a smaller or larger number of organic material layers.

In one embodiment, the organic material layer can comprise a light emitting layer, and in this case, the organic material layer comprising the first compound and the second compound can be the light emitting layer.

In another embodiment, the organic material layer can comprise a hole injection layer, a hole transport layer, a light emitting layer, and an electron injection and transport layer, and in this case, the organic material layer comprising the composition can be the light emitting layer.

In another embodiment, the organic material layer can comprise a hole injection layer, a hole transport layer, an electron blocking layer, a light emitting layer, and an electron injection and transport layer, and in this case, the organic material layer comprising the composition can be the light emitting layer.

In another embodiment, the organic material layer can comprise a hole injection layer, a hole transport layer, an electron blocking layer, a light emitting layer, a hole blocking layer, an electron transport layer, and an electron injection layer, and in this case, the organic material layer comprising the composition can be the light emitting layer.

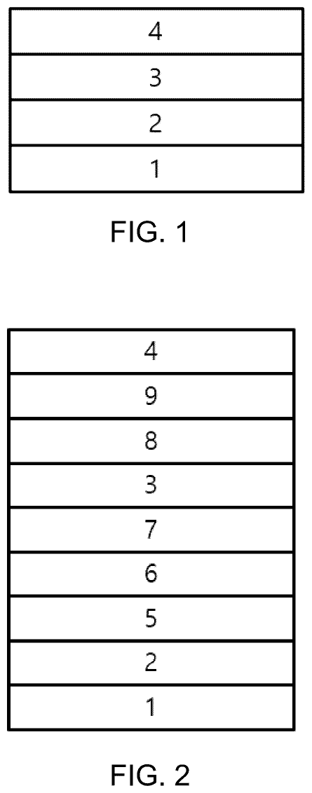

In addition, the organic light emitting device according to the present disclosure can be an organic light emitting device of a normal type structure in which an anode, one or more organic material layers, and a cathode are sequentially stacked on a substrate. In addition, the organic light emitting device according to the present disclosure can be an organic light emitting device of an inverted type structure in which a cathode, one or more organic material layers, and an anode are sequentially stacked on a substrate. For example, the structure of the organic light emitting device according to an embodiment of the present disclosure is illustrated in FIG. 1 and FIG. 2.

FIG. 1 shows an example of an organic light emitting device composed of a substrate (1), an anode (2), a light emitting layer (3), and a cathode (4). In such a structure, the composition, or the first compound and the second compound can be included in the light emitting layer.

FIG. 2 shows an example of an organic light emitting device composed of a substrate (1), an anode (2), a hole injection layer (5), a hole transport layer (6), an electron blocking layer (7), a light emitting layer (3), a hole blocking layer (8), an electron transport and injection layer (9), and a cathode (4). In such a structure, the composition, or the first compound and the second compound can be included in the light emitting layer.

As an example, the organic light emitting device according to the present disclosure can be composed of a substrate, an anode, a hole injection layer, a first hole transport layer, a second hole transport layer, an electron blocking layer, a light emitting layer, a hole blocking layer, an electron injection and transport layer, and a cathode. In such a structure, the composition, or the first compound and the second compound can be included in the light emitting layer.

In addition, the organic light emitting device can be manufactured by materials and methods known in the art, except that one or more of the organic material layers comprise the composition, or the first compound and the second compound. In addition, when the organic light emitting device includes a plurality of organic material layers, the organic material layers can be formed of the same material or different materials.

For example, the organic light emitting device according to the present disclosure can be manufactured by sequentially stacking an anode, an organic material layer, and a cathode on a substrate. At this time, the organic light-emitting device can be manufactured by forming an anode on the substrate through deposition of a metal, a conductive metal oxide, or an alloy thereof using PVD methods such as sputtering or e-beam evaporation, then forming organic material layers comprising a hole injection layer, a hole transport layer, an emission layer, and an electron transport layer thereon, and finally depositing a material that can serve as the cathode thereon. In addition to such a method, an organic light emitting device can be made by sequentially depositing a cathode material, an organic material layer, and an anode material on a substrate. (WO 2003/012890). However, the manufacturing method is not limited thereto.

In addition, one or more of the organic material layers can be formed by a solution coating method. Here, the solution coating method means spin coating, dip coating, doctor blading, inkjet printing, screen printing, a spray method, or roll coating, etc., but is not limited thereto.

In addition, the organic light emitting device can be a bottom emission device, a top emission device, or a dual-sided emission device, and in particular, can be a bottom emission device that requires relatively high luminous efficiency.

Hereinafter, each component of the organic light emitting device will be described in detail.

### Anode and Cathode

The anode and cathode used in the present disclosure mean the electrodes used in an organic light emitting device.

As the anode material, a material with a large work function is generally preferable so that hole injection into the organic material layer can be smooth. Specific examples of the anode material include metals such as vanadium, chromium, copper, zinc, and gold, or alloys thereof, metal oxides such as zinc oxide, indium oxide, indium tin oxide (ITO), and indium zinc oxide (IZO); a combination of a metal and an oxide such as ZnO:Al or SnO2:Sb; and conductive polymers such as poly(3-methylthiophene), poly[3,4-(ethylene-1,2-dioxy)thiophene](PEDOT), polypyrrole, and polyaniline, but are not limited thereto.

As the cathode material, a material with a small work function is generally preferable so that electron injection into the organic material layer is easy. Specific examples of the cathode material include metals such as magnesium, calcium, sodium, potassium, titanium, indium, yttrium, lithium, gadolinium, aluminum, silver, tin, and lead, or alloys thereof; and multilayer structure materials such as LiF/Al or LiO₂/Al, but are not limited thereto.

### Hole Injection Layer

The organic light emitting device according to the present disclosure can optionally include a hole injection layer between the anode and the hole transport layer described below.

The hole injection layer is a layer which is located on the anode and injects holes from the anode, and includes a hole injection material. As such a hole injection material, a compound is preferable that has the ability to transport holes, has an excellent hole injection effect from the anode to the light emitting layer or the light emitting material, prevents the movement of excitons generated in the light emitting layer to the electron injection layer or the electron injection material, and also has an excellent thin film forming ability. In particular, it is suitable that the HOMO (highest occupied molecular orbital) of the hole injection material is between the work function of the anode material and the HOMO of the surrounding organic material layer.

Specific examples of the hole injection material include the compound represented by Chemical Formula 1, metal porphyrin, oligothiophene, an arylamine-based organic material, a hexanitrilehexaazatriphenylene-based organic material, a quinacridone-based organic material, a perylene-based organic material, anthraquinone, polyaniline and polythiophene-based conductive polymer, and the like, but are not limited thereto.

### Hole Transport Layer

The organic light emitting device according to the present disclosure can optionally include one or more hole transport layers between the anode and the light emitting layer.

The hole transport layer is a layer that receives holes from the anode, or from a hole injection layer formed on the anode, and transports the holes to the light emitting layer, and includes a hole transport material. The hole transport material is suitably a material having large mobility to the holes, which can receive holes from the anode or the hole injection layer and transfer the holes to the light emitting layer. Specific examples include arylamine-based organic material, a conductive polymer, a block copolymer in which a conjugate portion and a non-conjugate portion are present together, and the like, but are not limited thereto.

### Electron Blocking Layer

The organic light emitting device according to the present disclosure can optionally include an electron blocking layer between the hole transport layer and the light emitting layer. The electron blocking layer refers to a layer which is formed on the hole transport layer, preferably provided in contact with the light emitting layer, and serves to adjust the hole mobility, prevent excessive movement of electrons, and increase the probabilities of hole-electron coupling, thereby improving the efficiency of the organic light emitting device. The electron blocking layer includes an electron blocking material, and examples of such electron blocking material can include an arylamine-based organic material, and the like, but is not limited thereto.

### Light Emitting Layer

The organic light emitting device according to the present disclosure includes a light emitting layer between the anode and the cathode.

The light emitting layer means a layer that can emit light in the visible light region by combining holes and electrons received from the anode and the cathode. Generally, the light emitting layer includes a host material and a dopant material.

As the host material, the composition described above or the first compound and the second compound can be used simultaneously. Further, the host material can further include a fused aromatic ring derivative or a heterocycle-containing compound or the like. Specific examples of the fused aromatic ring derivatives include anthracene derivatives, pyrene derivatives, naphthalene derivatives, pentacene derivatives, phenanthrene compounds, fluoranthene compounds, and the like. Examples of the heterocyclic-containing compounds include carbazole derivatives, dibenzofuran derivatives, ladder-type furan compounds, pyrimidine derivatives, and the like, but are not limited thereto.

Examples of the dopant material include an aromatic amine derivative, a styrylamine compound, a boron complex, a fluoranthene compound, a metal complex, and the like. Specifically, the aromatic amine derivative is a substituted or unsubstituted fused aromatic ring derivative having an arylamino group, and examples thereof include pyrene, anthracene, chrysene, periflanthene and the like, which have an arylamino group. The styrylamine compound is a compound where at least one arylvinyl group is substituted in substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, the metal complex includes an iridium complex, a platinum complex, and the like, but is not limited thereto.

More specifically, as the dopant material, a compound such as the following can be used, but it is not limited thereto:

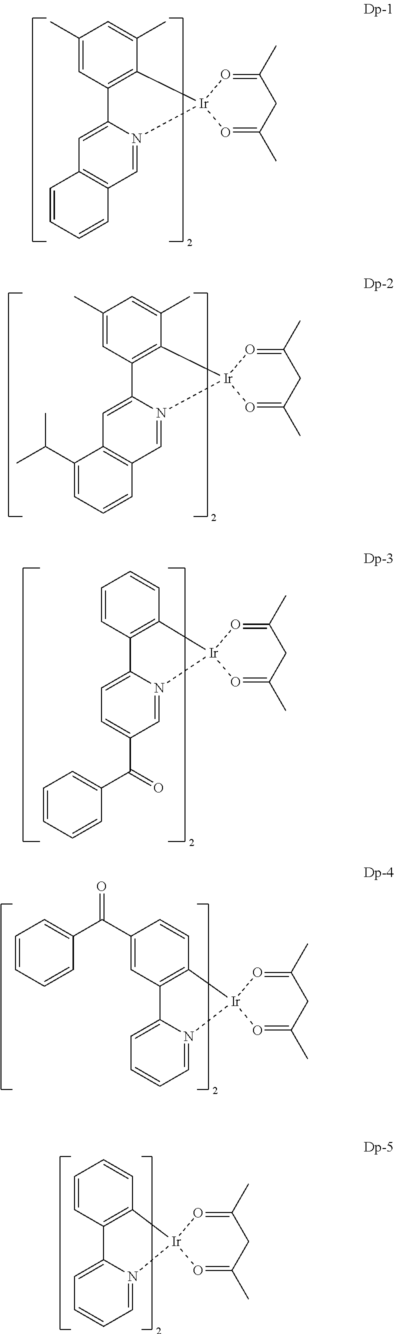

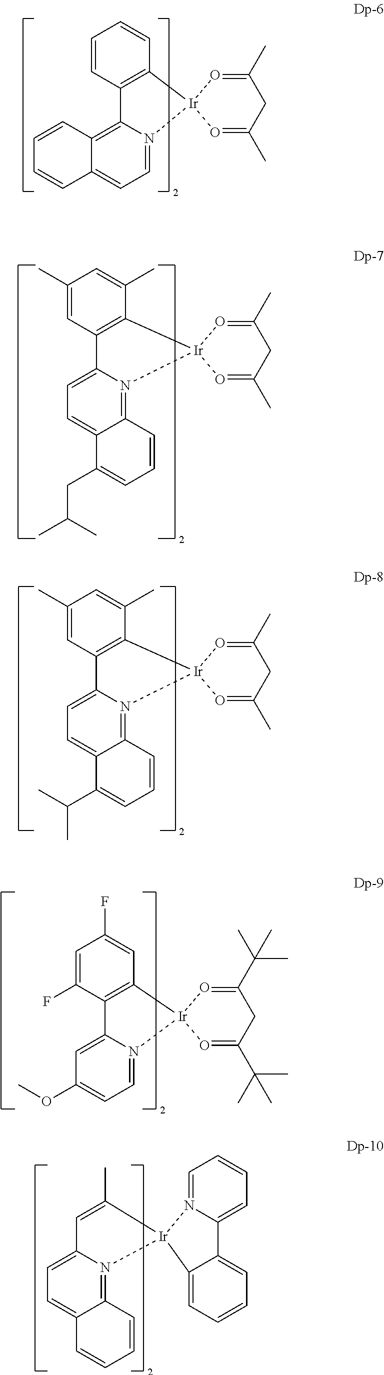

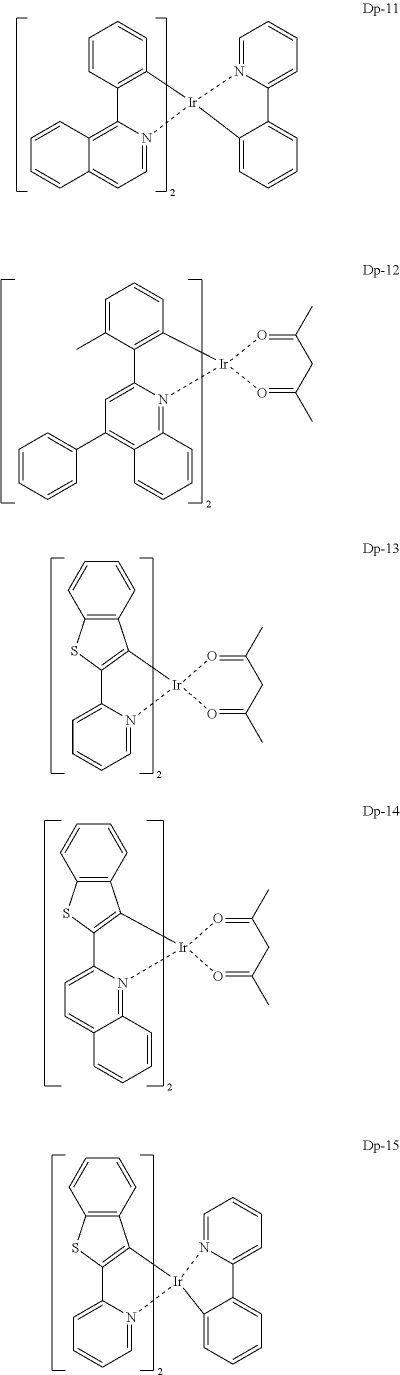

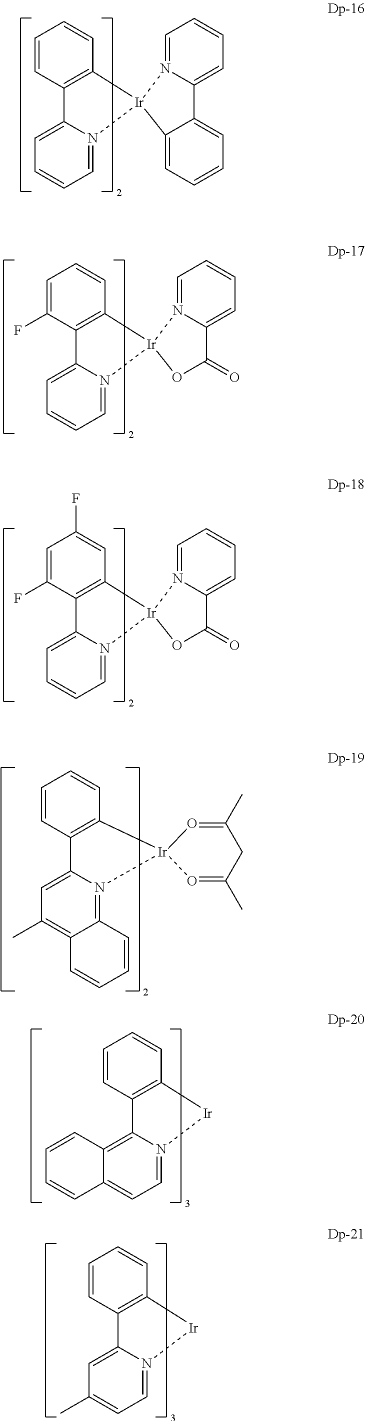

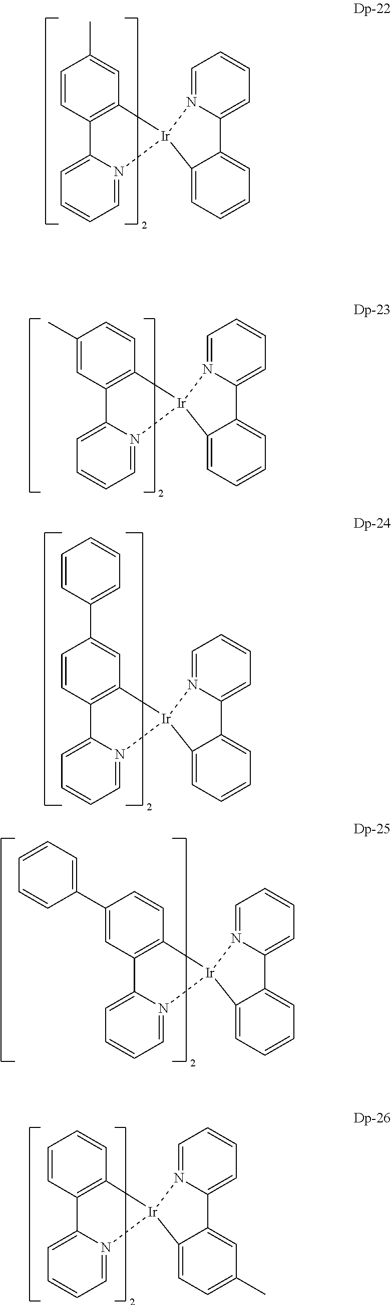

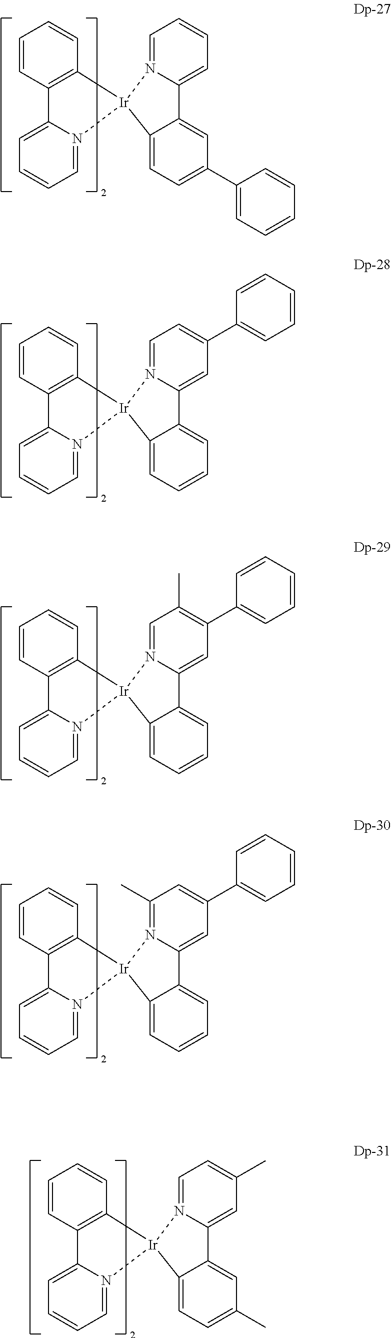

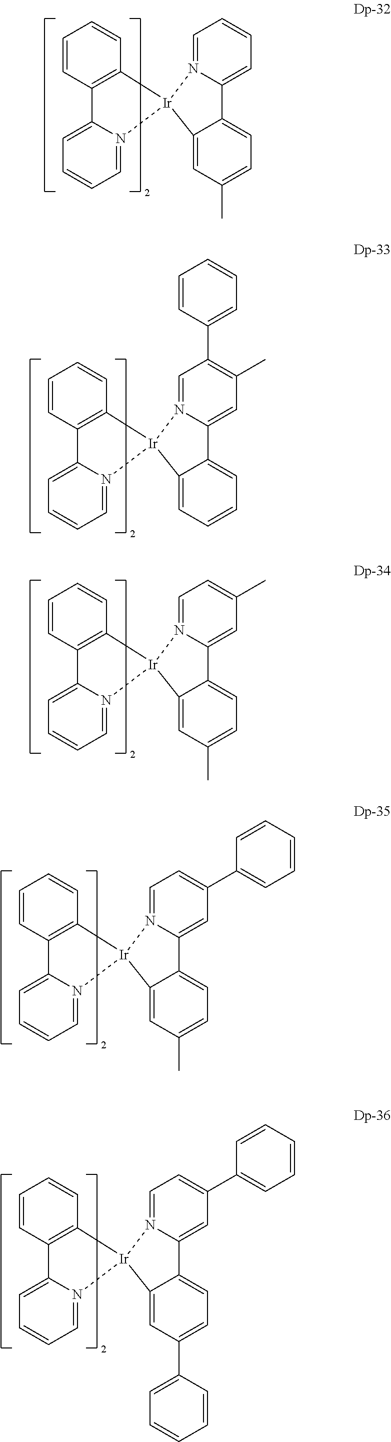

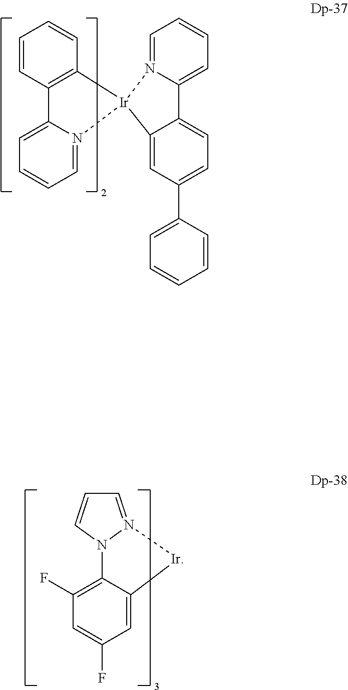

### Hole Blocking Layer

The organic light emitting device according to the present disclosure can optionally include a hole blocking layer between the light emitting layer and the electron injection and transport layer, or the electron transport layer, or the electron injection layer described below.

The hole blocking layer refers to a layer which is formed on the light emitting layer, and preferably, is provided in contact with the light emitting layer, and thus severs to control electron mobility, to prevent excessive movement of holes, and to increase the probabilities of hole-electron bonding, thereby improving the efficiency of the organic light emitting device. The hole blocking layer includes a hole blocking material, and as an example of such hole blocking material, a compound into which an electron-withdrawing group is introduced, such as azine derivatives including triazine; triazole derivatives; oxadiazole derivatives; phenanthroline derivatives; phosphine oxide derivatives can be used, but is not limited thereto.

Electron injection and transport layer, electron transport layer, electron injection layer The organic light emitting device according to the present disclosure can optionally include an electron injection and transport layer, or an electron transport layer, or an electron injection layer between the light emitting layer or the hole blocking layer and the cathode. The electron injection and transport layer is a layer for simultaneously performing the roles of an electron transport layer and an electron injection layer that inject electrons from an electrode and transport the received electrons up to the light emitting layer, and is formed on the light emitting layer or the hole blocking layer. The electron injection and transport material is suitably a material which can receive electrons well from a cathode and transfer the electrons to a light emitting layer, and has a large mobility for electrons. Specific examples of the electron injection and transport material include: an Al complex of 8-hydroxyquinoline; a complex including Alq₃; an organic radical compound; a hydroxyflavone-metal complex, a triazine derivative, and the like, but are not limited thereto. Alternatively, it can be used together with fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto.

The electron injection and transport layer can also be formed as a separate layer such as an electron injection layer and an electron transport layer. In such a case, the electron transport layer is formed on the light emitting layer or the hole blocking layer, and the above-mentioned electron injection and transport material can be used as the electron transport material included in the electron transport layer. In addition, the electron injection layer is formed on the electron transport layer, and examples of the electron injection material included in the electron injection layer include LiF, NaCl, CsF, Li₂O, BaO, fluorenone, anthraquinodimethane, diphenoquinone, thiopyran dioxide, oxazole, oxadiazole, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like.

The metal complex compound includes 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium, and the like, but is not limited thereto.

The organic light emitting device according to the present disclosure can exhibit excellent efficiency, driving voltage, and/or lifetime characteristics by including the first compound and the second compound having a specific structure, or a composition including them, in the organic material layer.

### EXAMPLES

Hereinafter, preferred examples are presented to aid in understanding the present disclosure. However, the following examples are provided only to facilitate understanding of the present disclosure, and the content of the present disclosure is not limited thereto.

### Preparation Example 1-1. Preparation of Compound 1-1

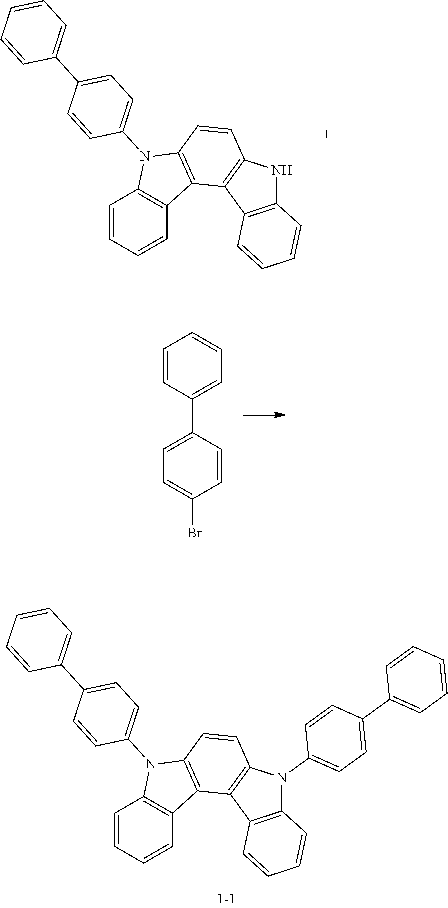 [SMILES: c1ccc(-c2ccc(-n3c4ccccc4c4c5c(ccc43)[nH]c3ccccc35)cc2)cc1 ; Brc1ccc(-c2ccccc2)cc1 ; c1ccc(-c2ccc(-n3c4ccccc4c4c5c6ccccc6n(-c6ccc(-c7ccccc7)cc6)c5ccc43)cc2)cc1]

Under a nitrogen atmosphere, 5-([1,1′-biphenyl]-4-yl)-5,8-dihydroindolo[2,3-c]carbazole (10 g, 24.5 mmol) and 4-bromo-1,1′-biphenyl (5.7 g, 24.5 mmol) were put into 200 ml of xylene, and then stirred and refluxed. To the resulting mixture, sodium tert-butoxide (7.1 g, 73.4 mmol) was added and sufficiently stirred, and then bis(tri-tert-butylphosphine)palladium (0.4 g, 0.7 mmol) was added. After reacting for 3 hours, it was cooled to room temperature (23±5° C.), and the resulting solid was filtered. The filtered solid was added to 412 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was recrystallized with chloroform and ethyl acetate to obtain a white solid, Compound 1-1 (8.6 g, 63%, MS: [M+H]+=561.7).

### Preparation Example 1-2. Preparation of Compound 1-2

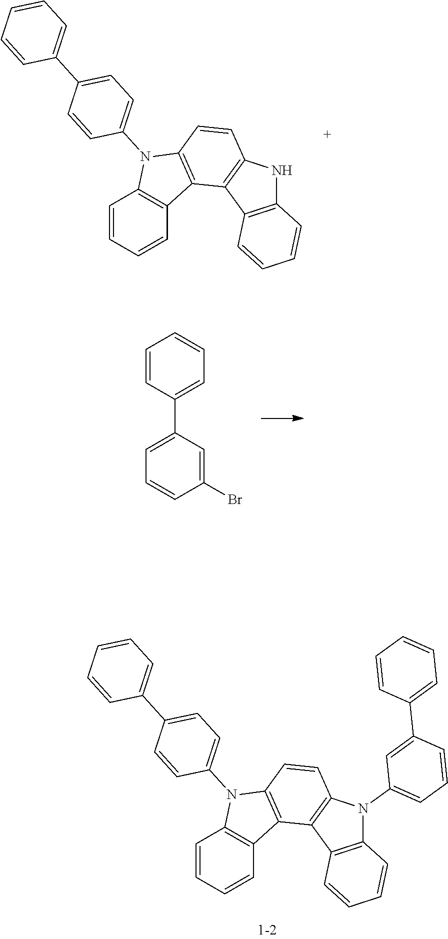 [SMILES: c1ccc(-c2ccc(-n3c4ccccc4c4c5c(ccc43)[nH]c3ccccc35)cc2)cc1 ; Brc1cccc(-c2ccccc2)c1 ; c1ccc(-c2ccc(-n3c4ccccc4c4c5c6ccccc6n(-c6cccc(-c7ccccc7)c6)c5ccc43)cc2)cc1]

A white solid, Compound 1-2, was prepared by performing the same method as in Preparation Example 1-1, except that 3-bromo-1,1′-biphenyl was used instead of 4-bromo-1,1′-biphenyl (6.6 g, 48%, MS: [M+H]+=561.7).

### Preparation Example 1-3. Preparation of Compound 1-3

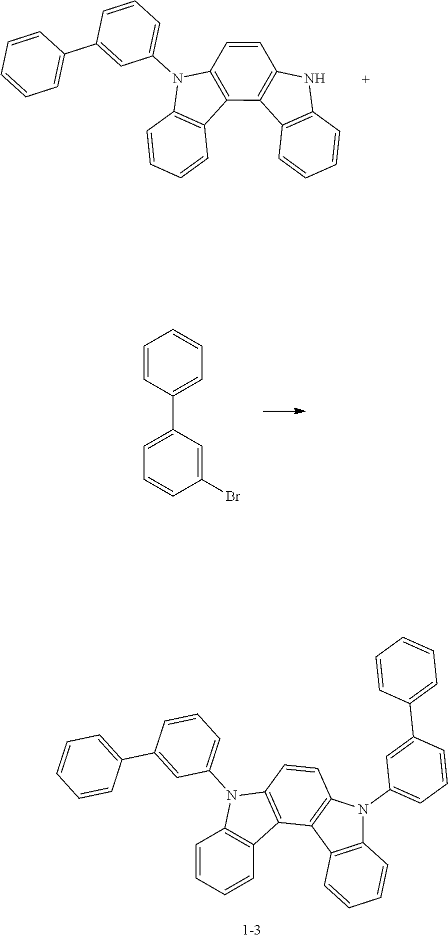 [SMILES: c1ccc(-c2cccc(-n3c4ccccc4c4c5c(ccc43)[nH]c3ccccc35)c2)cc1 ; Brc1cccc(-c2ccccc2)c1 ; c1ccc(-c2cccc(-n3c4ccccc4c4c5c6ccccc6n(-c6cccc(-c7ccccc7)c6)c5ccc43)c2)cc1]

A white solid, Compound 1-3, was prepared by performing the same method as in Preparation Example 1-1, except that 5-([1,1′-biphenyl]-3-yl)-5,8-dihydroindolo[2,3-c]carbazole was used instead of 5-([1,1′-biphenyl]-4-yl)-5,8-dihydroindolo[2,3-c]carbazole, and 3-bromo-1,1′-biphenyl was used instead of 4-bromo-1,1′-biphenyl (7.5 g, 55%, MS: [M+H]+=561.7).

### Preparation Example 1-4. Preparation of Compound 1-4

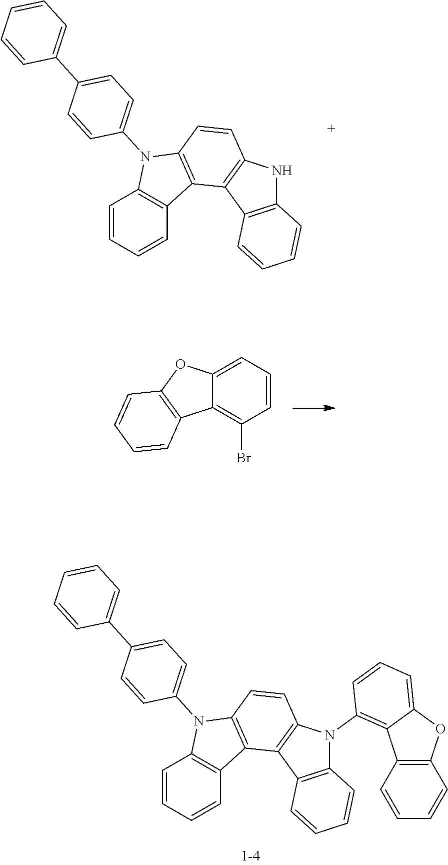 [SMILES: c1ccc(-c2ccc(-n3c4ccccc4c4c5c(ccc43)[nH]c3ccccc35)cc2)cc1 ; Brc1cccc2oc3ccccc3c12 ; c1ccc(-c2ccc(-n3c4ccccc4c4c5c6ccccc6n(-c6cccc7oc8ccccc8c67)c5ccc43)cc2)cc1]

A white solid, Compound 1-4, was prepared by performing the same method as in Preparation Example 1-1, except that 1-bromodibenzo[b,d]furan was used instead of 4-bromo-1,1′-biphenyl (8.6 g, 61%, MS: [M+H]+=575.7).

### Preparation Example 1-5. Preparation of Compound 1-5

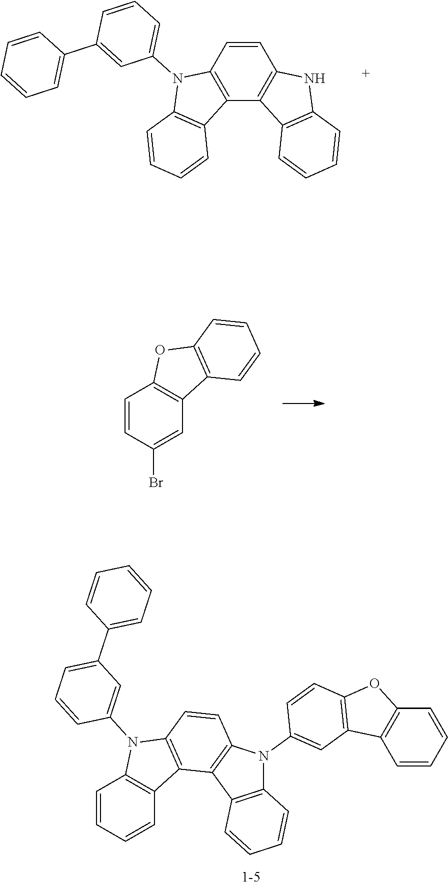 [SMILES: c1ccc(-c2cccc(-n3c4ccccc4c4c5c(ccc43)[nH]c3ccccc35)c2)cc1 ; Brc1ccc2oc3ccccc3c2c1 ; c1ccc(-c2cccc(-n3c4ccccc4c4c5c6ccccc6n(-c6ccc7oc8ccccc8c7c6)c5ccc43)c2)cc1]

A white solid, Compound 1-5, was prepared by performing the same method as in Preparation Example 1-1, except that 5-([1,1′-biphenyl]-3-yl)-5,8-dihydroindolo[2,3-c]carbazole was used instead of 5-([1,1′-biphenyl]-4-yl)-5,8-dihydroindolo[2,3-c]carbazole, and 2-bromodibenzo[b,d]furan was used instead of 4-bromo-1,1′-biphenyl (5.8 g, 41%, MS: [M+H]+=575.7).

### Preparation Example 1-6. Preparation of Compound 1-6

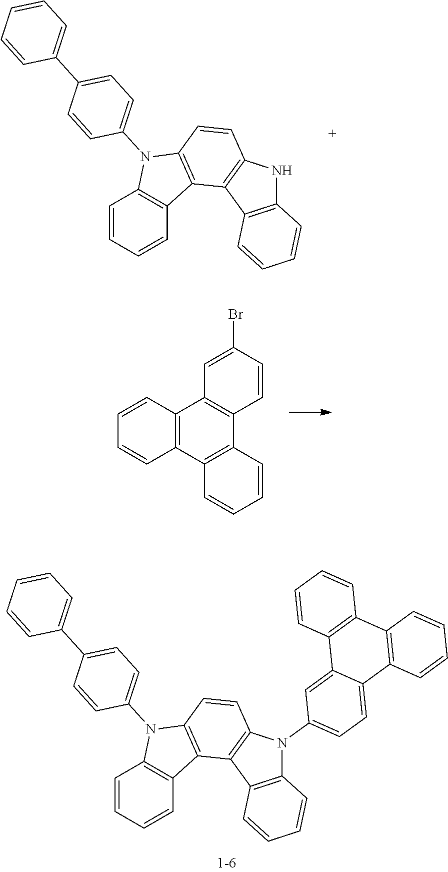 [SMILES: c1ccc(-c2ccc(-n3c4ccccc4c4c5c(ccc43)[nH]c3ccccc35)cc2)cc1 ; Brc1ccc2c3ccccc3c3ccccc3c2c1 ; c1ccc(-c2ccc(-n3c4ccccc4c4c5c6ccccc6n(-c6ccc7c8ccccc8c8ccccc8c7c6)c5ccc43)cc2)cc1]

A white solid, Compound 1-6, was prepared by performing the same method as in Preparation Example 1-1, except that 2-bromotriphenylene was used instead of 4-bromo-1,1′-biphenyl (11 g, 71%, MS: [M+H]+=635.8).

### Preparation Example 1-7. Preparation of Compound 1-7

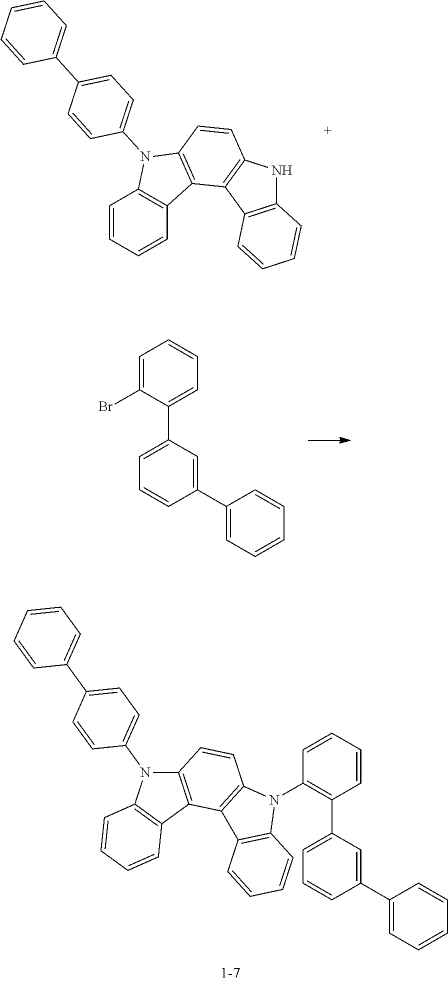 [SMILES: c1ccc(-c2ccc(-n3c4ccccc4c4c5c(ccc43)[nH]c3ccccc35)cc2)cc1 ; Brc1ccccc1-c1cccc(-c2ccccc2)c1 ; c1ccc(-c2ccc(-n3c4ccccc4c4c5c6ccccc6n(-c6ccccc6-c6cccc(-c7ccccc7)c6)c5ccc43)cc2)cc1]

A white solid, Compound 1-7, was prepared by performing the same method as in Preparation Example 1-1, except that 2-bromo-1,1′:3′,1″-terphenyl was used instead of 4-bromo-1,1′-biphenyl (8.3 g, 53%, MS: [M+H]+=637.8).

### Preparation Example 1-8. Preparation of Compound 1-8

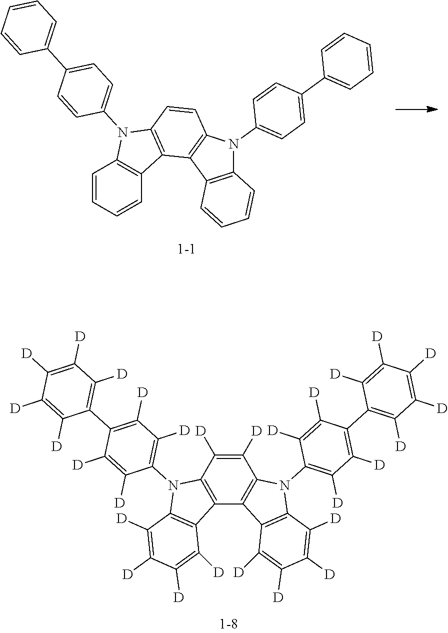 [SMILES: c1ccc(-c2ccc(-n3c4ccccc4c4c5c6ccccc6n(-c6ccc(-c7ccccc7)cc6)c5ccc43)cc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c(-c7c([2H])c([2H])c([2H])c([2H])c7[2H])c([2H])c6[2H])c5c([2H])c([2H])c43)c([2H])c2[2H])c([2H])c1[2H]]

Under a nitrogen atmosphere, Compound 1-1 (10 g, 17.8 mmol) and TfOH (2 ml) were put into C₆D₆(100 ml) and stirred at 40° C. for 4 hours. After the reaction was completed, the temperature of the resulting reaction product was lowered to room temperature, D₂O (20 ml) was added and stirred for 30 minutes, and then trimethylamine (2.4 ml) was added dropwise. The resulting reaction solution was transferred to a separatory funnel, extracted with water and chloroform, and then anhydrous magnesium sulfate was added and stirred. The resulting reaction product was filtered, and the filtrate was distilled under reduced pressure. The resulting concentrated compound was recrystallized with chloroform and ethyl acetate to obtain a white solid, Compound 1-8 (7.9 g, 76%, MS: [M+H]+=587).

### Preparation Example 1-9. Preparation of Compound 1-9

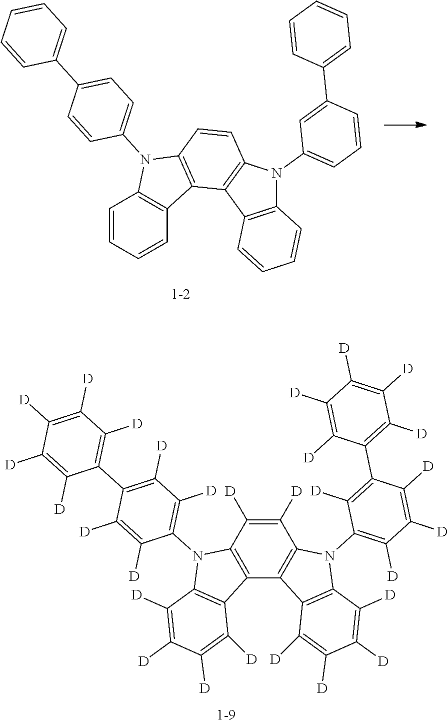 [SMILES: c1ccc(-c2ccc(-n3c4ccccc4c4c5c6ccccc6n(-c6cccc(-c7ccccc7)c6)c5ccc43)cc2)cc1 ; [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c([2H])c(-c7c([2H])c([2H])c([2H])c([2H])c7[2H])c6[2H])c5c([2H])c([2H])c43)c([2H])c2[2H])c([2H])c1[2H]]

A white solid, Compound 1-9, was prepared by performing the same method as in Preparation Example 1-8, except that Compound 1-2 was used instead of Compound 1-1 (7.4 g, 71%, MS: [M+H]+=587).

### Preparation Example 1-10. Preparation of Compound 1-10

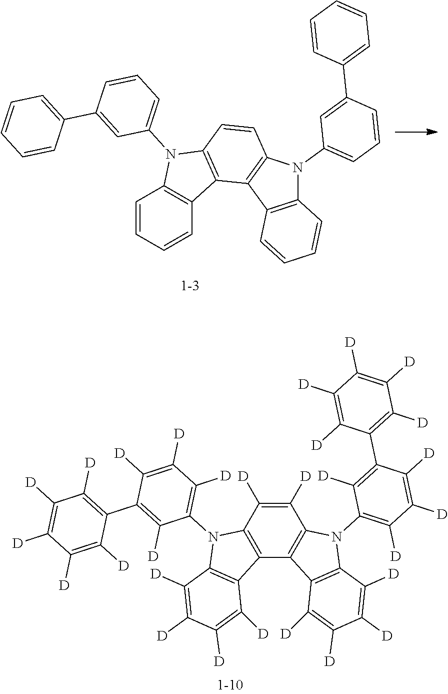 [SMILES: c1ccc(-c2cccc(-n3c4ccccc4c4c5c6ccccc6n(-c6cccc(-c7ccccc7)c6)c5ccc43)c2)cc1 ; [2H]c1c([2H])c([2H])c(-c2c([2H])c([2H])c([2H])c(-n3c4c([2H])c([2H])c([2H])c([2H])c4c4c5c6c([2H])c([2H])c([2H])c([2H])c6n(-c6c([2H])c([2H])c([2H])c(-c7c([2H])c([2H])c([2H])c([2H])c7[2H])c6[2H])c5c([2H])c([2H])c43)c2[2H])c([2H])c1[2H]]

A white solid, Compound 1-10, was prepared by performing the same method as in Preparation Example 1-8, except that Compound 1-3 was used instead of Compound 1-1 (7.2 g, 69%, MS: [M+H]+=587).

### Preparation Example 1-11. Preparation of Compound 1-11

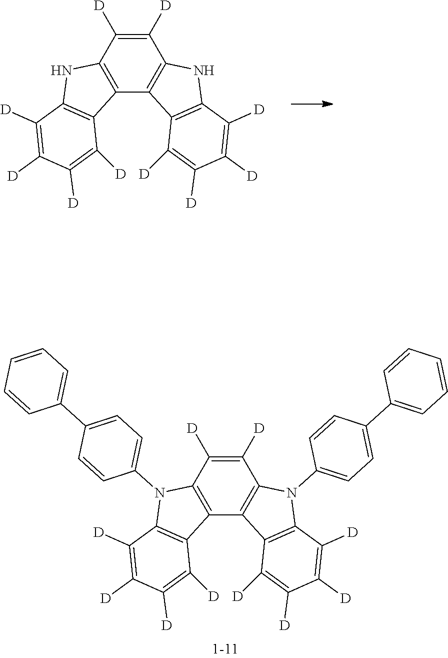 [SMILES: [2H]c1c([2H])c([2H])c2c([nH]c3c([2H])c([2H])c4[nH]c5c([2H])c([2H])c([2H])c([2H])c5c4c32)c1[2H] ; [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1]

Under a nitrogen atmosphere, 5,8-dihydroindolo[2,3-c]carbazole-1,2,3,4,6,7,9,10,11,12-d10 (10 g, 37.8 mmol) and 4-bromo-1,1′-biphenyl (17.6 g, 75.6 mmol) were put into 200 ml of xylene, and then stirred and refluxed. To the resulting reaction product, sodium tert-butoxide (21.8 g, 227.0 mmol) was added. After sufficient stirring, bis(tri-tert-butylphosphine)palladium (2 g, 3.8 mmol) was added. After reacting for 3 hours, the resulting reaction product was cooled to room temperature, and the resulting solid was filtered. The obtained solid was added to 645 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was recrystallized with chloroform and ethyl acetate to obtain a white solid, Compound 1-11 (17.2 g, 80%, MS: [M+H]+=569.8).

### Synthesis Example 1. Preparation of Compound A1

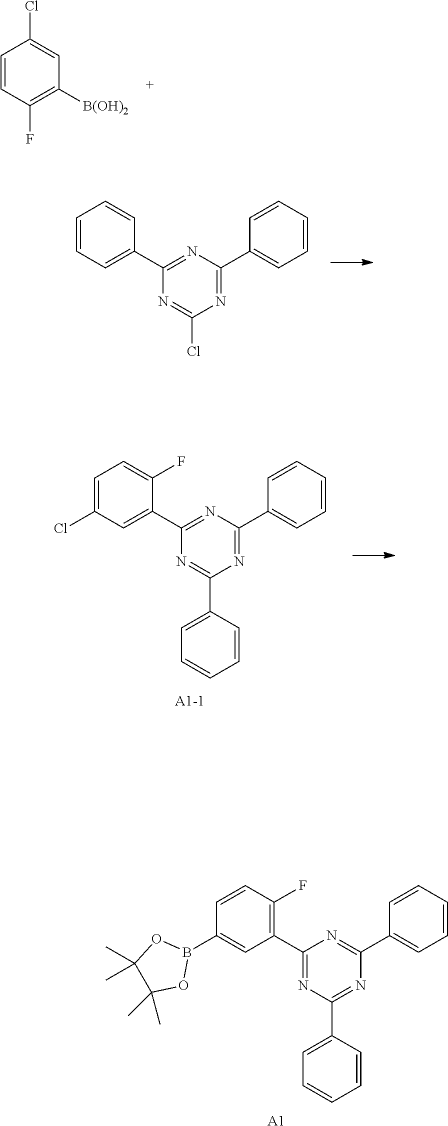

### Step 1) Preparation of Compound A1-1

Under a nitrogen atmosphere, (5-chloro-2-fluorophenyl)boronic acid (40 g, 229.4 mmol) and 2-chloro-4,6-diphenyl-1,3,5-triazine (61.4 g, 229.4 mmol) were put into 400 ml of tetrahydrofuran, and then stirred and refluxed. Potassium carbonate (95.1 g, 688.2 mmol) was dissolved in 95 ml of water and added to the resulting mixture. After sufficient stirring, [1,1′-bis(diphenylphosphino)ferrocene]dichloropalladium(II) (3.4 g, 4.6 mmol) was added and reacted for 11 hours. After the reaction was completed, the resulting reaction product was cooled to room temperature to separate into the organic layer and the water layer, and the organic layer was distilled. The obtained product was added to 830 mL of toluene and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using toluene and ethyl acetate to obtain a gray solid, Compound A1-1 (58.9 g, 71%, MS: [M+H]+=362.8).

### Step 2) Preparation of Compound A1

Under a nitrogen atmosphere, Compound A1-1 (50 g, 138.2 mmol) prepared in Step 1 and bis(pinacolato)diboron (38.7 g, 165.8 mmol) were put into 750 ml of Diox, and then stirred and refluxed. To the resulting mixture, potassium acetate (39.9 g, 414.6 mmol) was added. After sufficient stirring, palladium dibenzylideneacetone palladium (2.4 g, 4.1 mmol) and tricyclohexylphosphine (2.3 g, 8.3 mmol) were added. After reacting for 5 hours, the resulting reaction product was cooled to room temperature to separate the organic layer. The separated organic layer was filtered to remove salt, and then the filtered organic layer was distilled. The obtained product was added to 626 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to prepare a yellow solid, Compound A1 (53.3 g, 85%, MS: [M+H]+=454.3).

### Synthesis Example 2. Preparation of Compound B1

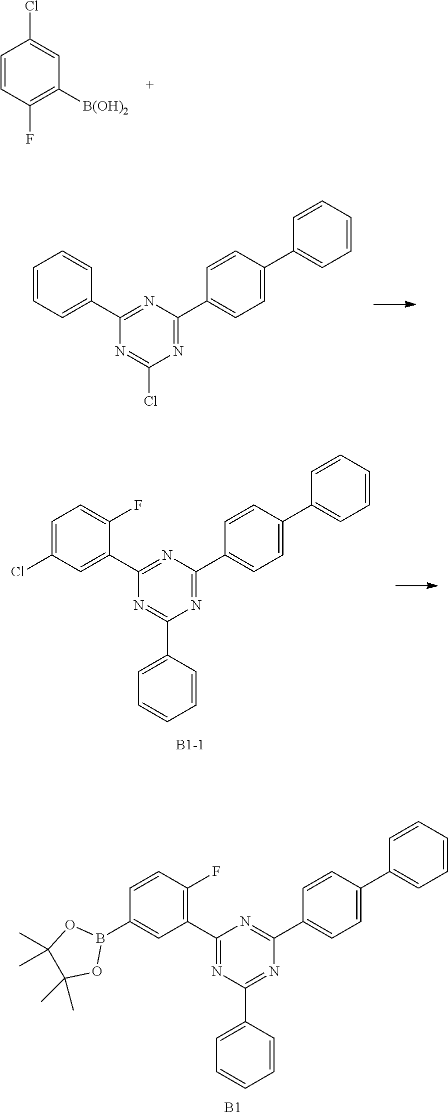

Compound B1 was prepared by performing the same method as in Synthesis Example 1, except that 2-([1,1′-biphenyl]-4-yl)-4-chloro-6-phenyl-1,3,5-triazine was used instead of 2-chloro-4,6-diphenyl-1,3,5-triazine (35.3 g, 73%, MS: [M+H]+=530.4).

### Synthesis Example 3. Preparation of Compound C1

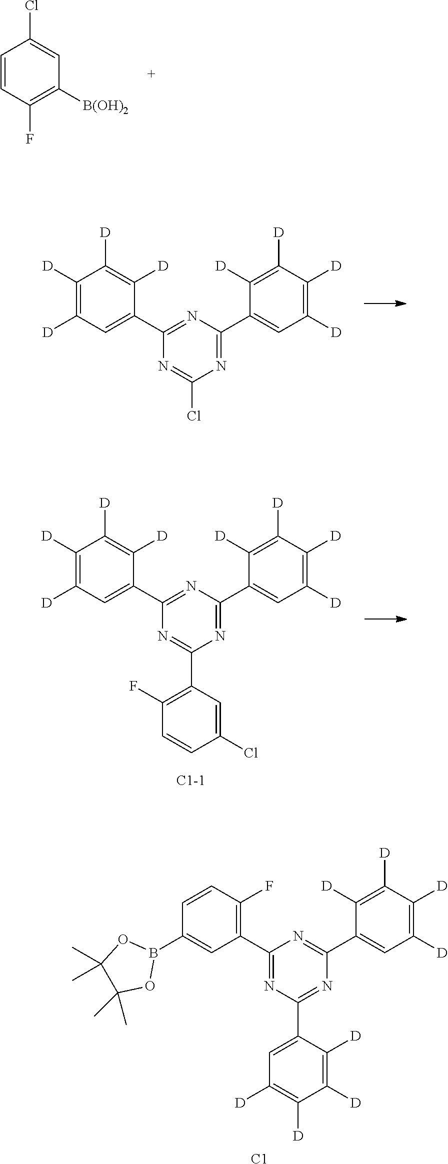 [SMILES: OB(O)c1cc(Cl)ccc1F ; [2H]c1cc(-c2nc(Cl)nc(-c3cc([2H])c([2H])c([2H])c3[2H])n2)c([2H])c([2H])c1[2H] ; [2H]c1cc(-c2nc(-c3cc(Cl)ccc3F)nc(-c3cc([2H])c([2H])c([2H])c3[2H])n2)c([2H])c([2H])c1[2H] ; [2H]c1cc(-c2nc(-c3cc(B4OC(C)(C)C(C)(C)O4)ccc3F)nc(-c3cc([2H])c([2H])c([2H])c3[2H])n2)c([2H])c([2H])c1[2H] ; "C1"]

Compound C1 was prepared by performing the same method as in Synthesis Example 1, except that 2-chloro-4,6-bis(phenyl-2,3,4,5-d4)-1,3,5-triazine was used instead of 2-chloro-4,6-diphenyl-1,3,5-triazine (30.5 g, 70%, MS: [M+H]+=461.2).

### Synthesis Example 4. Preparation of Compound D1

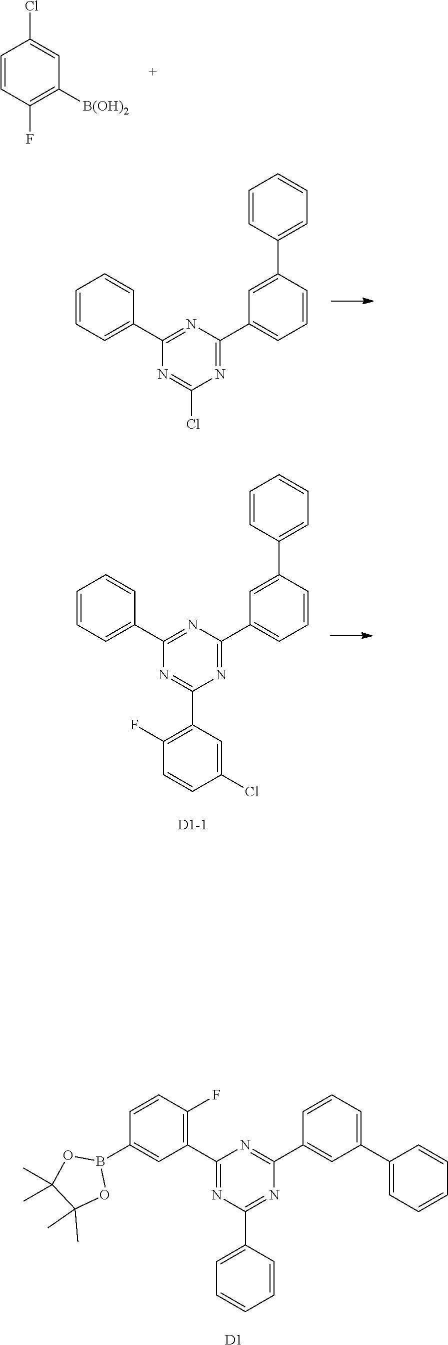

Compound D1 was prepared by performing the same method as in Synthesis Example 1, except that 2-([1,1′-biphenyl]-3-yl)-4-chloro-6-phenyl-1,3,5-triazine was used instead of 2-chloro-4,6-diphenyl-1,3,5-triazine (35.8 g, 77%, MS: [M+H]+=529).

### Preparation Example 2-1. Preparation of Compound 2-1

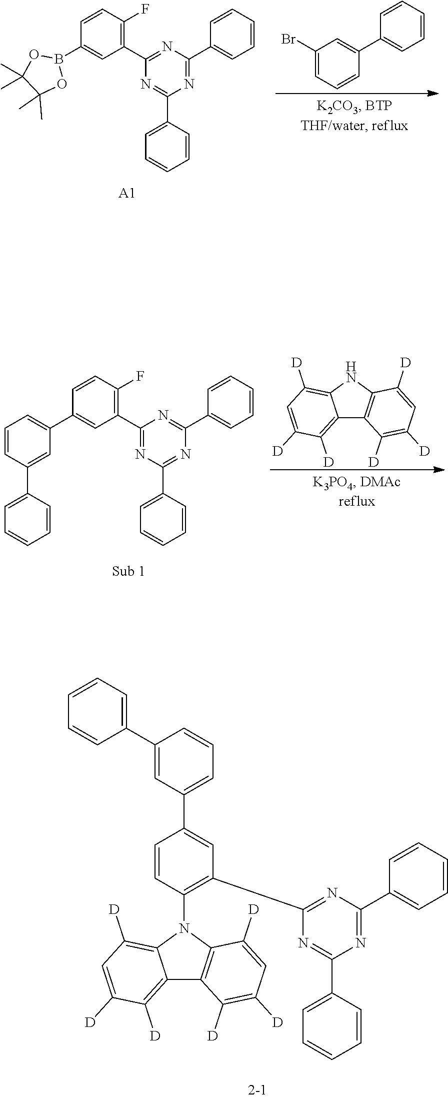

### Step 1) Preparation of Compound Sub 1

Under a nitrogen atmosphere, Compound A1 (36 g, 79.4 mmol) and 3-bromo-1,1′-biphenyl (18.5 g, 79.4 mmol) were put into 720 ml of tetrahydrofuran, and then stirred and refluxed. Potassium carbonate (32.9 g, 238.2 mmol) was dissolved in 33 ml of water and added to the resulting mixture. After sufficient stirring, bis(tri-tert-butylphosphine)palladium (0.8 g, 1.6 mmol) was added and reacted for 3 hours. After the reaction was completed, the resulting reaction product was cooled to room temperature, and the produced solid was filtered. The obtained solid was added to 1904 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to obtain a gray solid, Compound Sub 1 (28.9 g, 76%, MS: [M+H]+=480.6).

### Step 2) Preparation of Compound 2-1

Under a nitrogen atmosphere, Compound Sub 1 (40 g, 83.4 mmol) prepared in Step 1 and 9H-carbazole-1,3,4,5,6,8-d6 (14.5 g, 83.4 mmol) were put into 320 ml of dimethylacetamide, and then stirred and refluxed. Potassium phosphate (53.1 g, 250.2 mmol) was added to the resulting mixture, which was sufficiently stirred and reacted for 1 hour. After the reaction was completed, the resulting reaction product was cooled to room temperature and the organic layer was separated. The separated organic layer was filtered to remove salt, and then the filtered organic layer was distilled. The obtained product was added to 1583 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to obtain a yellow solid, Compound 2-1 (30.1 g, 57%, MS: [M+H]+=633.8).

### Preparation Example 2-2. Preparation of Compound 2-2

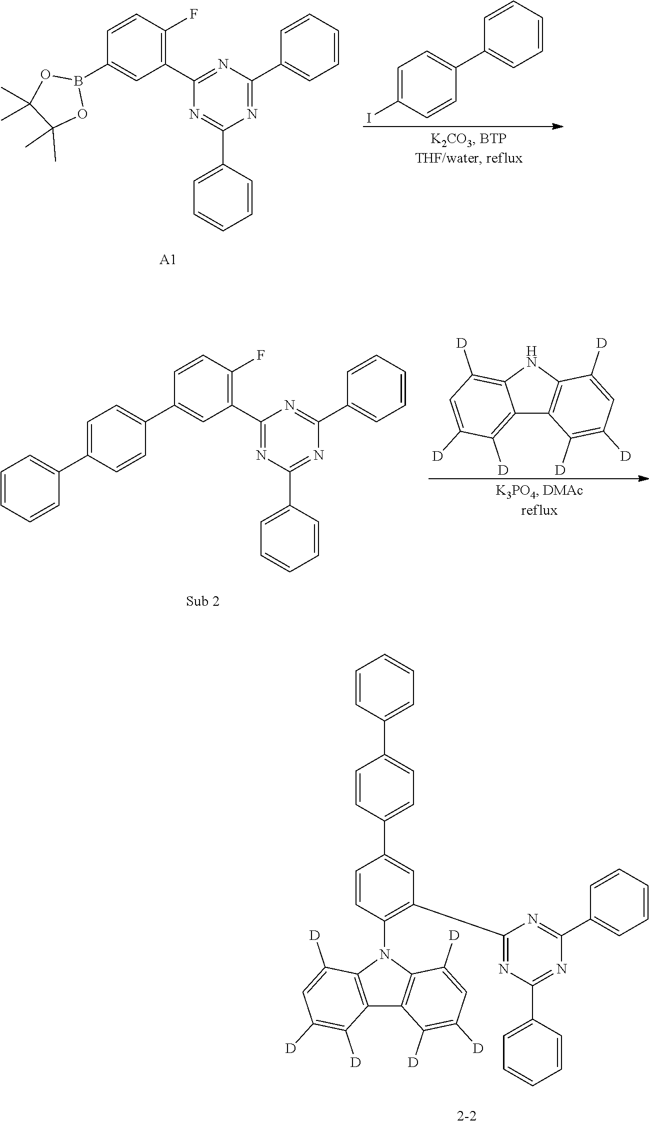

### Step 1) Preparation of Compound Sub 2

Under a nitrogen atmosphere, Compound A1 (36 g, 79.4 mmol) and 4-iodo-1,1′-biphenyl (22.2 g, 79.4 mmol) were put into 720 ml of tetrahydrofuran, and then stirred and refluxed. Potassium carbonate (32.9 g, 238.2 mmol) was dissolved in 33 ml of water and added to the resulting mixture. After sufficient stirring, bis(tri-tert-butylphosphine)palladium (0.8 g, 1.6 mmol) was added and reacted for 4 hours. After the reaction was completed, the resulting reaction product was cooled to room temperature, and the resulting solid was filtered. The obtained solid was added to 1904 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was recrystallized using chloroform and ethyl acetate to obtain a red solid, Compound Sub2 (34.7 g, 91%, MS: [M+H]+=480.6).

### Step 2) Preparation of Compound 2-2

Under a nitrogen atmosphere, Compound Sub2 (40 g, 83.4 mmol) prepared in Step 1 and 9H-carbazole-1,3,4,5,6,8-d6 (14.5 g, 83.4 mmol) were put into 320 ml of dimethylacetamide, and then stirred and refluxed. Potassium phosphate (53.1 g, 250.2 mmol) was added to the resulting mixture, which was sufficiently stirred and reacted for 1 hour. After the reaction was completed, the resulting reaction product was cooled to room temperature, and the organic layer was separated. The separated organic layer was filtered to remove salt, and then the filtered organic layer was distilled. The obtained product was added to 1583 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to obtain a yellow solid, Compound 2-2 (41.7 g, 79%, MS: [M+H]+=633.8).

### Preparation Example 2-3. Preparation of Compound 2-3

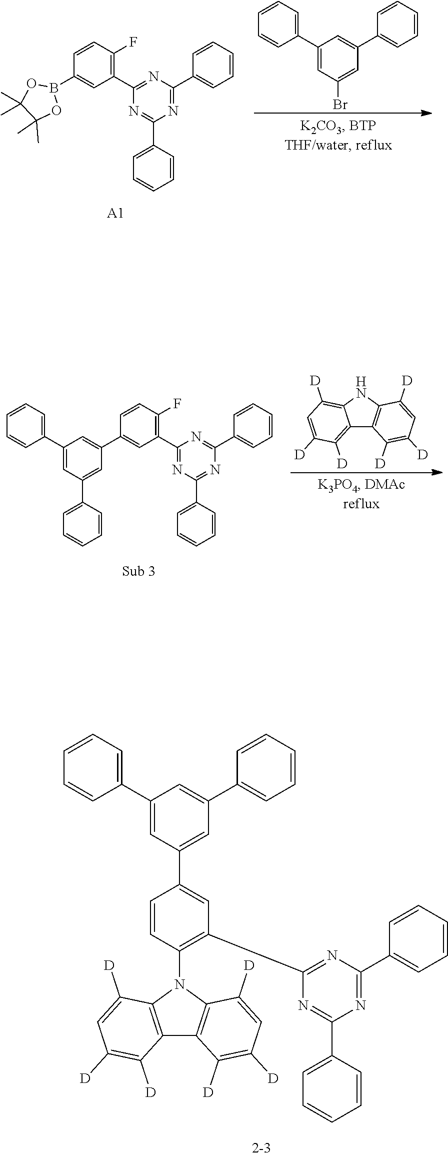

### Step 1) Preparation of Compound Sub 3

Under a nitrogen atmosphere, Compound A1 (36 g, 79.4 mmol) and 5′-bromo-1,1′:3′,1″-terphenyl (24.6 g, 79.4 mmol) were put into 720 ml of tetrahydrofuran, and then stirred and refluxed. Potassium carbonate (32.9 g, 238.2 mmol) was dissolved in 33 ml of water and added to the resulting mixture. After sufficient stirring, bis(tri-tert-butylphosphine)palladium (0.8 g, 1.6 mmol) was added and reacted for 3 hours. After the reaction was completed, the resulting reaction product was cooled to room temperature, and the produced solid was filtered. The obtained solid was added to 2206 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was recrystallized using chloroform and ethyl acetate to obtain a gray solid, Compound Sub3 (27.4 g, 62%, MS: [M+H]+=556.7).

### Step 2) Preparation of Compound 2-3

Under a nitrogen atmosphere, Compound Sub3 (40 g, 72 mmol) prepared in Step 1 and 9H-carbazole-1,3,4,5,6,8-d6 (12.5 g, 72 mmol) were put into 320 ml of dimethylacetamide, and then stirred and refluxed. Potassium phosphate (45.8 g, 216 mmol) was added to the resulting mixture, which was sufficiently stirred and reacted for 2 hours. After the reaction was completed, the resulting reaction product was cooled to room temperature, and the organic layer was separated. The separated organic layer was filtered to remove salt, and then the filtered organic layer was distilled. The obtained product was added to 1531 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to obtain a yellow solid, Compound 2-3 (40.8 g, 80%, MS: [M+H]+=709.9).

### Preparation Example 4. Preparation of Compound 2-4

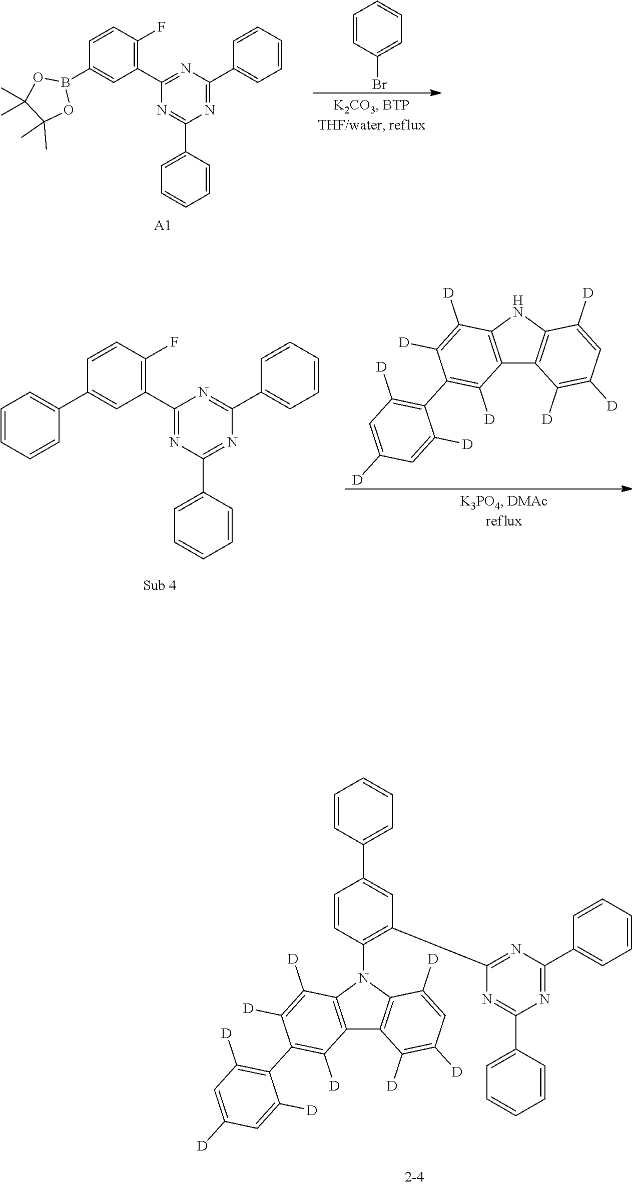

### Step 1) Preparation of Compound Sub 4

Under a nitrogen atmosphere, Compound A1 (30 g, 66.2 mmol) and Bromobenzene (10.4 g, 66.2 mmol) were put into 300 ml of tetrahydrofuran, and then stirred and refluxed. Potassium carbonate (27.4 g, 198.5 mmol) was dissolved in 27 ml of water and added to the resulting mixture. After sufficient stirring, bis(tri-tert-butylphosphine)palladium (0.7 g, 1.3 mmol) was added and reacted for 3 hours. After the reaction was completed, the resulting reaction product was cooled to room temperature, and the resulting solid was filtered. The obtained solid was added to 1335 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was recrystallized using chloroform and ethyl acetate to obtain a gray solid, Compound Sub4 (19.5 g, 73%, MS: [M+H]+=404.5).

### Step 2) Preparation of Compound 2-4

Under a nitrogen atmosphere, Compound Sub4 (30 g, 74.4 mmol) prepared in Step 1 and 3-(phenyl-2,4,6-d3)-9H-carbazole-1,2,4,5,6,8-d6 (18.8 g, 74.4 mmol) were put into 240 ml of dimethylacetamide, and then stirred and refluxed. To the resulting mixture, potassium phosphate (47.4 g, 223.1 mmol) was added, and after sufficient stirring, it was reacted for 1 hour. After the reaction was completed, the resulting reaction product was cooled to room temperature, and the organic layer was separated. The separated organic layer was filtered to remove salt, and then the filtered organic layer was distilled. The obtained product was added to 1418 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to obtain a yellow solid, Compound 2-4 (32.1 g, 68%, MS: [M+H]+=636.8).

### Preparation Example 2-5. Preparation of Compound 2-5

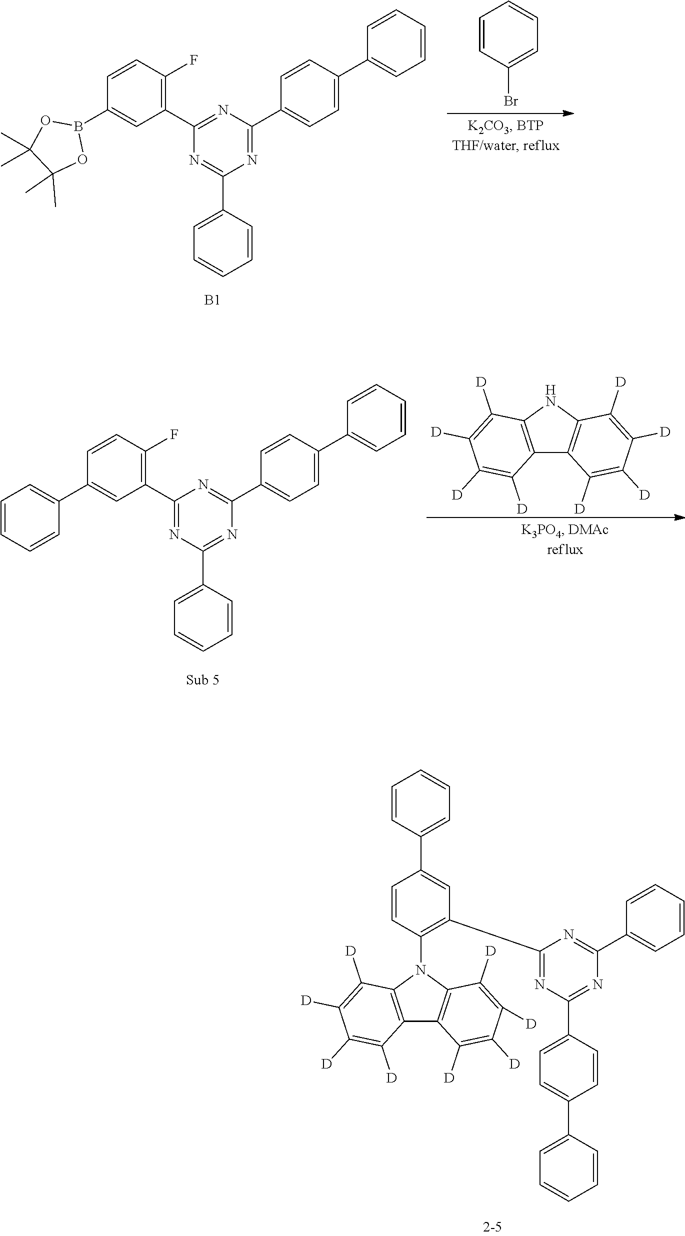

### Step 1) Preparation of Compound Sub 5

Under a nitrogen atmosphere, Compound B1 (30 g, 56.7 mmol) and Bromobenzene (8.9 g, 56.7 mmol) were put into 450 ml of tetrahydrofuran, and then stirred and refluxed. Potassium carbonate (23.5 g, 170 mmol) was dissolved in 23 ml of water and added to the resulting mixture. After sufficient stirring, [1,1′-bis(diphenylphosphino)ferrocene]-dichloropalladium(II) (0.8 g, 1.1 mmol) was added and reacted for 12 hours. After the reaction was completed, the resulting reaction product was cooled to room temperature to separate into the organic layer and the water layer. The organic layer was distilled. The obtained product was added to 272 mL of toluene and dissolved. After washing the resulting solution twice with water, the organic layer was separated. Anhydrous magnesium sulfate was added to the separated organic layer and then stirred and filtered. The filtrate was distilled under reduced pressure. The resulting concentrated compound was purified through a silica column using toluene and ethyl acetate to obtain a gray solid, Compound Sub 5 (16.6 g, 61%, MS: [M+H]+=480.6).

### Step 2) Preparation of Compound 2-5

Under a nitrogen atmosphere, Compound Sub 5 (30 g, 62.6 mmol) prepared in Step 1 and 9H-carbazole-d8 (11 g, 62.6 mmol) were put into 240 ml of dimethylacetamide, and then stirred and refluxed. Potassium phosphate (39.8 g, 187.7 mmol) was added to the resulting mixture, which was sufficiently stirred and reacted for 1 hour. After the reaction was completed, the resulting reaction product was cooled to room temperature and the organic layer was separated. The separated organic layer was filtered to remove salt, and then the filtered organic layer was distilled. The obtained product was added to 1191 mL of chloroform and dissolved. After washing the resulting solution twice with water, the organic layer was separated. Anhydrous magnesium sulfate was added to the separated organic layer, and then stirred and filtered. The filtrate was distilled under reduced pressure. The resulting concentrated compound was purified through a silica column using chloroform and ethyl acetate to obtain a yellow solid, Compound 2-5 (20.7 g, 52%, MS: [M+H]+=635.8).

### Preparation Example 2-6. Preparation of Compound 2-6

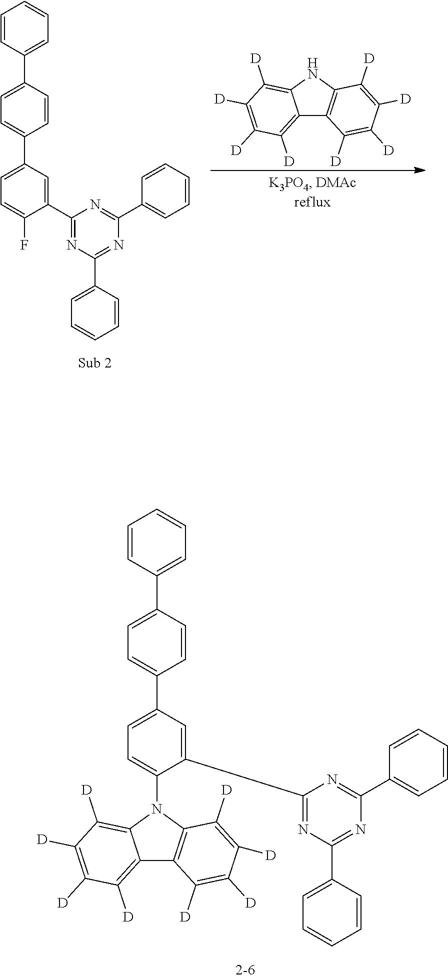 [SMILES: Fc1ccc(-c2ccc(-c3ccccc3)cc2)cc1-c1nc(-c2ccccc2)nc(-c2ccccc2)n1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc(-c2ccc(-c3ccccc3)cc2)cc1-c1nc(-c2ccccc2)nc(-c2ccccc2)n1]

Compound 2-6 was prepared by performing the same method as in Preparation Example 2-2, except that 9H-carbazole-d8 was used instead of 9H-carbazole-1,3,4,5,6,8-d6 (21.5 g, 70%, MS: [M+H]+=634).

### Preparation Example 2-7. Preparation of Compound 2-7

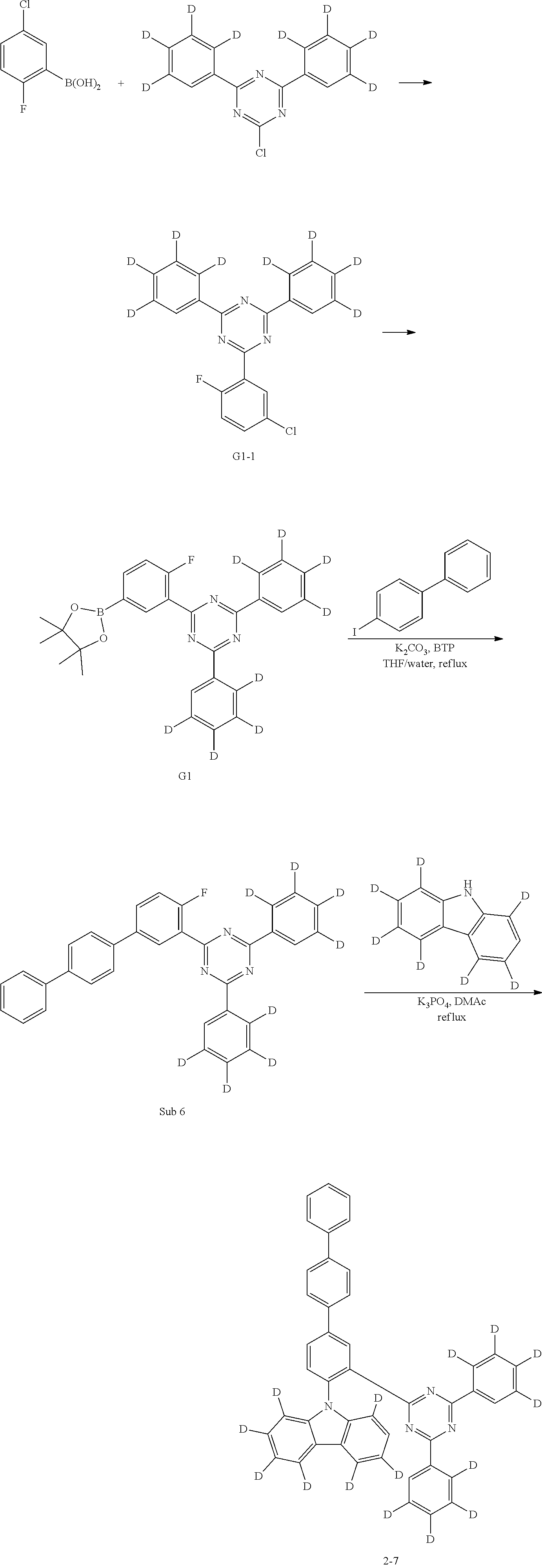

### Step 1) Preparation of Compound G1

Compound G1 was prepared by performing the same method as in Synthesis Example 1, except that 2-chloro-4,6-bis(phenyl-2,3,4,5-d4)-1,3,5-triazine was used instead of 2-chloro-4,6-diphenyl-1,3,5-triazine (30.5 g, 70%, MS: [M+H]+=461.2).

### Step 2) Preparation of Compound Sub 6

Under a nitrogen atmosphere, Compound G1 (35 g, 75.9 mmol) prepared in Step 1 and 4-iodo-1,1′-biphenyl (21.2 g, 75.9 mmol) were put into 350 ml of tetrahydrofuran, and then stirred and refluxed. Potassium carbonate (31.5 g, 227.6 mmol) was dissolved in 31 ml of water and added to the resulting mixture. After sufficient stirring, bis(tri-tert-butylphosphine)palladium (0.8 g, 1.5 mmol) was added and reacted for 5 hours. After the reaction was completed, the resulting reaction product was cooled to room temperature, and the produced solid was filtered. The obtained solid was added to 1850 mL of chloroform and dissolved. After washing the resulting solution twice with water, the organic layer was separated. Anhydrous magnesium sulfate was added to the separated organic layer and then stirred and filtered. The filtrate was distilled under reduced pressure. The resulting concentrated compound was purified through a silica column using chloroform and ethyl acetate to obtain a gray solid, Compound Sub 6 (27 g, 73%, MS: [M+H]+=488).

### Step 3) Preparation of Compound 2-7

Under a nitrogen atmosphere, Compound Sub 6 (25 g, 51.3 mmol) prepared in Step 2 and 9H-carbazole-1,2,3,4,5,6,8-d7 (8.9 g, 51.3 mmol) were put into 200 ml of dimethylacetamide, and then stirred and refluxed. Potassium phosphate (32.6 g, 153.8 mmol) was added to the resulting mixture, which was sufficiently stirred and reacted for 1 hour. After the reaction was completed, the resulting reaction product was cooled to room temperature and the organic layer was separated. The separated organic layer was filtered to remove salt, and then the filtered organic layer was distilled. The obtained product was added to 987 mL of chloroform and dissolved. After washing the resulting solution twice with water, the organic layer was separated. Anhydrous magnesium sulfate was added to the separated organic layer and then stirred and filtered. The filtrate was distilled under reduced pressure. The resulting concentrated compound was purified through a silica column using chloroform and ethyl acetate to obtain a yellow solid, Compound 2-7 (17.4 g, 53%, MS: [M+H]+=642).

### Preparation Example 2-8. Preparation of Compound 2-8

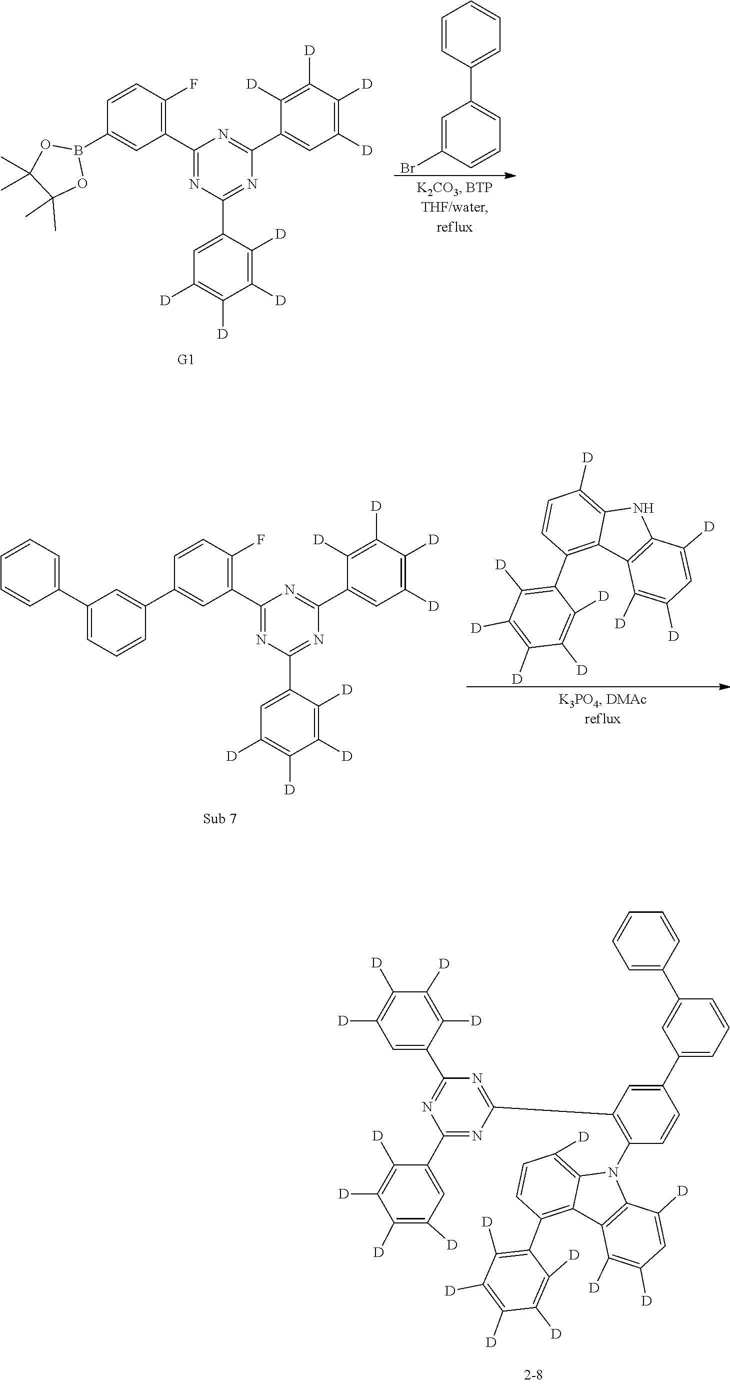

### Step 1) Preparation of Compound Sub 7

Under a nitrogen atmosphere, Compound G1 (35 g, 75.9 mmol) and 3-bromo-1,1′-biphenyl (17.7 g, 75.9 mmol) were put into 350 ml of tetrahydrofuran, and then stirred and refluxed. Potassium carbonate (31.5 g, 227.6 mmol) was dissolved in 31 ml of water and added to the resulting mixture. After sufficient stirring, bis(tri-tert-butylphosphine)palladium (0.8 g, 1.5 mmol) was added and reacted for 4 hours. After the reaction was completed, the resulting reaction product was cooled to room temperature, and the produced solid was filtered. The obtained solid was added to 1850 mL of chloroform and dissolved. After washing the resulting solution twice with water, the organic layer was separated. Anhydrous magnesium sulfate was added to the separated organic layer and then stirred and filtered. The filtrate was distilled under reduced pressure. The resulting concentrated compound was purified through a silica column using chloroform and ethyl acetate to obtain a gray solid, Compound Sub 7 (29.2 g, 79%, MS: [M+H]+=488.6).

### Step 2) Preparation of Compound 2-8

Under a nitrogen atmosphere, Compound Sub 7 (25 g, 51.3 mmol) prepared in Step 1 and 4-(phenyl-d5)-9H-carbazole-1,5,6,8-d4 (12.9 g, 51.3 mmol) were put into 200 ml of dimethylacetamide, and then stirred and refluxed. Potassium phosphate (32.6 g, 153.8 mmol) was added to the resulting mixture, which was sufficiently stirred and reacted for 2 hours. After the reaction was completed, the resulting reaction product was cooled to room temperature and the organic layer was separated. The separated organic layer was filtered to remove salt, and the filtered organic layer was distilled. The obtained product was added to 1093 mL of chloroform and dissolved. After washing the resulting solution twice with water, the organic layer was separated. Anhydrous magnesium sulfate was added to the separated organic layer and then stirred and filtered. The filtrate was distilled under reduced pressure. The resulting concentrated compound was purified through a silica column using chloroform and ethyl acetate to obtain a yellow solid, Compound 2-8 (23.7 g, 65%, MS: [M+H]+=720).

### Preparation Example 2-9. Preparation of Compound 2-9

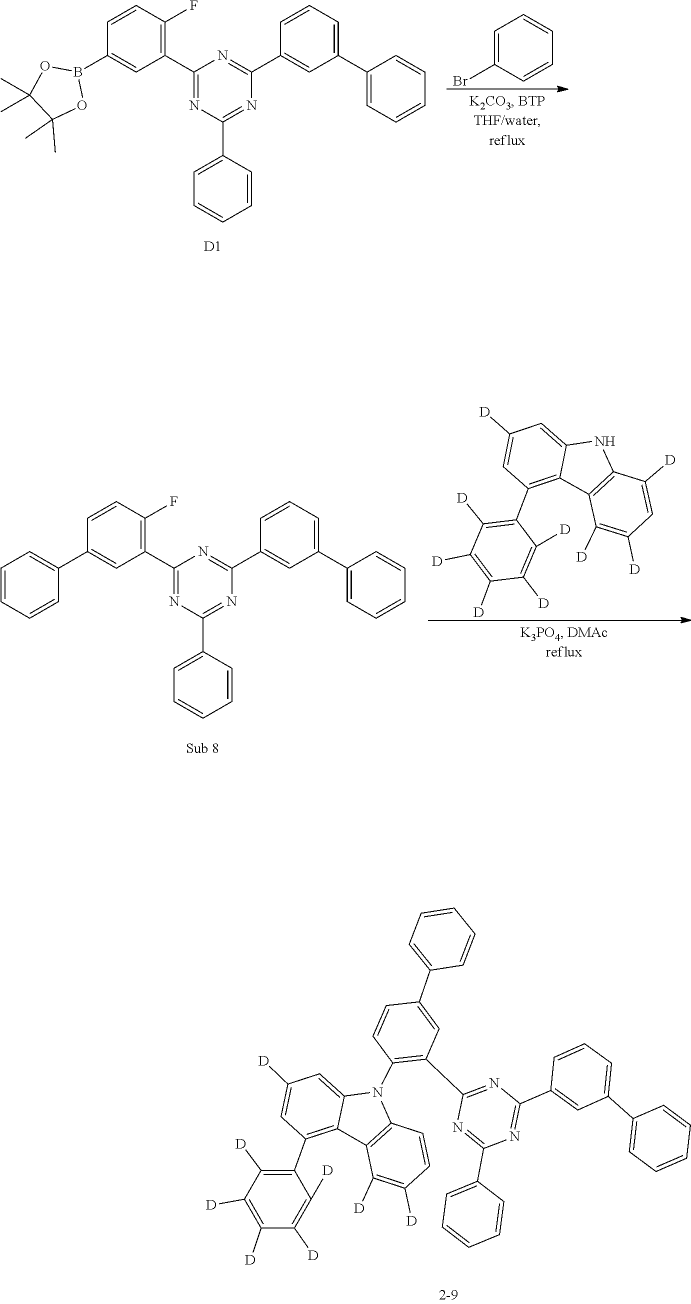

### Step 1) Preparation of Compound Sub 8

Under a nitrogen atmosphere, Compound D1 (35 g, 66.1 mmol) and bromobenzene (10.4 g, 66.1 mmol) were put into 350 ml of tetrahydrofuran, and then stirred and refluxed. Potassium carbonate (27.4 g, 198.3 mmol) was dissolved in 27 ml of water and added to the resulting mixture. After sufficient stirring, bis(tri-tert-butylphosphine)palladium (0.7 g, 1.3 mmol) was added and reacted for 3 hours. After the reaction was completed, the resulting reaction product was cooled to room temperature, and the produced solid was filtered. The obtained solid was added to 1585 mL of chloroform and dissolved. After washing the resulting solution twice with water, the organic layer was separated. Anhydrous magnesium sulfate was added to the separated organic layer and stirred, then filtered. The filtrate was distilled under reduced pressure. The resulting concentrated compound was purified through a silica column using chloroform and ethyl acetate to obtain a gray solid, Compound Sub 8 (25.4 g, 80%, MS: [M+H]+=480.6).

### Step 2) Preparation of Compound 2-9

Under a nitrogen atmosphere, Compound Sub 8 (25 g, 52.1 mmol) prepared in Step 1 and 4-(phenyl-d5)-9H-carbazole-2,5,6,8-d4 (13.2 g, 52.1 mmol) were put into 200 ml of dimethylacetamide, and then stirred and refluxed. Potassium phosphate (33.2 g, 156.4 mmol) was added to the resulting mixture, which was sufficiently stirred, and reacted for 3 hours. After the reaction was completed, the resulting reaction product was cooled to room temperature, and the organic layer was separated. The separated organic layer was filtered to remove salt, and then the filtered organic layer was distilled. The obtained product was added to 1099 mL of chloroform and dissolved. After washing the resulting solution twice with water, the organic layer was separated. Anhydrous magnesium sulfate was added to the separated organic layer and then stirred and filtered. The filtrate was distilled under reduced pressure. The resulting concentrated compound was purified through a silica column using chloroform and ethyl acetate to obtain a yellow solid, Compound 2-9 (23.1 g, 63%, MS: [M+H]+=712).

### Preparation Example 2-10: Preparation of Compound 2-10

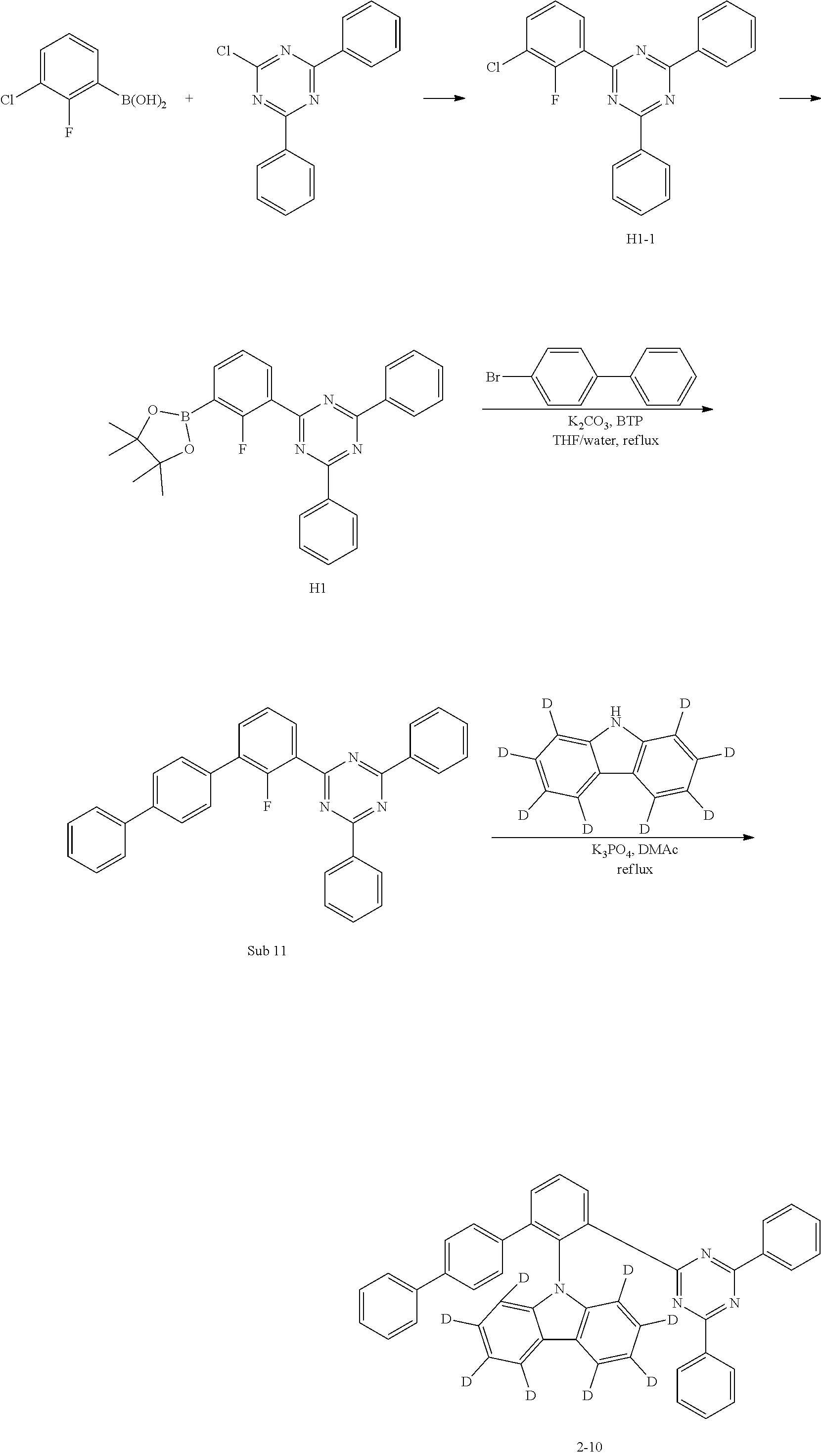

### Step 1) Preparation of Compound H1-1

Under a nitrogen atmosphere, (3-chloro-2-fluorophenyl)boronic acid (40 g, 229.4 mmol) and 2-chloro-4,6-diphenyl-1,3,5-triazine (61.4 g, 229.4 mmol) were put into 400 ml of tetrahydrofuran, and then stirred and refluxed. Thereafter, potassium carbonate (95.1 g, 688.2 mmol) was dissolved in 95 ml of water and added to resulting mixture. After sufficient stirring, [1,1′-bis(diphenylphosphino)ferrocene]dichloropalladium(II) (3.4 g, 4.6 mmol) was added. After reacting for 11 hours, it was cooled to room temperature to separate into the organic layer and the water layer. The organic layer was distilled. The resulting product was again added to 830 mL of toluene and dissolved. After washing the resulting solution twice with water, the organic layer was separated. Anhydrous magnesium sulfate was added to the separated organic layer, and then stirred and filtered. The filtrate was distilled under reduced pressure. The concentrated compound was purified through a silica column using toluene and ethyl acetate to prepare a gray solid, Compound H1-1.

### Step 2) Preparation of Compound H1

Under a nitrogen atmosphere, H1-1 (50 g, 138.2 mmol) and bis(pinacolato)diboron (38.7 g, 165.8 mmol) were put into 750 ml of Diox, and then stirred and refluxed. Thereafter, potassium acetate (39.9 g, 414.6 mmol) was added to the resulting mixture. After sufficient stirring, palladium dibenzylideneacetone palladium (2.4 g, 4.1 mmol) and tricyclohexylphosphine (2.3 g, 8.3 mmol) were added. After reacting for 5 hours, it was cooled to room temperature. The organic layer was filtered to remove salt, and then the filtered organic layer was distilled. The resulting product was again added to 626 mL of chloroform and dissolved. After washing the resulting solution twice with water, the organic layer was separated. Anhydrous magnesium sulfate was added to the separated organic layer and then stirred and filtered. The filtrate was distilled under reduced pressure. The concentrated compound was purified through a silica column using chloroform and ethyl acetate to prepare a yellow solid, Compound H1 (39 g, 62%, MS: [M+H]+=453.3).

### Step 3) Preparation of Compound Sub 11

Under a nitrogen atmosphere, Compound H1 (35 g, 77.2 mmol) and 3-bromo-1,1′-biphenyl (18 g, 77.2 mmol) were put into 350 ml of tetrahydrofuran, and then stirred and refluxed. Thereafter, potassium carbonate (32 g, 231.6 mmol) was dissolved in 27 ml of water and added to resulting mixture. After sufficient stirring, bis(tri-tert-butylphosphine)palladium (0.8 g, 1.5 mmol) was added. After reacting for 3 hours, it was cooled to room temperature and the produced solid was filtered. The solid was added to 1834 mL of chloroform and dissolved. After washing the resulting solution twice with water, the organic layer was separated. Anhydrous magnesium sulfate was added to the separated organic layer, and then stirred and filtered. The filtrate was distilled under reduced pressure. The concentrated compound was purified through a silica column using chloroform and ethyl acetate to prepare a gray solid, Compound Sub 11 (22.9 g, 62%, MS: [M+H]+=481).

### Step 4) Preparation of Compound 2-10

Under a nitrogen atmosphere, Compound Sub 11 (20 g, 41.7 mmol) and 9H-carbazole-d8 (7.3 g, 41.7 mmol) were put into 200 ml of dimethylacetamide, and then stirred and refluxed. Thereafter, potassium phosphate (26.6 g, 125.1 mmol) was added to the resulting mixture, and sufficiently stirred. After reacting for 2 hours, the resulting reaction product was cooled to room temperature and the organic layer was separated. The organic layer was filtered to remove salt, and then the filtered organic layer was distilled. The resulting product was again added to 1000 mL of chloroform and dissolved. After washing the resulting solution twice with water, the organic layer was separated. Anhydrous magnesium sulfate was added to the separated organic layer and stirred, then filtered. The filtrate was distilled under reduced pressure. The concentrated compound was purified through a silica column using chloroform and ethyl acetate to prepare a yellow solid, Compound 2-10 (19.1 g, 72%, MS: [M+H]+=636).

### Preparation Example 2-11: Preparation of Compound 2-11

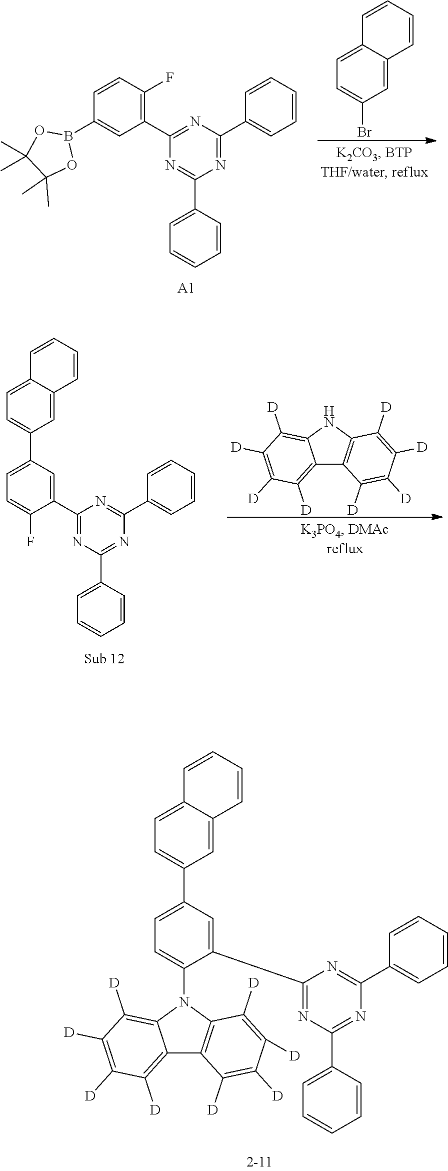

### Step 1) Preparation of Compound Sub 12

Under a nitrogen atmosphere, Compound A1 (36 g, 79.4 mmol) and 2-bromonaphthalene (16.44 g, 79.4 mmol) were put into 720 ml of tetrahydrofuran, and then stirred and refluxed. Potassium carbonate (32.9 g, 238.2 mmol) was dissolved in 33 ml of water and added to the resulting mixture. After sufficient stirring, bis(tri-tert-butylphosphine)palladium (0.8 g, 1.6 mmol) was added. After reacting for 3 hours, it was cooled to room temperature and the produced solid was filtered. The solid was added to 1904 mL of chloroform and dissolved. After washing the resulting solution twice with water, the organic layer was separated. Anhydrous magnesium sulfate was added, and then stirred and filtered. The filtrate was distilled under reduced pressure. The concentrated compound was purified through a silica column using chloroform and ethyl acetate to prepare a gray solid, Compound Sub 12 (20 g, 56%, MS: [M+H]+=454.5).

### Step 2) Preparation of Compound 2-11

Under a nitrogen atmosphere, Compound Sub 12 (20 g, 44.1 mmol) and 9H-carbazole-d8 (7.7 g, 42.7 mmol) were put into 200 ml of dimethylacetamide, and then stirred and refluxed. Potassium phosphate (28.1 g, 132.2 mmol) was added to the resulting mixture and sufficiently stirred. After reaction for 2 hours, the resulting reaction product was cooled to room temperature and the organic layer was separated. The organic layer was filtered to remove salt, and then the filtered organic layer was distilled. The resulting product was again added to 1000 mL of chloroform and dissolved. After washing the resulting solution twice with water, the organic layer was separated. Anhydrous magnesium sulfate was added to the separated organic layer, and the stirred and filtered. The filtrate was distilled under reduced pressure. The concentrated compound was purified through a silica column using chloroform and ethyl acetate to prepare a yellow solid, Compound 2-11 (16.9 g, 63%, MS: [M+H]+=610).

### Preparation Example 2-12: Preparation of Compound 2-12

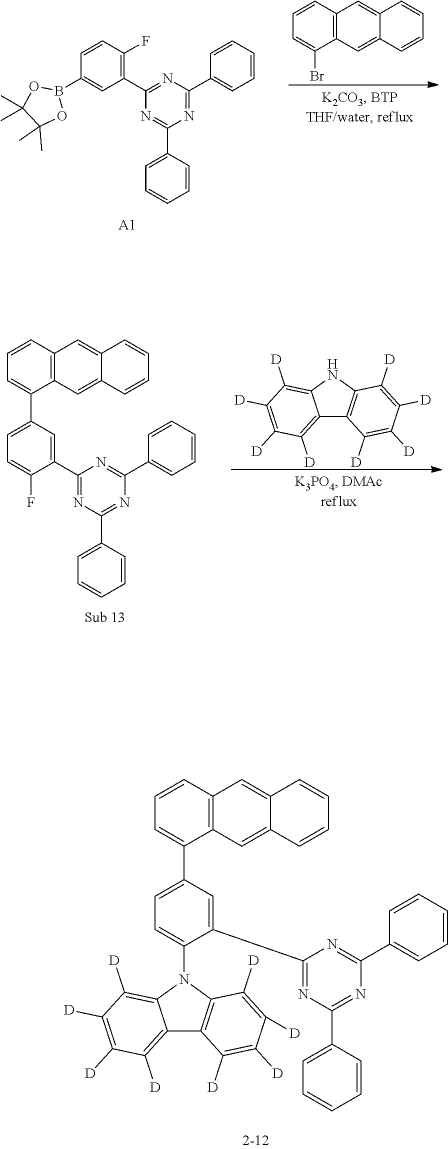 [SMILES: CC1(C)OB(c2ccc(F)c(-c3nc(-c4ccccc4)nc(-c4ccccc4)n3)c2)OC1(C)C ; Brc1cccc2cc3ccccc3cc12 ; "A1" ; Fc1ccc(-c2cccc3cc4ccccc4cc23)cc1-c1nc(-c2ccccc2)nc(-c2ccccc2)n1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc(-c2cccc3cc4ccccc4cc23)cc1-c1nc(-c2ccccc2)nc(-c2ccccc2)n1]

### Step 1) Preparation of Compound Sub 13

Compound Sub 13 was prepared by the same preparation method as for Compound Sub 12, except that 1-bromoanthracene was used instead of 2-bromonaphthalene in Step 1 of Preparation Example 2-11 (15.3 g, 69%, MS: [M+H]+=505).

### Step 2) Preparation of Compound 2-12

Under a nitrogen atmosphere, Compound Sub 13 (20 g, 39.7 mmol) and 9H-carbazole-d8 (7 g, 39.7 mmol) were put into 200 ml of dimethylacetamide, and then stirred and refluxed. Potassium phosphate (25.3 g, 119.1 mmol) was added to the resulting mixture and sufficient stirred. After reacting for 2 hours, the resulting reaction product was cooled to room temperature and the organic layer was separated. The organic layer was filtered to remove salt, and then the filtered organic layer was distilled. The resulting product was again added to 1000 mL of chloroform and dissolved. After washing the resulting solution twice with water, the organic layer was separated. Anhydrous magnesium sulfate was added to the separated organic layer, and then stirred and filtered. The filtrate was distilled under reduced pressure. The concentrated compound was purified through a silica column using chloroform and ethyl acetate to prepare a yellow solid, Compound 2-12 (17.8 g, 68%, MS: [M+H]+=660).

### Preparation Example 2-13: Preparation of Compound 2-13

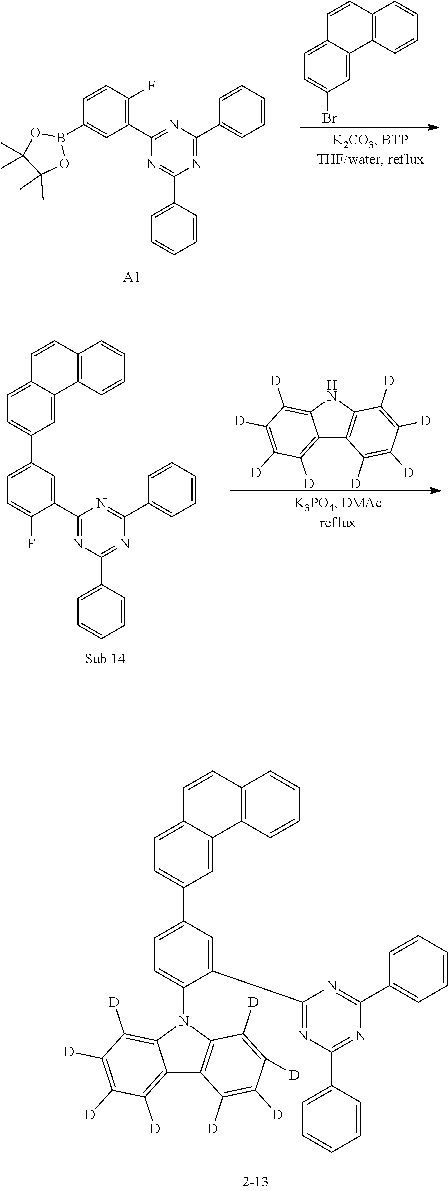 [SMILES: CC1(C)OB(c2ccc(F)c(-c3nc(-c4ccccc4)nc(-c4ccccc4)n3)c2)OC1(C)C ; Brc1ccc2ccc3ccccc3c2c1 ; "A1" ; Fc1ccc(-c2ccc3ccc4ccccc4c3c2)cc1-c1nc(-c2ccccc2)nc(-c2ccccc2)n1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc(-c2ccc3ccc4ccccc4c3c2)cc1-c1nc(-c2ccccc2)nc(-c2ccccc2)n1]

### Step 1) Preparation of Compound Sub 14

Compound Sub 14 was prepared by the same preparation method as for Compound Sub 12, except that 3-bromophenanthrene was used instead of 2-bromonaphthalene in Step 1 of Preparation Example 2-11 (16.4 g, 74%, MS: [M+H]+=505).

### Step 2) Preparation of Compound 2-13

Under a nitrogen atmosphere, Compound Sub 14 (20 g, 39.7 mmol) and 9H-carbazole-d8 (7 g, 39.7 mmol) were put into 200 ml of dimethylacetamide, and then stirred and refluxed. Potassium phosphate (25.3 g, 119.1 mmol) was added to the resulting mixture, and sufficiently stirred. After reacting for 2 hours, the resulting reaction product was cooled to room temperature and the organic layer was separated. The organic layer was filtered to remove salt, and then the filtered organic layer was distilled. The resulting product was again added to 1000 mL of chloroform and dissolved. After washing the resulting solution twice with water, the organic layer was separated. Anhydrous magnesium sulfate was added and stirred, then filtered. The filtrate was distilled under reduced pressure. The concentrated compound was purified through a silica column using chloroform and ethyl acetate to prepare a yellow solid, Compound 2-13 (20.7 g, 79%, MS: [M+H]+=660).

### Preparation Example 2-14: Preparation of Compound 2-14

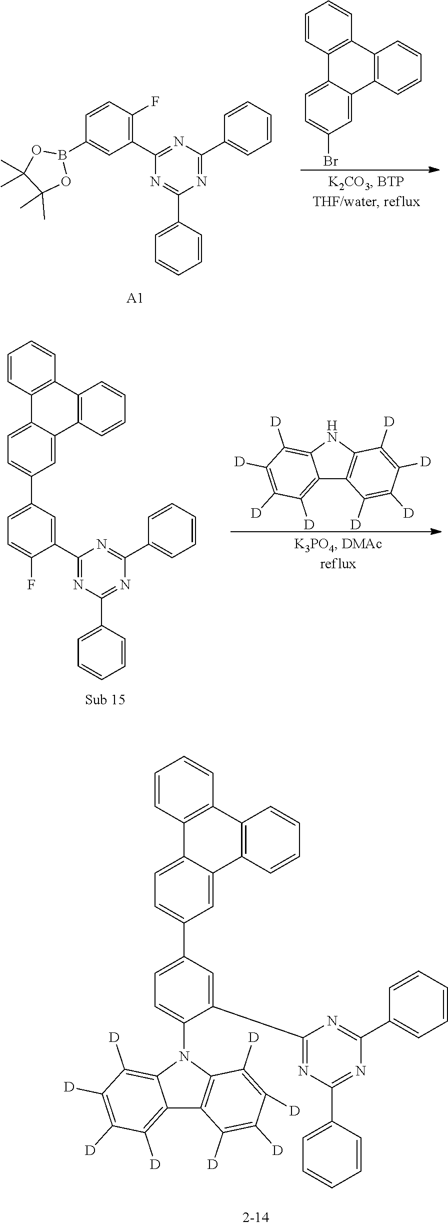

### Step 1) Preparation of Compound Sub 15

Compound Sub 15 was prepared by the same preparation method as for Compound Sub 12, except that 2-bromotriphenylene was used instead of 2-bromonaphthalene in Step 1 of Preparation Example 2-11 (17.1 g, 70%, MS: [M+H]+=555).

### Step 2) Preparation of Compound 2-14

Under a nitrogen atmosphere, Compound Sub 15 (20 g, 36 mmol) and 9H-carbazole-d8 (6.3 g, 36 mmol) were put into 200 ml of dimethylacetamide, and then stirred and refluxed. Potassium phosphate (22.9 g, 108 mmol) was added to the resulting mixture and sufficiently stirred. After reacting for 2 hours, the resulting reaction product was cooled to room temperature and the organic layer was separated. The separated organic layer was filtered to remove salt, and then the filtered organic layer was distilled. The resulting product was again added to 1000 mL of chloroform and dissolved. After washing the resulting solution twice with water, the organic layer was separated. Anhydrous magnesium sulfate was added to the separated organic layer, and then stirred and filtered. The filtrate was distilled under reduced pressure. The concentrated compound was purified through a silica column using chloroform and ethyl acetate to prepare a yellow solid, Compound 2-14 (18.6 g, 73%, MS: [M+H]+=710).

### Example 1

A glass substrate on which ITO (indium tin oxide) was coated as a thin film to a thickness of 1,000 Å was put into distilled water in which a detergent was dissolved, and ultrasonically cleaned. A product manufactured by Fischer Co. was used as the detergent, and as the distilled water, distilled water filtered twice using a filter manufactured by Millipore Co. was used. After the ITO was cleaned for 30 minutes, ultrasonic cleaning was repeated twice using distilled water for 10 minutes. After the cleaning with distilled water was completed, the substrate was ultrasonically cleaned with solvents of isopropyl alcohol, acetone, and methanol, dried, and then transferred to a plasma cleaner. In addition, the substrate was cleaned for 5 minutes using oxygen plasma and then transferred to a vacuum depositor.

On the ITO transparent electrode thus prepared, the following compound HI-A was thermally vacuum-deposited to a thickness of 60 nm to form a hole injection layer.

On the hole injection layer, the following Compound HAT was vacuum-deposited to form a first hole transport layer with a thickness of 5 nm, and on the first hole transport layer, the following Compound HT-A was vacuum-deposited to form a second hole transport layer with a thickness of 50 nm.

On the second hole transport layer, the following Compound HT-B was thermally vacuum-deposited to a thickness of 45 nm to form an electron blocking layer. On the electron blocking layer, the previously prepared Compound 1-1 and Compound 2-1 were mixed in a 1:1 weight ratio, and then the mixture and the following Compound GD were vacuum-deposited in a weight ratio of 90:10 to a thickness of 40 nm to form a light emitting layer. On the light emitting layer, the following Compound ET-A was vacuum-deposited to a thickness of 5 nm to form a hole blocking layer. On the hole blocking layer, the following Compound ET-B and the following Compound LiQ were vacuum-deposited in a 1:1 weight ratio to form an electron injection and transport layer with a thickness of 35 nm.

On the electron injection and transport layer, lithium fluoride (LiF) was deposited to a thickness of 1 nm, and then aluminum was deposited to a thickness of 100 nm to form a cathode, thereby manufacturing an organic light emitting device.

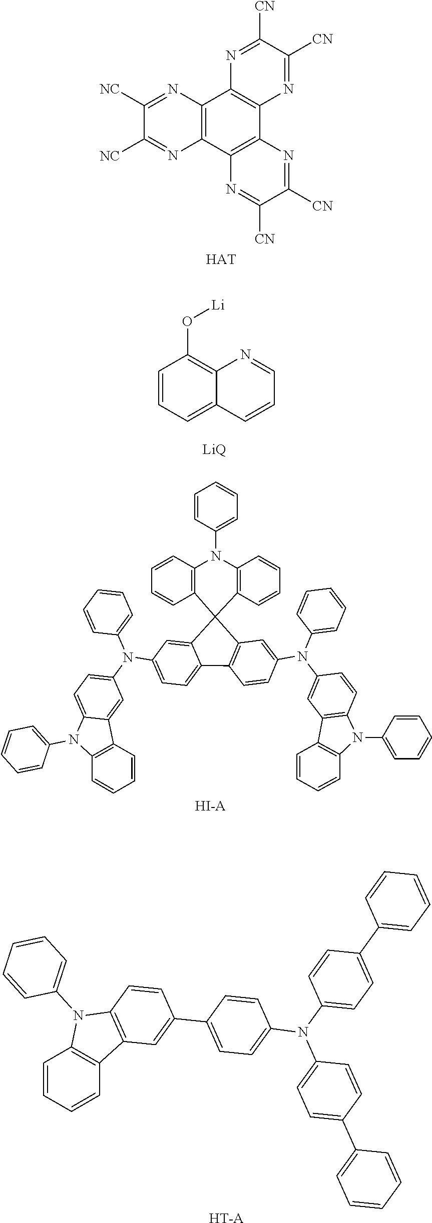

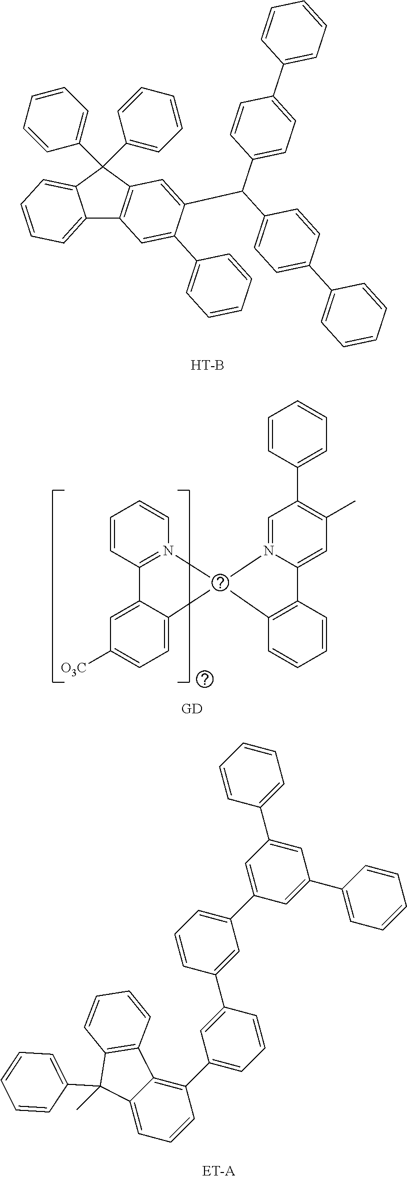

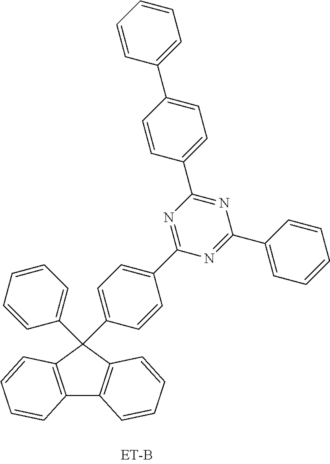 [SMILES: c1ccc(-c2ccc(-c3nc(-c4ccccc4)nc(-c4ccc(C5(c6ccccc6)c6ccccc6-c6ccccc65)cc4)n3)cc2)cc1]

In the above-mentioned processes, the deposition rate of the organic material was maintained at 0.04 nm/sec to 0.09 nm/sec, the deposition rate of lithium fluoride was maintained at 0.03 nm/sec, and the deposition rate of aluminum was maintained at 0.2 nm/sec. The degree of vacuum during deposition was maintained at 1*10-7 torr to 5*10⁻⁵ torr.

### Examples 2 to 37, and Comparative Examples 1 to 10

Organic light emitting devices were manufactured in the same manner as in Example 1, except that the compounds listed in Table 1 below were used instead of Compound 1-1 or 2-1 in Example 1.

Meanwhile, the structures of compounds GH1 to GH10 in Table 1 below are as follows, respectively.

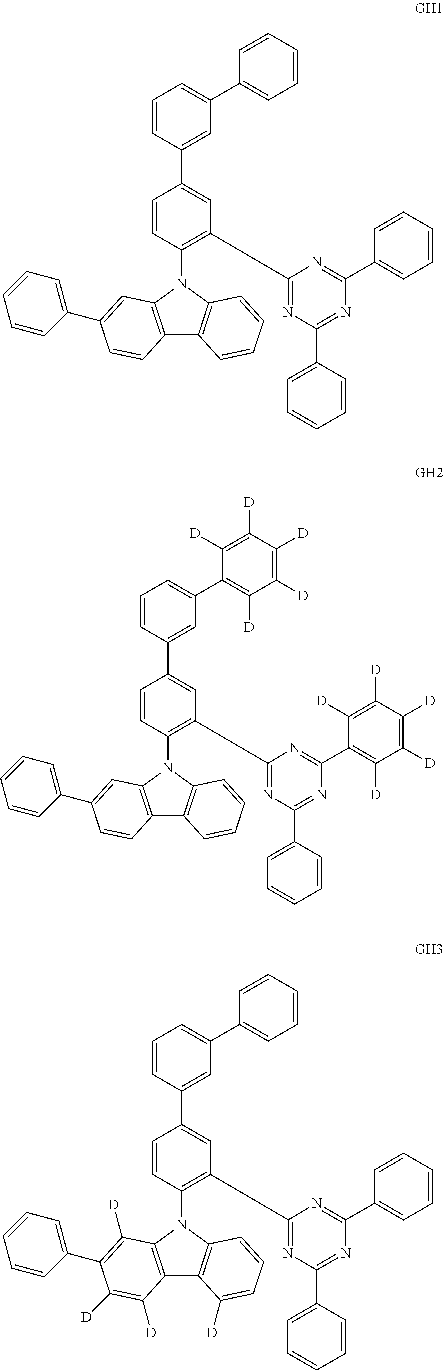 [SMILES: c1ccc(-c2cccc(-c3ccc(-n4c5ccccc5c5ccc(-c6ccccc6)cc54)c(-c4nc(-c5ccccc5)nc(-c5ccccc5)n4)c3)c2)cc1 ; [2H]c1c([2H])c([2H])c(-c2cccc(-c3ccc(-n4c5ccccc5c5ccc(-c6ccccc6)cc54)c(-c4nc(-c5ccccc5)nc(-c5c([2H])c([2H])c([2H])c([2H])c5[2H])n4)c3)c2)c([2H])c1[2H] ; [2H]c1c(-c2ccccc2)c([2H])c2c(c1[2H])c1c([2H])cccc1n2-c1ccc(-c2cccc(-c3ccccc3)c2)cc1-c1nc(-c2ccccc2)nc(-c2ccccc2)n1]

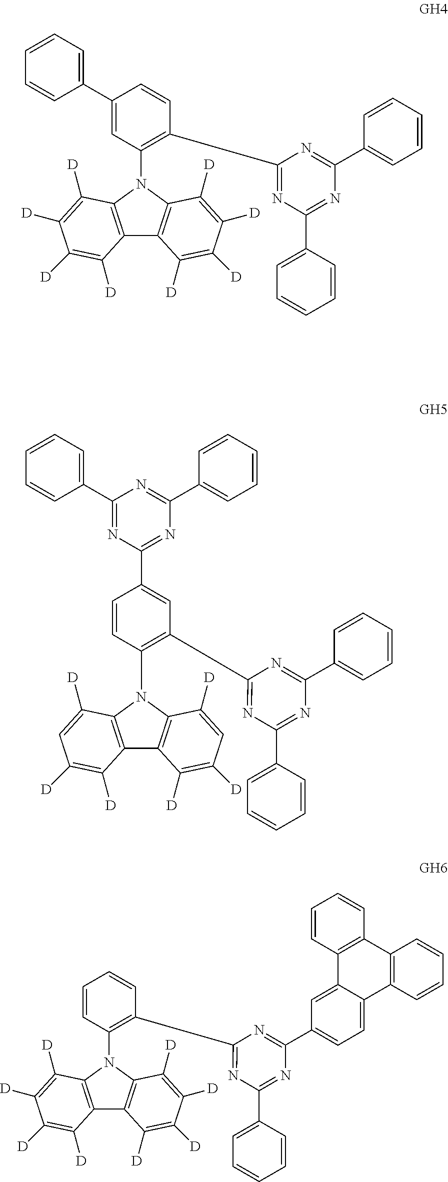 [SMILES: [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2ccccc2)n1 ; [2H]c1cc([2H])c2c(c1[2H])c1c([2H])c([2H])cc([2H])c1n2-c1ccc(-c2nc(-c3ccccc3)nc(-c3ccccc3)n2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1ccccc1-c1nc(-c2ccccc2)nc(-c2ccc3c4ccccc4c4ccccc4c3c2)n1]

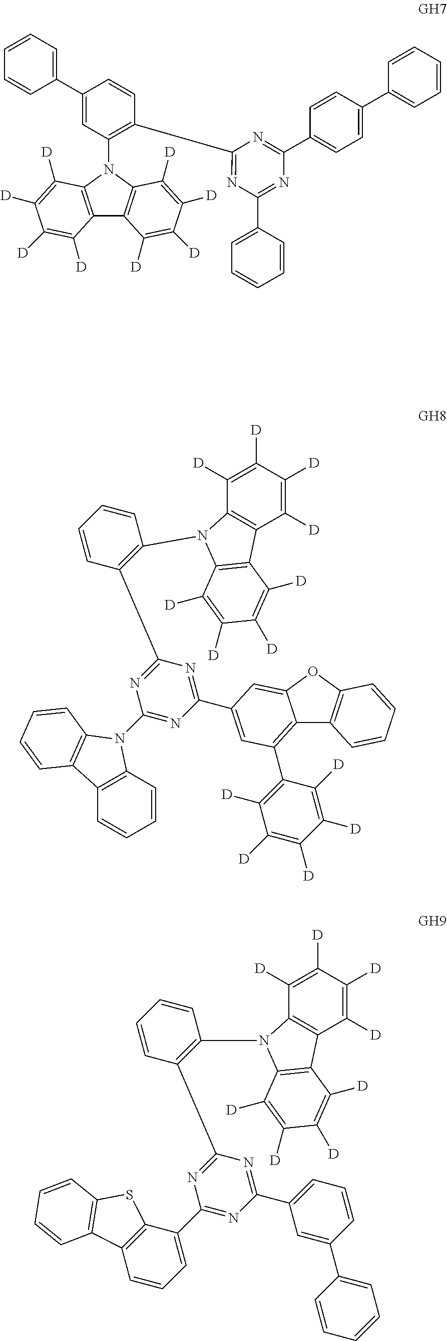 [SMILES: [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2ccc(-c3ccccc3)cc2)n1 ; [2H]c1c([2H])c([2H])c(-c2cc(-c3nc(-c4ccccc4-n4c5c([2H])c([2H])c([2H])c([2H])c5c5c([2H])c([2H])c([2H])c([2H])c54)nc(-n4c5ccccc5c5ccccc54)n3)cc3oc4ccccc4c23)c([2H])c1[2H] ; [2H]c1c([2H])c([2H])c2c(c1[2H])c1c([2H])c([2H])c([2H])c([2H])c1n2-c1ccccc1-c1nc(-c2cccc(-c3ccccc3)c2)nc(-c2cccc3c2sc2ccccc23)n1]

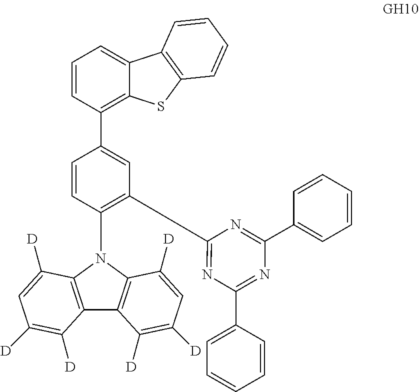 [SMILES: [2H]c1cc([2H])c2c(c1[2H])c1c([2H])c([2H])cc([2H])c1n2-c1ccc(-c2cccc3c2sc2ccccc23)cc1-c1nc(-c2ccccc2)nc(-c2ccccc2)n1]

### Experimental Example

The voltage, efficiency and lifetime were measured by applying a current to the organic light emitting devices manufactured in the Examples and Comparative Examples, and the results are shown in Tables 1 to 3 below. At this time, the voltage and efficiency were measured by applying a current density of 10 mA/cm², and T95 means the time (hr) required for the luminance to be reduced to 95% of the initial luminance at a current density of 20 mA/cm².

TABLE 1

| | | | | Efficiency | | |
|---|---|---|---|---|---|---|
| | First | Second | Voltage (V) | (cd/A) | Emission | T₉₅(hr) |
| Category | Compound | Compound | (@10 mA/cm²) | (@10 mA/cm²) | Color | (@20 mA/cm²) |
| Example | Compound | Compound | 3.89 | 43.27 | Green | 135 |
| 1 | 1-1 | 2-1 | | | | |
| Example | | Compound | 3.91 | 44.20 | Green | 121 |
| 2 | | 2-3 | | | | |
| Example | | Compound | 3.79 | 46.88 | Green | 151 |
| 3 | | 2-8 | | | | |
| Example | Compound | Compound | 3.81 | 43.89 | Green | 126 |
| 4 | 1-2 | 2-5 | | | | |
| Example | | Compound | 3.71 | 44.98 | Green | 130 |
| 5 | | 2-7 | | | | |
| Example | | Compound | 3.69 | 46.90 | Green | 147 |
| 6 | | 2-9 | | | | |
| Example | Compound | Compound | 3.68 | 47.01 | Green | 132 |
| 7 | 1-3 | 2-2 | | | | |
| Example | | Compound | 3.81 | 42.35 | Green | 121 |
| 8 | | 2-4 | | | | |
| Example | | Compound | 3.67 | 47.05 | Green | 155 |
| 9 | | 2-6 | | | | |
| Example | | Compound | 3.69 | 47.04 | Green | 181 |
| 10 | | 2-7 | | | | |
| Example | Compound | Compound | 3.89 | 46.05 | Green | 133 |
| 11 | 1-4 | 2-2 | | | | |
| Example | | Compound | 3.87 | 46.01 | Green | 156 |
| 12 | | 2-6 | | | | |
| Example | | Compound | 3.75 | 43.88 | Green | 152 |
| 13 | | 2-8 | | | | |
| Example | Compound | Compound | 3.91 | 43.98 | Green | 150 |
| 14 | 1-5 | 2-3 | | | | |
| Example | | Compound | 3.80 | 44.20 | Green | 144 |
| 15 | | 2-5 | | | | |
| Example | | Compound | 3.86 | 43.50 | Green | 151 |
| 16 | | 2-8 | | | | |
| Example | Compound | Compound | 3.94 | 43.95 | Green | 146 |
| 17 | 1-6 | 2-2 | | | | |
| Example | | Compound | 3.55 | 42.95 | Green | 138 |
| 18 | | 2-8 | | | | |

TABLE 2

| | | | | Efficiency | | |
|---|---|---|---|---|---|---|
| | First | Second | Voltage (V) | (cd/A) | Emission | T₉₅(hr) |
| Category | Compound | Compound | (@10 mA/cm²) | (@10 mA/cm²) | Color | (@20 mA/cm²) |
| Example | Compound | Compound | 3.96 | 43.10 | Green | 129 |
| 19 | 1-7 | 2-2 | | | | |
| Example | | Compound | 3.65 | 45.33 | Green | 137 |
| 20 | | 2-4 | | | | |
| Example | | Compound | 3.66 | 43.80 | Green | 150 |
| 21 | | 2-8 | | | | |
| Example | Compound | Compound | 3.94 | 43.27 | Green | 159 |
| 22 | 1-8 | 2-3 | | | | |
| Example | | Compound | 3.89 | 44.32 | Green | 136 |
| 23 | | 2-5 | | | | |
| Example | | Compound | 3.74 | 47.01 | Green | 195 |
| 24 | | 2-8 | | | | |
| Example | Compound | Compound | 3.90 | 42.33 | Green | 136 |
| 25 | 1-9 | 2-1 | | | | |
| Example | | Compound | 3.71 | 47.00 | Green | 165 |
| 26 | | 2-9 | | | | |
| Example | Compound | Compound | 3.69 | 47.06 | Green | 150 |
| 27 | 1-10 | 2-2 | | | | |
| Example | | Compound | 3.68 | 47.03 | Green | 178 |
| 28 | | 2-6 | | | | |
| Example | | Compound | 3.70 | 47.10 | Green | 201 |
| 29 | | 2-7 | | | | |
| Example | Compound | Compound | 3.86 | 44.23 | Green | 136 |
| 30 | 1-11 | 2-2 | | | | |
| Example | | Compound | 3.95 | 43.21 | Green | 145 |
| 31 | | 2-3 | | | | |
| Example | | Compound | 3.77 | 46.89 | Green | 172 |
| 32 | | 2-8 | | | | |

TABLE 3

| | | | | Efficiency | | |
|---|---|---|---|---|---|---|
| | First | Second | Voltage (V) | (cd/A) | Emission | T₉₅(hr) |
| Category | Compound | Compound | (@10 mA/cm²) | (@10 mA/cm²) | Color | (@20 mA/cm²) |
| Example | Compound | Compound | 3.89 | 45.01 | Green | 137 |
| 33 | 1-1 | 2-10 | | | | |
| Example | | Compound | 3.81 | 45.22 | Green | 158 |
| 34 | | 2-11 | | | | |
| Example | | Compound | 3.87 | 46.01 | Green | 162 |
| 35 | | 2-12 | | | | |
| Example | | Compound | 3.79 | 46.19 | Green | 170 |
| 36 | | 2-13 | | | | |
| Example | | Compound | 3.82 | 47.28 | Green | 165 |
| 37 | | 2-14 | | | | |

TABLE 4

| | | | | Efficiency | | |
|---|---|---|---|---|---|---|
| | First | Second | Voltage (V) | (cd/A) | Emission | T₉₅(hr) |
| Category | Compound | Compound | (@10 mA/cm²) | (@10 mA/cm²) | Color | (@20 mA/cm²) |
| Comparative | Compound | Compound | 4.23 | 38.32 | Green | 67 |
| Example 1 | 1-1 | GH-1 | | | | |
| Comparative | | Compound | 4.26 | 38.36 | Green | 82 |
| Example 2 | | GH-2 | | | | |
| Comparative | | Compound | 4.25 | 38.30 | Green | 75 |
| Example 3 | | GH-3 | | | | |
| Comparative | | Compound | 4.33 | 37.30 | Green | 60 |
| Example 4 | | GH-4 | | | | |
| Comparative | | Compound | 4.26 | 37.88 | Green | 65 |
| Example 5 | | GH-5 | | | | |
| Comparative | | Compound | 4.34 | 37.60 | Green | 72 |
| Example 6 | | GH-6 | | | | |
| Comparative | | Compound | 4.40 | 37.82 | Green | 59 |
| Example 7 | | GH-7 | | | | |
| Comparative | | Compound | 4.39 | 36.21 | Green | 63 |
| Example 8 | | GH-8 | | | | |
| Comparative | | Compound | 4.49 | 36.97 | Green | 55 |
| Example 9 | | GH-9 | | | | |
| Comparative | | Compound | 4.01 | 41.52 | Green | 75 |
| Example 10 | | GH-10 | | | | |

As a result of the experiment, the organic light emitting devices of the Examples comprising the first compound represented by Formula 1 and the second compound represented by Formula 2 of the present disclosure in the light emitting layer showed excellent efficiency, driving voltage, and lifetime characteristics compared to the Comparative Examples.

[Description of Symbols]

| | |
|---|---|
| 1: substrate | 2: anode |
| 3: Light emitting layer | 4: Cathode |
| 5: Hole injection layer | 6: Hole transport layer |
| 7: Electron blocking layer | 8: Hole blocking layer |
| 9: Electron injection and transport layer | |

1. A composition for an organic light emitting device comprising a first compound represented by the following Chemical Formula 1 and a second compound represented by the following Chemical Formula 2: 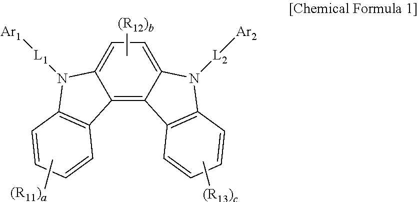
wherein in the Chemical Formula 1,
Ar₁ and Ar₂ are each independently a substituted or unsubstituted C₆₋₆₀ aryl; or a substituted or unsubstituted C₂₋₆₀ heteroaryl containing any one or more selected from the group consisting of N, O and S,
L₁ and L₂ are each independently a single bond; or a substituted or unsubstituted C₆₋₆₀ arylene,
R₁₁, R₁₂ and R₁₃ are each independently deuterium,
a and c are each independently an integer of 0 to 4,
b is an integer of 0 to 2, and 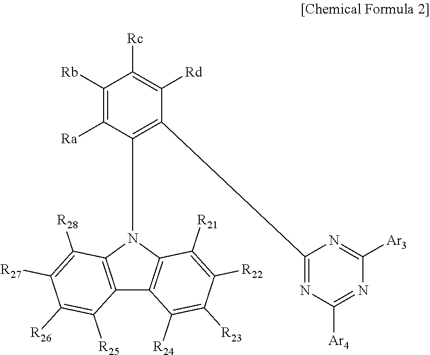
wherein in Chemical Formula 2,
Ar₃ and Ar₄ are each independently a substituted or unsubstituted C₆₋₁₅ aryl,
Rₐ and R_{d} are each independently hydrogen; deuterium; or a substituted or unsubstituted C₆₋₆₀ aryl,
R_{b} is hydrogen or deuterium,
R_{c} is hydrogen; deuterium; or a C₆₋₆₀ aryl unsubstituted or substituted with deuterium,
R₂₁ to R₂₈ are each independently hydrogen; deuterium; or a substituted or unsubstituted C₆₋₆₀ aryl, provided that at least one of R₂₁ to R₂₈ is deuterium or a C₆₋₆₀ aryl substituted with deuterium, and
the second compound is substituted with six or more deuteriums.

2. The composition for an organic light emitting device according to claim 1, wherein:
Ar₁ and Ar₂ are each independently, phenyl, biphenyl, terphenyl, triphenylenyl, dibenzofuranyl, dibenzothiophenyl, carbazolyl, or 9-phenyl carbazole, and
the Ar₁ and Ar₂ are each independently unsubstituted, or substituted with one or more deuterium atoms.

3. The composition for an organic light emitting device according to claim 1, wherein:
one of Ar₁ and Ar₂ is phenyl, biphenyl, or terphenyl, and the other is phenyl, biphenyl, terphenyl, triphenylenyl, dibenzofuranyl, dibenzothiophenyl, carbazolyl, or 9-phenyl carbazole, and
the Ar₁ and Ar₂ are each independently unsubstituted, or substituted with one or more deuterium atoms.

4. The composition for an organic light emitting device according to claim 1, wherein:
L₁ and L₂ are each independently a single bond or phenylene, and
the phenylene is unsubstituted, or substituted with one or more deuterium atoms.

5. The composition for an organic light emitting device according to claim 1, wherein:
a and c are each 4, and
b is 2.

6. The composition for an organic light emitting device according to claim 1, wherein:
the first compound is any one selected from the group consisting of the following compounds:

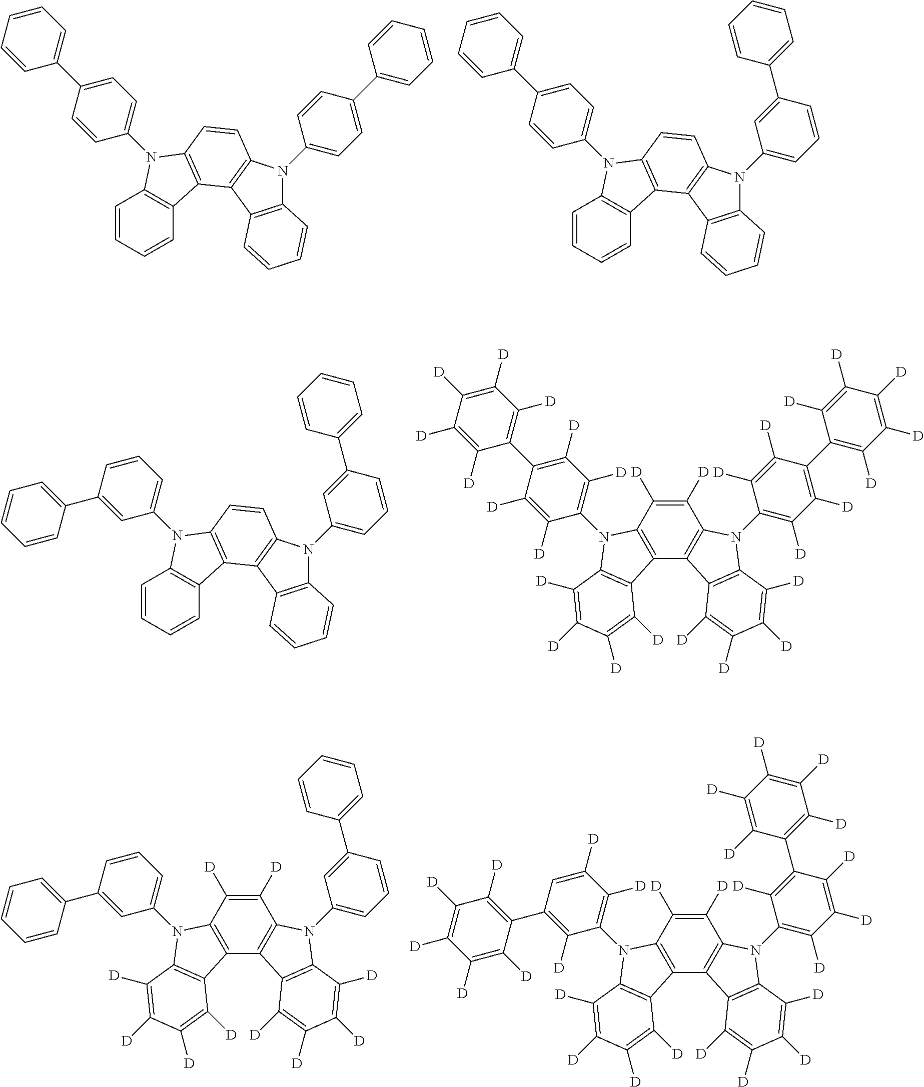

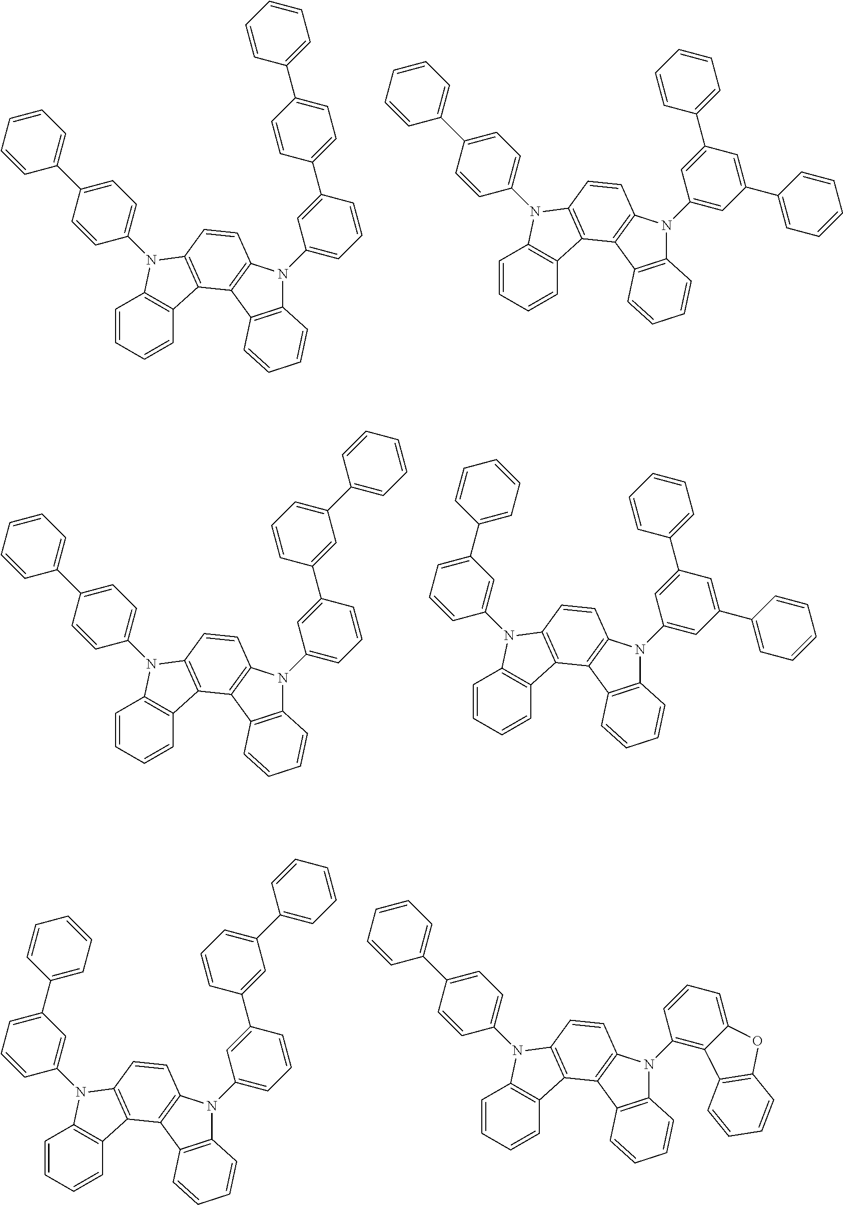

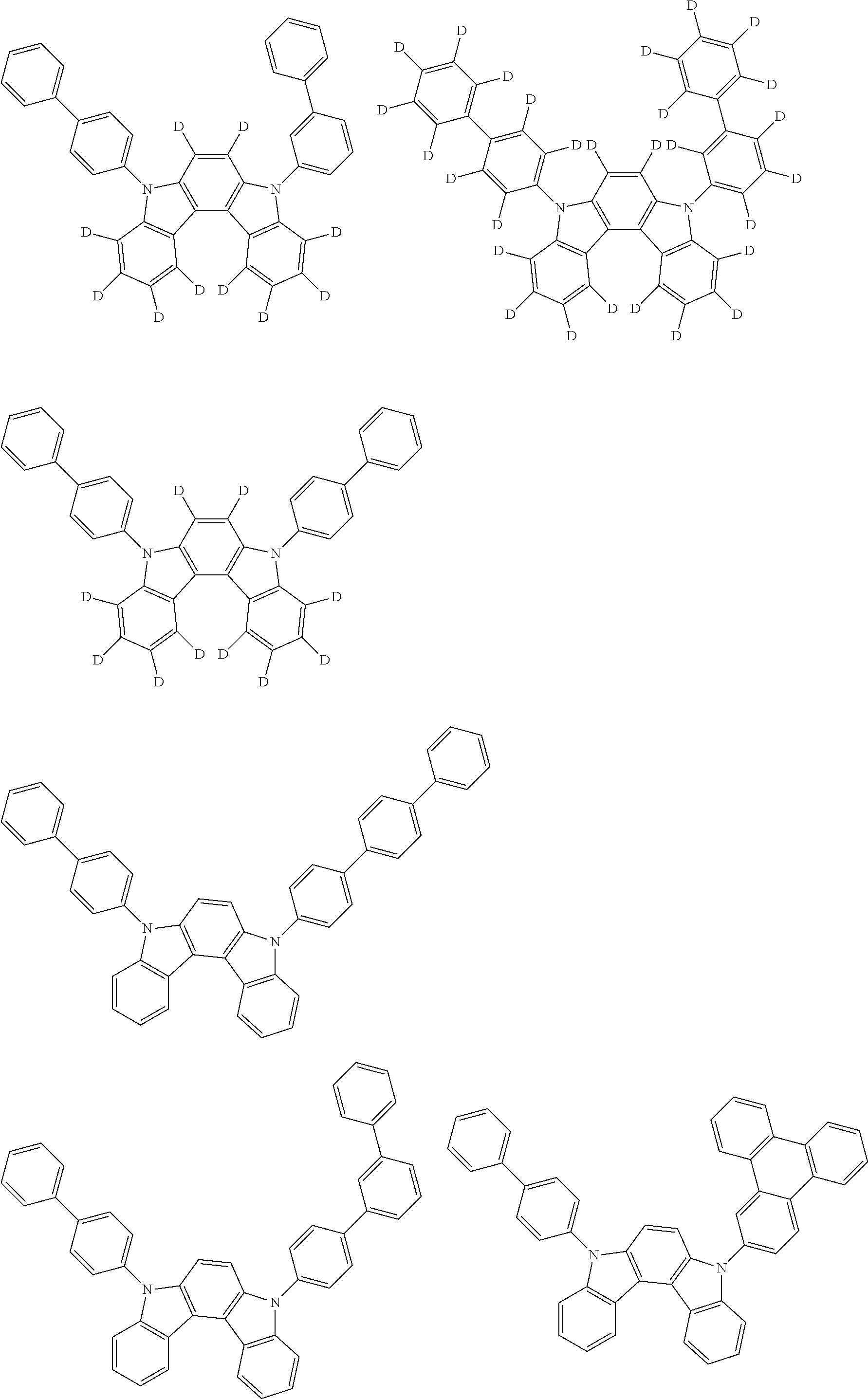

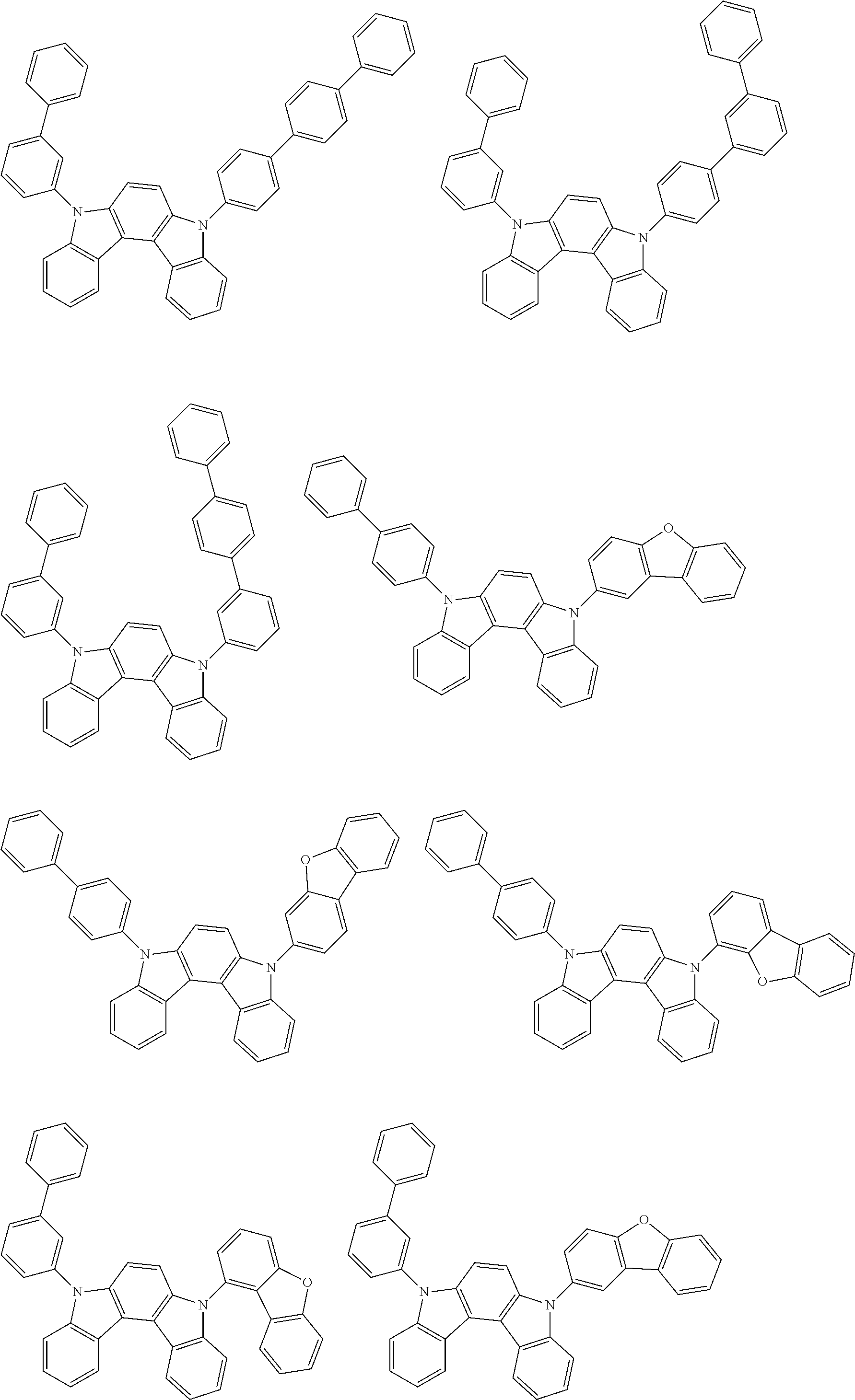

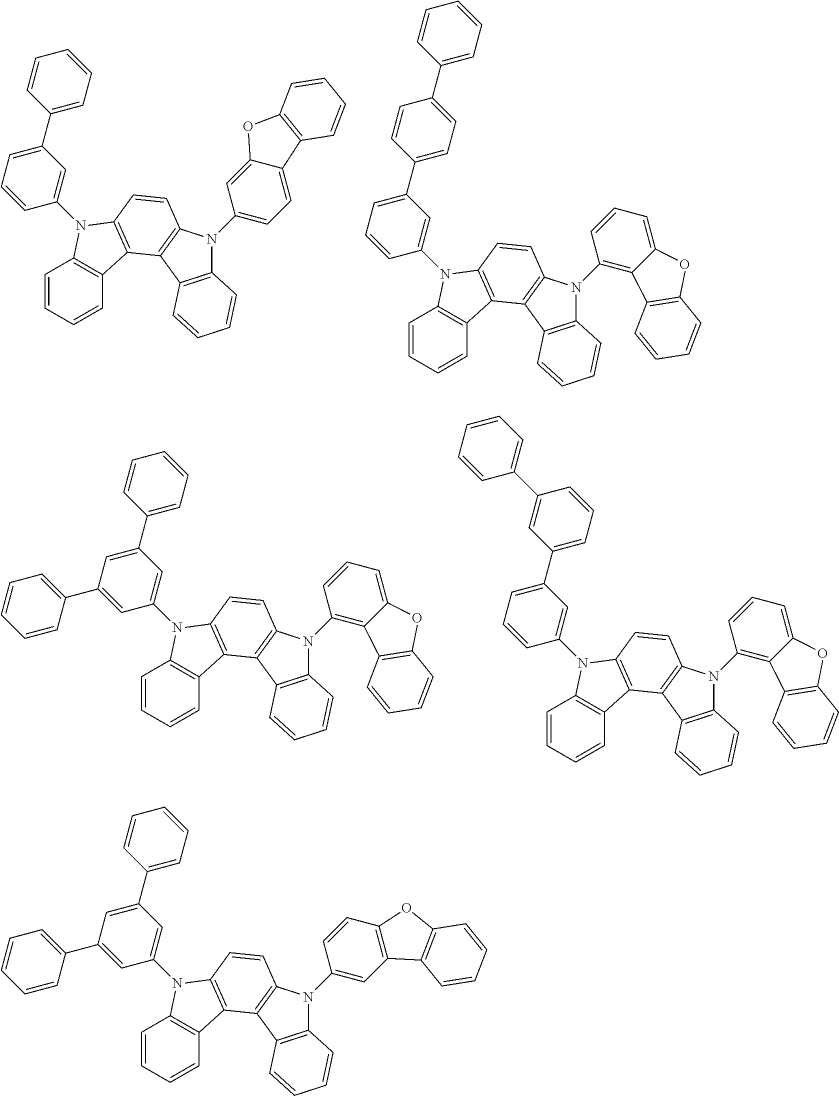 [SMILES: c1ccc(-c2cccc(-n3c4ccccc4c4c5c6ccccc6n(-c6ccc7c(c6)oc6ccccc67)c5ccc43)c2)cc1 ; c1ccc(-c2ccc(-c3cccc(-n4c5ccccc5c5c6c7ccccc7n(-c7cccc8oc9ccccc9c78)c6ccc54)c3)cc2)cc1 ; c1ccc(-c2cc(-c3ccccc3)cc(-n3c4ccccc4c4c5c6ccccc6n(-c6cccc7oc8ccccc8c67)c5ccc43)c2)cc1 ; c1ccc(-c2cccc(-c3cccc(-n4c5ccccc5c5c6c7ccccc7n(-c7cccc8oc9ccccc9c78)c6ccc54)c3)c2)cc1 ; c1ccc(-c2cc(-c3ccccc3)cc(-n3c4ccccc4c4c5c6ccccc6n(-c6ccc7oc8ccccc8c7c6)c5ccc43)c2)cc1]

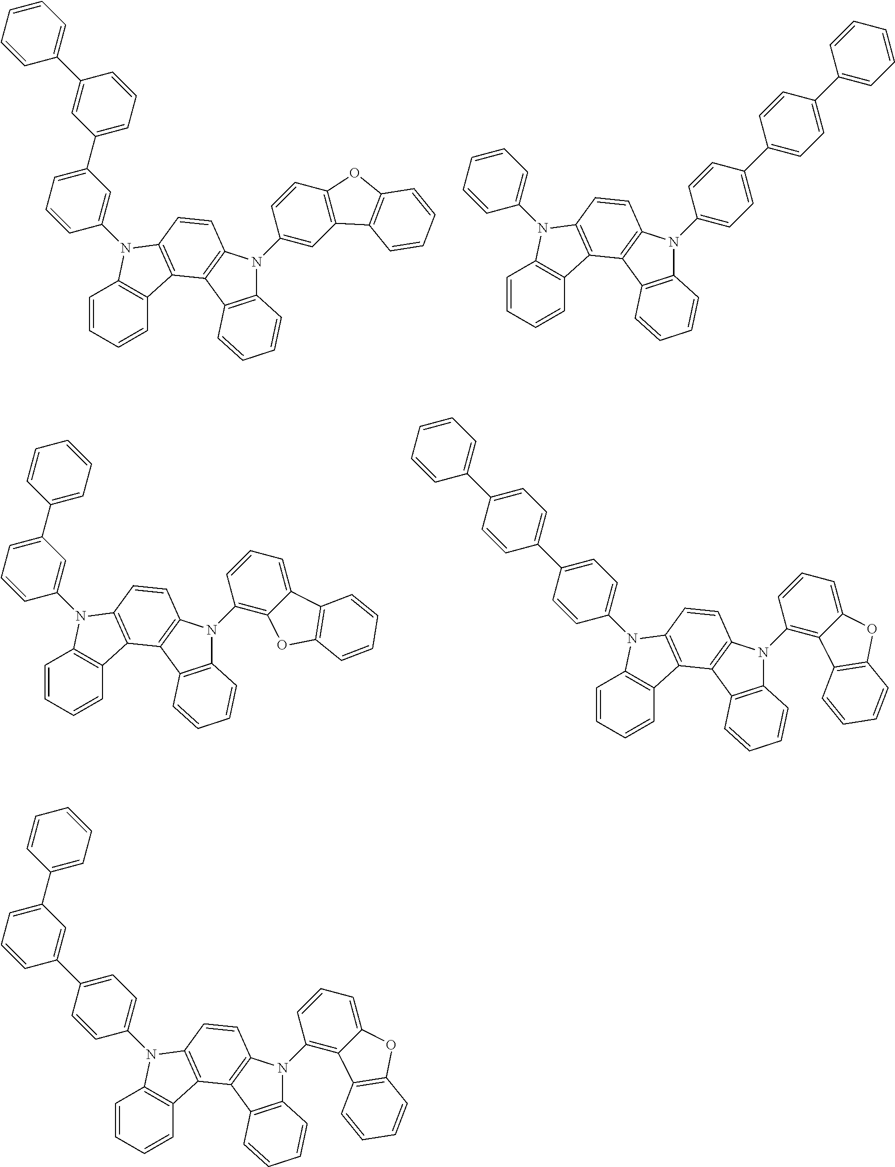

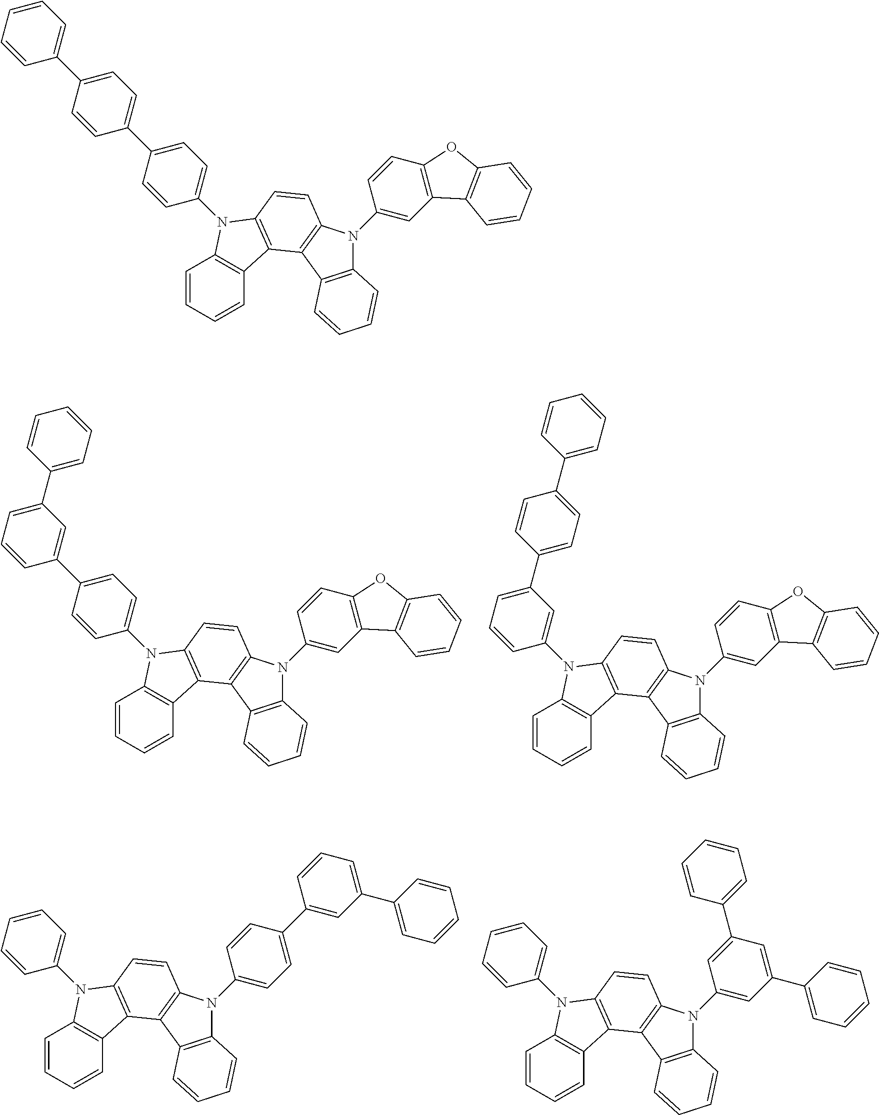

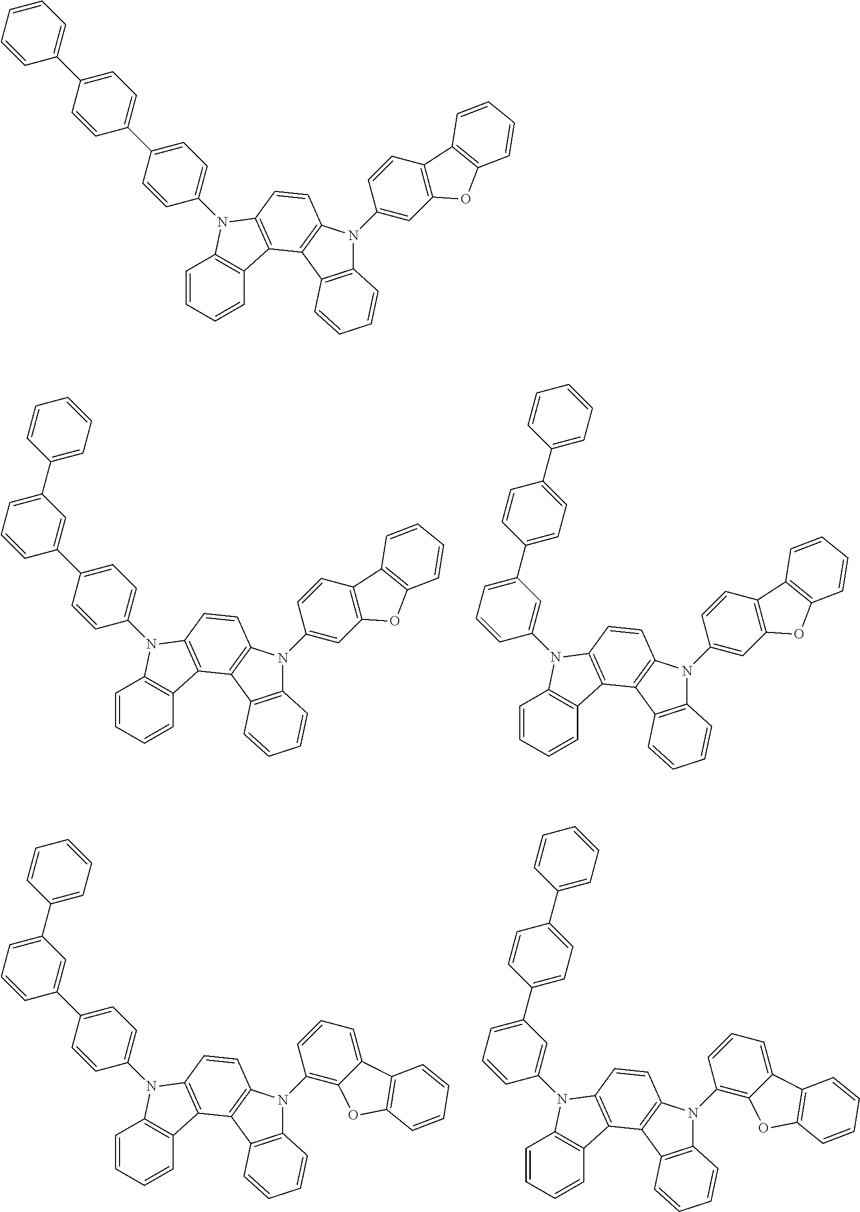

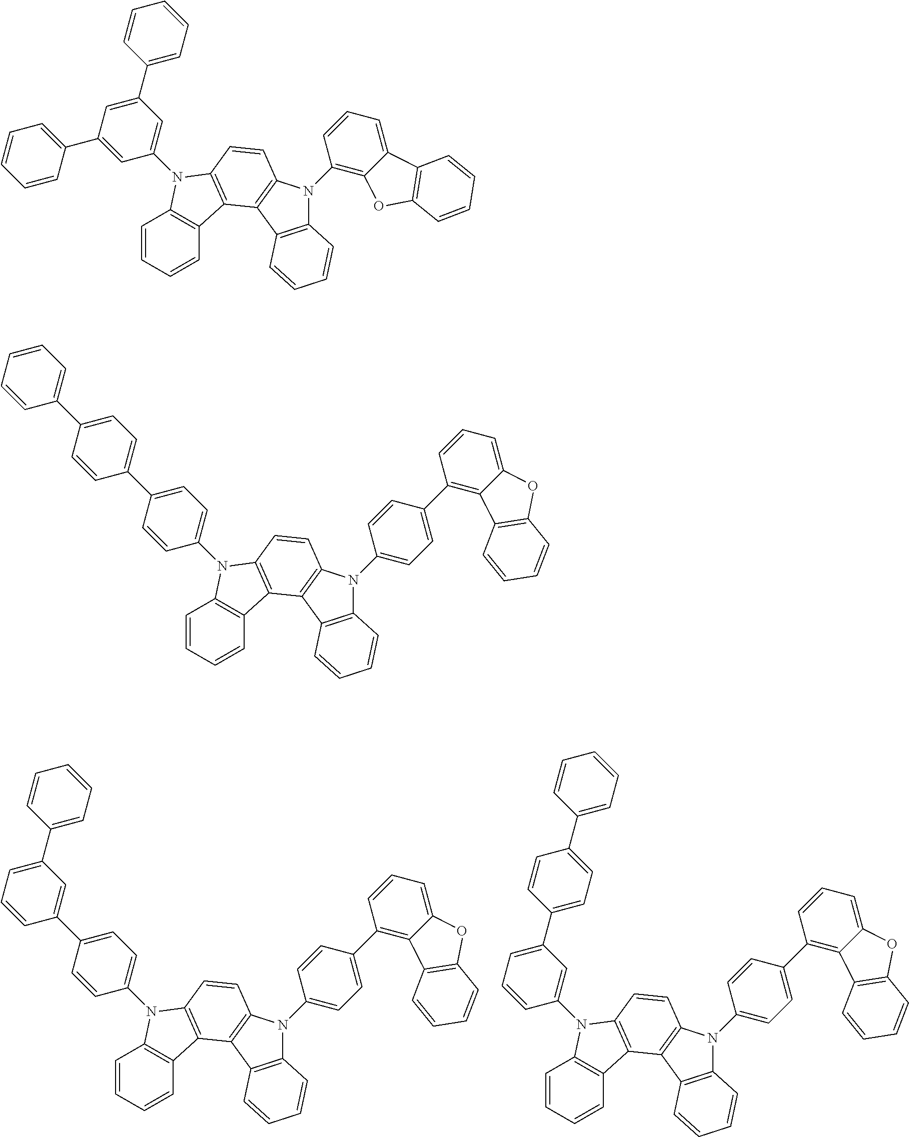

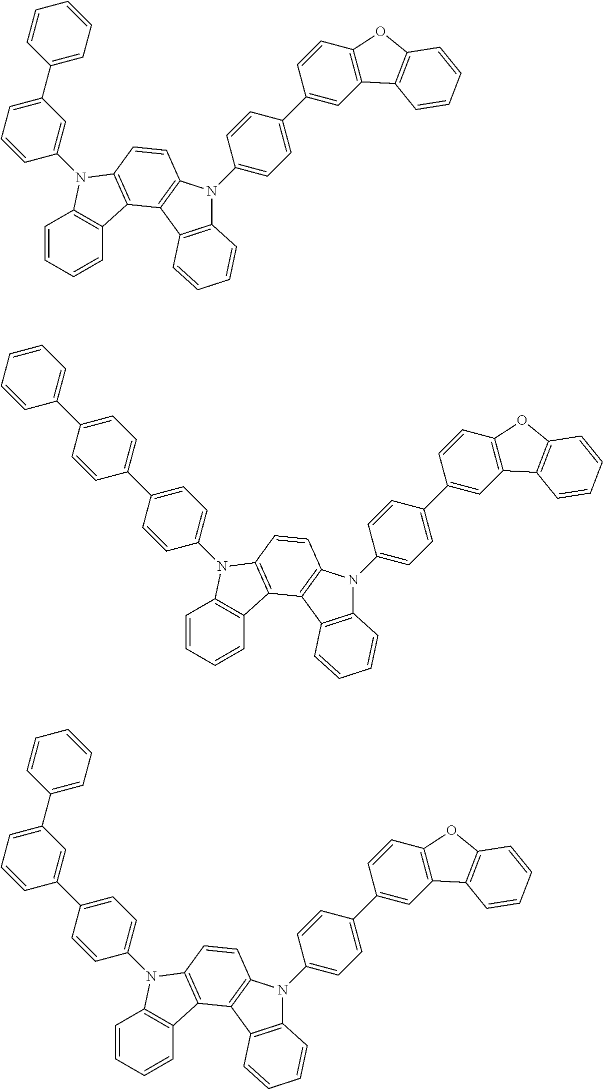 [SMILES: c1ccc(-c2cccc(-n3c4ccccc4c4c5c6ccccc6n(-c6ccc(-c7ccc8oc9ccccc9c8c7)cc6)c5ccc43)c2)cc1 ; c1ccc(-c2ccc(-c3ccc(-n4c5ccccc5c5c6c7ccccc7n(-c7ccc(-c8ccc9oc%10ccccc%10c9c8)cc7)c6ccc54)cc3)cc2)cc1 ; c1ccc(-c2cccc(-c3ccc(-n4c5ccccc5c5c6c7ccccc7n(-c7ccc(-c8ccc9oc%10ccccc%10c9c8)cc7)c6ccc54)cc3)c2)cc1]

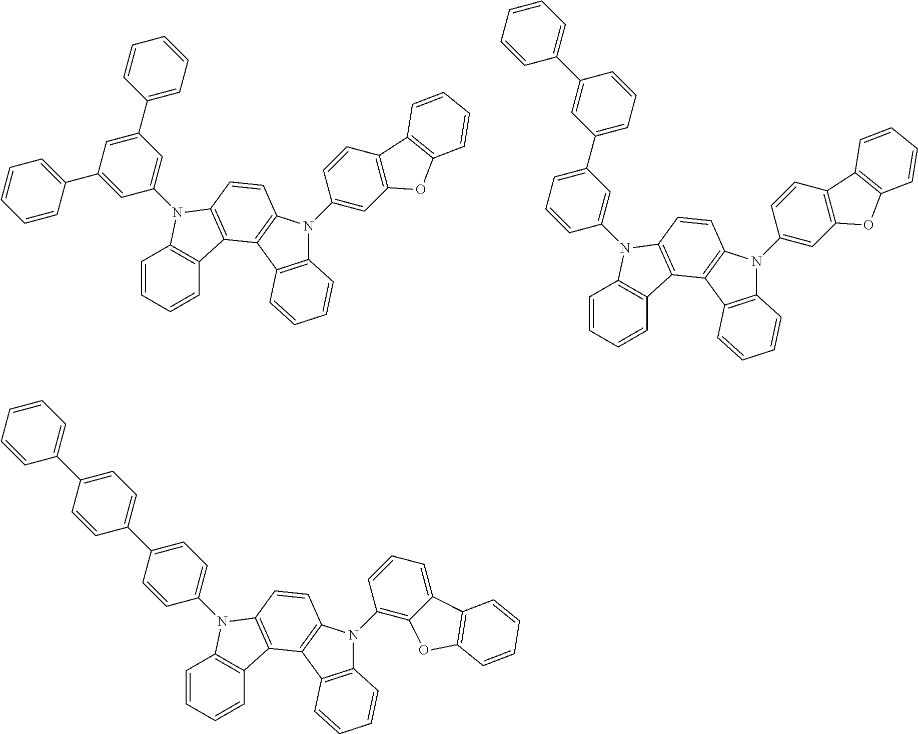 [SMILES: c1ccc(-c2cc(-c3ccccc3)cc(-n3c4ccccc4c4c5c6ccccc6n(-c6ccc7c(c6)oc6ccccc67)c5ccc43)c2)cc1 ; c1ccc(-c2cccc(-c3cccc(-n4c5ccccc5c5c6c7ccccc7n(-c7ccc8c(c7)oc7ccccc78)c6ccc54)c3)c2)cc1 ; c1ccc(-c2ccc(-c3ccc(-n4c5ccccc5c5c6c7ccccc7n(-c7cccc8c7oc7ccccc78)c6ccc54)cc3)cc2)cc1]

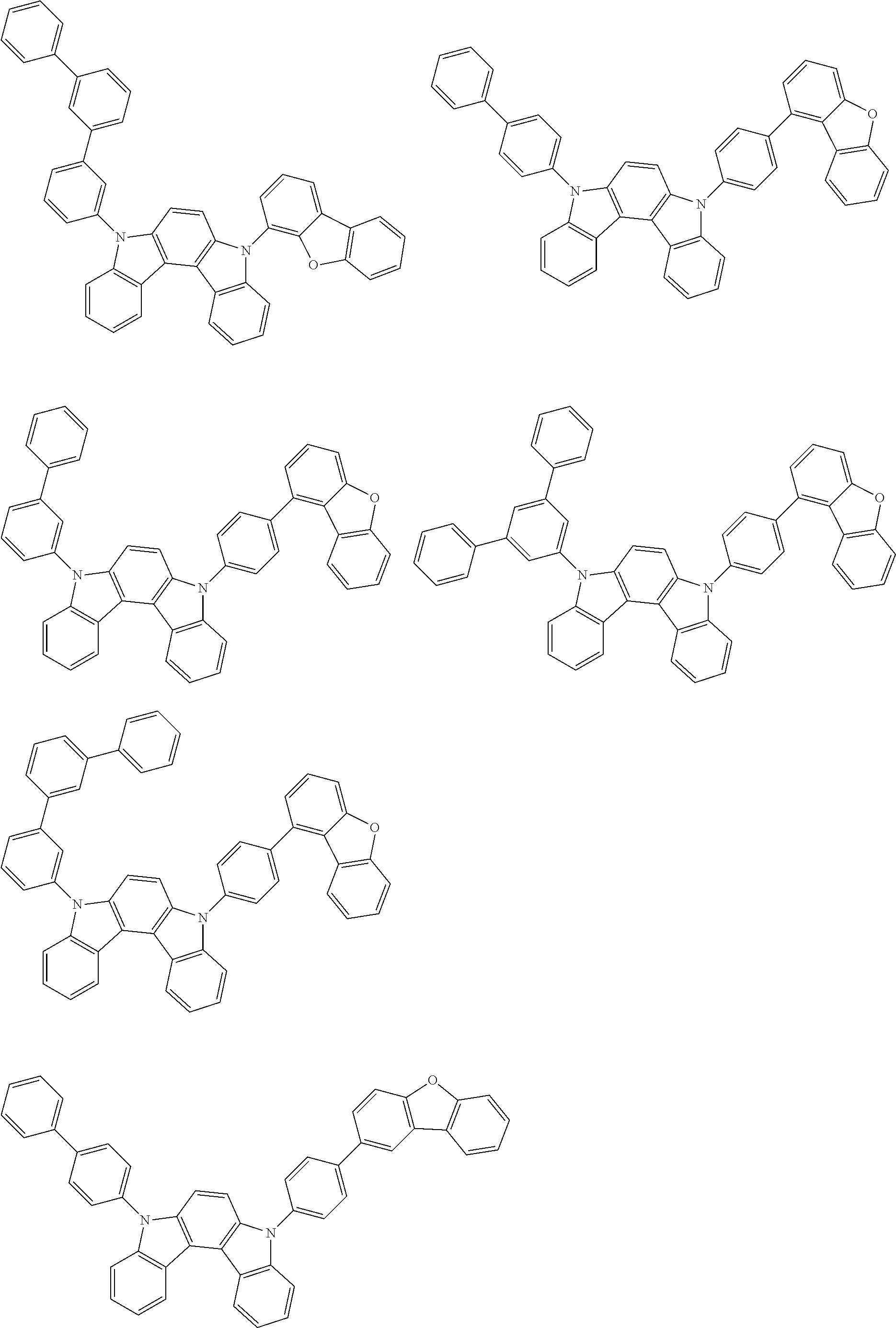

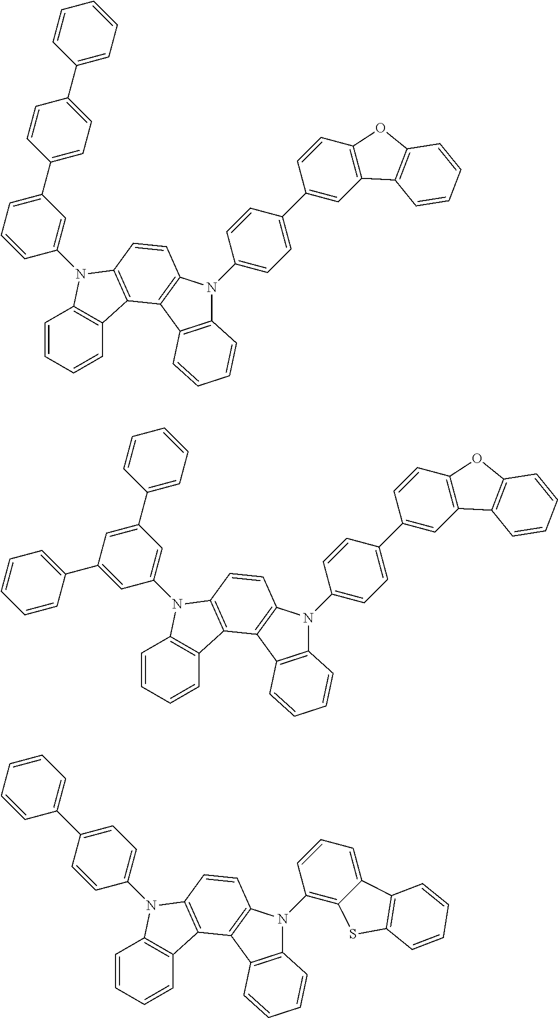 [SMILES: c1ccc(-c2ccc(-c3cccc(-n4c5ccccc5c5c6c7ccccc7n(-c7ccc(-c8ccc9oc%10ccccc%10c9c8)cc7)c6ccc54)c3)cc2)cc1 ; c1ccc(-c2cc(-c3ccccc3)cc(-n3c4ccccc4c4c5c6ccccc6n(-c6ccc(-c7ccc8oc9ccccc9c8c7)cc6)c5ccc43)c2)cc1 ; c1ccc(-c2ccc(-n3c4ccccc4c4c5c6ccccc6n(-c6cccc7c6sc6ccccc67)c5ccc43)cc2)cc1]

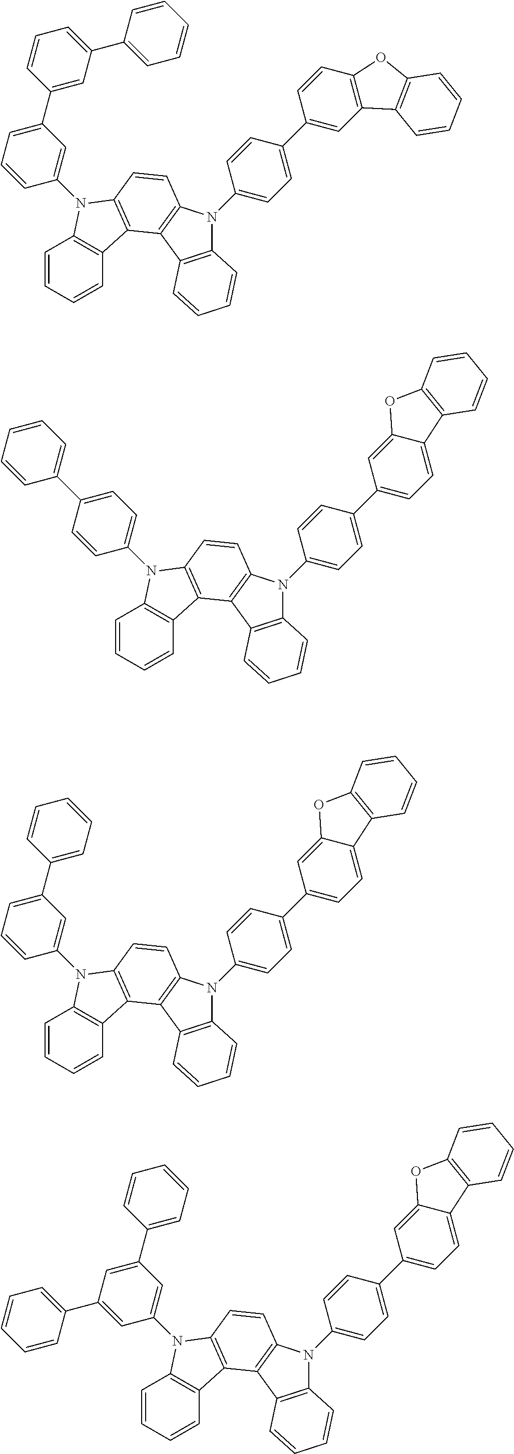 [SMILES: c1ccc(-c2cccc(-c3cccc(-n4c5ccccc5c5c6c7ccccc7n(-c7ccc(-c8ccc9oc%10ccccc%10c9c8)cc7)c6ccc54)c3)c2)cc1 ; c1ccc(-c2ccc(-n3c4ccccc4c4c5c6ccccc6n(-c6ccc(-c7ccc8c(c7)oc7ccccc78)cc6)c5ccc43)cc2)cc1 ; c1ccc(-c2cccc(-n3c4ccccc4c4c5c6ccccc6n(-c6ccc(-c7ccc8c(c7)oc7ccccc78)cc6)c5ccc43)c2)cc1 ; c1ccc(-c2cc(-c3ccccc3)cc(-n3c4ccccc4c4c5c6ccccc6n(-c6ccc(-c7ccc8c(c7)oc7ccccc78)cc6)c5ccc43)c2)cc1]

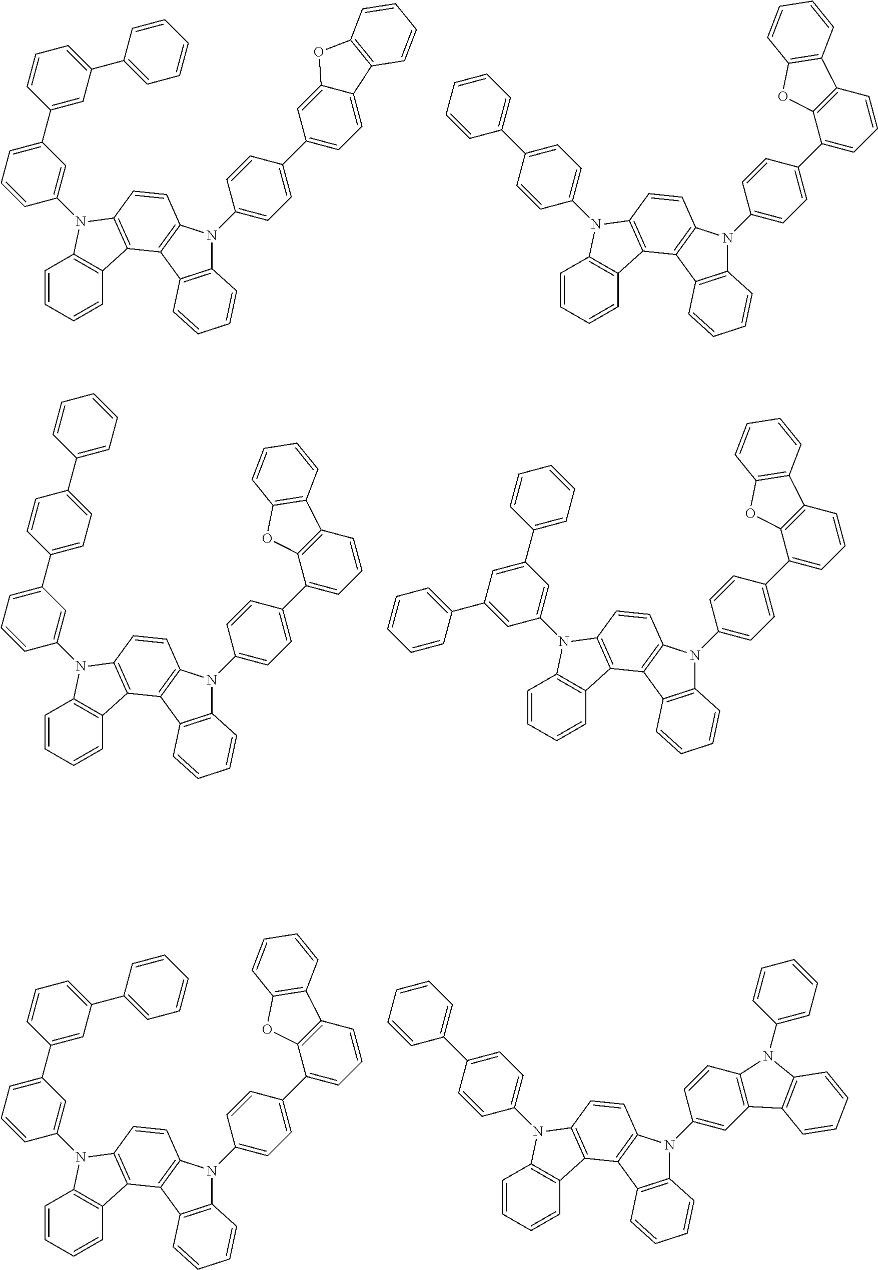

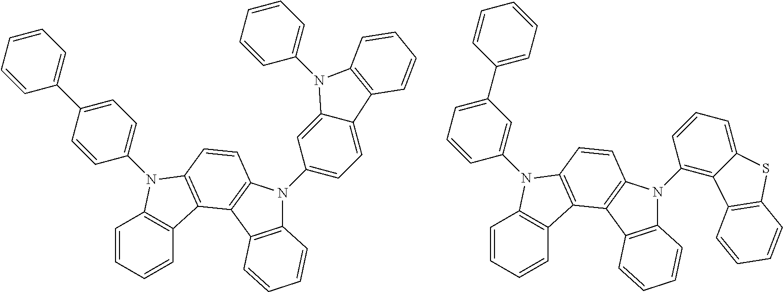 [SMILES: c1ccc(-c2ccc(-n3c4ccccc4c4c5c6ccccc6n(-c6ccc7c8ccccc8n(-c8ccccc8)c7c6)c5ccc43)cc2)cc1 ; c1ccc(-c2cccc(-n3c4ccccc4c4c5c6ccccc6n(-c6cccc7sc8ccccc8c67)c5ccc43)c2)cc1]

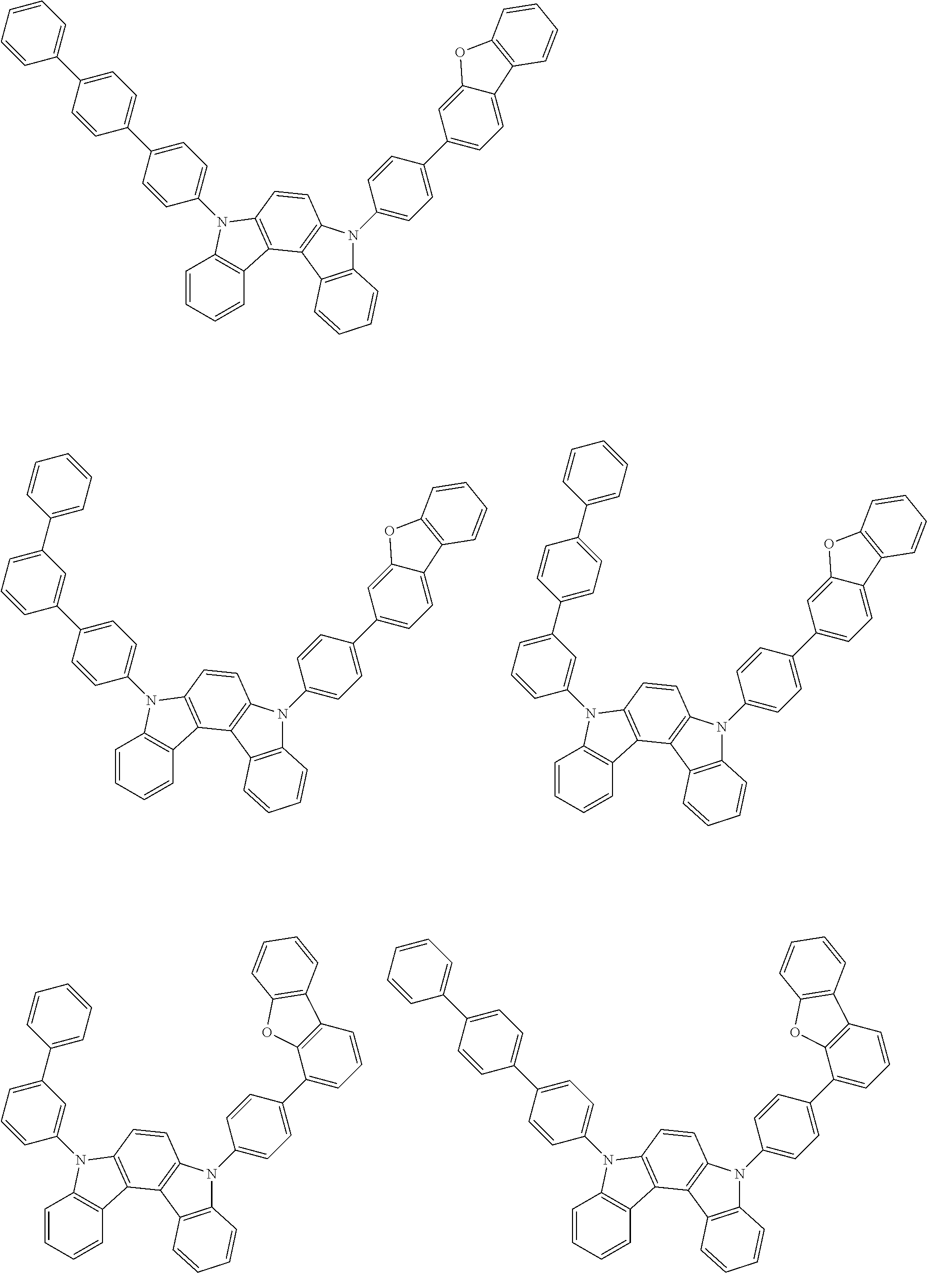 [SMILES: c1ccc(-c2ccc(-c3ccc(-n4c5ccccc5c5c6c7ccccc7n(-c7ccc(-c8ccc9c(c8)oc8ccccc89)cc7)c6ccc54)cc3)cc2)cc1 ; c1ccc(-c2cccc(-c3ccc(-n4c5ccccc5c5c6c7ccccc7n(-c7ccc(-c8ccc9c(c8)oc8ccccc89)cc7)c6ccc54)cc3)c2)cc1 ; c1ccc(-c2ccc(-c3cccc(-n4c5ccccc5c5c6c7ccccc7n(-c7ccc(-c8ccc9c(c8)oc8ccccc89)cc7)c6ccc54)c3)cc2)cc1 ; c1ccc(-c2cccc(-n3c4ccccc4c4c5c6ccccc6n(-c6ccc(-c7cccc8c7oc7ccccc78)cc6)c5ccc43)c2)cc1 ; c1ccc(-c2ccc(-c3ccc(-n4c5ccccc5c5c6c7ccccc7n(-c7ccc(-c8cccc9c8oc8ccccc89)cc7)c6ccc54)cc3)cc2)cc1]

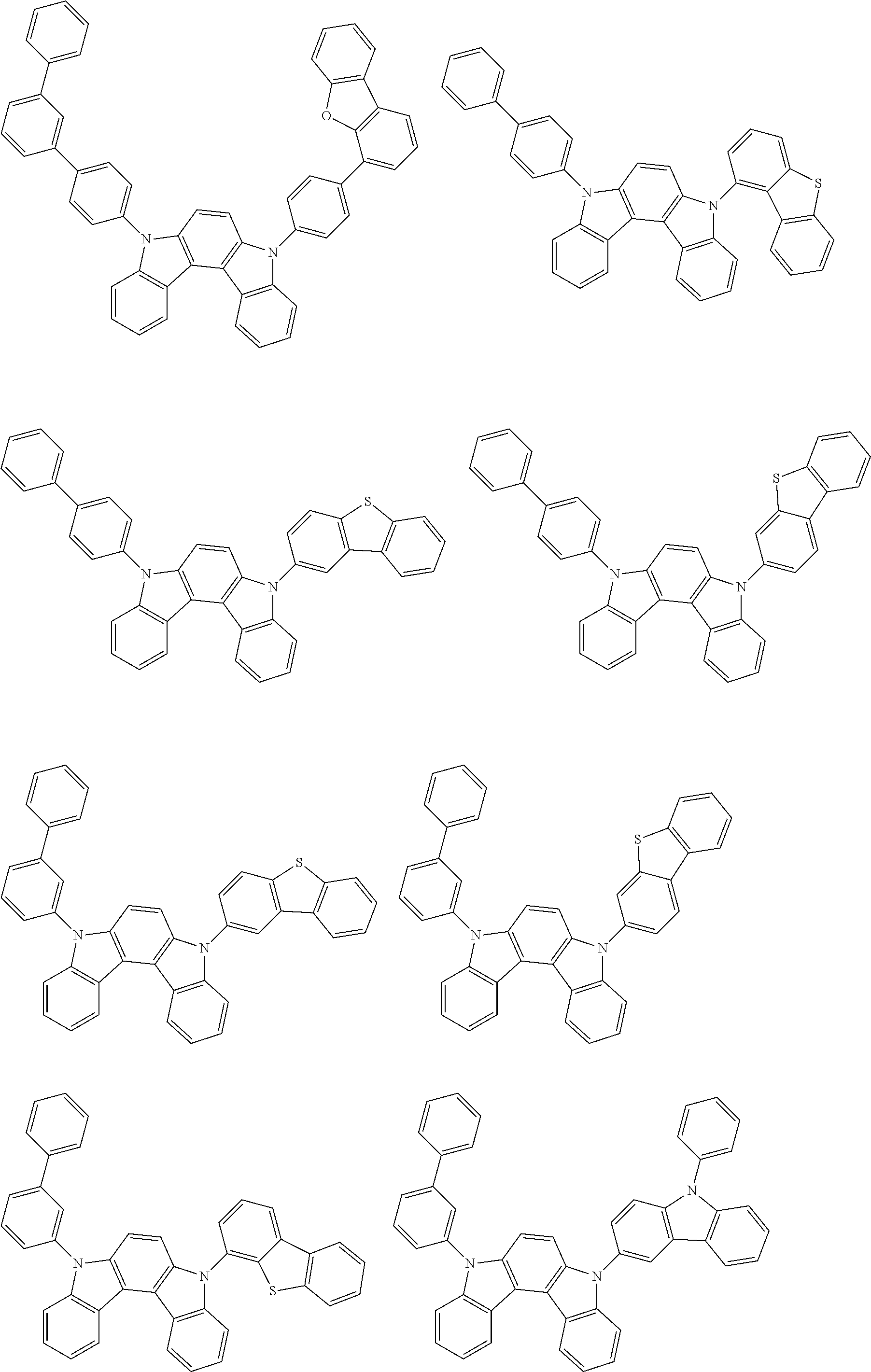

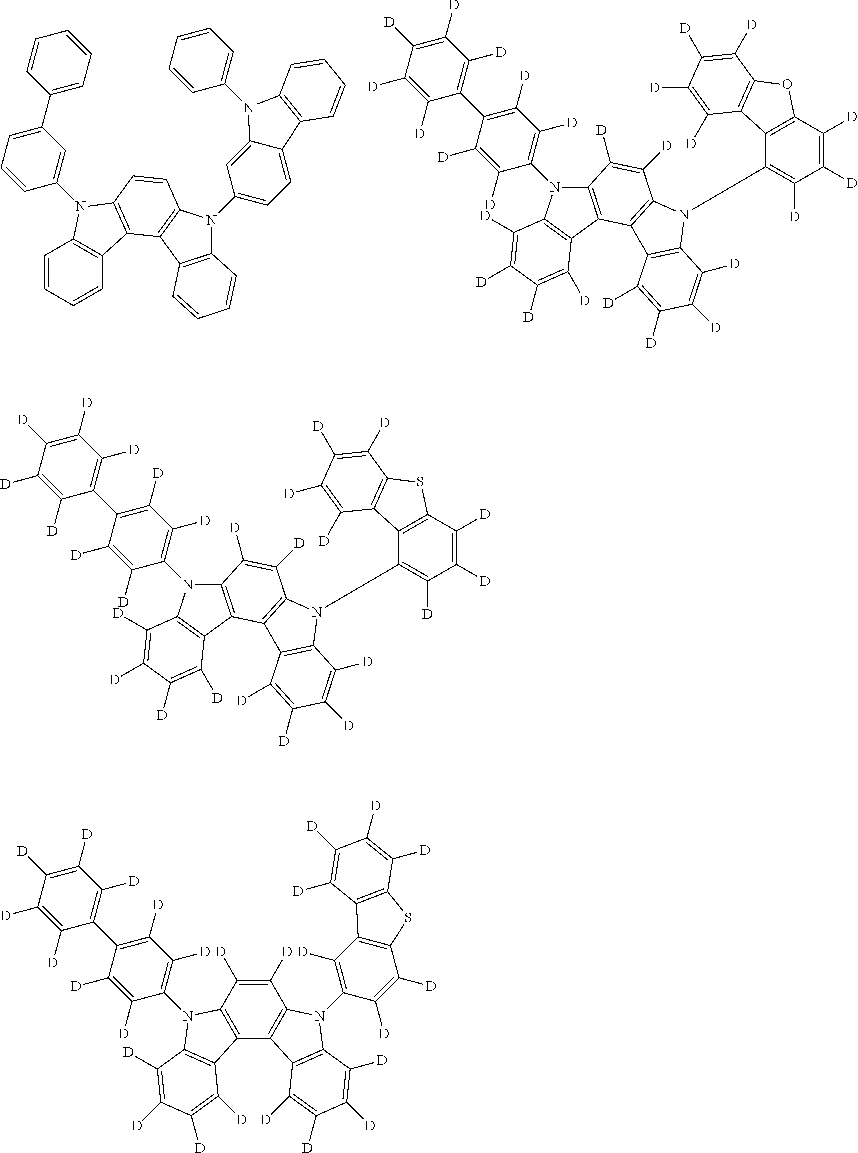

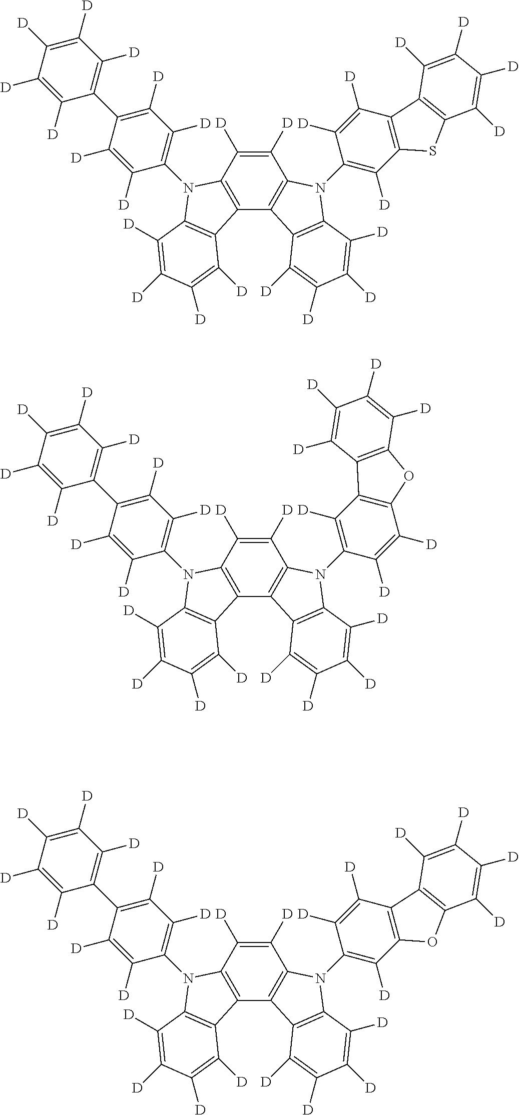

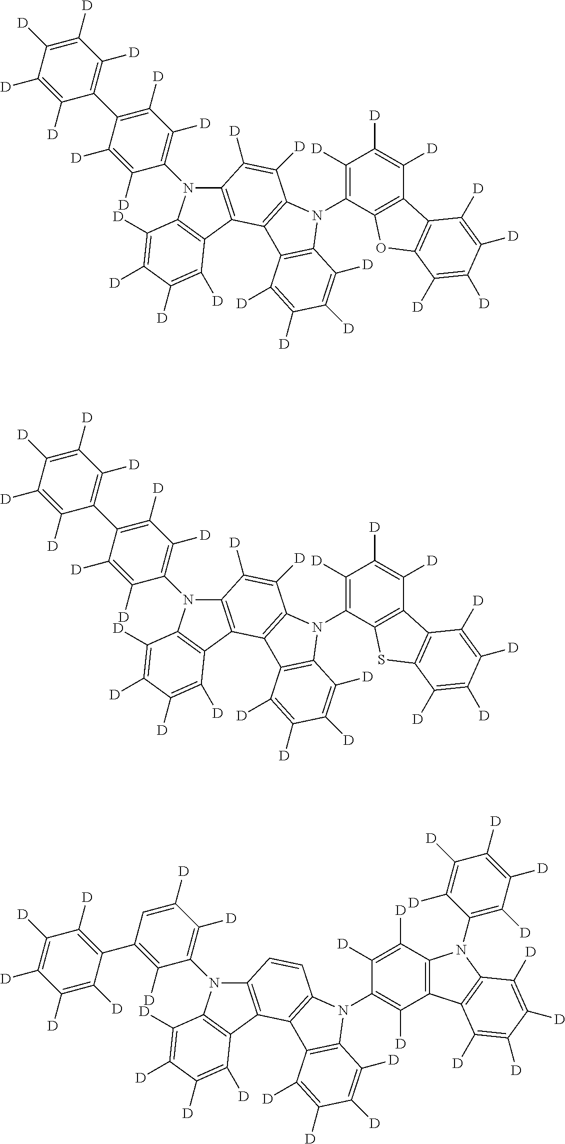

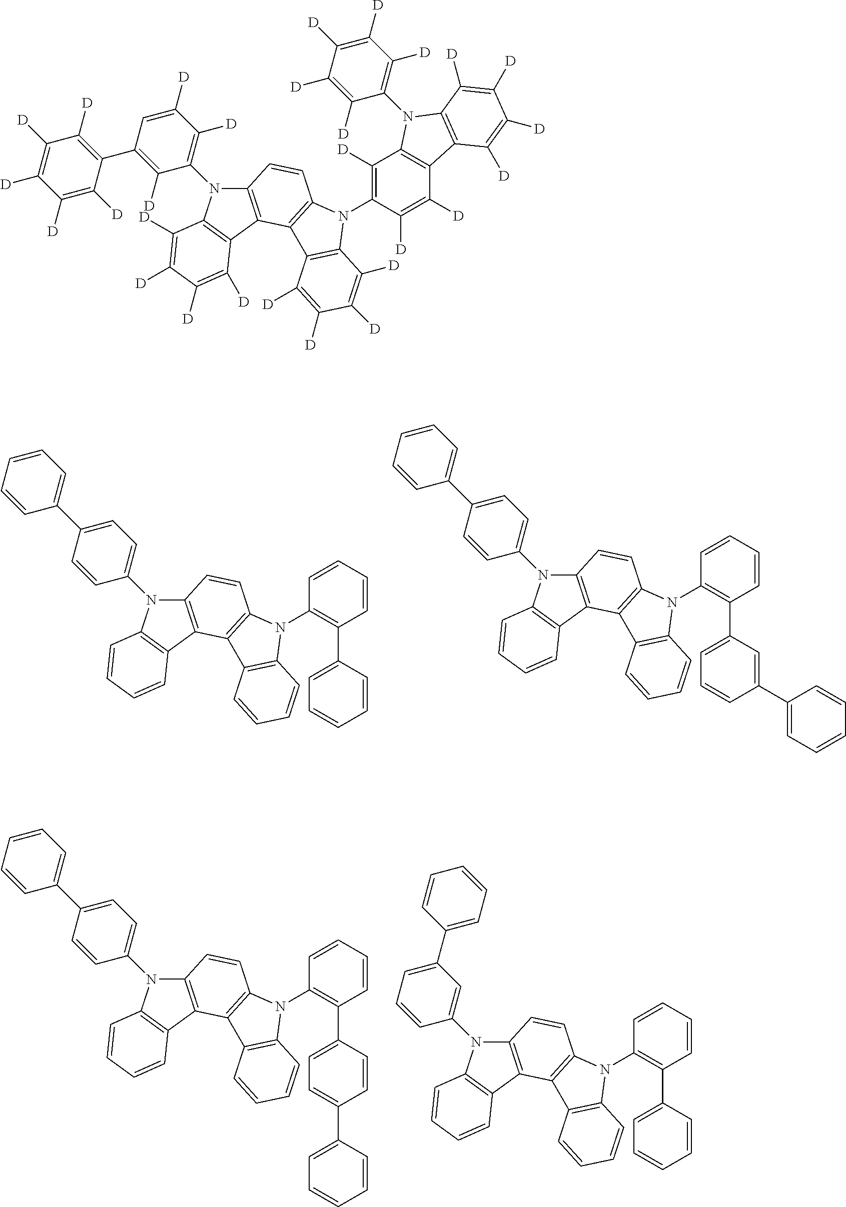

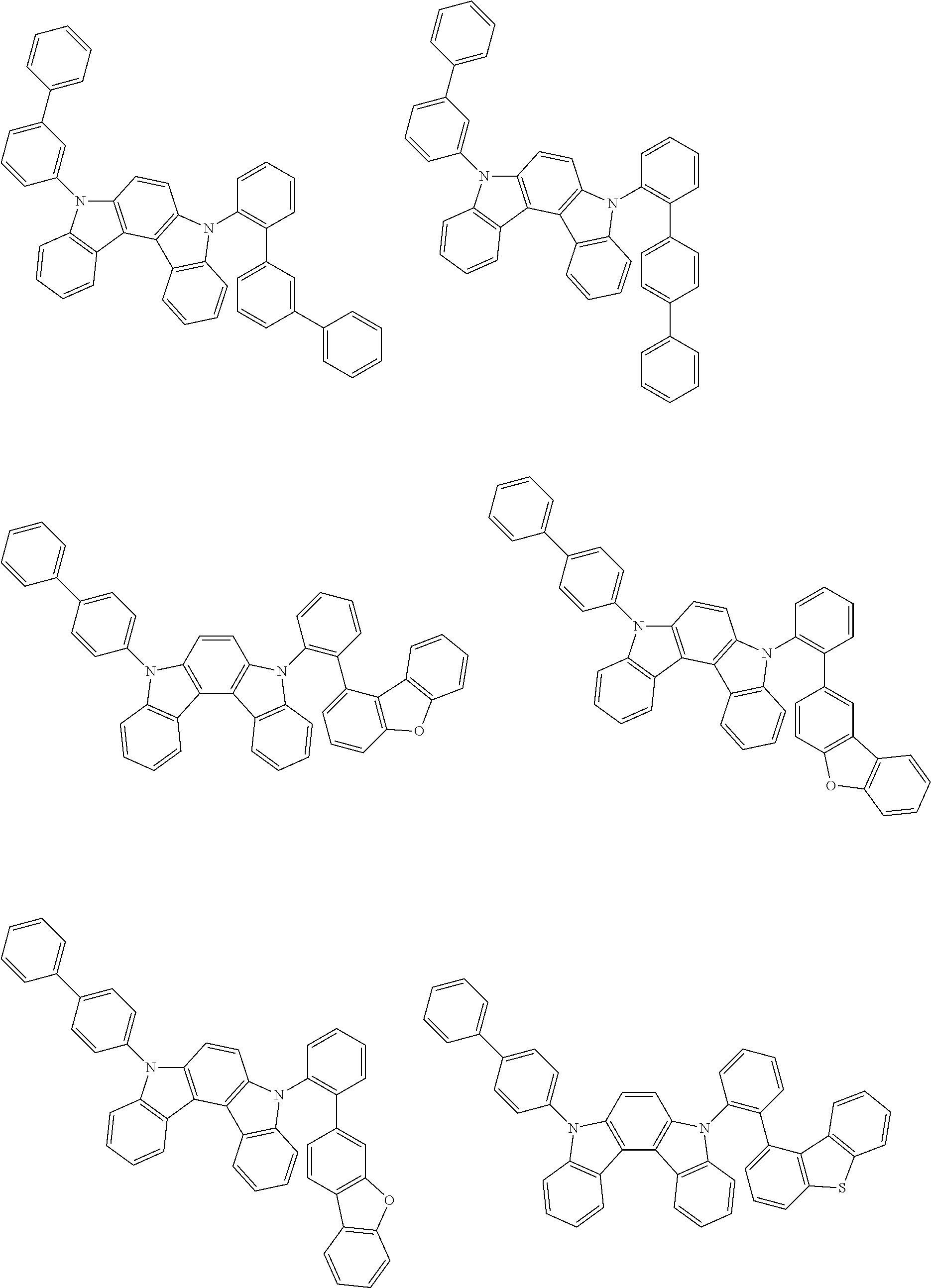

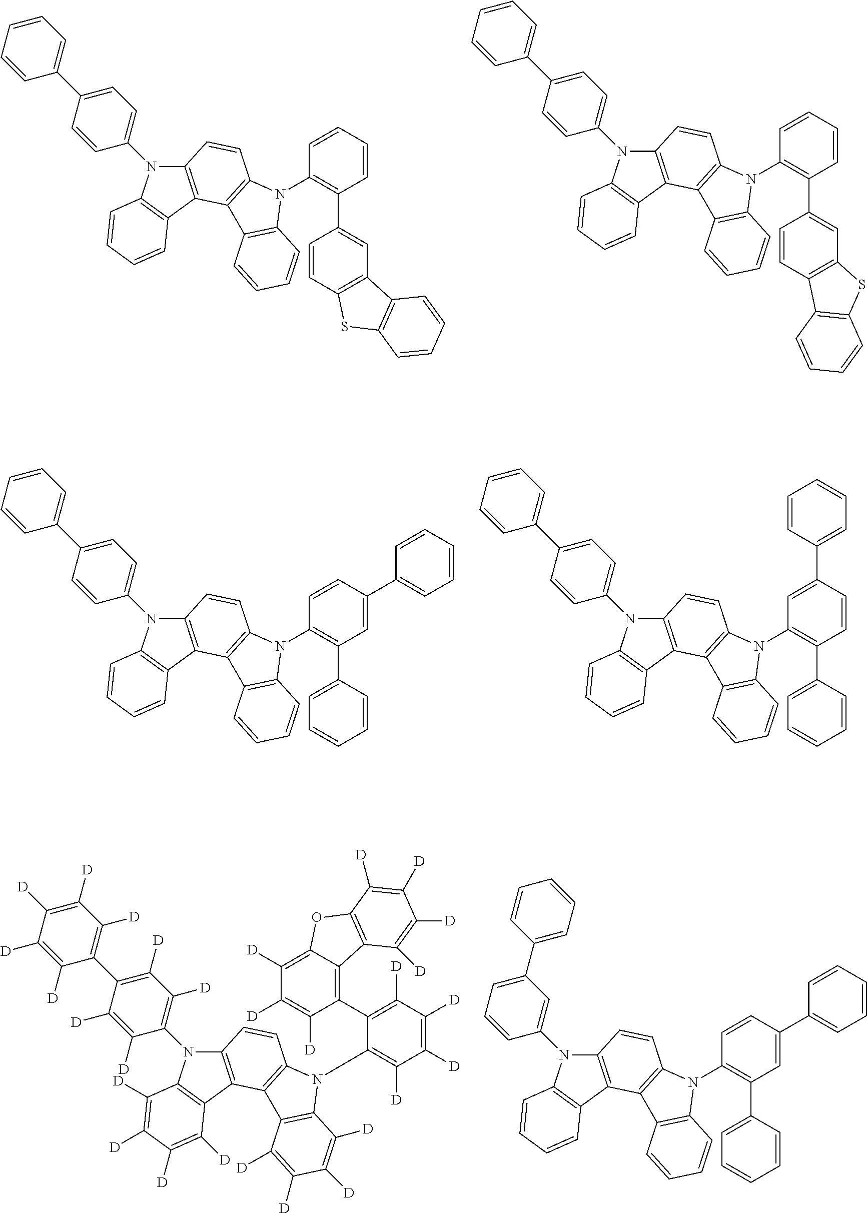

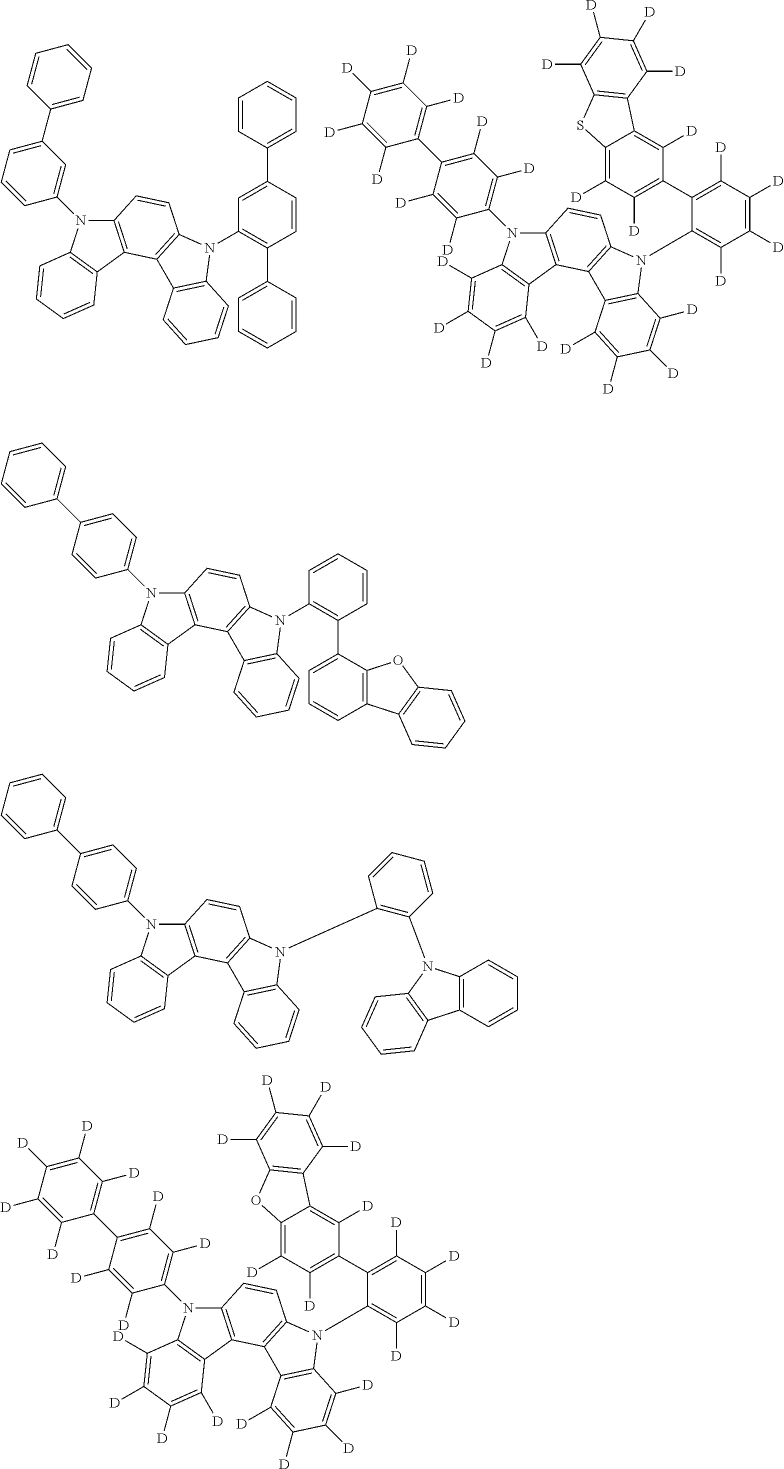

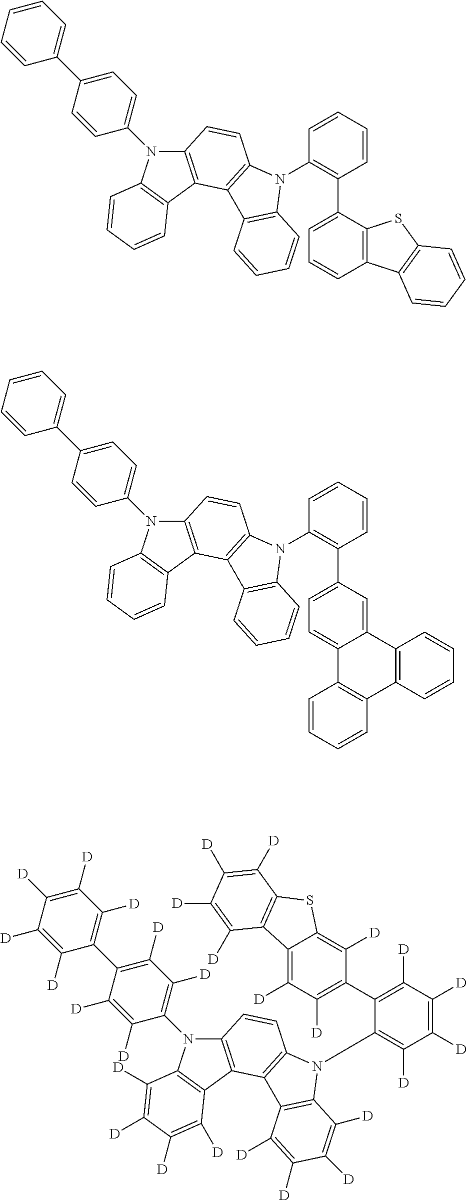 [SMILES: c1ccc(-c2ccc(-n3c4ccccc4c4c5c6ccccc6n(-c6ccccc6-c6cccc7c6sc6ccccc67)c5ccc43)cc2)cc1 ; c1ccc(-c2ccc(-n3c4ccccc4c4c5c6ccccc6n(-c6ccccc6-c6ccc7c8ccccc8c8ccccc8c7c6)c5ccc43)cc2)cc1 ; [2H]c1c([2H])c([2H])c(-c2c([2H])c([2H])c(-n3c4ccc5c(c6c([2H])c([2H])c([2H])c([2H])c6n5-c5c([2H])c([2H])c([2H])c([2H])c5-c5c([2H])c([2H])c6c(sc7c([2H])c([2H])c([2H])c([2H])c76)c5[2H])c4c4c([2H])c([2H])c([2H])c([2H])c43)c([2H])c2[2H])c([2H])c1[2H]]

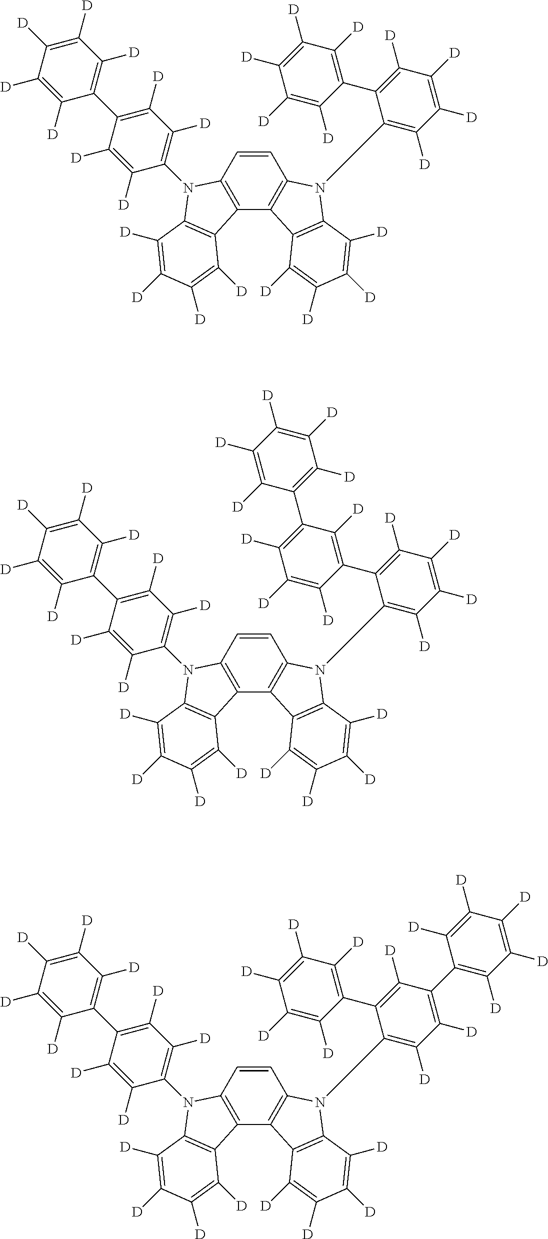

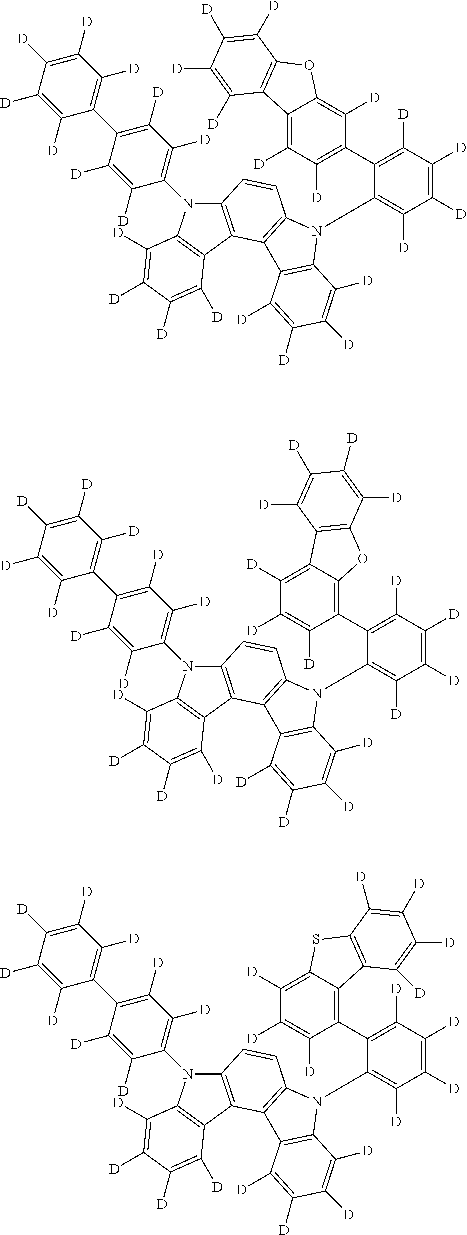

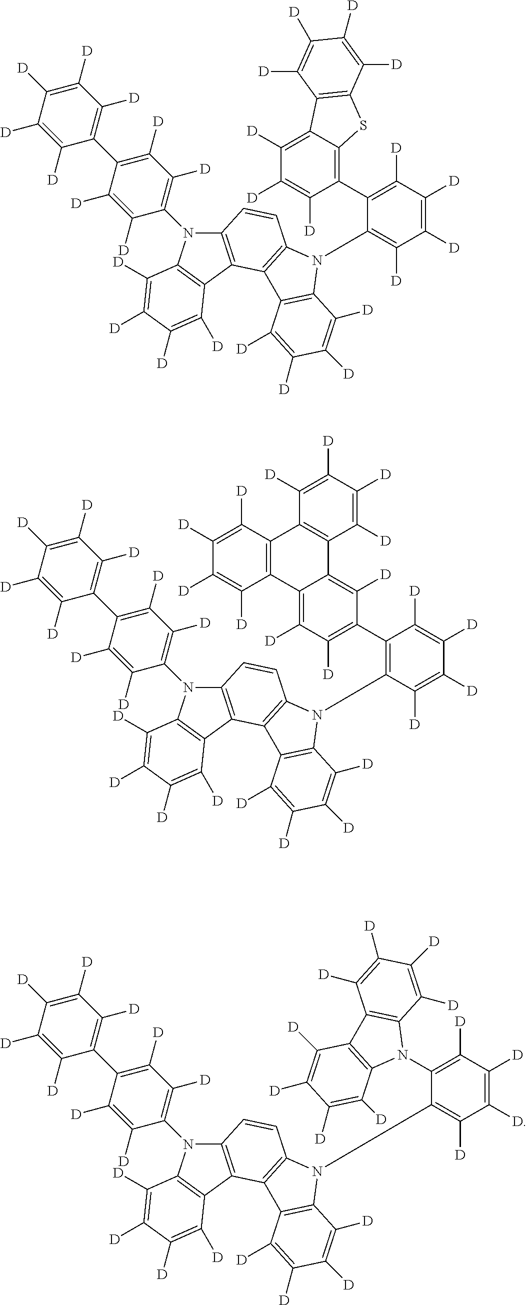

7. The composition for an organic light emitting device according to claim 1, wherein:
one of Ar₃ and Ar₄ is phenyl, and the other is phenyl or biphenyl, and
the Ar₃ and Ar₄ are each independently unsubstituted or substituted with one or more deuterium atoms.

8. The composition for an organic light emitting device according to claim 1, wherein:
Rₐ and R_{d} are each independently hydrogen, deuterium, phenyl, biphenyl, terphenyl, naphthyl, anthracenyl, phenanthrenyl, or triphenylenyl, and
the phenyl, biphenyl, terphenyl, naphthyl, anthracenyl, phenanthrenyl, and triphenylenyl are each independently unsubstituted, or substituted with one or more deuterium atoms.

9. The composition for an organic light emitting device according to claim 1, wherein:
R_{C} is hydrogen, deuterium, phenyl, biphenyl, terphenyl, naphthyl, anthracenyl, phenanthrenyl, or triphenylenyl, and
the phenyl, biphenyl, terphenyl, naphthyl, anthracenyl, phenanthrenyl, and triphenylenyl are each independently unsubstituted, or substituted with one or more deuterium atoms.

10. The composition for an organic light emitting device according to claim 1, wherein:
R₂₁ to R₂₈ are each independently hydrogen, deuterium, unsubstituted phenyl, or phenyl substituted with 1 to 5 deuterium atoms, provided that at least one of R₂₁ to R₂₈ is deuterium, or phenyl substituted with 1 to 5 deuterium atoms.

11. The composition for an organic light emitting device according to claim 1, wherein:
the second compound is any one selected from the group consisting of the following compounds:

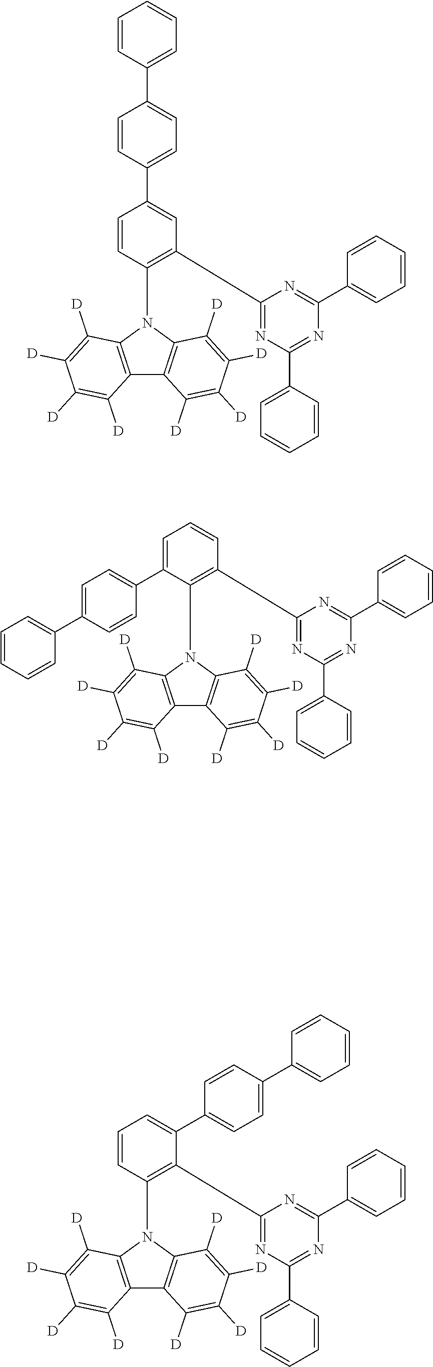 [SMILES: [2H]c1c([2H])c([2H])c2c(c1[2H])c1c([2H])c([2H])c([2H])c([2H])c1n2-c1ccc(-c2ccc(-c3ccccc3)cc2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2ccc(-c3ccccc3)cc2)cccc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cccc(-c2ccc(-c3ccccc3)cc2)c1-c1nc(-c2ccccc2)nc(-c2ccccc2)n1]

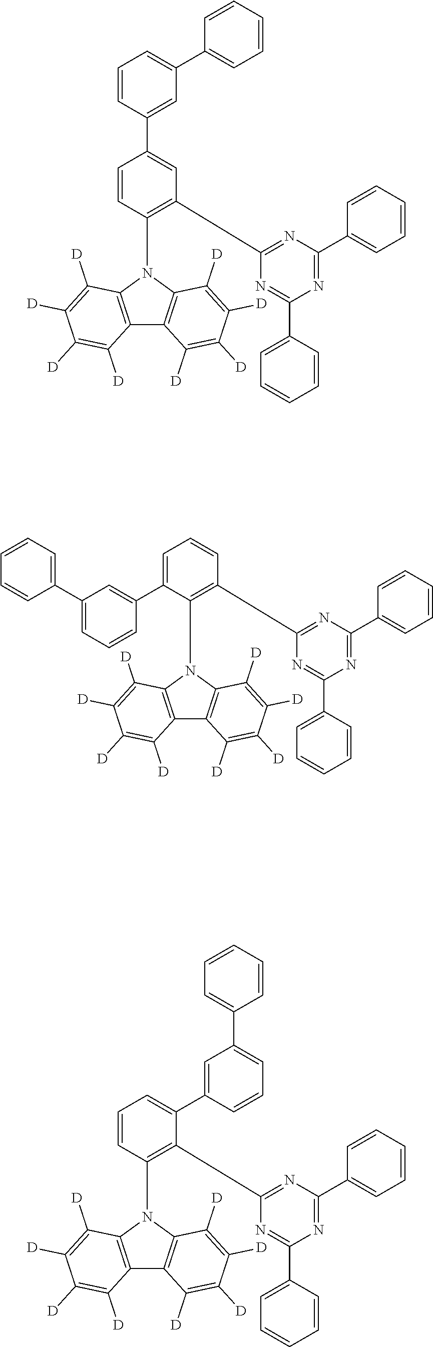 [SMILES: [2H]c1c([2H])c([2H])c2c(c1[2H])c1c([2H])c([2H])c([2H])c([2H])c1n2-c1ccc(-c2cccc(-c3ccccc3)c2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2cccc(-c3ccccc3)c2)cccc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cccc(-c2cccc(-c3ccccc3)c2)c1-c1nc(-c2ccccc2)nc(-c2ccccc2)n1]

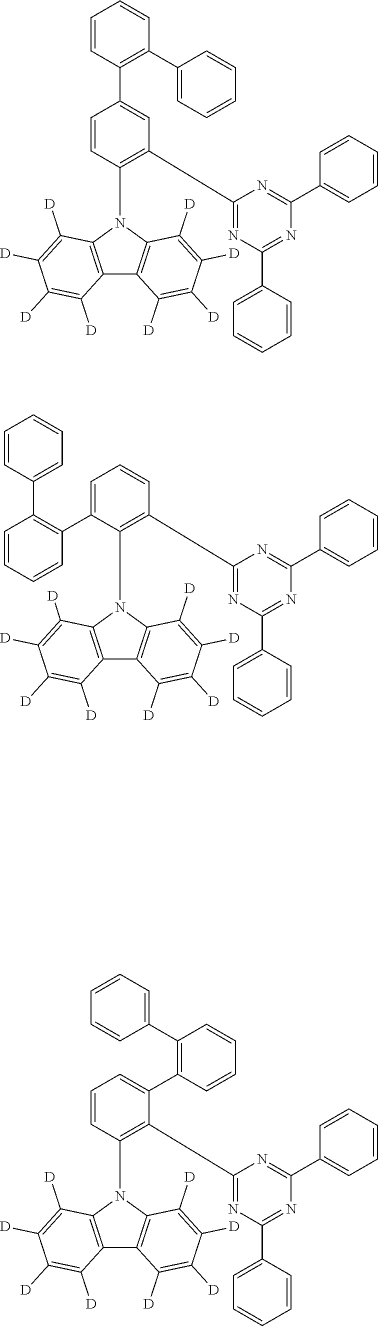 [SMILES: [2H]c1c([2H])c([2H])c2c(c1[2H])c1c([2H])c([2H])c([2H])c([2H])c1n2-c1ccc(-c2ccccc2-c2ccccc2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2nc(-c3ccccc3)nc(-c3ccccc3)n2)cccc1-c1ccccc1-c1ccccc1 ; [2H]c1c([2H])c([2H])c2c(c1[2H])c1c([2H])c([2H])c([2H])c([2H])c1n2-c1cccc(-c2ccccc2-c2ccccc2)c1-c1nc(-c2ccccc2)nc(-c2ccccc2)n1]

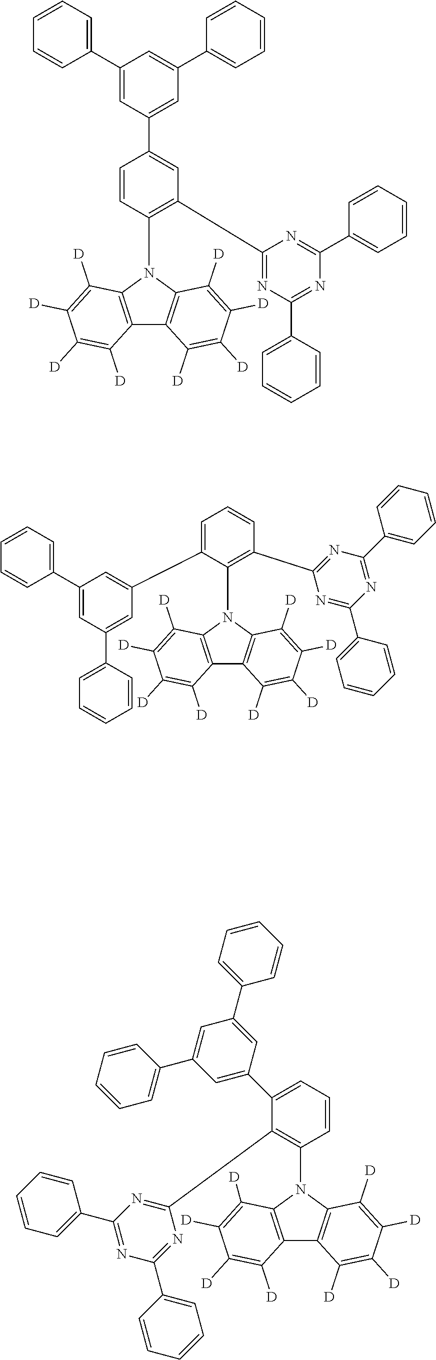 [SMILES: [2H]c1c([2H])c([2H])c2c(c1[2H])c1c([2H])c([2H])c([2H])c([2H])c1n2-c1ccc(-c2cc(-c3ccccc3)cc(-c3ccccc3)c2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2cc(-c3ccccc3)cc(-c3ccccc3)c2)cccc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cccc(-c2cc(-c3ccccc3)cc(-c3ccccc3)c2)c1-c1nc(-c2ccccc2)nc(-c2ccccc2)n1]

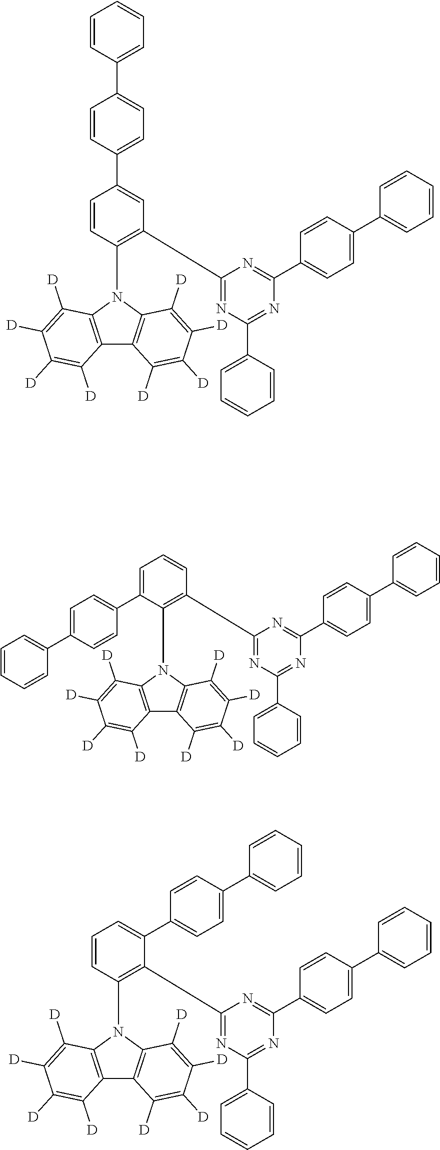 [SMILES: [2H]c1c([2H])c([2H])c2c(c1[2H])c1c([2H])c([2H])c([2H])c([2H])c1n2-c1ccc(-c2ccc(-c3ccccc3)cc2)cc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1c(-c2ccc(-c3ccccc3)cc2)cccc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1cccc(-c2ccc(-c3ccccc3)cc2)c1-c1nc(-c2ccccc2)nc(-c2ccc(-c3ccccc3)cc2)n1]

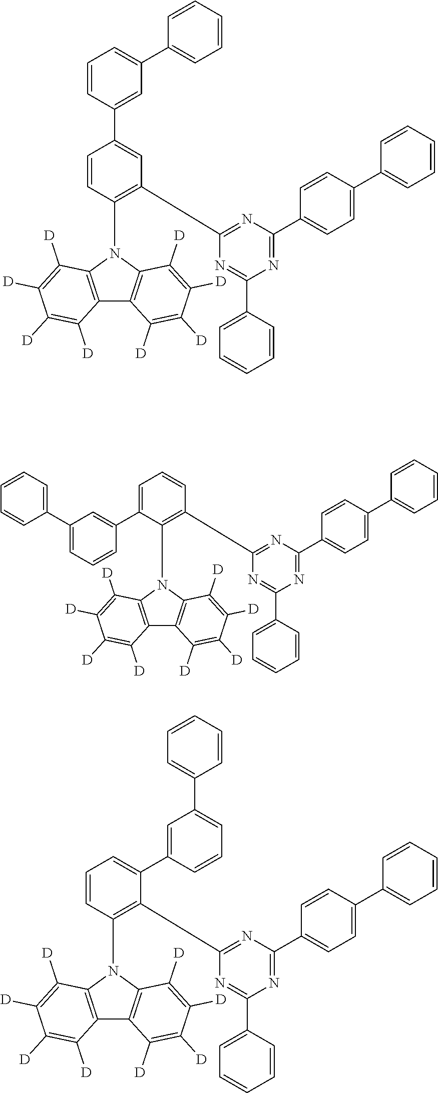 [SMILES: [2H]c1c([2H])c([2H])c2c(c1[2H])c1c([2H])c([2H])c([2H])c([2H])c1n2-c1ccc(-c2cccc(-c3ccccc3)c2)cc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1c(-c2cccc(-c3ccccc3)c2)cccc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1cccc(-c2cccc(-c3ccccc3)c2)c1-c1nc(-c2ccccc2)nc(-c2ccc(-c3ccccc3)cc2)n1]

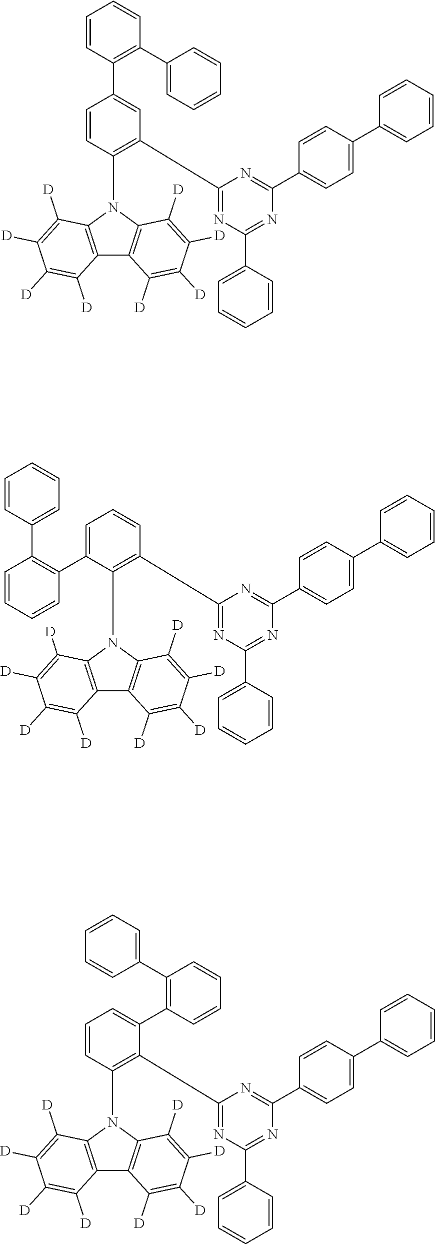 [SMILES: [2H]c1c([2H])c([2H])c2c(c1[2H])c1c([2H])c([2H])c([2H])c([2H])c1n2-c1ccc(-c2ccccc2-c2ccccc2)cc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1c(-c2nc(-c3ccccc3)nc(-c3ccc(-c4ccccc4)cc3)n2)cccc1-c1ccccc1-c1ccccc1 ; [2H]c1c([2H])c([2H])c2c(c1[2H])c1c([2H])c([2H])c([2H])c([2H])c1n2-c1cccc(-c2ccccc2-c2ccccc2)c1-c1nc(-c2ccccc2)nc(-c2ccc(-c3ccccc3)cc2)n1]

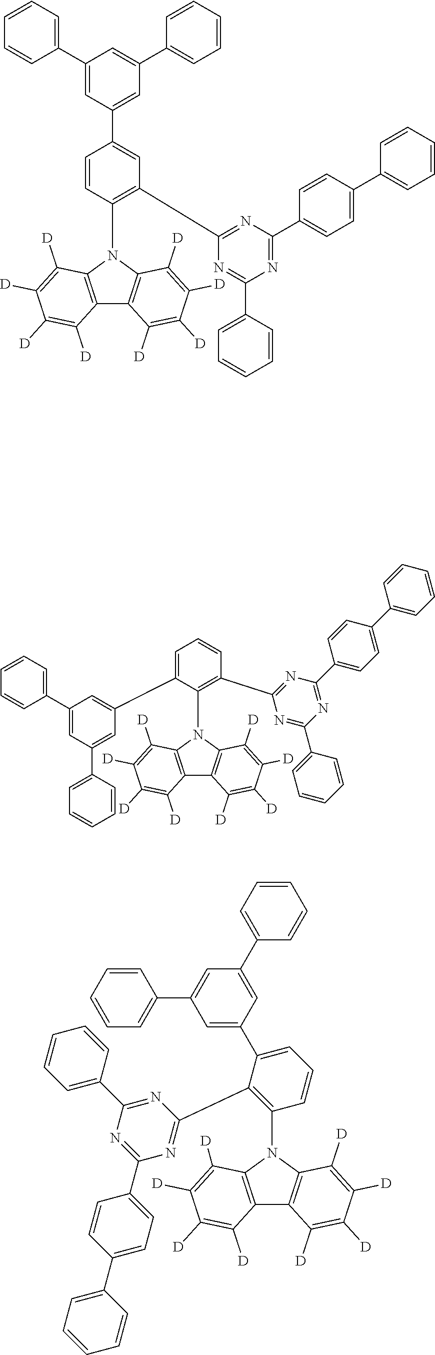 [SMILES: [2H]c1c([2H])c([2H])c2c(c1[2H])c1c([2H])c([2H])c([2H])c([2H])c1n2-c1ccc(-c2cc(-c3ccccc3)cc(-c3ccccc3)c2)cc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1c(-c2cc(-c3ccccc3)cc(-c3ccccc3)c2)cccc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1cccc(-c2cc(-c3ccccc3)cc(-c3ccccc3)c2)c1-c1nc(-c2ccccc2)nc(-c2ccc(-c3ccccc3)cc2)n1]

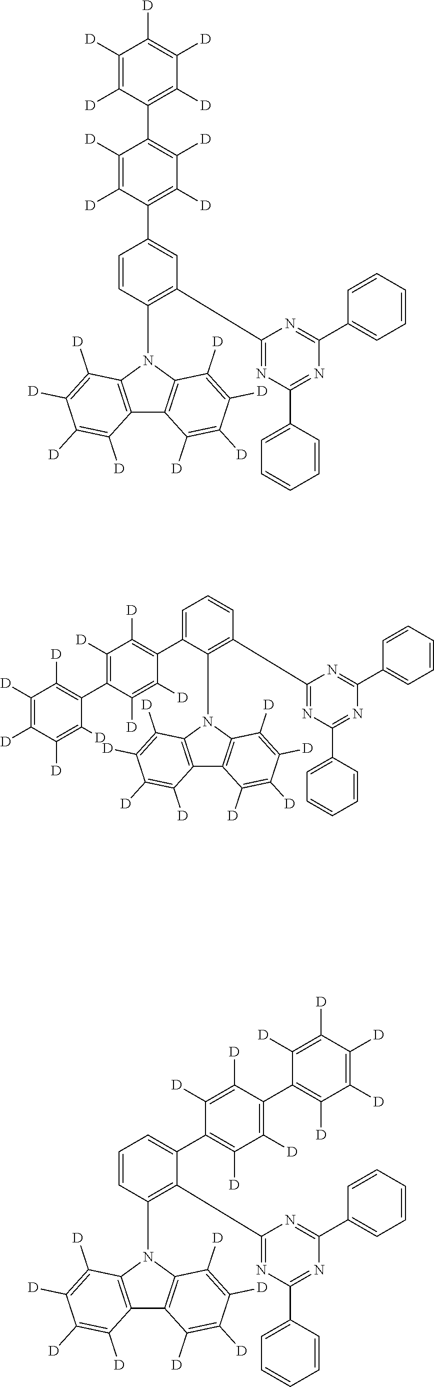

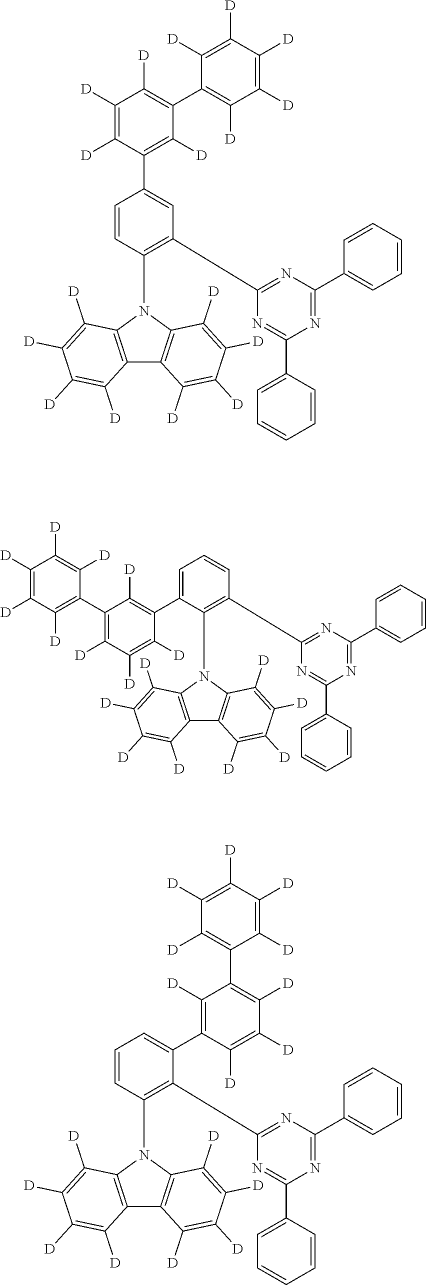

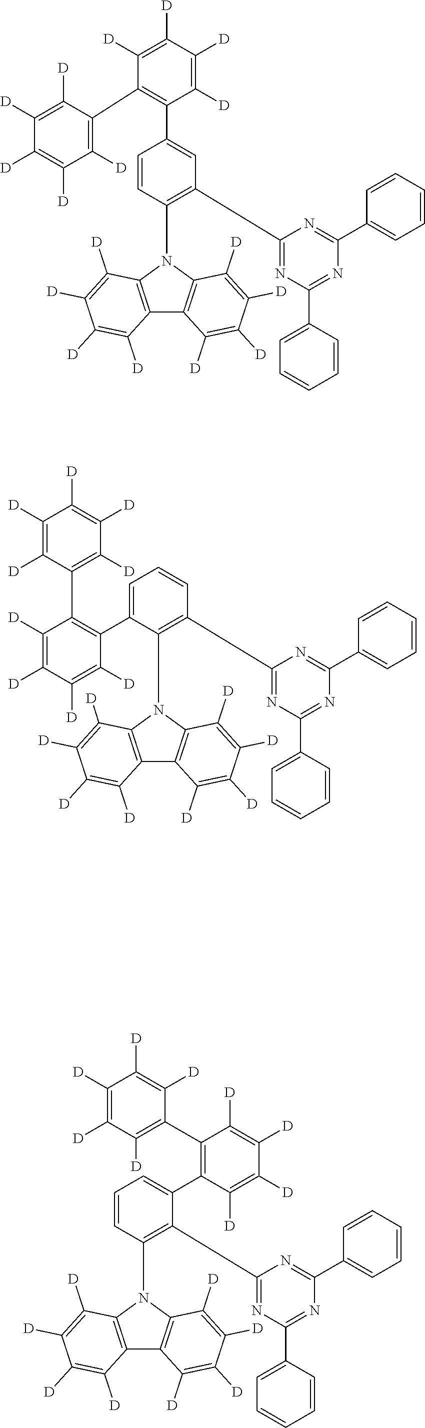

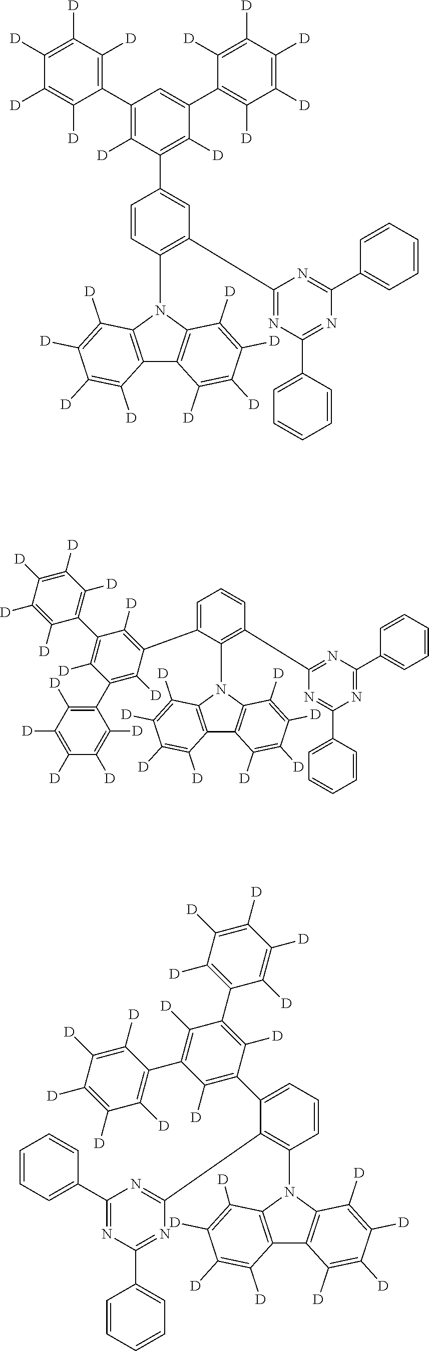

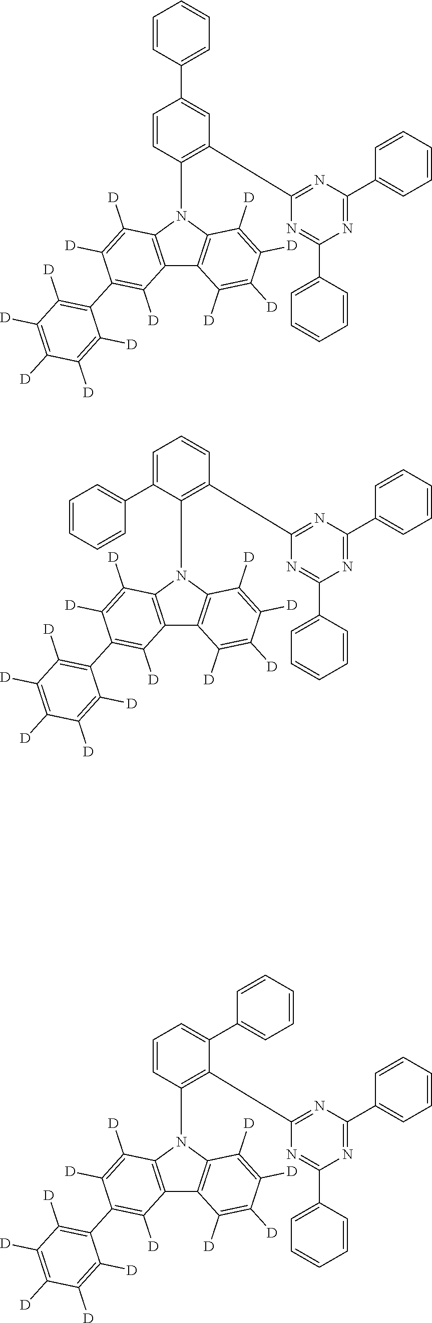 [SMILES: [2H]c1c([2H])c([2H])c(-c2c([2H])c([2H])c3c(c2[2H])c2c([2H])c([2H])c([2H])c([2H])c2n3-c2ccc(-c3ccccc3)cc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2cccc(-c3ccccc3)c2-c2nc(-c3ccccc3)nc(-c3ccccc3)n2)c([2H])c1[2H]]

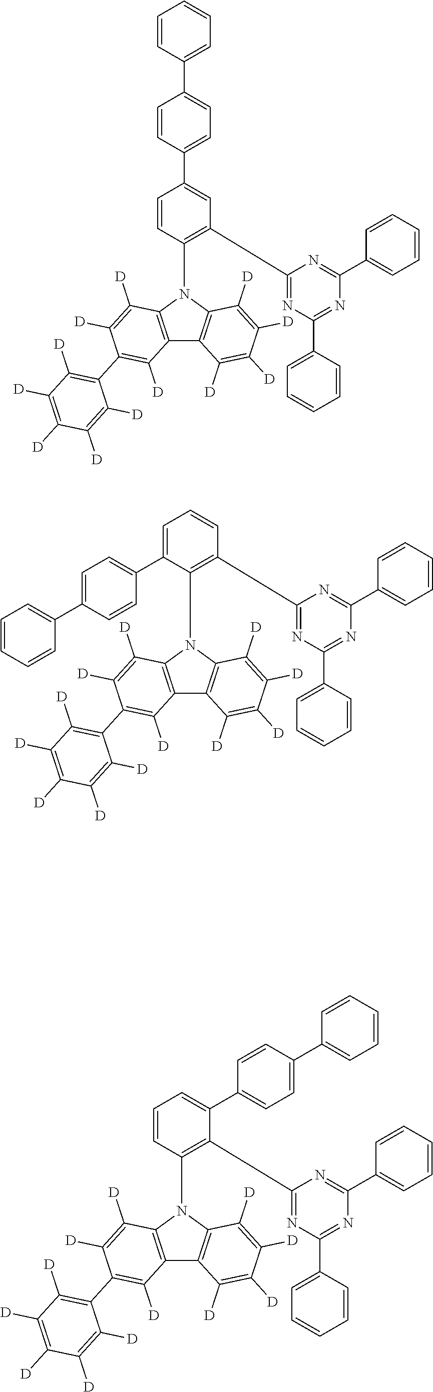 [SMILES: [2H]c1c([2H])c([2H])c(-c2c([2H])c([2H])c3c(c2[2H])c2c([2H])c([2H])c([2H])c([2H])c2n3-c2ccc(-c3ccc(-c4ccccc4)cc3)cc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccc(-c4ccccc4)cc3)cccc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2cccc(-c3ccc(-c4ccccc4)cc3)c2-c2nc(-c3ccccc3)nc(-c3ccccc3)n2)c([2H])c1[2H]]

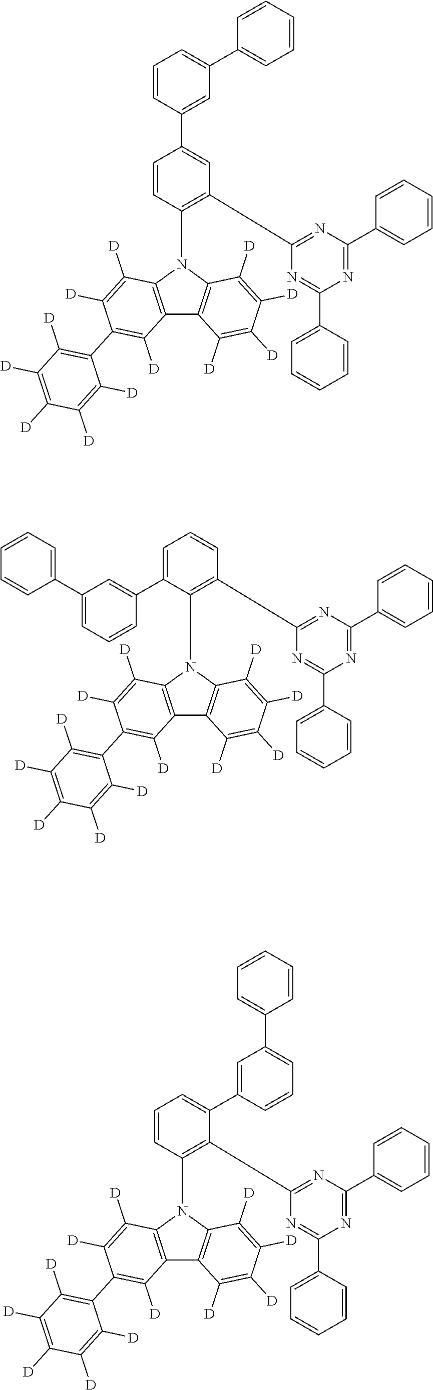 [SMILES: [2H]c1c([2H])c([2H])c(-c2c([2H])c([2H])c3c(c2[2H])c2c([2H])c([2H])c([2H])c([2H])c2n3-c2ccc(-c3cccc(-c4ccccc4)c3)cc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2c(-c3cccc(-c4ccccc4)c3)cccc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2cccc(-c3cccc(-c4ccccc4)c3)c2-c2nc(-c3ccccc3)nc(-c3ccccc3)n2)c([2H])c1[2H]]

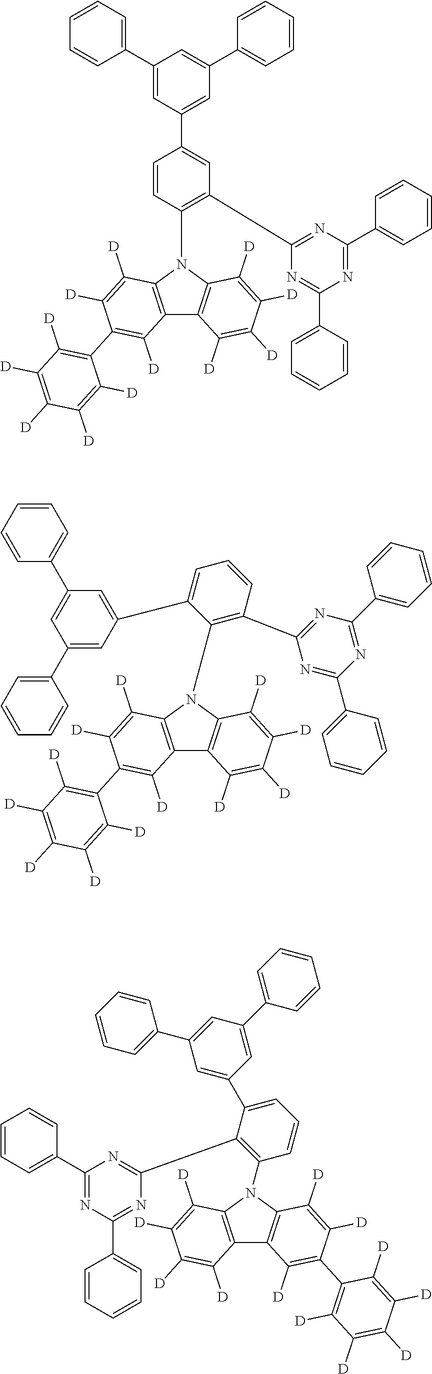

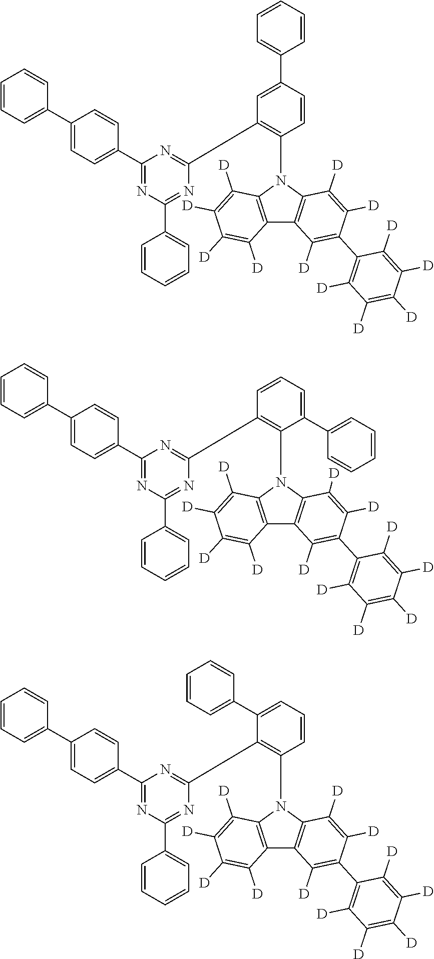 [SMILES: [2H]c1c([2H])c([2H])c(-c2c([2H])c([2H])c3c(c2[2H])c2c([2H])c([2H])c([2H])c([2H])c2n3-c2ccc(-c3ccccc3)cc2-c2nc(-c3ccccc3)nc(-c3ccc(-c4ccccc4)cc3)n2)c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2nc(-c3ccccc3)nc(-c3ccc(-c4ccccc4)cc3)n2)c([2H])c1[2H] ; [2H]c1c([2H])c([2H])c(-c2c([2H])c([2H])c3c(c2[2H])c2c([2H])c([2H])c([2H])c([2H])c2n3-c2cccc(-c3ccccc3)c2-c2nc(-c3ccccc3)nc(-c3ccc(-c4ccccc4)cc3)n2)c([2H])c1[2H]]

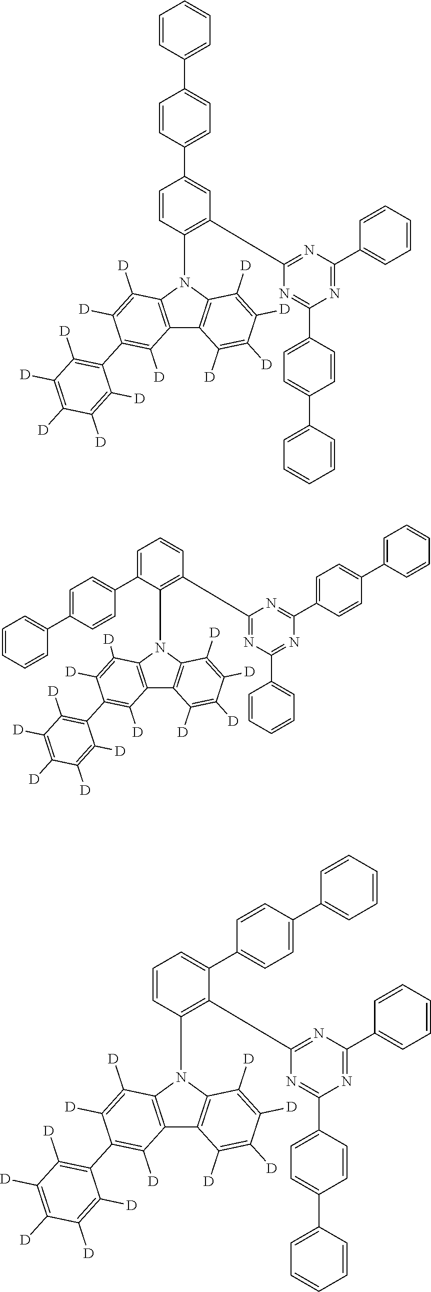

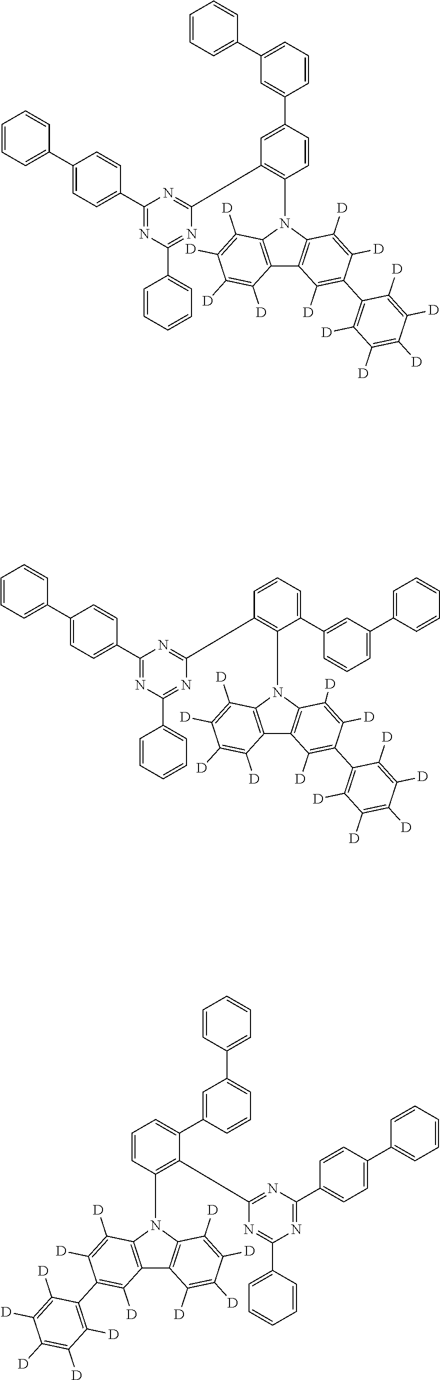

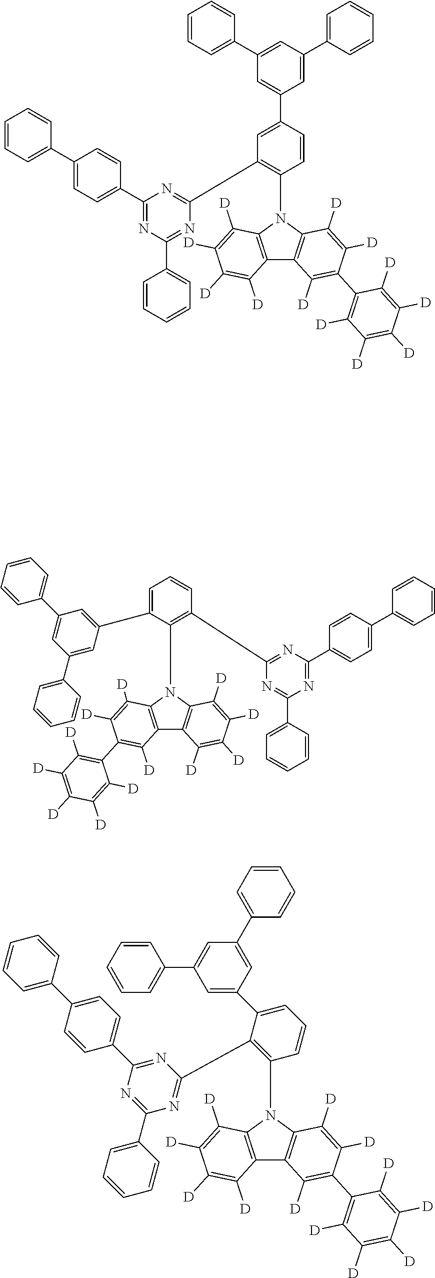

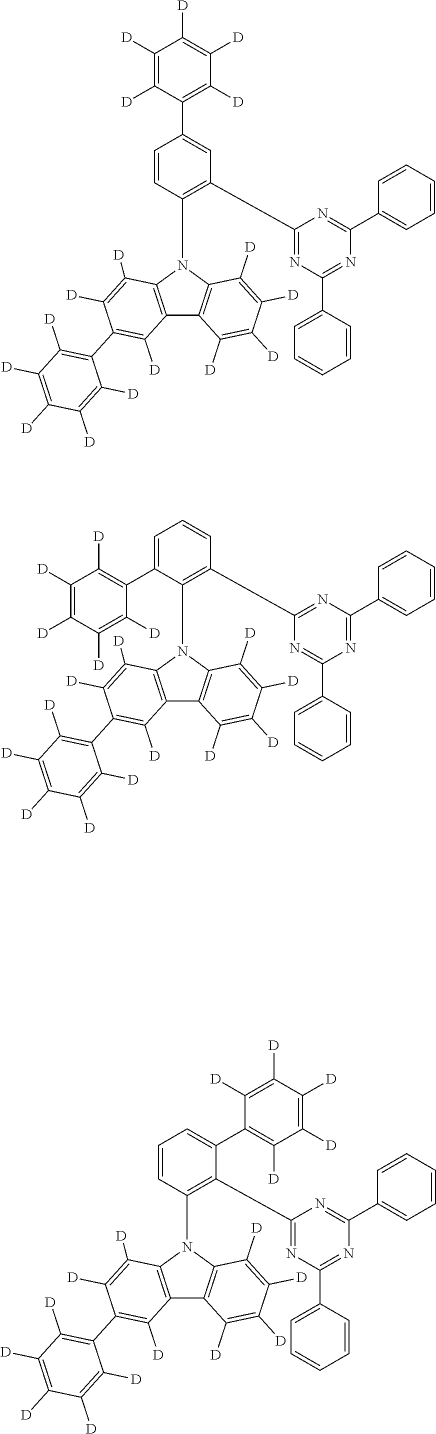

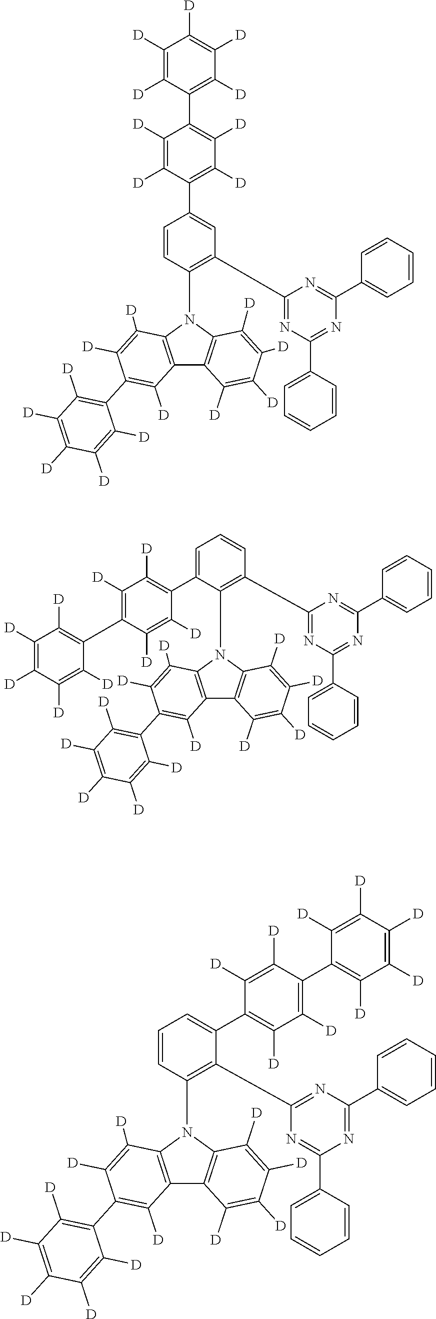

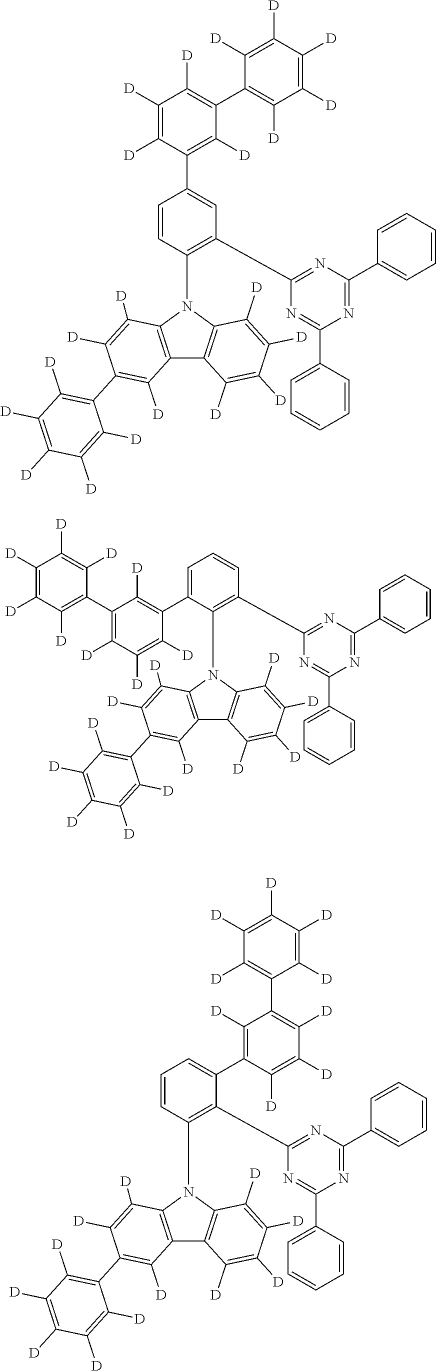

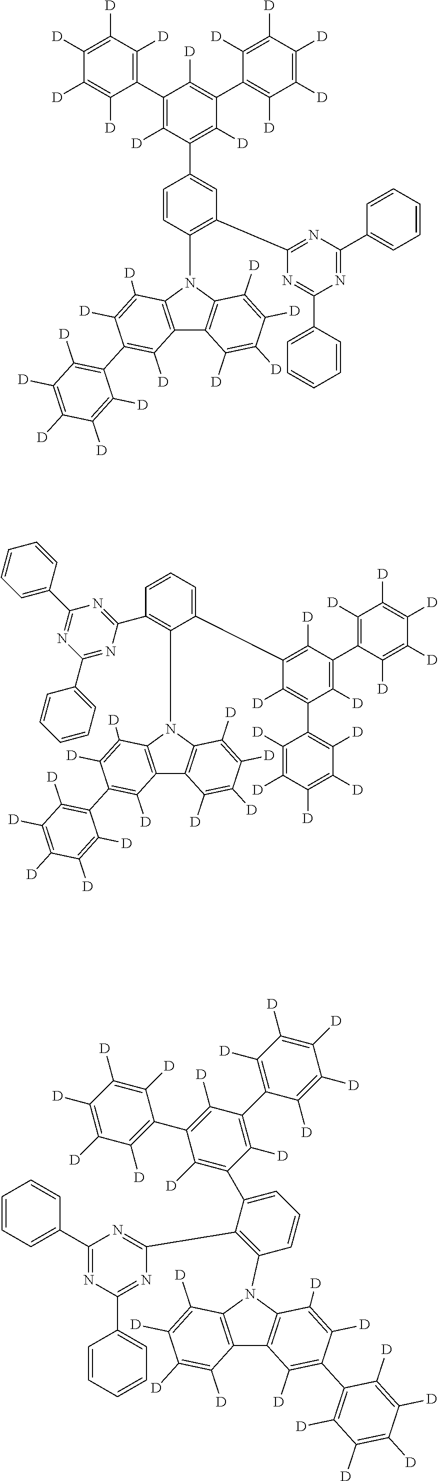

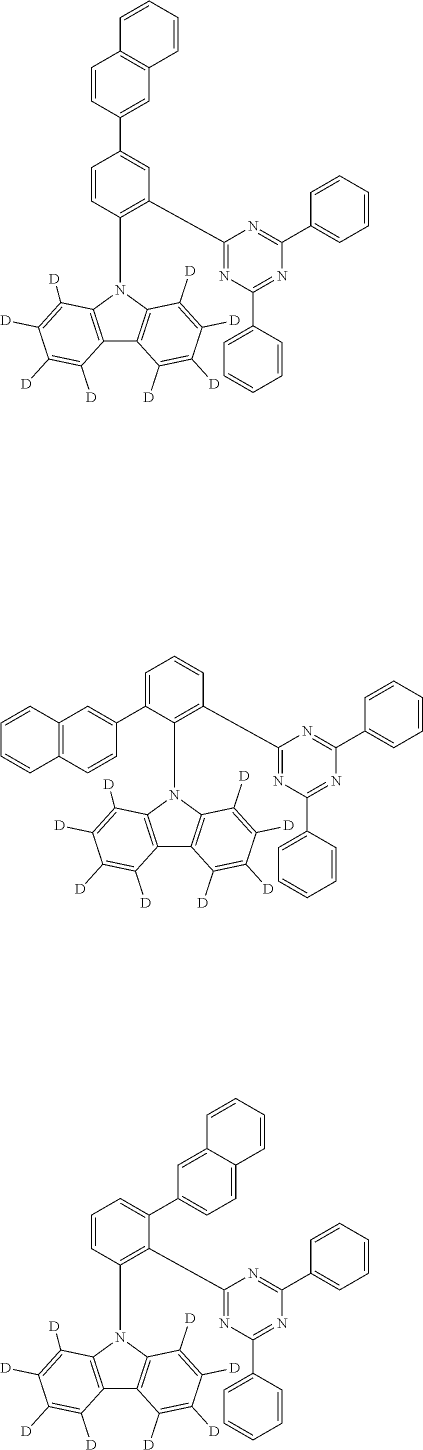 [SMILES: [2H]c1c([2H])c([2H])c2c(c1[2H])c1c([2H])c([2H])c([2H])c([2H])c1n2-c1ccc(-c2ccc3ccccc3c2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2ccc3ccccc3c2)cccc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cccc(-c2ccc3ccccc3c2)c1-c1nc(-c2ccccc2)nc(-c2ccccc2)n1]

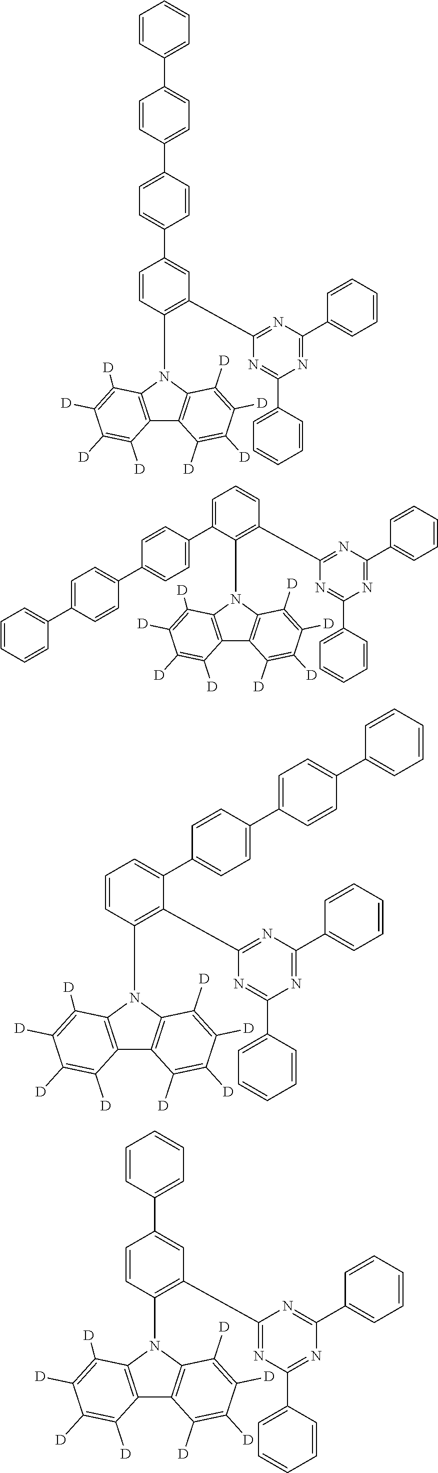

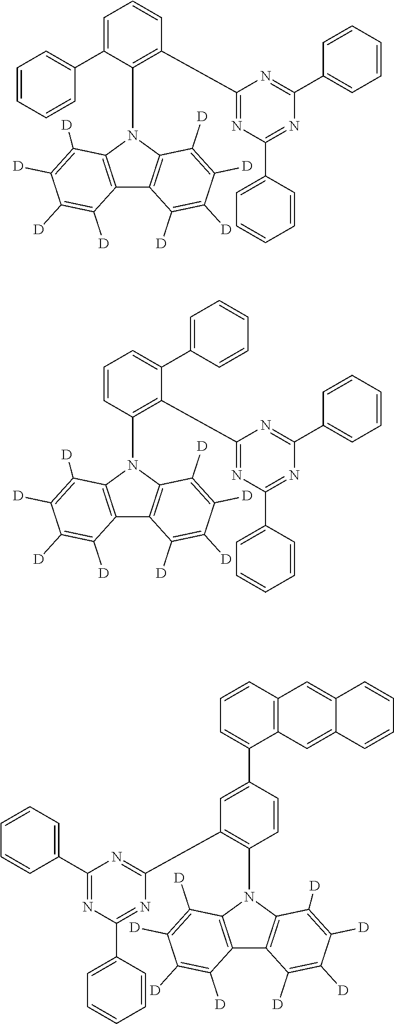 [SMILES: [2H]c1c([2H])c([2H])c2c(c1[2H])c1c([2H])c([2H])c([2H])c([2H])c1n2-c1c(-c2ccccc2)cccc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cccc(-c2ccccc2)c1-c1nc(-c2ccccc2)nc(-c2ccccc2)n1 ; [2H]c1c([2H])c([2H])c2c(c1[2H])c1c([2H])c([2H])c([2H])c([2H])c1n2-c1ccc(-c2cccc3cc4ccccc4cc23)cc1-c1nc(-c2ccccc2)nc(-c2ccccc2)n1]

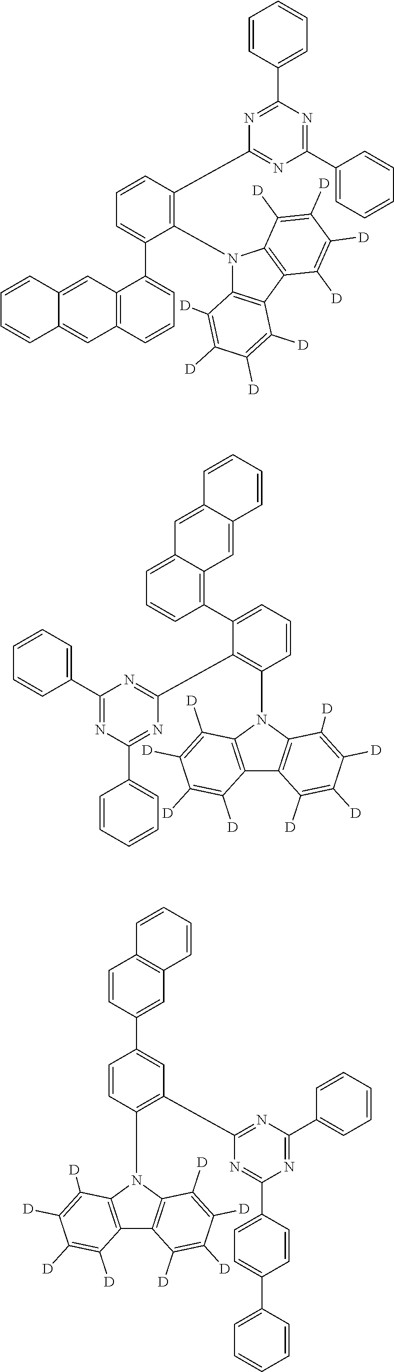 [SMILES: [2H]c1c([2H])c([2H])c2c(c1[2H])c1c([2H])c([2H])c([2H])c([2H])c1n2-c1c(-c2nc(-c3ccccc3)nc(-c3ccccc3)n2)cccc1-c1cccc2cc3ccccc3cc12 ; [2H]c1c([2H])c([2H])c2c(c1[2H])c1c([2H])c([2H])c([2H])c([2H])c1n2-c1cccc(-c2cccc3cc4ccccc4cc23)c1-c1nc(-c2ccccc2)nc(-c2ccccc2)n1 ; [2H]c1c([2H])c([2H])c2c(c1[2H])c1c([2H])c([2H])c([2H])c([2H])c1n2-c1ccc(-c2ccc3ccccc3c2)cc1-c1nc(-c2ccccc2)nc(-c2ccc(-c3ccccc3)cc2)n1]

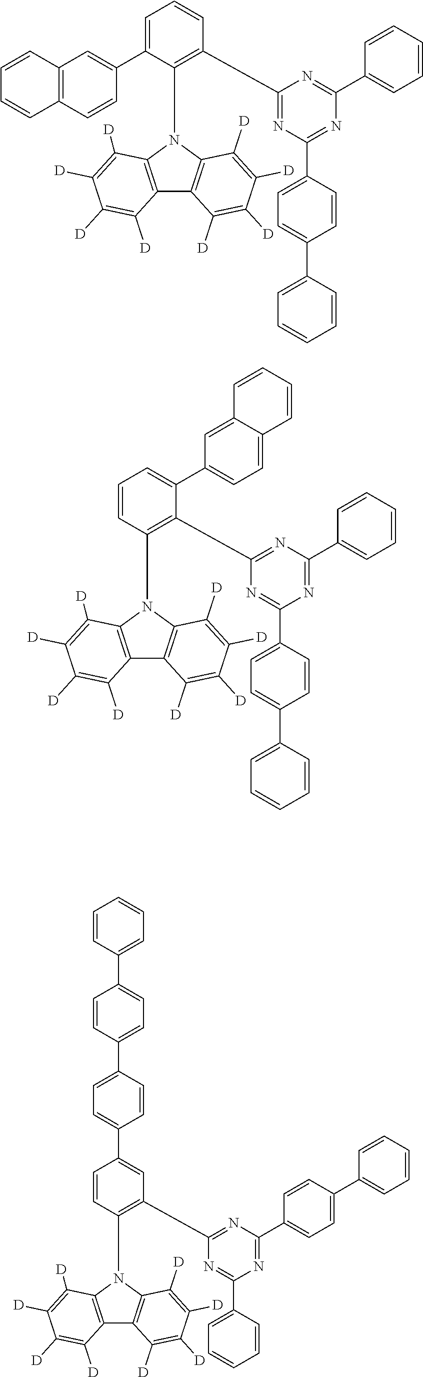

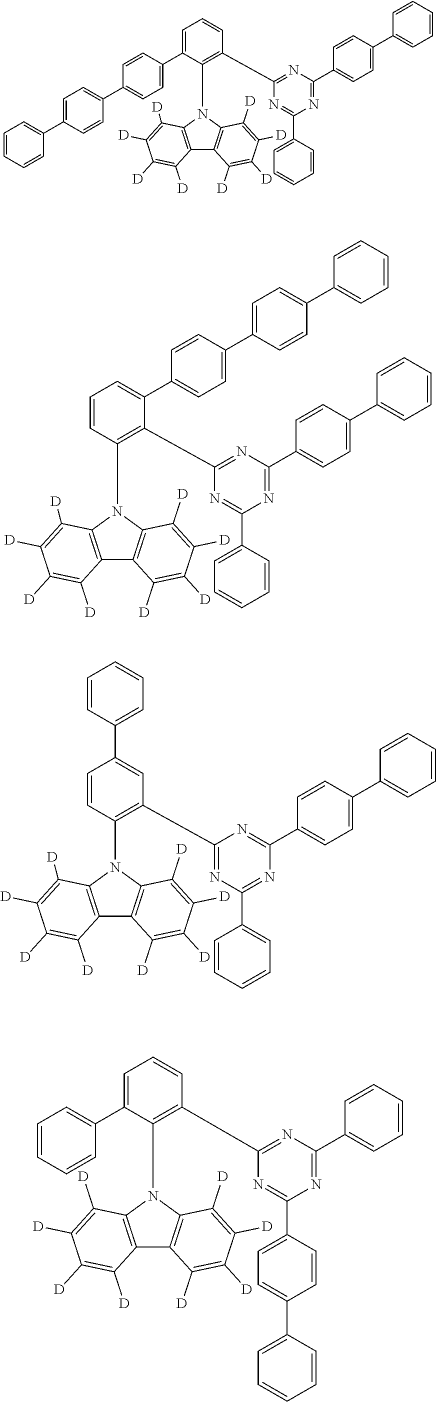

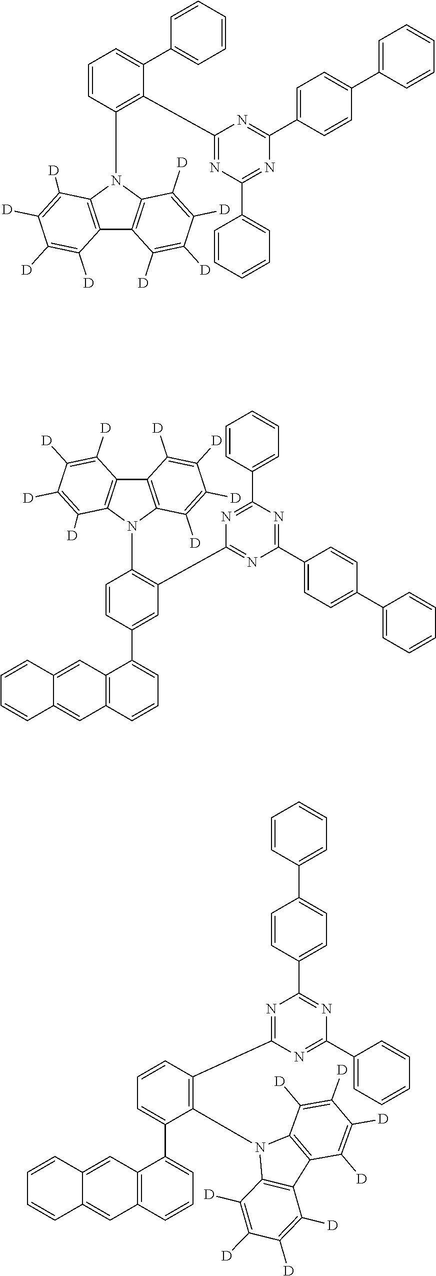 [SMILES: [2H]c1c([2H])c([2H])c2c(c1[2H])c1c([2H])c([2H])c([2H])c([2H])c1n2-c1cccc(-c2ccccc2)c1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1ccc(-c2cccc3cc4ccccc4cc23)cc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1c(-c2nc(-c3ccccc3)nc(-c3ccc(-c4ccccc4)cc3)n2)cccc1-c1cccc2cc3ccccc3cc12]

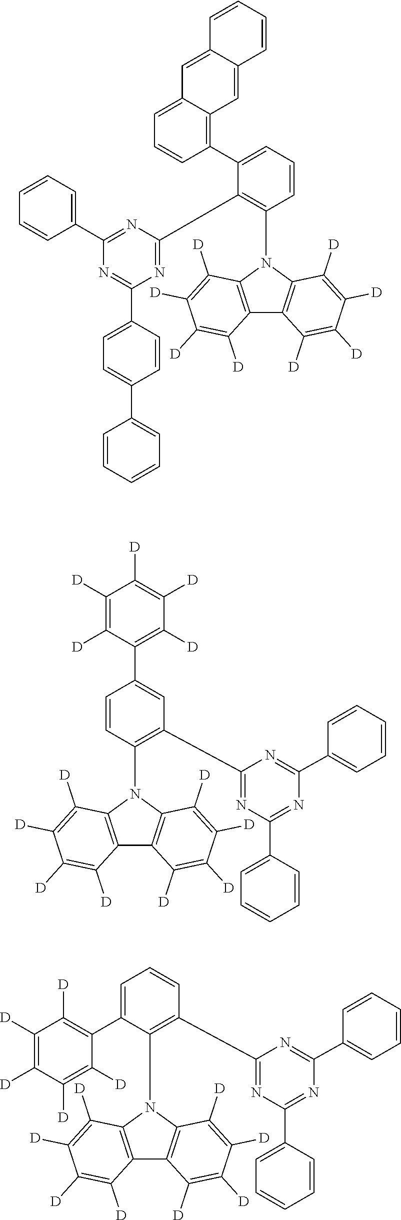 [SMILES: [2H]c1c([2H])c([2H])c2c(c1[2H])c1c([2H])c([2H])c([2H])c([2H])c1n2-c1cccc(-c2cccc3cc4ccccc4cc23)c1-c1nc(-c2ccccc2)nc(-c2ccc(-c3ccccc3)cc2)n1 ; [2H]c1c([2H])c([2H])c(-c2ccc(-n3c4c([2H])c([2H])c([2H])c([2H])c4c4c([2H])c([2H])c([2H])c([2H])c43)c(-c3nc(-c4ccccc4)nc(-c4ccccc4)n3)c2)c([2H])c1[2H] ; [2H]c1c([2H])c([2H])c(-c2cccc(-c3nc(-c4ccccc4)nc(-c4ccccc4)n3)c2-n2c3c([2H])c([2H])c([2H])c([2H])c3c3c([2H])c([2H])c([2H])c([2H])c32)c([2H])c1[2H]]

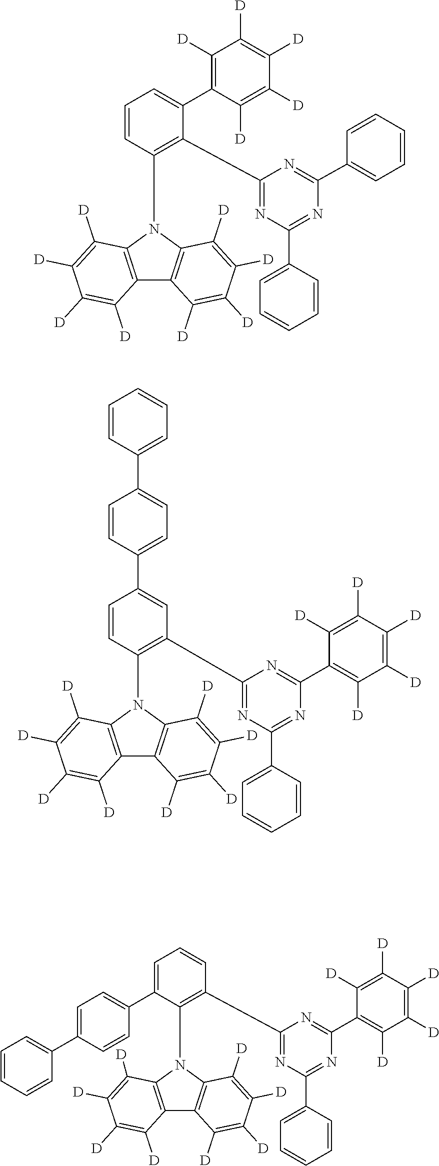 [SMILES: [2H]c1c([2H])c([2H])c(-c2cccc(-n3c4c([2H])c([2H])c([2H])c([2H])c4c4c([2H])c([2H])c([2H])c([2H])c43)c2-c2nc(-c3ccccc3)nc(-c3ccccc3)n2)c([2H])c1[2H] ; [2H]c1c([2H])c([2H])c(-c2nc(-c3ccccc3)nc(-c3cc(-c4ccc(-c5ccccc5)cc4)ccc3-n3c4c([2H])c([2H])c([2H])c([2H])c4c4c([2H])c([2H])c([2H])c([2H])c43)n2)c([2H])c1[2H] ; [2H]c1c([2H])c([2H])c(-c2nc(-c3ccccc3)nc(-c3cccc(-c4ccc(-c5ccccc5)cc4)c3-n3c4c([2H])c([2H])c([2H])c([2H])c4c4c([2H])c([2H])c([2H])c([2H])c43)n2)c([2H])c1[2H]]

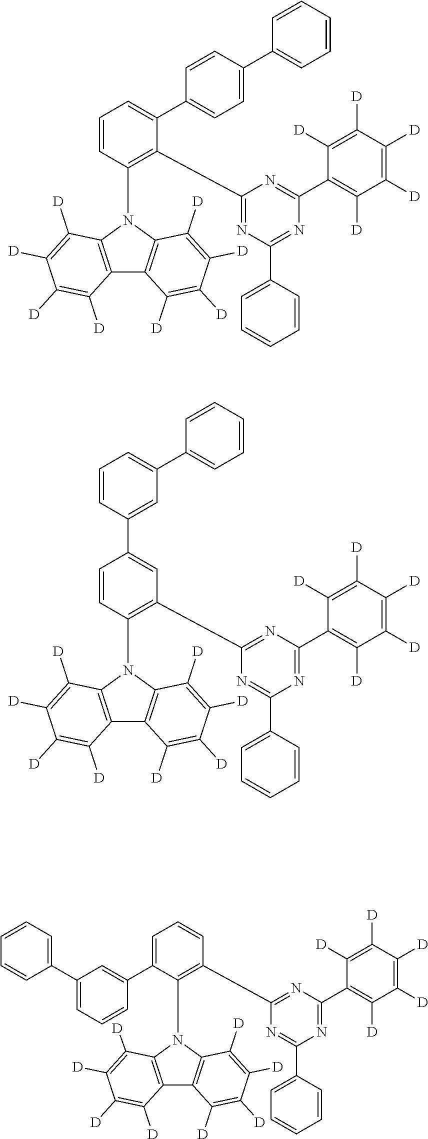 [SMILES: [2H]c1c([2H])c([2H])c(-c2nc(-c3ccccc3)nc(-c3c(-c4ccc(-c5ccccc5)cc4)cccc3-n3c4c([2H])c([2H])c([2H])c([2H])c4c4c([2H])c([2H])c([2H])c([2H])c43)n2)c([2H])c1[2H] ; [2H]c1c([2H])c([2H])c(-c2nc(-c3ccccc3)nc(-c3cc(-c4cccc(-c5ccccc5)c4)ccc3-n3c4c([2H])c([2H])c([2H])c([2H])c4c4c([2H])c([2H])c([2H])c([2H])c43)n2)c([2H])c1[2H] ; [2H]c1c([2H])c([2H])c(-c2nc(-c3ccccc3)nc(-c3cccc(-c4cccc(-c5ccccc5)c4)c3-n3c4c([2H])c([2H])c([2H])c([2H])c4c4c([2H])c([2H])c([2H])c([2H])c43)n2)c([2H])c1[2H]]

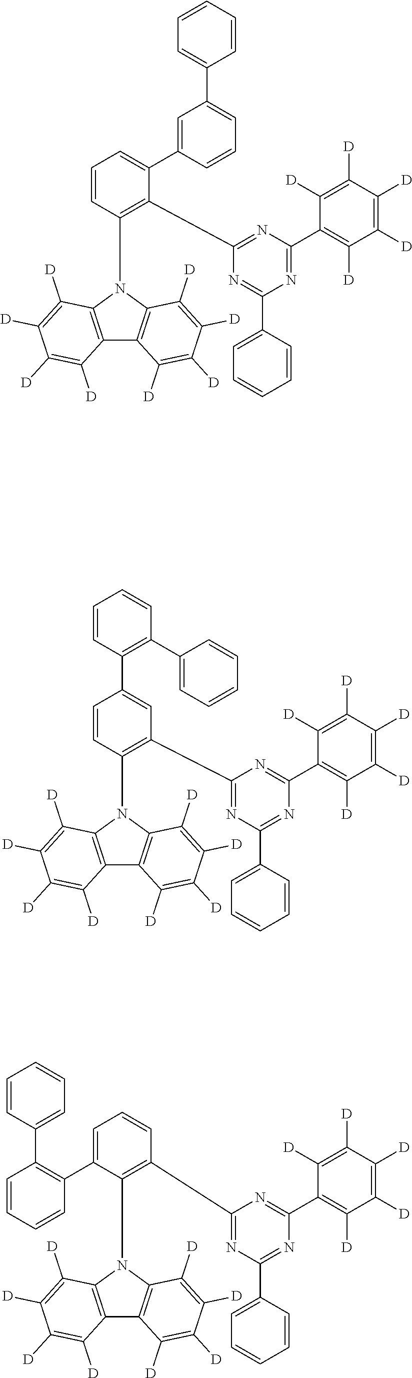 [SMILES: [2H]c1c([2H])c([2H])c(-c2nc(-c3ccccc3)nc(-c3c(-c4cccc(-c5ccccc5)c4)cccc3-n3c4c([2H])c([2H])c([2H])c([2H])c4c4c([2H])c([2H])c([2H])c([2H])c43)n2)c([2H])c1[2H] ; [2H]c1c([2H])c([2H])c(-c2nc(-c3ccccc3)nc(-c3cc(-c4ccccc4-c4ccccc4)ccc3-n3c4c([2H])c([2H])c([2H])c([2H])c4c4c([2H])c([2H])c([2H])c([2H])c43)n2)c([2H])c1[2H] ; [2H]c1c([2H])c([2H])c(-c2nc(-c3ccccc3)nc(-c3cccc(-c4ccccc4-c4ccccc4)c3-n3c4c([2H])c([2H])c([2H])c([2H])c4c4c([2H])c([2H])c([2H])c([2H])c43)n2)c([2H])c1[2H]]

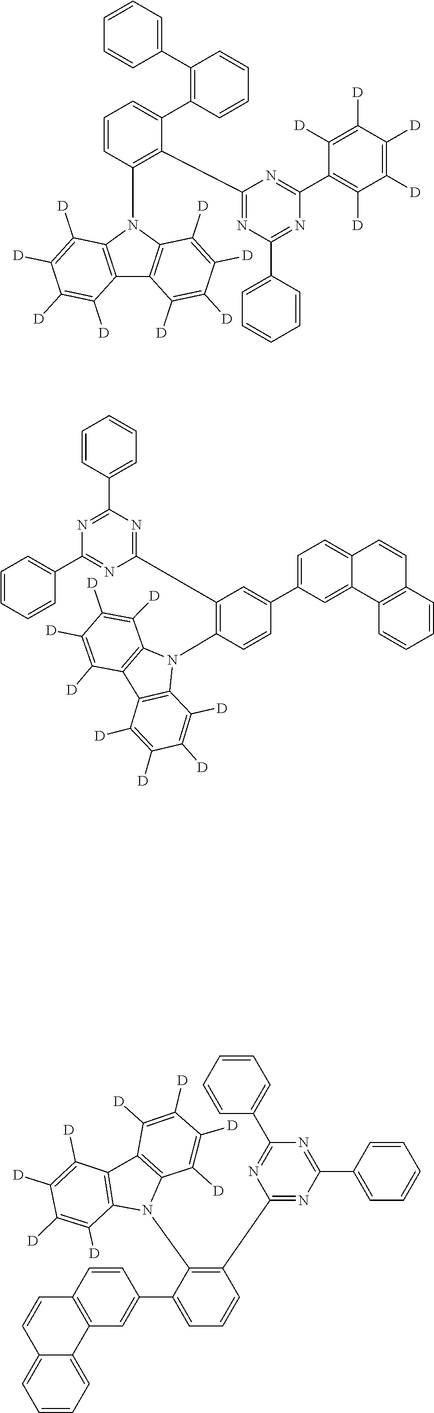 [SMILES: [2H]c1c([2H])c([2H])c(-c2nc(-c3ccccc3)nc(-c3c(-c4ccccc4-c4ccccc4)cccc3-n3c4c([2H])c([2H])c([2H])c([2H])c4c4c([2H])c([2H])c([2H])c([2H])c43)n2)c([2H])c1[2H] ; [2H]c1c([2H])c([2H])c2c(c1[2H])c1c([2H])c([2H])c([2H])c([2H])c1n2-c1ccc(-c2ccc3ccc4ccccc4c3c2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2ccc3ccc4ccccc4c3c2)cccc1-c1nc(-c2ccccc2)nc(-c2ccccc2)n1]

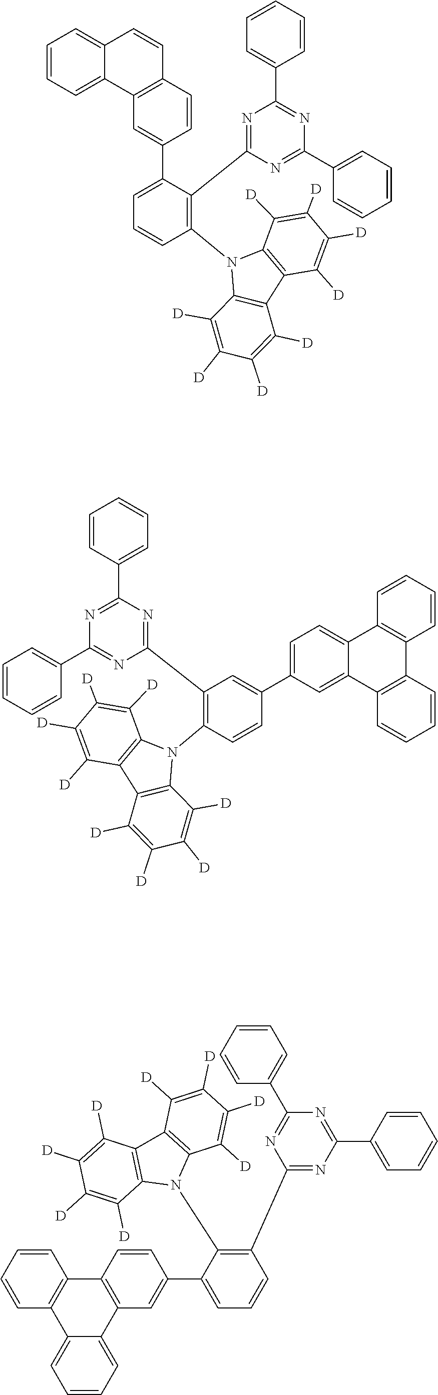 [SMILES: [2H]c1c([2H])c([2H])c2c(c1[2H])c1c([2H])c([2H])c([2H])c([2H])c1n2-c1cccc(-c2ccc3ccc4ccccc4c3c2)c1-c1nc(-c2ccccc2)nc(-c2ccccc2)n1 ; [2H]c1c([2H])c([2H])c2c(c1[2H])c1c([2H])c([2H])c([2H])c([2H])c1n2-c1ccc(-c2ccc3c4ccccc4c4ccccc4c3c2)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1c(-c2ccc3c4ccccc4c4ccccc4c3c2)cccc1-c1nc(-c2ccccc2)nc(-c2ccccc2)n1]

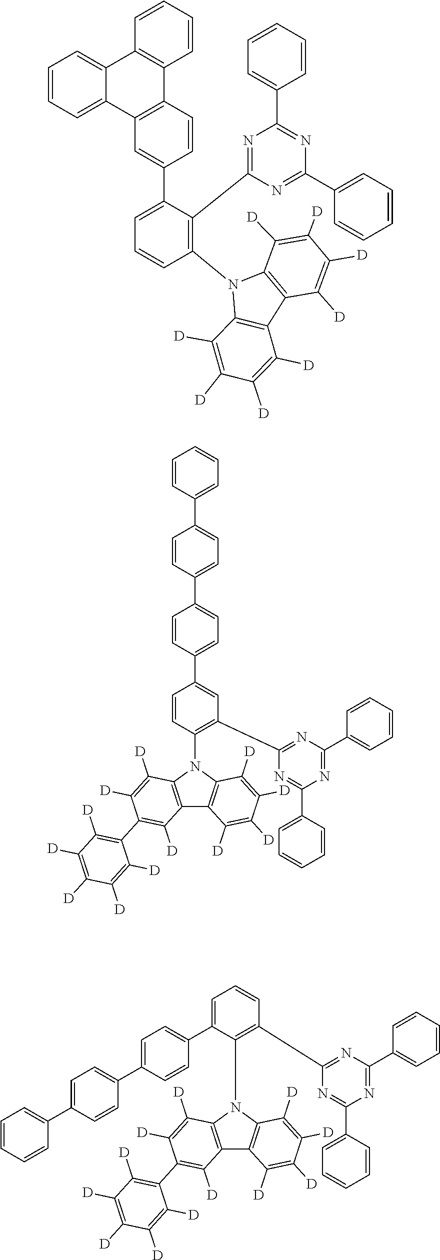 [SMILES: [2H]c1c([2H])c([2H])c2c(c1[2H])c1c([2H])c([2H])c([2H])c([2H])c1n2-c1cccc(-c2ccc3c4ccccc4c4ccccc4c3c2)c1-c1nc(-c2ccccc2)nc(-c2ccccc2)n1 ; [2H]c1c([2H])c([2H])c(-c2c([2H])c([2H])c3c(c2[2H])c2c([2H])c([2H])c([2H])c([2H])c2n3-c2ccc(-c3ccc(-c4ccc(-c5ccccc5)cc4)cc3)cc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccc(-c4ccc(-c5ccccc5)cc4)cc3)cccc2-c2nc(-c3ccccc3)nc(-c3ccccc3)n2)c([2H])c1[2H]]

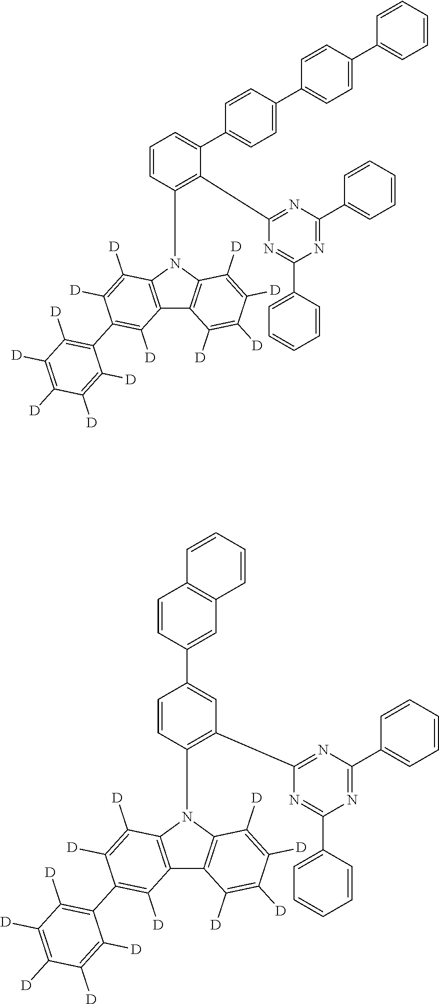 [SMILES: [2H]c1c([2H])c([2H])c(-c2c([2H])c([2H])c3c(c2[2H])c2c([2H])c([2H])c([2H])c([2H])c2n3-c2cccc(-c3ccc(-c4ccc(-c5ccccc5)cc4)cc3)c2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2ccc(-c3ccc4ccccc4c3)cc2-c2nc(-c3ccccc3)nc(-c3ccccc3)n2)c([2H])c1[2H]]

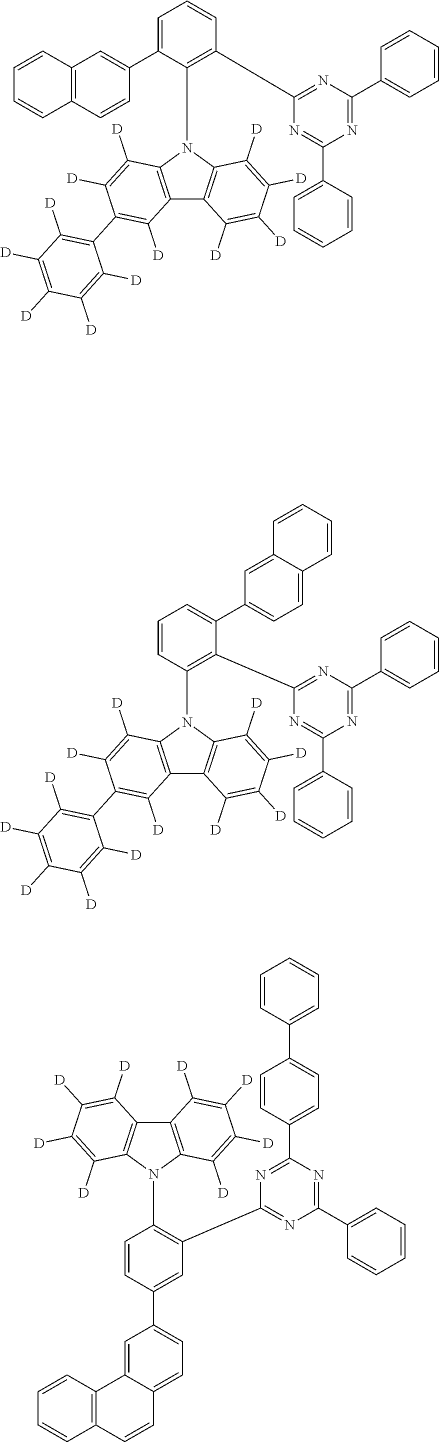 [SMILES: [2H]c1c([2H])c([2H])c(-c2c([2H])c([2H])c3c(c2[2H])c2c([2H])c([2H])c([2H])c([2H])c2n3-c2c(-c3ccc4ccccc4c3)cccc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2cccc(-c3ccc4ccccc4c3)c2-c2nc(-c3ccccc3)nc(-c3ccccc3)n2)c([2H])c1[2H] ; [2H]c1c([2H])c([2H])c2c(c1[2H])c1c([2H])c([2H])c([2H])c([2H])c1n2-c1ccc(-c2ccc3ccc4ccccc4c3c2)cc1-c1nc(-c2ccccc2)nc(-c2ccc(-c3ccccc3)cc2)n1]

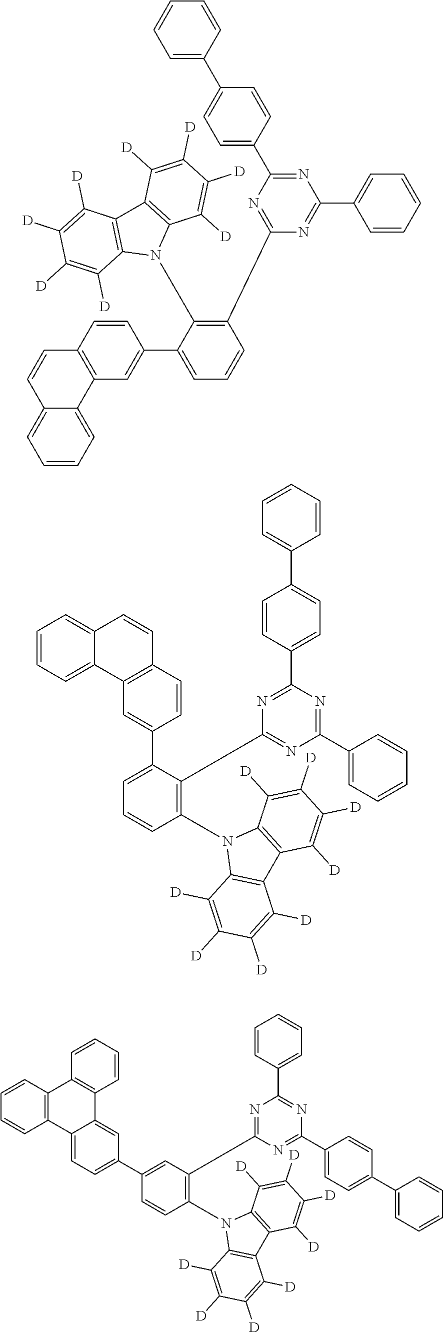 [SMILES: [2H]c1c([2H])c([2H])c2c(c1[2H])c1c([2H])c([2H])c([2H])c([2H])c1n2-c1c(-c2ccc3ccc4ccccc4c3c2)cccc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1cccc(-c2ccc3ccc4ccccc4c3c2)c1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1ccc(-c2ccc3c4ccccc4c4ccccc4c3c2)cc1-c1nc(-c2ccccc2)nc(-c2ccc(-c3ccccc3)cc2)n1]

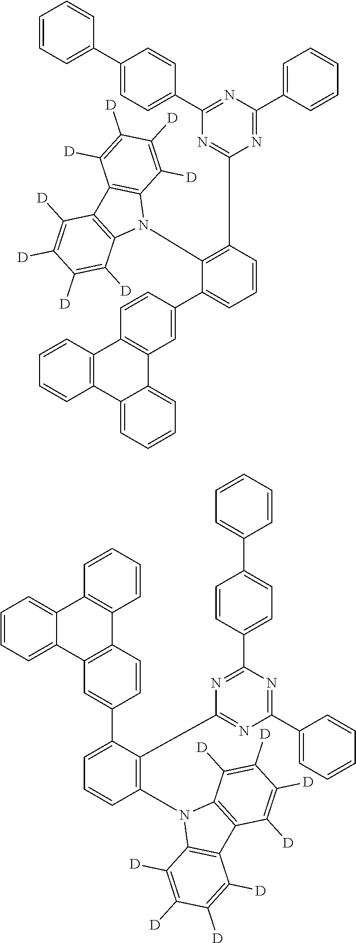 [SMILES: [2H]c1c([2H])c([2H])c2c(c1[2H])c1c([2H])c([2H])c([2H])c([2H])c1n2-c1c(-c2ccc3c4ccccc4c4ccccc4c3c2)cccc1-c1nc(-c2ccccc2)nc(-c2ccc(-c3ccccc3)cc2)n1 ; [2H]c1c([2H])c([2H])c2c(c1[2H])c1c([2H])c([2H])c([2H])c([2H])c1n2-c1cccc(-c2ccc3c4ccccc4c4ccccc4c3c2)c1-c1nc(-c2ccccc2)nc(-c2ccc(-c3ccccc3)cc2)n1]

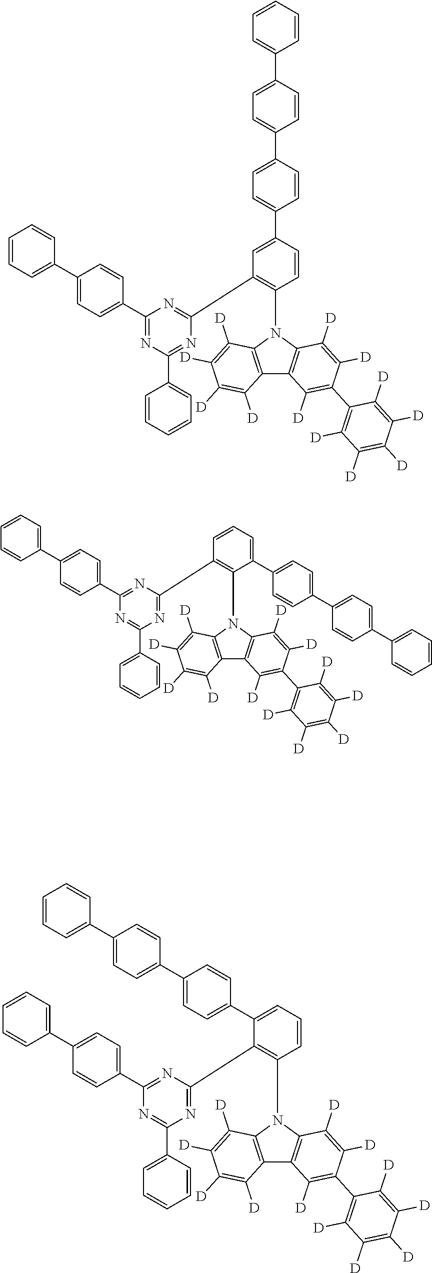

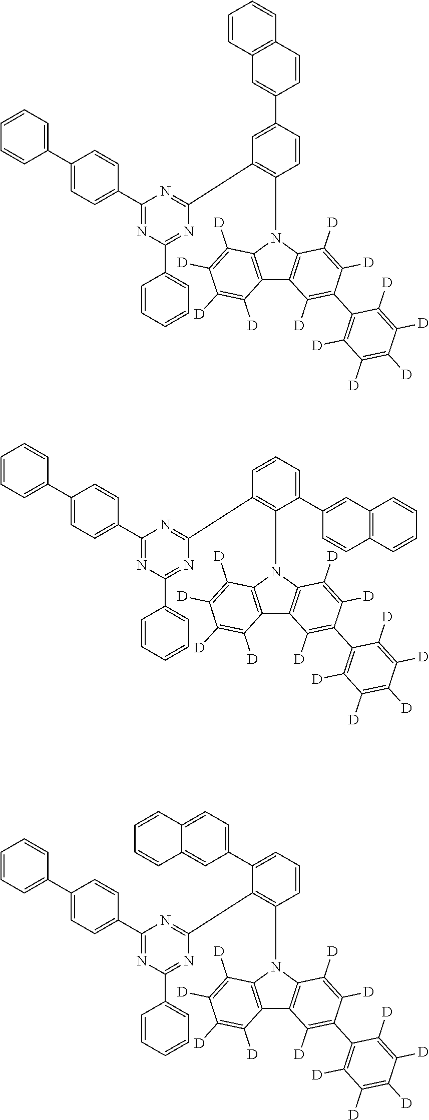

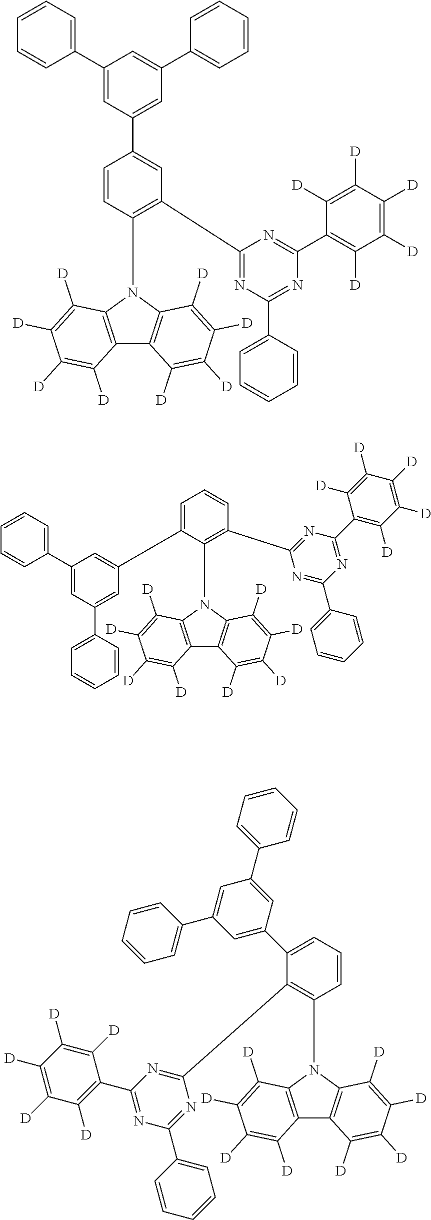

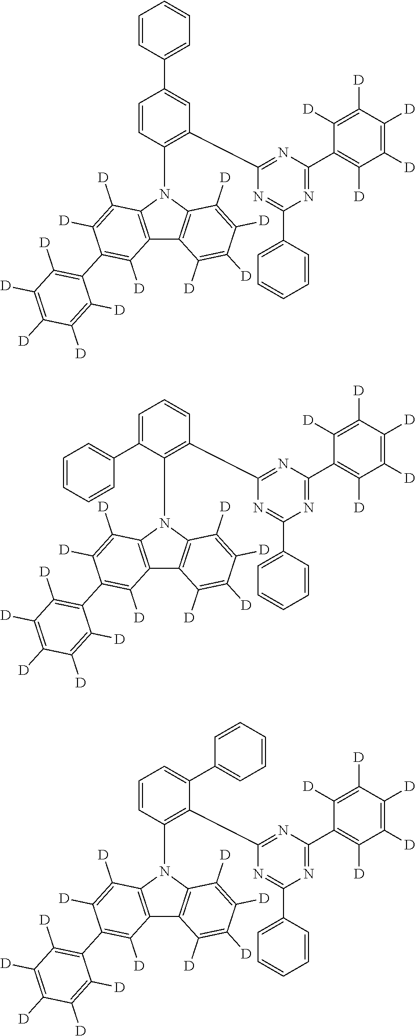

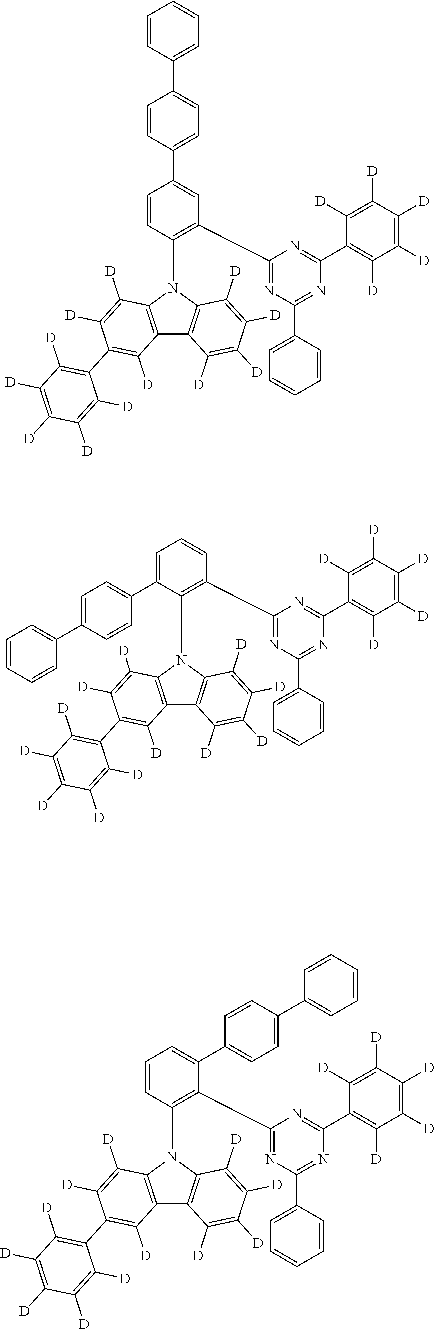

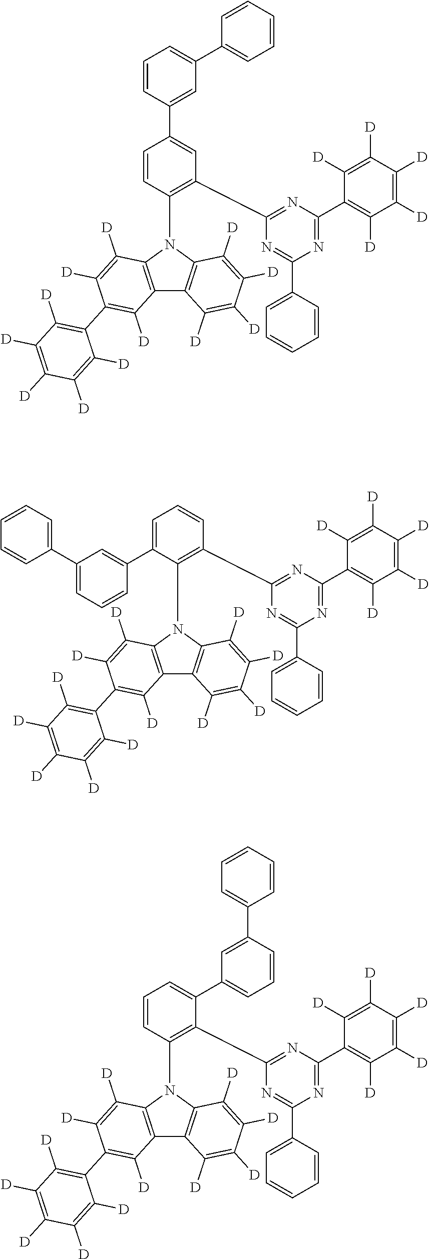

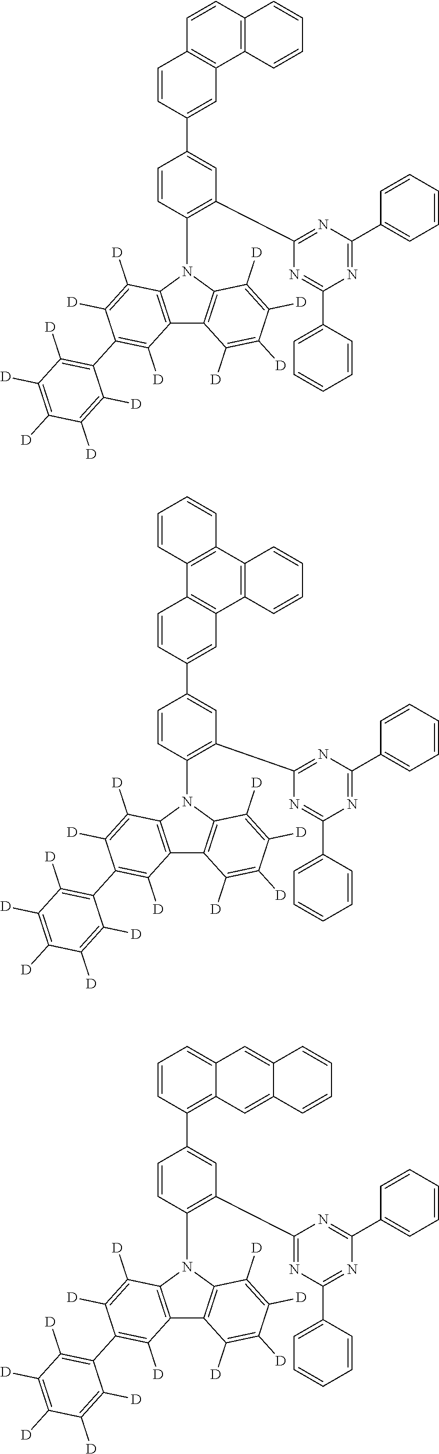 [SMILES: [2H]c1c([2H])c([2H])c(-c2c([2H])c([2H])c3c(c2[2H])c2c([2H])c([2H])c([2H])c([2H])c2n3-c2ccc(-c3ccc4ccc5ccccc5c4c3)cc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2ccc(-c3ccc4c5ccccc5c5ccccc5c4c3)cc2-c2nc(-c3ccccc3)nc(-c3ccccc3)n2)c([2H])c1[2H] ; [2H]c1c([2H])c([2H])c(-c2c([2H])c([2H])c3c(c2[2H])c2c([2H])c([2H])c([2H])c([2H])c2n3-c2ccc(-c3cccc4cc5ccccc5cc34)cc2-c2nc(-c3ccccc3)nc(-c3ccccc3)n2)c([2H])c1[2H]]

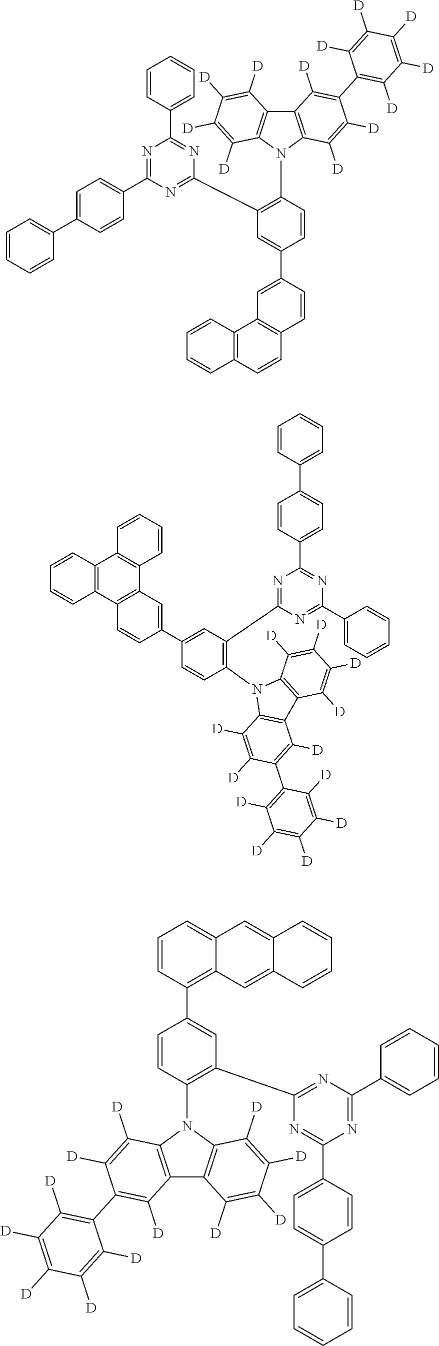

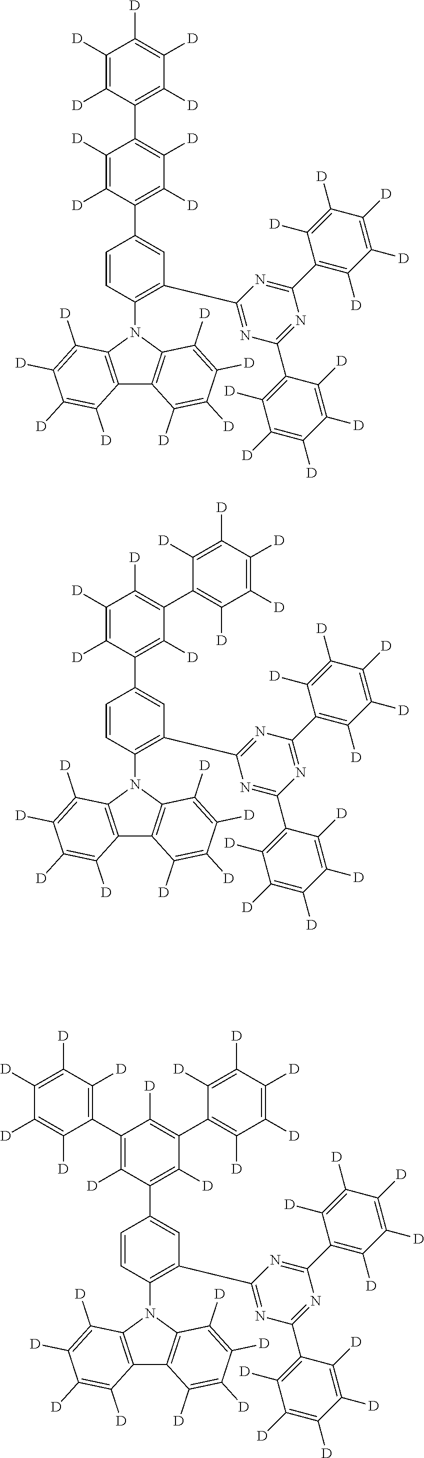

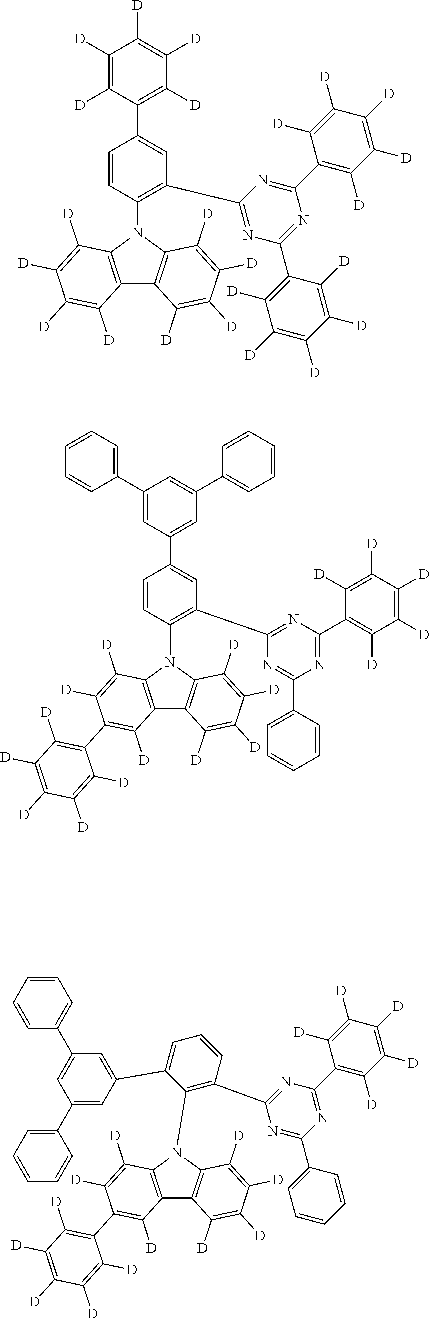

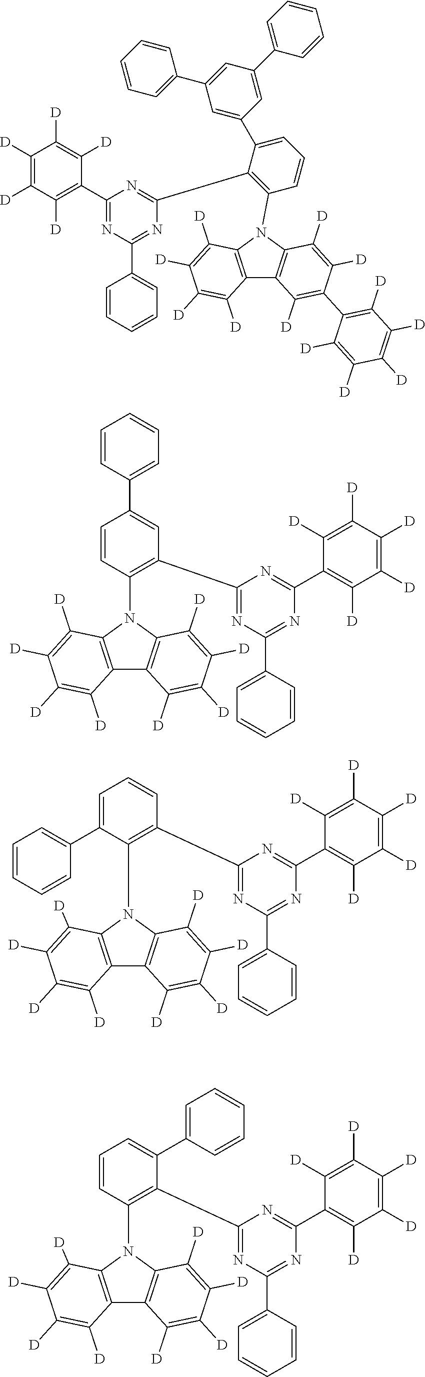

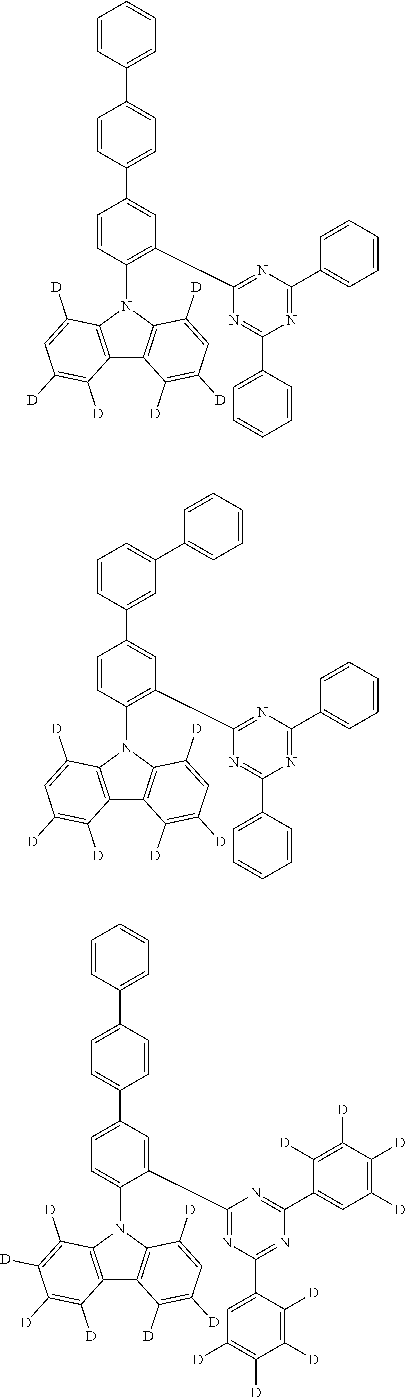 [SMILES: [2H]c1cc([2H])c2c(c1[2H])c1c([2H])c([2H])cc([2H])c1n2-c1ccc(-c2ccc(-c3ccccc3)cc2)cc1-c1nc(-c2ccccc2)nc(-c2ccccc2)n1 ; [2H]c1cc([2H])c2c(c1[2H])c1c([2H])c([2H])cc([2H])c1n2-c1ccc(-c2cccc(-c3ccccc3)c2)cc1-c1nc(-c2ccccc2)nc(-c2ccccc2)n1 ; [2H]c1cc(-c2nc(-c3cc(-c4ccc(-c5ccccc5)cc4)ccc3-n3c4c([2H])cc([2H])c([2H])c4c4c([2H])c([2H])c([2H])c([2H])c43)nc(-c3cc([2H])c([2H])c([2H])c3[2H])n2)c([2H])c([2H])c1[2H]]

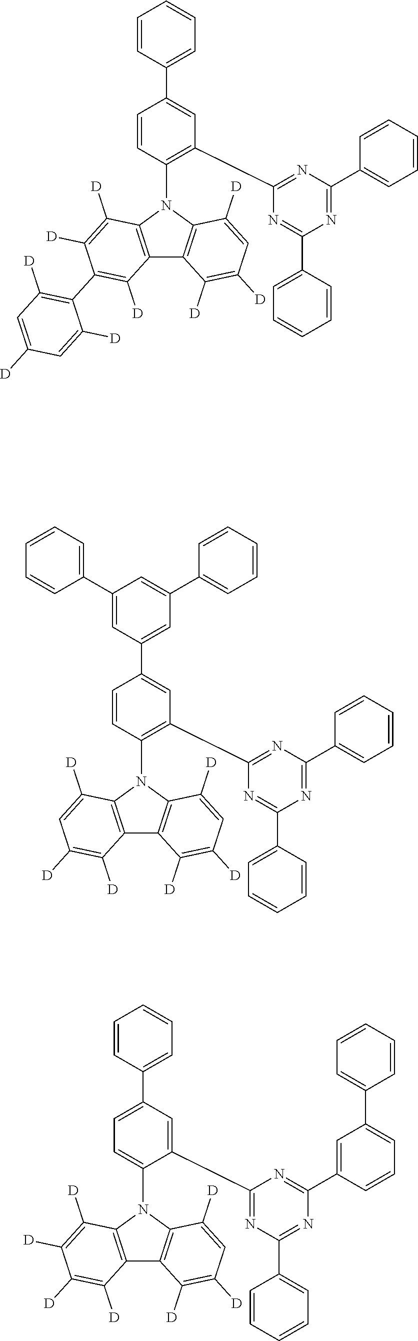 [SMILES: [2H]c1cc([2H])c(-c2c([2H])c([2H])c3c(c2[2H])c2c([2H])c([2H])cc([2H])c2n3-c2ccc(-c3ccccc3)cc2-c2nc(-c3ccccc3)nc(-c3ccccc3)n2)c([2H])c1 ; [2H]c1cc([2H])c2c(c1[2H])c1c([2H])c([2H])cc([2H])c1n2-c1ccc(-c2cc(-c3ccccc3)cc(-c3ccccc3)c2)cc1-c1nc(-c2ccccc2)nc(-c2ccccc2)n1 ; [2H]c1cc([2H])c2c(c1[2H])c1c([2H])c([2H])c([2H])c([2H])c1n2-c1ccc(-c2ccccc2)cc1-c1nc(-c2ccccc2)nc(-c2cccc(-c3ccccc3)c2)n1]

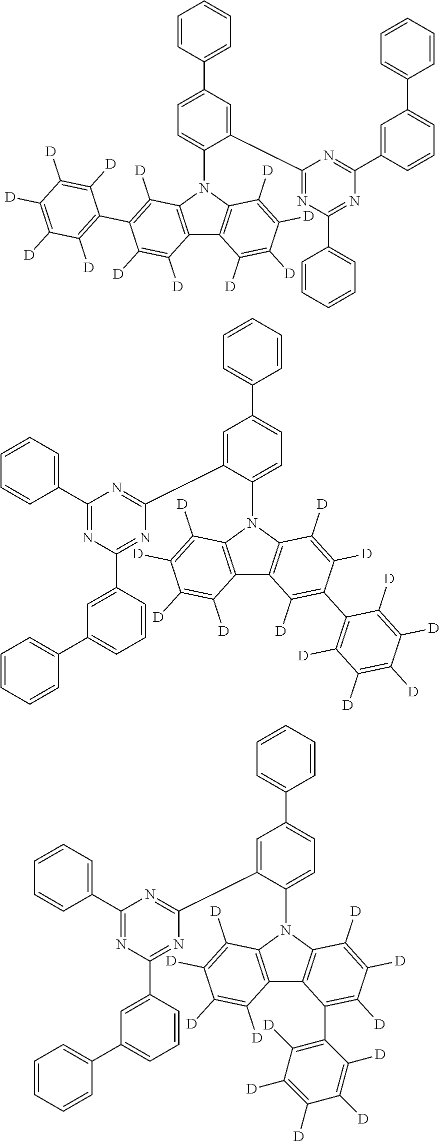

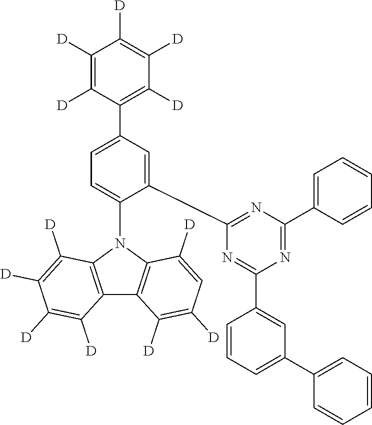 [SMILES: [2H]c1cc([2H])c2c(c1[2H])c1c([2H])c([2H])c([2H])c([2H])c1n2-c1ccc(-c2c([2H])c([2H])c([2H])c([2H])c2[2H])cc1-c1nc(-c2ccccc2)nc(-c2cccc(-c3ccccc3)c2)n1]

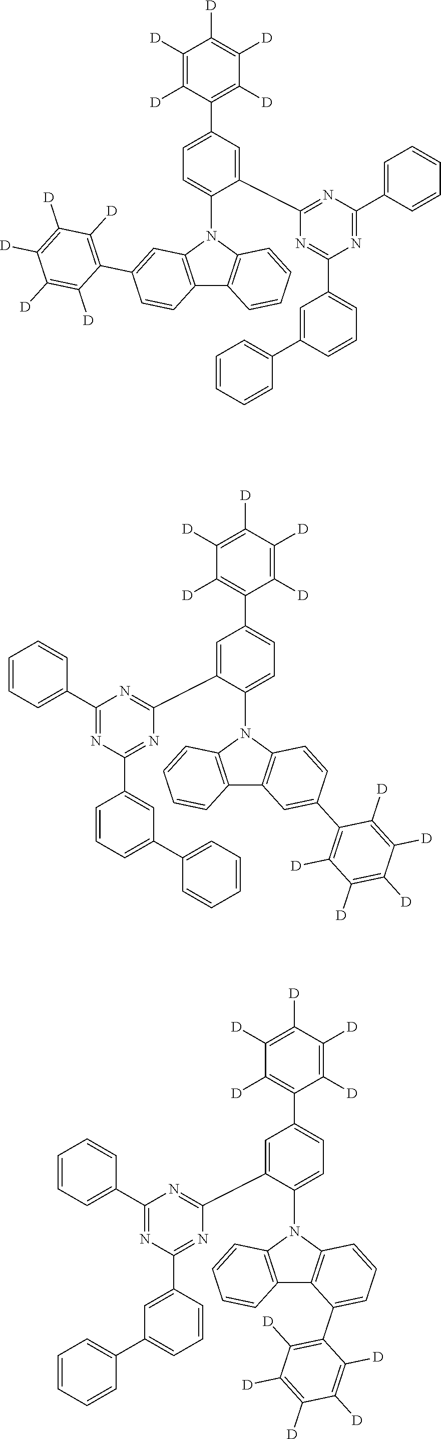 [SMILES: [2H]c1c([2H])c([2H])c(-c2ccc(-n3c4ccccc4c4ccc(-c5c([2H])c([2H])c([2H])c([2H])c5[2H])cc43)c(-c3nc(-c4ccccc4)nc(-c4cccc(-c5ccccc5)c4)n3)c2)c([2H])c1[2H] ; [2H]c1c([2H])c([2H])c(-c2ccc(-n3c4ccccc4c4cc(-c5c([2H])c([2H])c([2H])c([2H])c5[2H])ccc43)c(-c3nc(-c4ccccc4)nc(-c4cccc(-c5ccccc5)c4)n3)c2)c([2H])c1[2H] ; [2H]c1c([2H])c([2H])c(-c2ccc(-n3c4ccccc4c4c(-c5c([2H])c([2H])c([2H])c([2H])c5[2H])cccc43)c(-c3nc(-c4ccccc4)nc(-c4cccc(-c5ccccc5)c4)n3)c2)c([2H])c1[2H]]

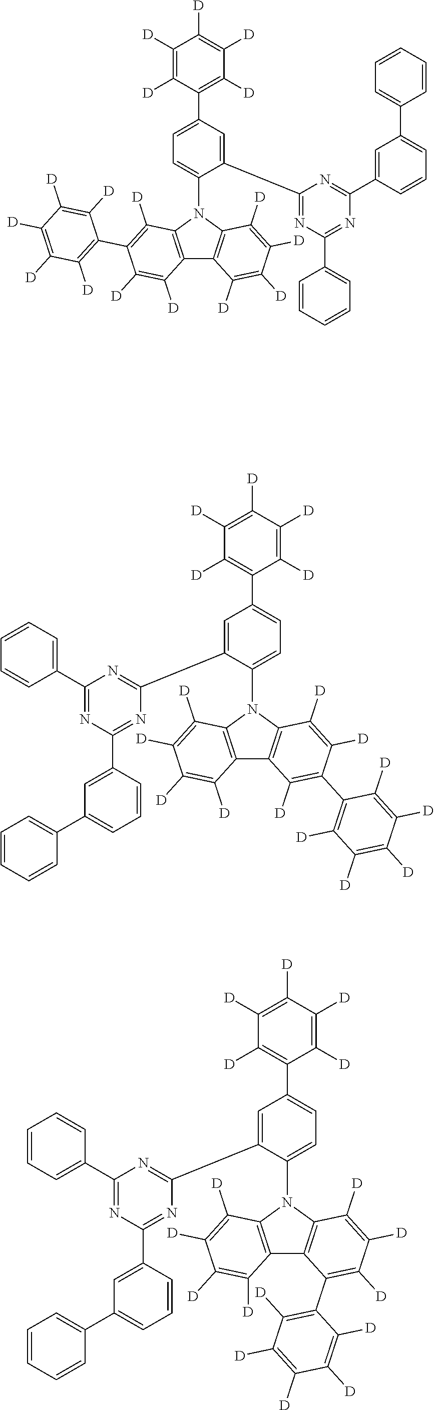

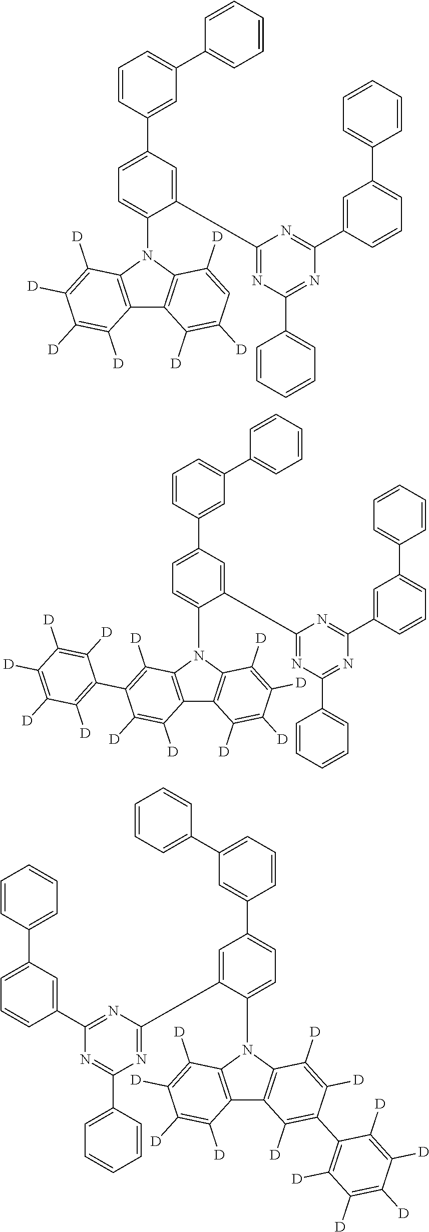

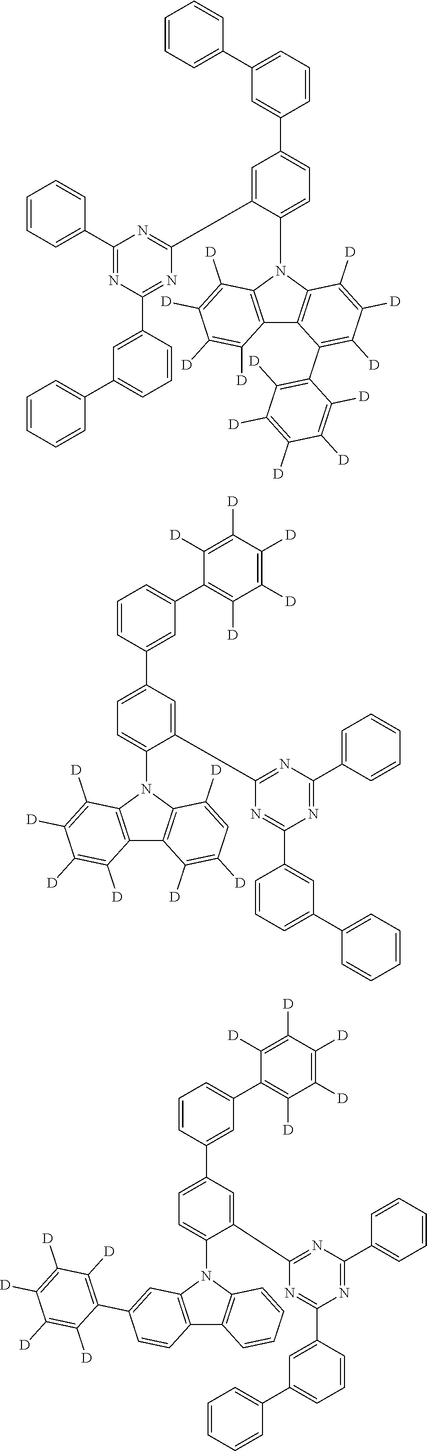 [SMILES: [2H]c1c([2H])c([2H])c(-c2c([2H])c([2H])c([2H])c3c2c2c([2H])c([2H])c([2H])c([2H])c2n3-c2ccc(-c3cccc(-c4ccccc4)c3)cc2-c2nc(-c3ccccc3)nc(-c3cccc(-c4ccccc4)c3)n2)c([2H])c1[2H] ; [2H]c1cc([2H])c2c(c1[2H])c1c([2H])c([2H])c([2H])c([2H])c1n2-c1ccc(-c2cccc(-c3c([2H])c([2H])c([2H])c([2H])c3[2H])c2)cc1-c1nc(-c2ccccc2)nc(-c2cccc(-c3ccccc3)c2)n1 ; [2H]c1c([2H])c([2H])c(-c2cccc(-c3ccc(-n4c5ccccc5c5ccc(-c6c([2H])c([2H])c([2H])c([2H])c6[2H])cc54)c(-c4nc(-c5ccccc5)nc(-c5cccc(-c6ccccc6)c5)n4)c3)c2)c([2H])c1[2H]]

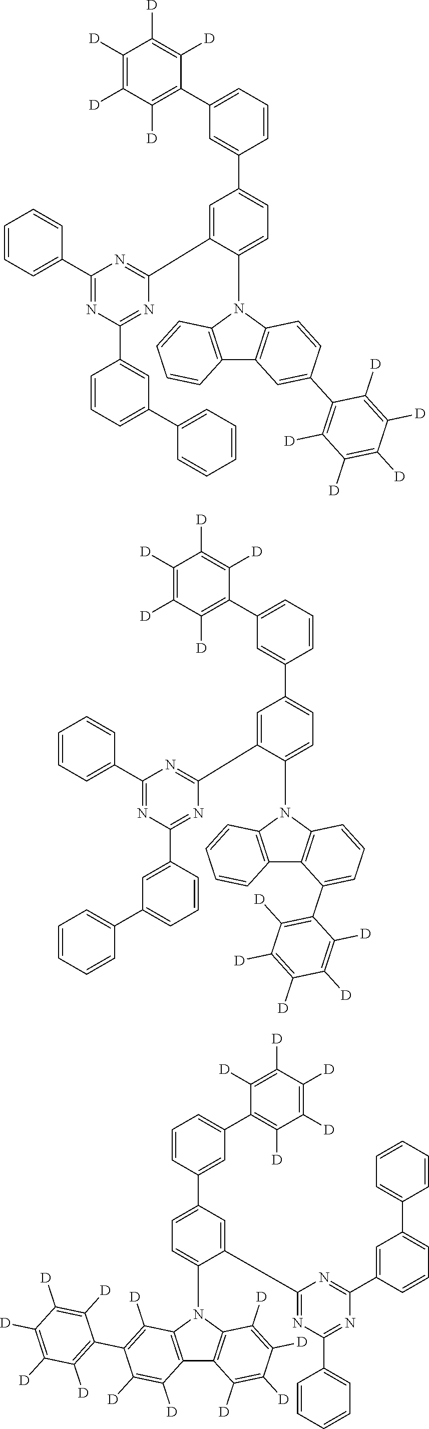

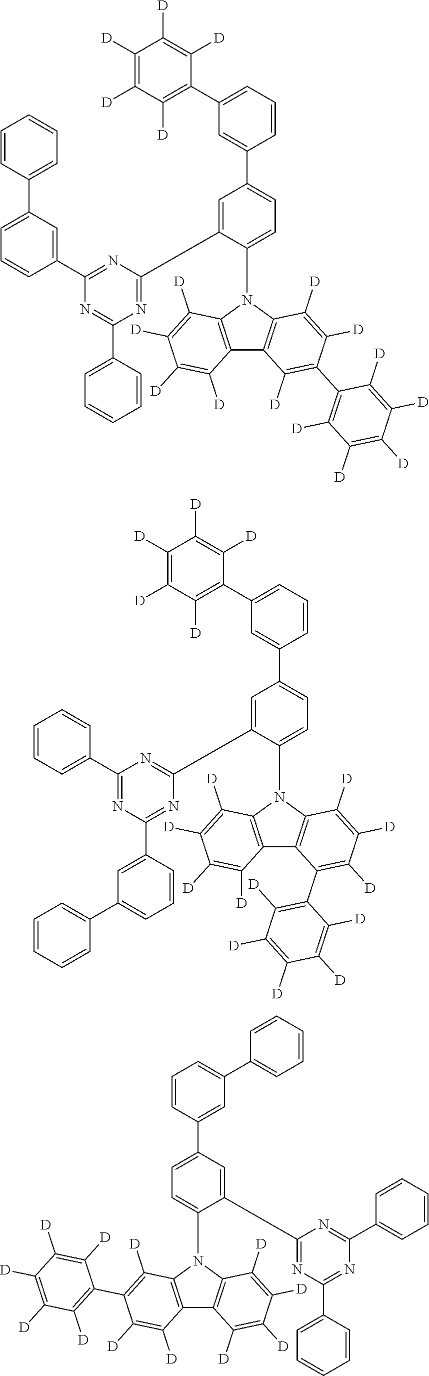

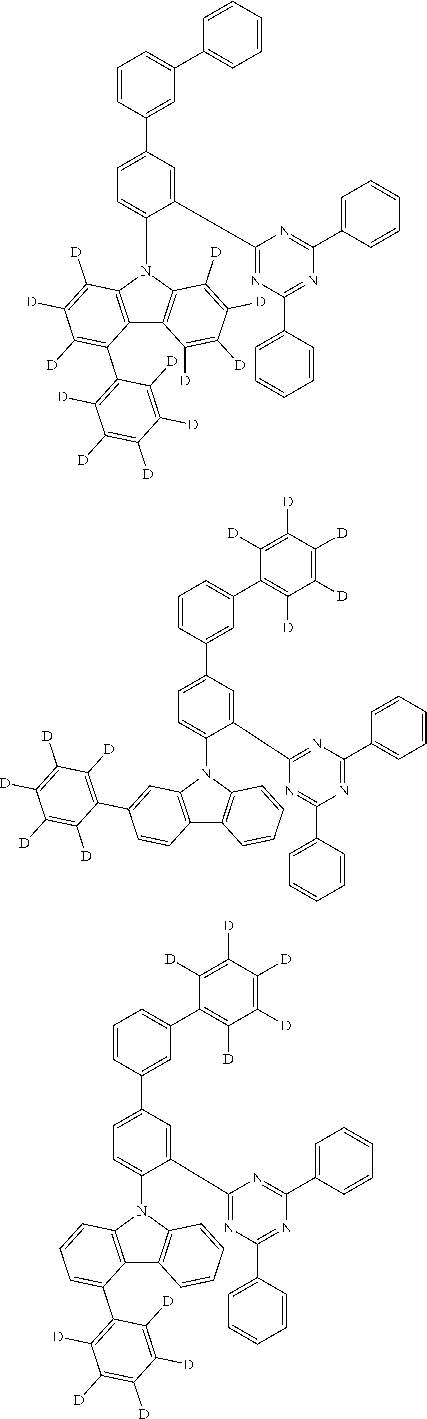 [SMILES: [2H]c1c([2H])c([2H])c(-c2c([2H])c([2H])c([2H])c3c2c2c([2H])c([2H])c([2H])c([2H])c2n3-c2ccc(-c3cccc(-c4ccccc4)c3)cc2-c2nc(-c3ccccc3)nc(-c3ccccc3)n2)c([2H])c1[2H] ; [2H]c1c([2H])c([2H])c(-c2cccc(-c3ccc(-n4c5ccccc5c5ccc(-c6c([2H])c([2H])c([2H])c([2H])c6[2H])cc54)c(-c4nc(-c5ccccc5)nc(-c5ccccc5)n4)c3)c2)c([2H])c1[2H] ; [2H]c1c([2H])c([2H])c(-c2cccc(-c3ccc(-n4c5ccccc5c5c(-c6c([2H])c([2H])c([2H])c([2H])c6[2H])cccc54)c(-c4nc(-c5ccccc5)nc(-c5ccccc5)n4)c3)c2)c([2H])c1[2H]]

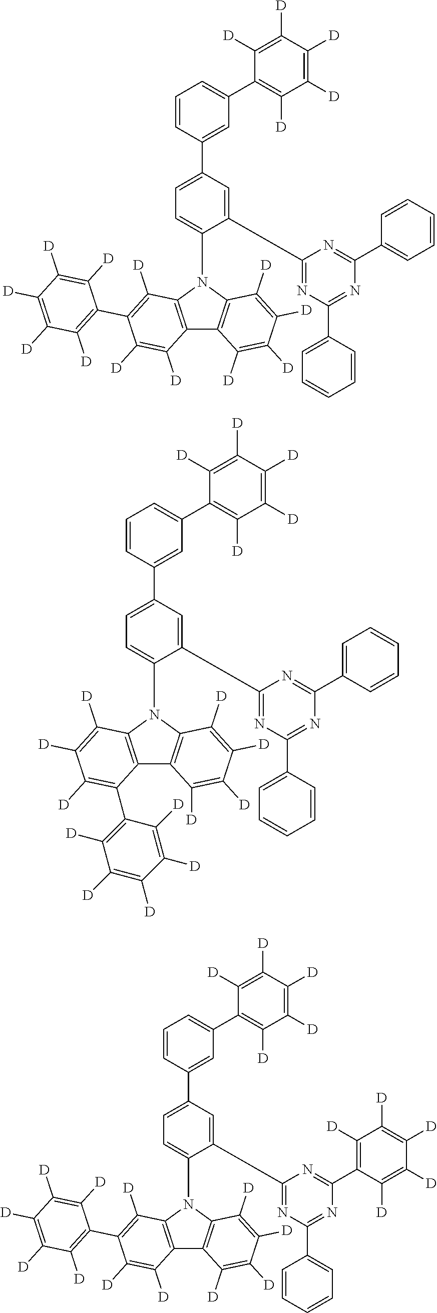

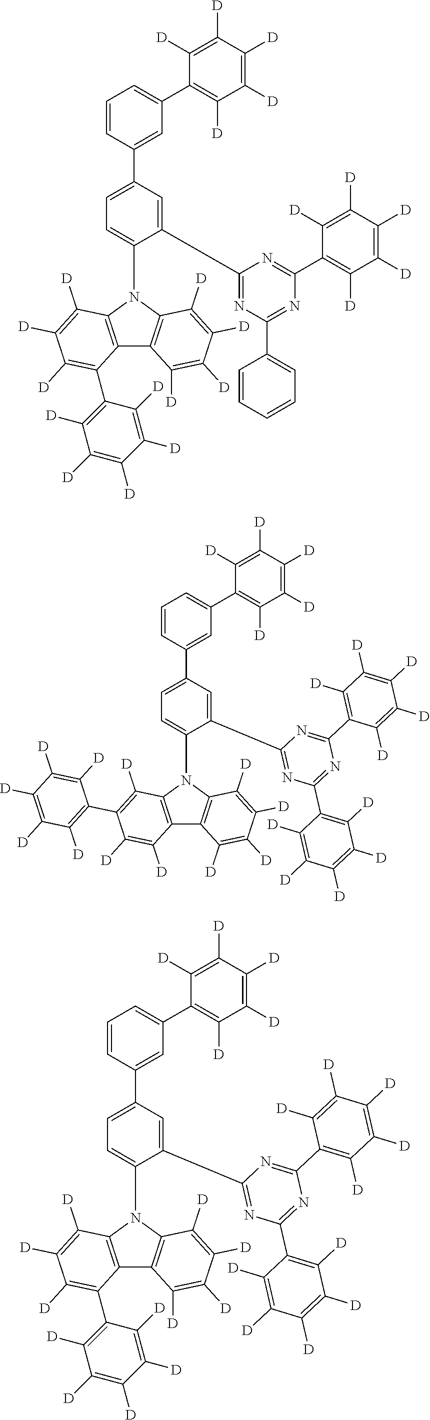

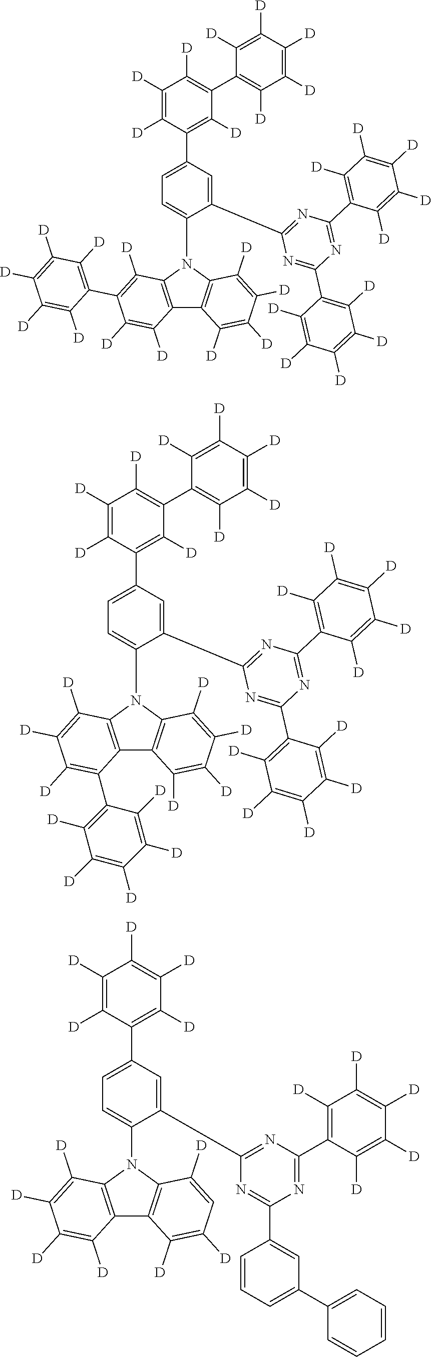

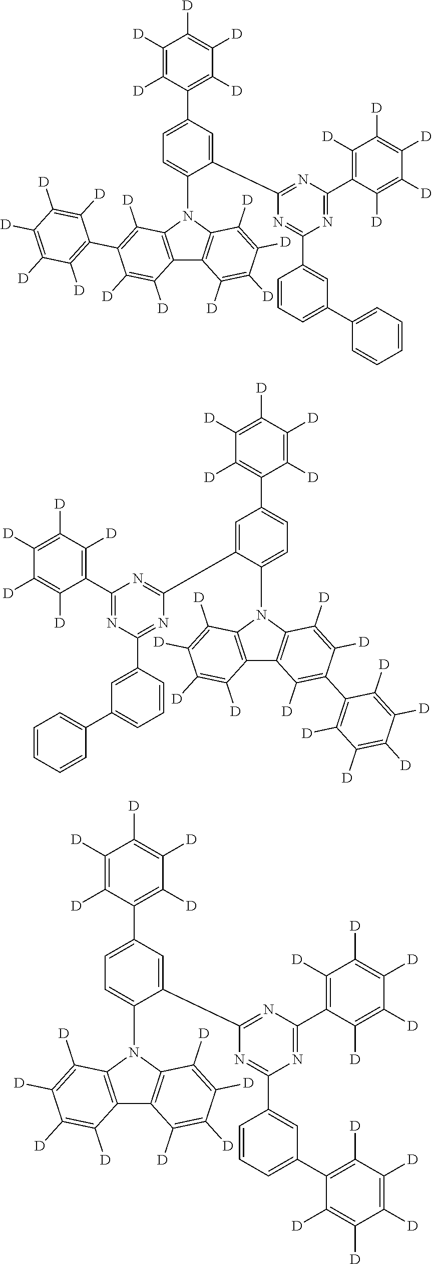

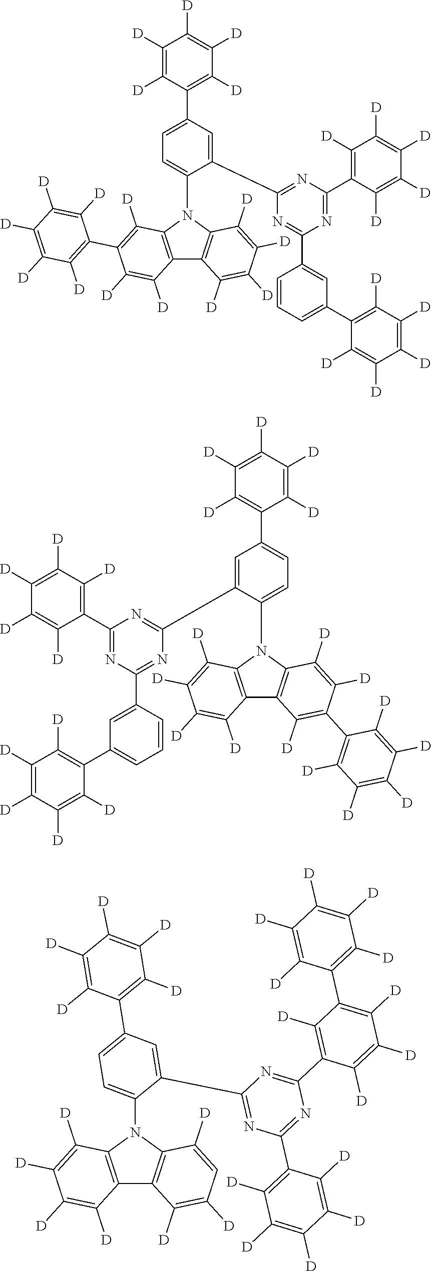

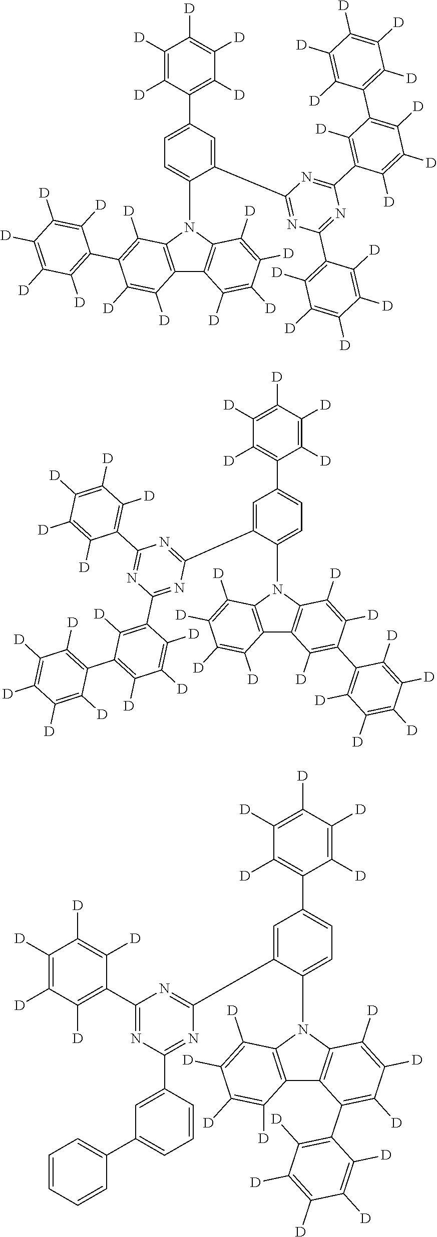

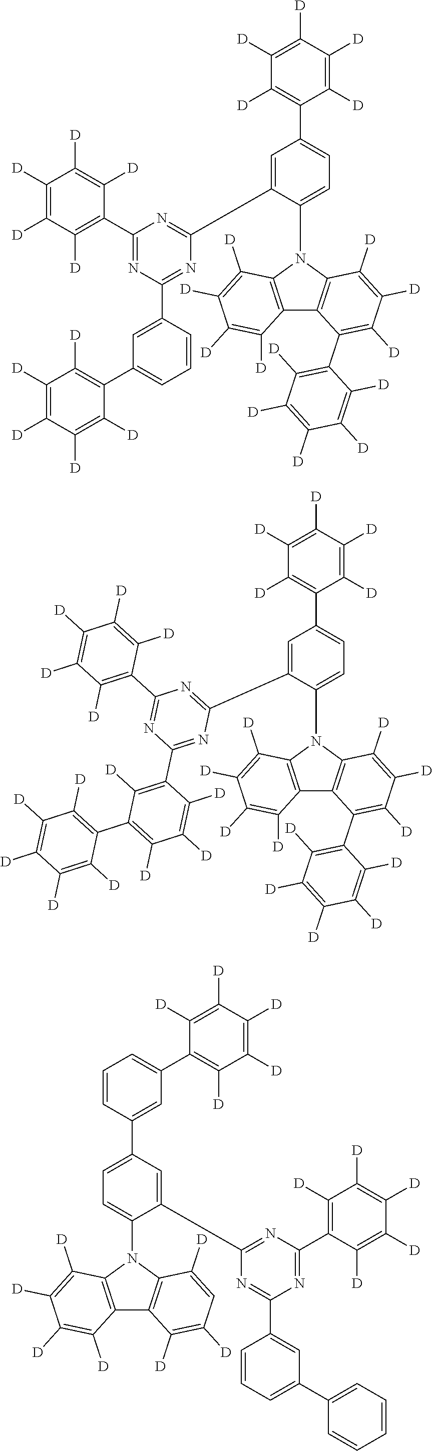

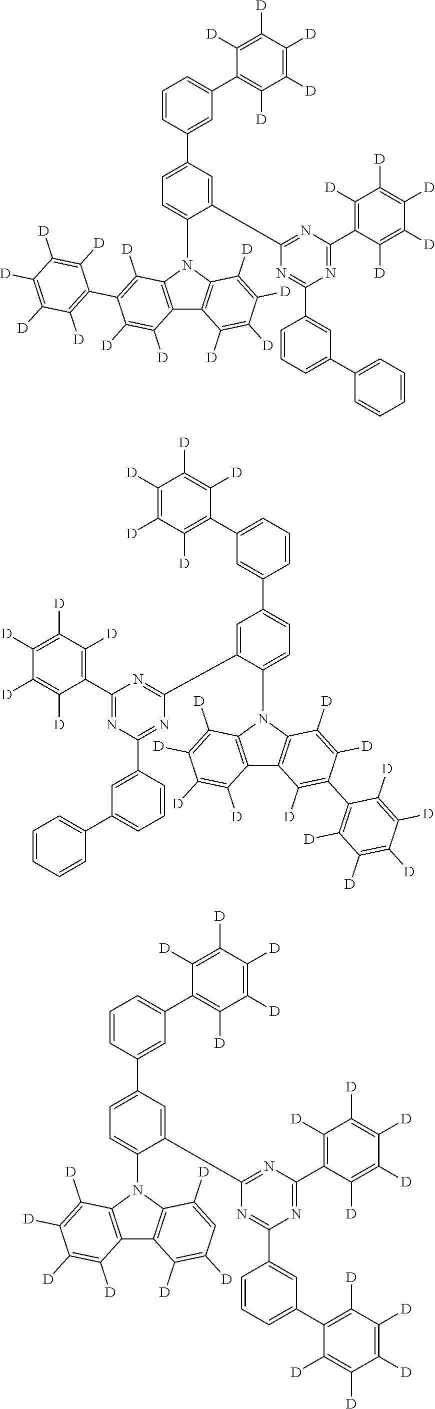

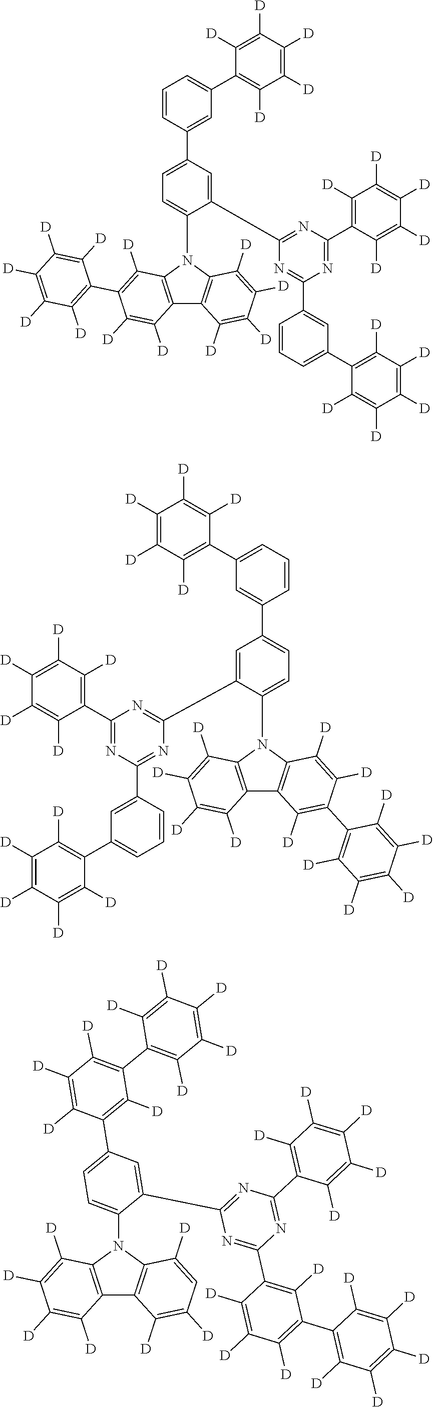

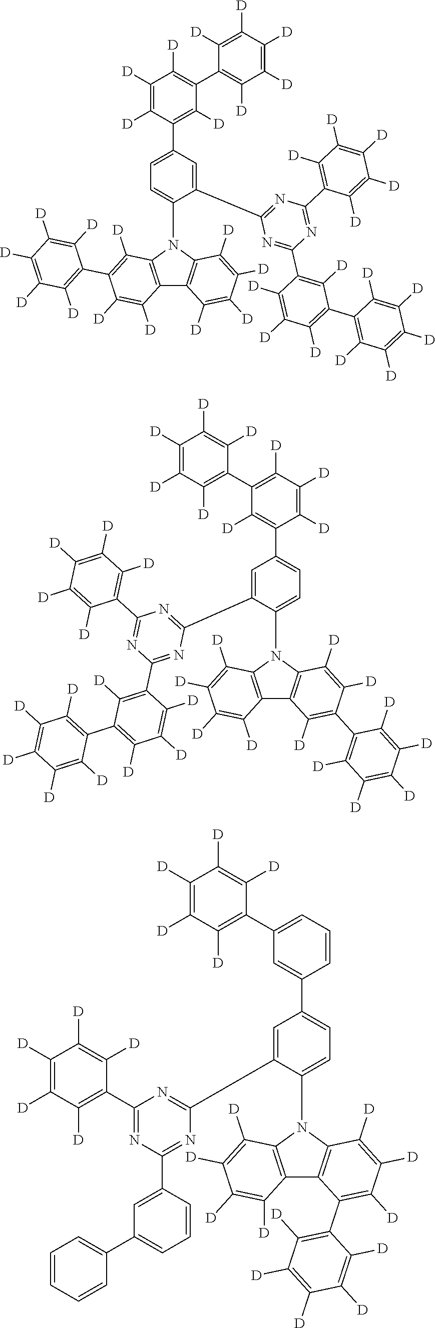

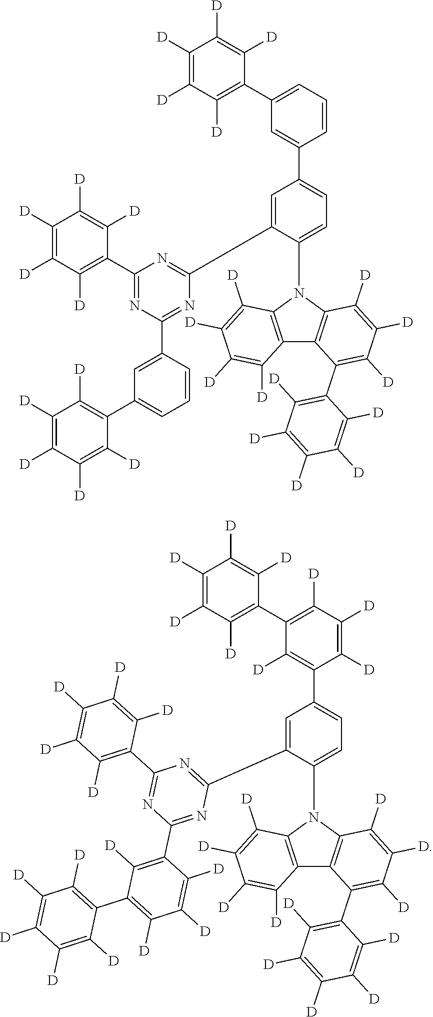

12. The composition for an organic light emitting device according to claim 1, wherein:
a weight ratio of the first compound and the second compound is 90:10 to 10:90.

13. The composition for an organic light emitting device according to claim 1, wherein:
the composition is a mixture or an organic alloy.

14. An organic light emitting device, comprising:
an anode;
a cathode provided opposite the anode; and
one or more organic material layers provided between the anode and the cathode,
wherein one or more layers of the organic material layers comprise the composition for an organic light emitting device according to claim 1.

15. The organic light emitting device according to claim 14, wherein:
the organic material layer comprising the composition for an organic light emitting device is a light emitting layer.

16. An organic light emitting device, comprising:
an anode;
a cathode provided opposite the anode; and
a light emitting layer provided between the anode and the cathode,
wherein the light emitting layer comprises a first compound represented by the following Chemical Formula 1 and a second compound represented by the following Chemical Formula 2: 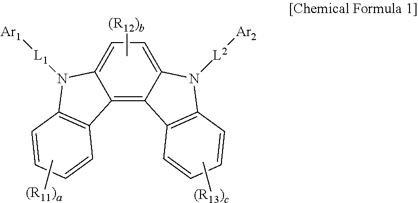
wherein in the Chemical Formula 1,
Ar₁ and Ar₂ are each independently a substituted or unsubstituted C₆₋₆₀ aryl; or a substituted or unsubstituted C₂₋₆₀ heteroaryl containing any one or more selected from the group consisting of N, O and S,
L₁ and L₂ are each independently a single bond; or a substituted or unsubstituted C₆₋₆₀ arylene,
R₁₁, R₁₂ and R₁₃ are each independently deuterium,
a and c are each independently an integer of 0 to 4,
b is an integer of 0 to 2, and 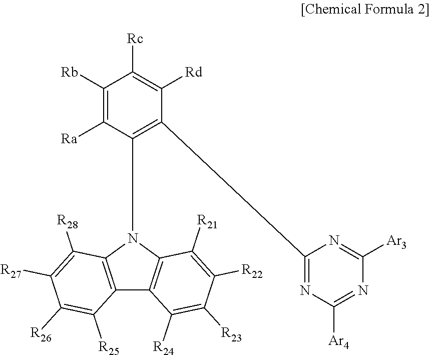
wherein in Chemical Formula 2,
Ar₃ and Ar₄ are each independently a substituted or unsubstituted C₆₋₁₅ aryl, Rₐ and R_{d} are each independently hydrogen; deuterium; or a substituted or unsubstituted C₆₋₆₀ aryl,
R_{b} is hydrogen or deuterium,
R_{c} is hydrogen; deuterium; or a C₆₋₆₀ aryl unsubstituted or substituted with deuterium,
R₂₁ to R₂₈ are each independently hydrogen; deuterium; or a substituted or unsubstituted C₆₋₆₀ aryl, provided that at least one of R₂₁ to R₂₈ is deuterium or a C₆₋₆₀ aryl substituted with deuterium, and
the second compound is substituted with six or more deuteriums.
